(19) United States
(12) Patent Application Publication
(10) Pub. No.: US 2024/0190905 A1
(43) Pub. Date: Jun. 13, 2024

(54) ORGANOMETALLIC COMPOUND, LIGHT-EMITTING DEVICE INCLUDING THE ORGANOMETALLIC COMPOUND, AND ELECTRONIC APPARATUS AND ELECTRONIC EQUIPMENT INCLUDING THE LIGHT-EMITTING DEVICE

(71) Applicant: Samsung Display Co., LTD., Yongin-si (KR)

(72) Inventors: Dongsun Yoo, Yongin-si (KR); Sooryun Cho, Yongin-si (KR); Gyeongheon Kim, Yongin-si (KR); Sohae Kim, Yongin-si (KR); Jihye Kim, Yongin-si (KR); Hoilim Kim, Yongin-si (KR); Saerom Park, Yongin-si (KR); Yongsub Shim, Yongin-si (KR)

(21) Appl. No.: 18/323,291

(22) Filed: May 24, 2023

(30) Foreign Application Priority Data
Oct. 20, 2022 (KR) 10-2022-0135842

(51) Int. Cl. C07F 15/00; H10K 50/11; H10K 50/30; H10K 85/30

(52) U.S. Cl. CPC C07F 15/0033; H10K 50/11; H10K 50/30; H10K 85/342

(57) ABSTRACT

Provided are an organometallic compound, a light-emitting device including the same, and an electronic apparatus and electronic equipment that include the light-emitting device. The organometallic compound includes iridium and emits a first light, wherein a photoluminescence (PL) spectrum of the first light has a first peak (Iₘₐₓ) having a maximum intensity and a second peak (I_{2nd}) having a second highest intensity, and the organometallic compound satisfies Condition 1 and at least one selected from Conditions 2 and 3: Condition 1: a wavelength of the first peak is in a range of 515 nm to 530 nm; Condition 2: an intensity of the second peak is at least 40% and not more than 60% compared to an intensity of the first peak; and Condition 3: a reorganization energy value of the organometallic compound is less than or equal to 0.22 eV.

### CROSS-REFERENCE TO RELATED APPLICATION

This application claims priority to and the benefit of Korean Patent Application No. 10-2022-0135842, filed on Oct. 20, 2022, in the Korean Intellectual Property Office, the entire content of which is incorporated by reference herein in its entirety.

### BACKGROUND

### 1. Field

One or more embodiments of the present disclosure relate to an organometallic compound, a light-emitting device including the organometallic compound, and an electronic apparatus and electronic equipment that include the light-emitting device.

### 2. Description of the Related Art

Self-emissive devices (for example, organic light-emitting devices and the like) among light-emitting devices not only have wide viewing angles and high contrast ratios, but also have short response times, and have excellent characteristics in terms of luminance, driving voltage, and response speed.

In a light-emitting device, a first electrode is on a substrate, and a hole transport region, an emission layer, an electron transport region, and a second electrode are sequentially on the first electrode. Holes provided from the first electrode move toward the emission layer through the hole transport region, and electrons provided from the second electrode move toward the emission layer through the electron transport region. Carriers, such as holes and electrons, recombine in the emission layer to produce excitons. These excitons transition from an excited state to a ground state to thereby generate light.

### SUMMARY

One or more embodiments of the present disclosure include an organometallic compound capable of providing low full width at half maximum and excellent electrical characteristics, a light-emitting device having excellent top-emission efficiency characteristics, and an electronic apparatus and electronic equipment that include the light-emitting device.

Additional aspects of embodiments will be set forth in part in the description which follows and, in part, will be apparent from the description, or may be learned by practice of the presented embodiments of the disclosure.

According to one or more embodiments, an organometallic compound includes iridium, wherein:
the organometallic compound may emit a first light,
a photoluminescence (PL) spectrum of the first light may have a first peak (Iₘₐₓ) having a maximum intensity and a second peak (I_{2nd}) having a second highest intensity, and
the organometallic compound may satisfy Condition 1 and at least one selected from Conditions 2 and 3:

### Condition 1

a wavelength of the first peak is in a range of 515 nm to 530 nm,

### Condition 2

an intensity of the second peak is at least 40% and not more than 60% compared to an intensity of the first peak, and

### Condition 3

a reorganization energy value of the organometallic compound is less than or equal to 0.22 eV.

According to one or more embodiments, an organometallic compound includes iridium, wherein:
the organometallic compound may include a first ligand, a second ligand, and a third ligand, each bonded to iridium,
the first ligand may be a bidentate ligand including ring B₁ and ring B₂,
the second ligand may be a bidentate ligand including ring B₃ and ring B₄,
the third ligand may be a bidentate ligand including ring B₅ and ring B₆,
ring B₂ may be a polycyclic group including at least one nitrogen atom (N),
ring B₃ and ring B₄ may be linked to each other via linkers T₁ and T₂, and
T₁ may be an alkylene group, and T₂ may be a single bond.

According to one or more embodiments, a light-emitting device includes a first electrode,
a second electrode facing the first electrode,
an interlayer between the first electrode and the second electrode, and
the organometallic compound.

According to one or more embodiments, an electronic apparatus includes the light-emitting device.

According to one or more embodiments, electronic equipment includes the light-emitting device.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a schematic cross-sectional view showing a structure of a light-emitting device according to one or more embodiments;

FIG. 2 is a schematic cross-sectional view showing a structure of an electronic apparatus according to one or more embodiments;

FIG. 3 shows a schematic cross-sectional view showing a structure of an electronic apparatus according to another embodiment;

FIG. 4 is a schematic perspective view of electronic equipment including a light-emitting device according to one or more embodiments;

FIG. 5 is a diagram illustrating an exterior of a vehicle as electronic equipment including a light-emitting device according to one or more embodiments;

FIGS. 6A to 6C are each a diagram schematically illustrating an interior of a vehicle according to various embodiments;

FIG. 7 is a diagram for explaining a method of deriving reorganization energy according to a density functional theory (DFT) calculation;

FIG. 8 is a diagram showing reorganization energy relative to a maximum emission wavelength (e.g., a wavelength of a first peak) of a light-emitting device of each of Examples 1 to 10 and Comparative Examples 1 to 9; and

FIG. 9 is a diagram showing top-emission efficiency relative to a maximum emission wavelength (e.g., a wavelength of a first peak) of a light-emitting device of each of Examples 1 to 10 and Comparative Examples 1 to 9.

### DETAILED DESCRIPTION

Reference will now be made in more detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of embodiments of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

An aspect of embodiments of the disclosure provides an organometallic compound includes iridium, wherein:
the organometallic compound may emit a first light,
a photoluminescence (PL) spectrum of the first light has a first peak (Iₘₐₓ) having a maximum intensity and a second peak (I_{2nd}) with a second highest intensity, and
the organometallic compound may satisfy Condition 1 and at least one selected from Conditions 2 and 3:

### Condition 1

a wavelength of the first peak is in a range of about 515 nm to about 530 nm;

### Condition 2

an intensity of the second peak is at least about 40% and not more than about 60% compared with an intensity of the first peak and

### Condition 3

a reorganization energy value of the organometallic compound is less than or equal to about 0.22 eV.

In a case where the wavelength of the first peak of the first light emitted by the organometallic compound is in a range of 515 nm to 530 nm and an intensity of the second peak of the first light is at least about 40% and not more than about 60% compared to an intensity of the first peak of the first light, the organometallic compound may have high color purity and small non-radiative decay due to small vibronic coupling, and accordingly, excellent photoluminescence quantum yield (PLQY) may be obtained.

In addition, in a case where the wavelength of the first peak of the first light emitted by the organometallic compound is in a range of 515 nm to 530 nm and the reorganization energy of the organometallic compound is satisfied within a range of less than or equal to about 0.22 eV, the organometallic compound may have a small full width at half maximum (FWHM) due to a small structural change caused by excitation and small non-radiative decay due to small vibronic coupling, and accordingly, excellent PLQY may be obtained.

Accordingly, a light-emitting device including the organometallic compound may have excellent top-emission efficiency (at 0°), and thus a high-quality electronic apparatus may be manufactured by using such a light-emitting device.

In the specification, the peak wavelength (or maximum emission wavelength) and peak intensity of the first light may be evaluated from an emission spectrum of a film including the organometallic compound. See, e.g., Evaluation Example 2.

The term “first peak” as used herein refers to a peak having a maximum intensity in the PL spectrum of the first light. The first peak may be separated by fitting the PL spectrum to a normal distribution in a region with a wavelength smaller than a wavelength of the maximum intensity. The central wavelength of the separated first peak corresponds to λ₁, and the intensity of the separated first peak corresponds to I₁.

The term “second peak” as used herein refers to a peak having the second maximum intensity in the PL spectrum of the first light. The second peak may be separated by fitting the PL spectrum to a normal distribution in a region of [λ₁, λ₁+60 nm]. The central wavelength of the separated second peak corresponds to λ₂, and the intensity of the separated second peak corresponds to I₂.

Accordingly, the organometallic compound may satisfy Equation 1:

0.40≤I₂/I₁≤0.60. Equation 1

In one or more embodiments, λ₂ may satisfy a range of [λ₁+30 nm, λ₁+40 nm].

The term “reorganization energy” may be calculated according to Equation 2 through calculation based on (e.g., performed utilizing) density functional theory (DFT):

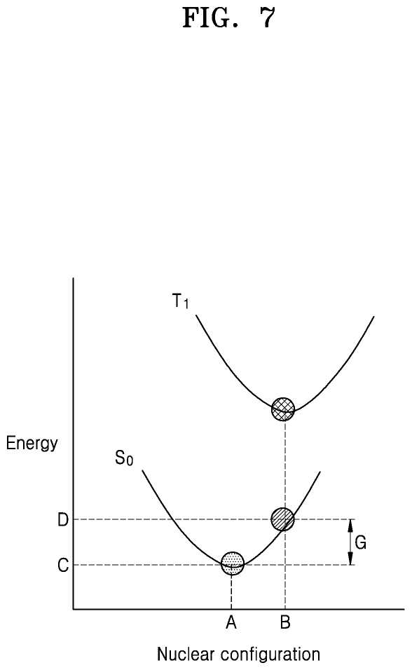

G=E(S0;T₁)−E(S0;S0) Equation 2
wherein, in Equation 2,
G represents a reorganization energy value of the organometallic compound, and
E(S0;S0) represents an energy value of the S0 state in the S0 structure of the organometallic compound (corresponding to C in FIG. 7), and E(S0;T₁) represents an energy value of the S0 state in the T₁ structure of the organometallic compound (corresponding to D in FIG. 7).

The S0 structure corresponds to the structure having the lowest energy in the S0 state (corresponding to A point in FIG. 7), and the T₁ structure corresponds to the structure having the lowest energy in the T₁ state (corresponding to point B in FIG. 7).

In one or more embodiments, the first light may be green light.

In one or more embodiments, the wavelength (maximum emission wavelength or maximum emission peak wavelength) of the first peak may be in a range of about 515 nm to about 530 nm.

For example, the emission peak wavelength of the first light may be in a range of 515 nm to 530 nm or 520 nm to 530 nm.

In one or more embodiments, the FWHM of the first light may be at least about 15 nm and not more than about 60 nm.

For example, the FWHM of the first light may be in a range of 20 nm to 60 nm, 25 nm to 60 nm, 30 nm to 60 nm, 35 nm to 60 nm, 40 nm to 60 nm, 45 nm to 60 nm, 45 nm to 55 nm, or 50 nm to 60 nm.

In one or more embodiments, the triplet energy of the organometallic compound may be at least about 2.42 eV or not more than about 2.48 eV.

For example, the triplet energy of the organometallic compound may be at least 2.42 eV and not more than 2.48 eV, at least 2.42 eV and not more than 2.47 eV, at least 2.42 eV and not more than 2.46 eV, or at least 2.42 eV and not more than 2.45 eV.

In one or more embodiments, the organometallic compound may include a first ligand, a second ligand, and a third ligand that are each bonded to iridium, wherein the first ligand may be a bidentate ligand including ring B₁ and ring B₂,
the second ligand may be a bidentate ligand including ring B₃ and ring B₄,
the third ligand may be a bidentate ligand including ring B₅ and ring B₆,
ring B₂ may be a polycyclic group including at least one nitrogen atom (N),
ring B₃ and ring B₄ may be linked to each other via linkers T₁ and T₂, and
T₁ may be an alkylene group, and T₂ may be a single bond.

The first ligand, the second ligand, and the third ligand may are further described in the descriptions herein below.

Another aspect of embodiments of the disclosure provides an organometallic compound including iridium, wherein:
the organometallic compound may include a first ligand, a second ligand, and a third ligand that are each bonded to iridium,
the first ligand may be a bidentate ligand including ring B₁ and ring B₂,
the second ligand may be a bidentate ligand including ring B₃ and ring B₄,
the third ligand may be a bidentate ligand including ring B₅ and ring B₆,
ring B₂ may be a polycyclic group including at least one nitrogen atom (N),
ring B₃ and ring B₄ may be linked to each other via linkers T₁ and T₂, and
T₁ may be an alkylene group, and T₂ may be a single bond.

In one or more embodiments, the organometallic compound may satisfy at least one selected from Conditions 1 to 3:

### Condition 1

the organometallic compound emits a first light,
a photoluminescence (PL) spectrum of the first light has a first peak (Iₘₐₓ) having a maximum intensity and a second peak (I_{2nd}) with a second highest intensity, and
an intensity of the second peak is at least about 40% and not more than about 60% compared to an intensity of the first peak; and

### Condition 2

the organometallic compound emits a first light,
a photoluminescence (PL) spectrum of the first light has a first peak (Iₘₐₓ) having maximum intensity, and a wavelength of the first peak is in a range of about 515 nm to about 530 nm; and

### Condition 3

a reorganization energy value of the organometallic compound is less than or equal to about 0.22 eV.

For example, the organometallic compound may satisfy: i) Condition 1, Condition 2, or Condition 3; ii) Condition 1 and Condition 2; Condition 1 and Condition 3; or Condition 2 and Condition 3; or iii) Condition 1, Condition 2, and Condition 3.

In one or more embodiments, the organometallic compound may be a heteroleptic complex.

In one or more embodiments, the first ligand and the second ligand may be different from each other.

In one or more embodiments, the third ligand may be identical to the second ligand.

In one or more embodiments, the third ligand may be identical to the first ligand.

In one or more embodiments, the third ligand may be different from each of the first ligand and the second ligand.

In one or more embodiments, ring B₂ may include at least one nitrogen atom (N), and may be a polycyclic group in which three or more monocyclic groups are condensed to one another.

In one or more embodiments, ring B₂ may be a polycyclic group in which at least one cyclic group in Group A1 and at least one cyclic group in Group A2 are condensed together with each other:

### Group A1

a pyridine group, a pyrimidine group, a pyrazine group, a pyridazine group, and a triazine group; and

### Group A2

a benzene group, a naphthalene group, a pyrrole group, a cyclopentadiene group, a borole group, a phosphole group, a silole group, a selenophene group, a furan group, a thiophene group, a pyridine group, a pyrimidine group, a pyrazine group, a pyridazine group, and a triazine group.

In one or more embodiments, ring B₂ may be a pyridine group, a pyrimidine group, a pyrazine group, a pyridazine group, or a triazine group, each condensed together with a benzene group, a naphthalene group, a pyrrole group, a cyclopentadiene group, a borole group, a phosphole group, a selenophene group, a furan group, a thiophene group, a pyridine group, a pyrimidine group, a pyrazine group, a pyridazine group, a triazine group, or any combination thereof.

For example, ring B₂ may be an azaindole group, an azaindene group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzofuran group, an azadibenzothiophene group, an azadibenzoselenophene group, an azacarbazole group, an azafluorene group, an azadibenzosilole group, an azanaphthobenzofuran group, an azanaphthobenzothiophene group, an azanaphthobenzoselenophene group, an azabenzocarbazole group, an azabenzofluorene group, an azabenzodibenzosilole group, an azadinaphthofuran group, an azadinaphthothiophene group, an azadinaphthoselenophene group, an azadibenzocarbazole group, an azadibenzofluorene group, an azadinaphthosilole group, an azaphenanthrenobenzofuran group, an azaphenanthrenobenzothiophene group, an azaphenanthrenobenzoselenophene group, an azanaphthocarbazole group, an azanaphthofluorene group, or azaphenanthrenobenzosilole group.

In one or more embodiments, ring B₁, ring B₃, and ring B₅ may each independently be:
a pyridine group, a pyrimidine group, a pyrazine group, a pyridazine group, or a triazine group; or
a pyridine group, a pyrimidine group, a pyrazine group, a pyridazine group, or a triazine group, each condensed together with a cyclopentane group, a cyclohexane group, a norbornane group, a benzene group, a pyridine group, a pyrimidine group, a pyrazine group, a pyridazine group, a triazine group, a furan group, a thiophene group, a selenophene group, a pyrrole group, a cyclopentadiene group, a silole group, or any combination thereof.

In one or more embodiments, ring B₄ and ring B₆ may each independently be:
a benzene group, a pyridine group, a pyrimidine group, a pyrazine group, or a pyridazine group; or
a benzene group, a pyridine group, a pyrimidine group, a pyrazine group, or a pyridazine group, each condensed together with a cyclopentane group, a cyclohexane group, a norbornane group, a benzene group, a pyridine group, a pyrimidine group, a pyrazine group, a pyridazine group, a furan group, a thiophene group, a selenophene group, a pyrrole group, a cyclopentadiene group, a silole group, or any combination thereof.

In one or more embodiments, the organometallic compound may include at least one substituent R_{X} which is not hydrogen.

In one or more embodiments, at least one selected from the first ligand, the second ligand, and the third ligand may include at least one substituent R_{X} which is not hydrogen. For example, the second ligand may include at least one substituent R_{X} which is not hydrogen.

In one or more embodiments, at least one selected from ring B₂ and ring B₃ may include a substituent R_{X} which is not hydrogen.

In one or more embodiments, R_{X} may be:
deuterium, —F, a cyano group, or a C₁-C₂₀ alkyl group;
a C₁-C₂₀ alkyl group or a C₃-C₁₀ cycloalkyl group, each substituted with deuterium, —F, a cyano group, or any combination thereof; or
a C₃-C₆₀ carbocyclic group or a C₁-C₆₀ heterocyclic group, each substituted with deuterium, —F, a cyano group, a C₁-C₂₀ alkyl group, a deuterated C₁-C₂₀ alkyl group, a fluorinated C₁-C₂₀ alkyl group, a deuterated phenyl group, a fluorinated phenyl group, a (C₁-C₂₀ alkyl)phenyl group, a deuterated biphenyl group, a fluorinated biphenyl group, or any combination thereof.

In one or more embodiments, the organometallic compound may include at least one selected from deuterium, —F, a cyano group, and a C₁-C₂₀ alkyl group.

In one or more embodiments, at least one selected from the first ligand, the second ligand, and the third ligand may include at least one selected from deuterium, —F, a cyano group, and a C₁-C₂₀ alkyl group.

In one or more embodiments, T₁ may include a substituted or unsubstituted methylene group or a substituted or unsubstituted ethylene group.

### Description of Formula

An aspect of embodiments of the disclosure provides the organometallic compound represented by Formula 1:

Ir(L₁)(L₂)(L₃) Formula 1
wherein, in Formula 1,
L₁ may be bonded to Ir in Formula 1, and may be a first ligand represented by Formula 1-1,
L₂ may be bonded to Ir in Formula 1, and may be a second ligand represented by Formula 1-2, and
L₃ may be bonded to Ir in Formula 1, and may be a third ligand represented by Formula 1-3:

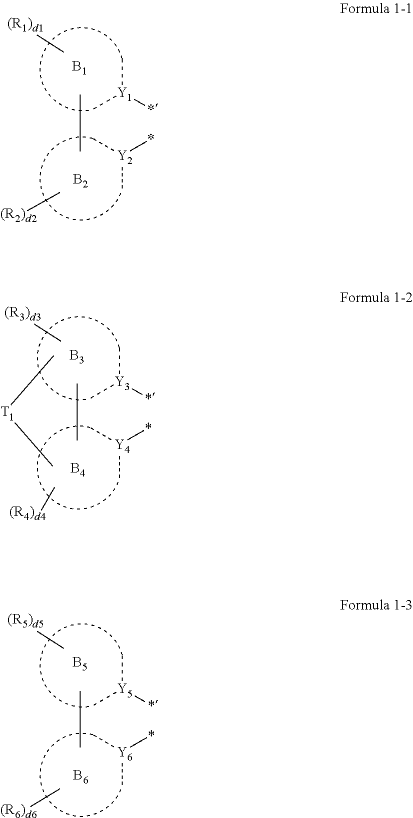

where, in Formulae 1-1 to 1-3,
Y₁ to Y₆ may each independently be C or N,
ring B₁ and B₃ to B₆ may each independently be a C₅-C₃₀ carbocyclic group or a C₁-C₃₀ heterocyclic group,
ring B₂ may be a polycyclic group including at least one nitrogen (N),
T₁ may be *″-[(CZ₁)(CZ₂)]ₖ₁—*″,
R₁ to R₆ and Z₁ and Z₂ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —P(Q₁)(Q₂), —C(═O)(Q₁), —S(═O)₂(Q₁), or —P(═O)(Q₁)(Q₂),
d1 to d6 may each independently be an integer from 0 to 10,
R₁₀ₐ is the same as described herein,
k1 may be an integer from 1 to 3,
* and *″ each indicate a binding site to a neighboring atom, and
*′″ and *″″ each indicate a binding site to a neighboring atom.

In one or more embodiments, the organometallic compound represented by Formula 1 may be a heteroleptic complex.

In one or more embodiments, in Formula 1,
i) L₃ may be identical to L₂,
ii) L₃ may be identical to L₁, or
iii) L₃ may be different from each of L₁ and L₂.
In one or more embodiments,
Y₁, Y₃, and Y₅ may each independently be N, and
Y₂, Y₄, and Y₆ may each independently be C.

In one or more embodiments, ring B₂ may be a polycyclic group in which at least one cyclic group in Group A1 and at least one cyclic group in Group A2 are condensed together with each other:

### Group A1

a pyridine group, a pyrimidine group, a pyrazine group, a pyridazine group, and a triazine group; and

### Group A2

a benzene group, a naphthalene group, a pyrrole group, a cyclopentadiene group, a borole group, a phosphole group, a silole group, a selenophene group, a furan group, a thiophene group, a pyridine group, a pyrimidine group, a pyrazine group, a pyridazine group, and a triazine group.

In one or more embodiments, ring B₂ may be a pyridine group, a pyrimidine group, a pyrazine group, a pyridazine group, or a triazine group, each condensed together with a benzene group, a naphthalene group, a pyrrole group, a cyclopentadiene group, a borole group, a phosphole group, a selenophene group, a furan group, a thiophene group, a pyridine group, a pyrimidine group, a pyrazine group, a pyridazine group, a triazine group, or any combination thereof.

For example, ring B₂ may be an azaindole group, an azaindene group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzofuran group, an azadibenzothiophene group, an azadibenzoselenophene group, an azacarbazole group, an azafluorene group, an azadibenzosilole group, an azanaphthobenzofuran group, an azanaphthobenzothiophene group, an azanaphthobenzoselenophene group, an azabenzocarbazole group, an azabenzofluorene group, an azabenzodibenzosilole group, an azadinaphthofuran group, an azadinaphthothiophene group, an azadinaphthoselenophene group, an azadibenzocarbazole group, an azadibenzofluorene group, an azadinaphthosilole group, an azaphenanthrenobenzofuran group, an azaphenanthrenobenzothiophene group, an azaphenanthrenobenzoselenophene group, an azanaphthocarbazole group, an azanaphthofluorene group, or azaphenanthrenobenzosilole group.

In one or more embodiments, ring B₂ may be represented by one selected from Formulae B2-1 to B2-6:

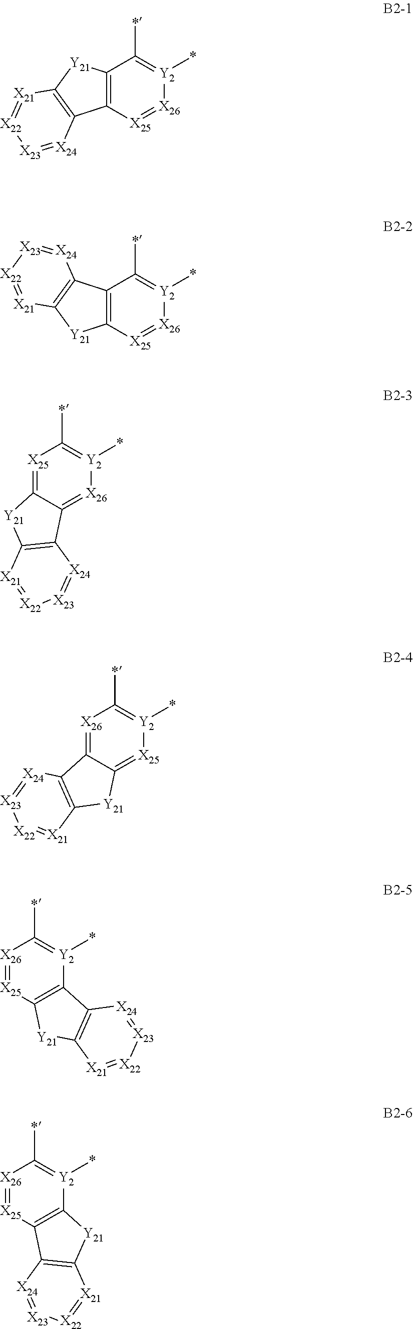

wherein, in Formulae B2-1 to B2-6,
Y₂ may be C or N,
Y₂₁ may be N(R₂₇), O, S, Se, C(R₂₇)(R₂₈), or Si(R₂₇)(R₂₈),
X₂₁ may be C(R₂₁) or N, X₂₂ may be C(R₂₂) or N, X₂₃ may be C(R₂₃) or N, X₂₄ may be C(R₂₄) or N, X₂₅ may be C(R₂₅) or N, and X₂₆ may be C(R₂₆) or N,
at least one selected from X₂₁ to X₂₆ may be N,
R₂₁ to R₂₈ are each the same as described in connection with R₂,
* indicates a binding site to iridium, and
*′ indicates a binding site to ring B₁.

In one or more embodiments, in Formulae B2-1 to B2-6, i) X₂₁, X₂₂, X₂₃, or X₂₄; ii) X₂₁ and X₂₂, X₂₁ and X₂₃, X₂₁ and X₂₄, X₂₂ and X₂₃, X₂₂ and X₂₄, or X₂₃ and X₂₄; iii) X₂₁, X₂₂, and X₂₃; X₂₁, X₂₂, and X₂₄; X₂₁, X₂₃, and X₂₄; or X₂₂, X₂₃, and X₂₄; or iv) X₂₁, X₂₂, X₂₃, and X₂₄ may each independently be N. For example, in Formulae B2-1 to B2-6, X₂₂ may be N.

In one or more embodiments, in Formulae B2-1 to B2-6, Y₂₁ may be O or S.

In one or more embodiments, ring B₁, ring B₃, and ring B₅ may each independently be:
a pyridine group, a pyrimidine group, a pyrazine group, a pyridazine group, or a triazine group; or
a pyridine group, a pyrimidine group, a pyrazine group, a pyridazine group, or a triazine group, each condensed together with a cyclopentane group, a cyclohexane group, a norbornane group, a benzene group, a pyridine group, a pyrimidine group, a pyrazine group, a pyridazine group, a triazine group, a furan group, a thiophene group, a selenophene group, a pyrrole group, a cyclopentadiene group, a silole group, or any combination thereof.

In one or more embodiments, ring B₄ and ring B₆ may each independently be:
a benzene group, a pyridine group, a pyrimidine group, a pyrazine group, or a pyridazine group; or
a benzene group, a pyridine group, a pyrimidine group, a pyrazine group, or a pyridazine group, each condensed together with a cyclopentane group, a cyclohexane group, a norbornane group, a benzene group, a pyridine group, a pyrimidine group, a pyrazine group, a pyridazine group, a furan group, a thiophene group, a selenophene group, a pyrrole group, a cyclopentadiene group, a silole group, or any combination thereof.

In one or more embodiments, a group represented by

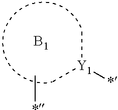

in Formula 1-1 and a group represented by

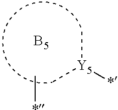

in Formula 1-3 may each independently be one selected from groups represented by Formulae BB-1 to BB-52:

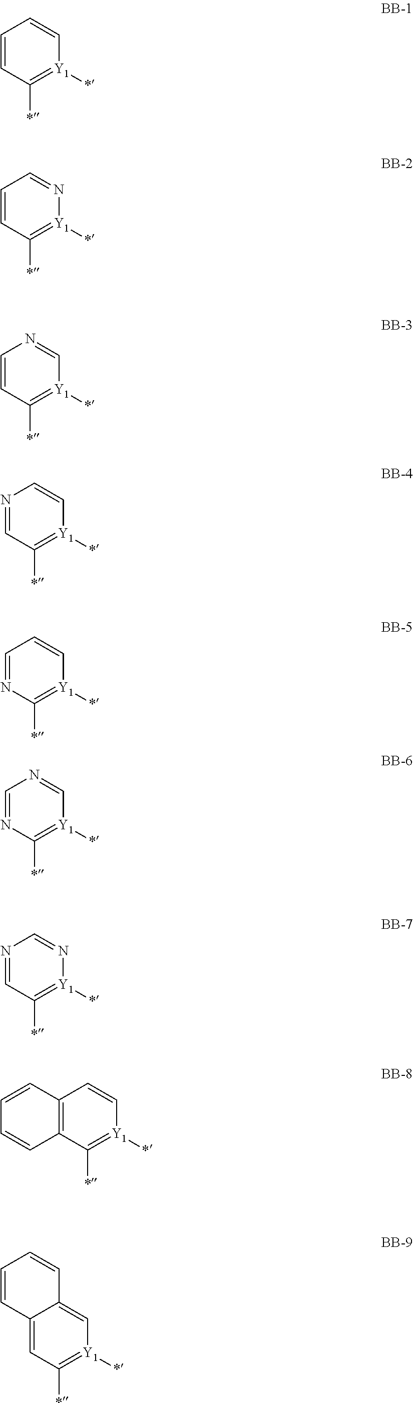

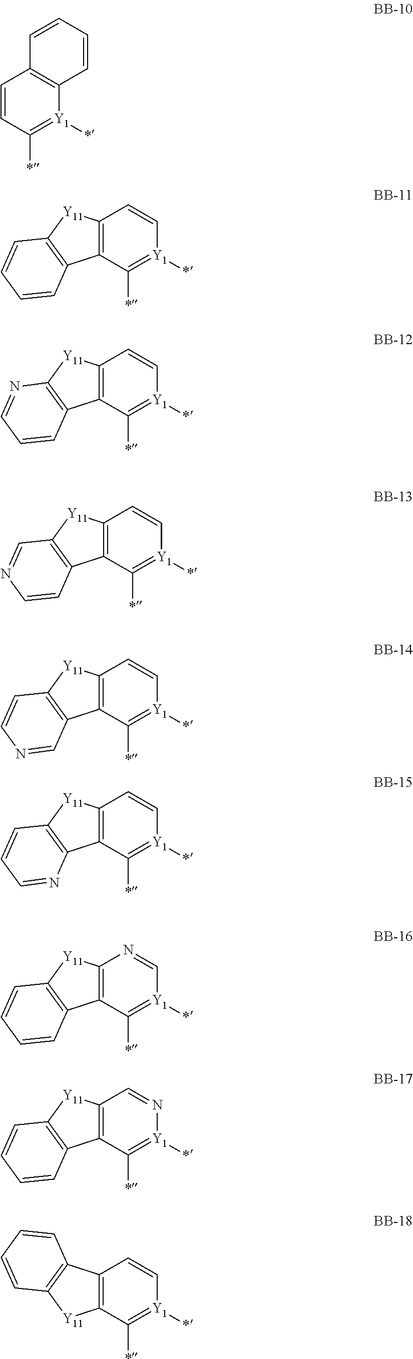

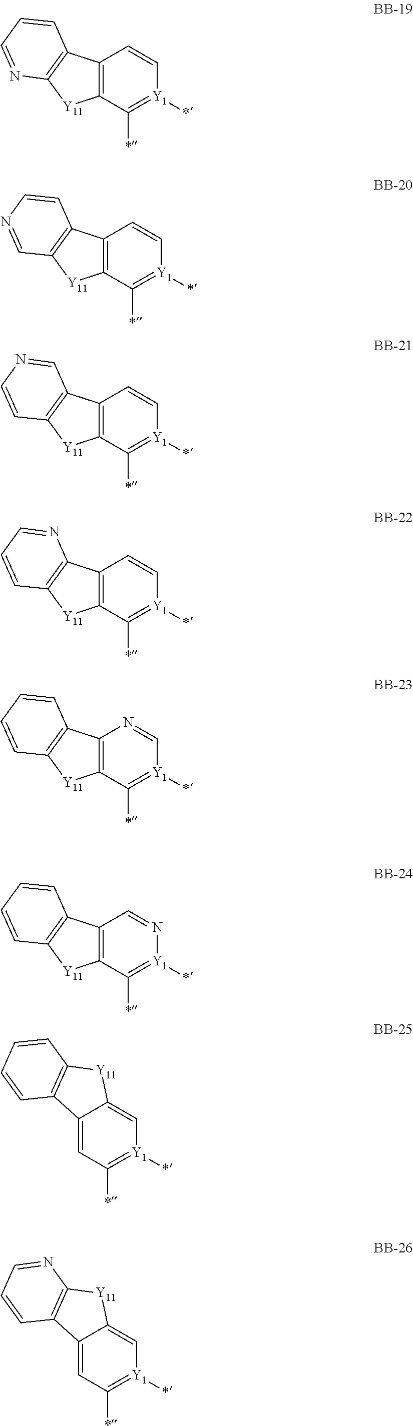

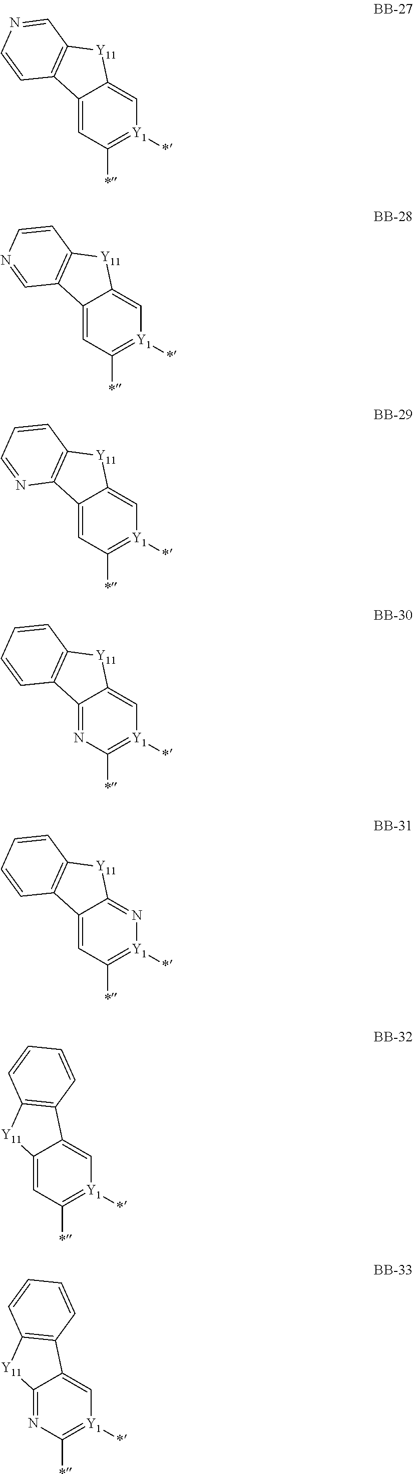

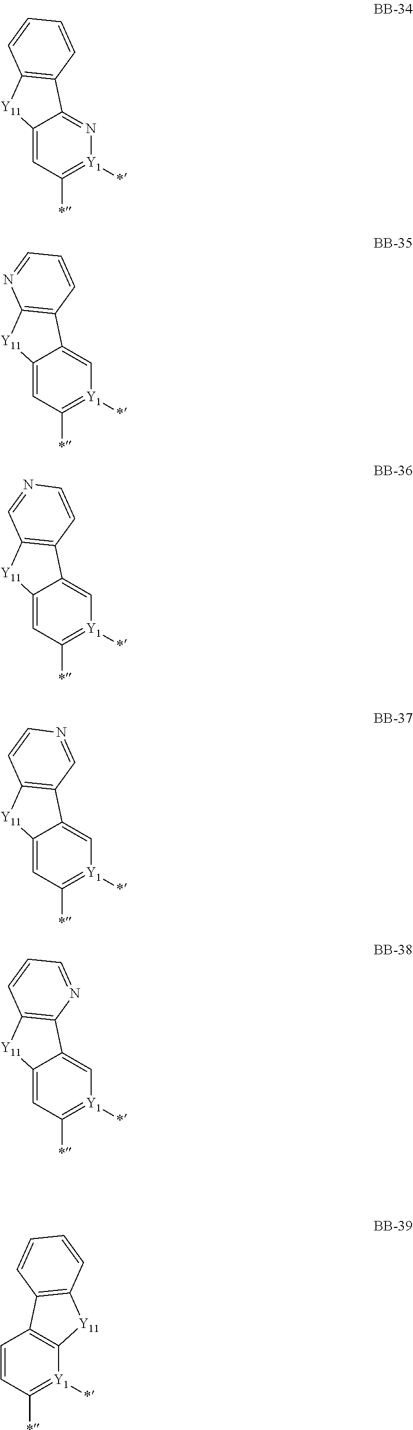

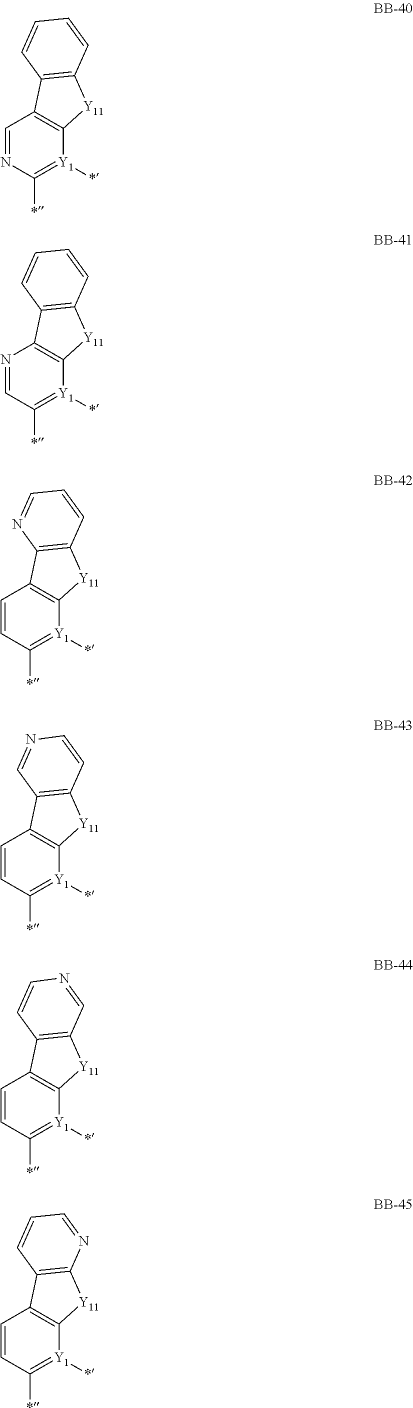

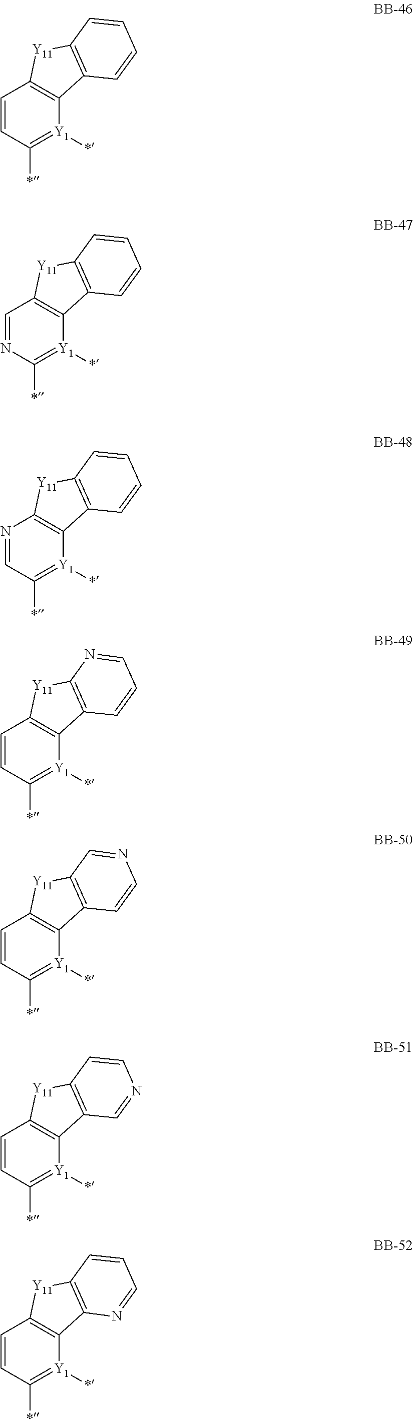

wherein, in Formulae BB-1 to BB-52,
Y₁ may be C or N,
Y₁₁ may be 0, S, Se, N(R₁₁ₐ), C(R₁₁ₐ)(R_{11b}), or Si(R₁₁ₐ)(R_{11b}),
R₁₁ₐ and R_{11b} are each independently the same as described in connection with R₁ or R₅,
*′ indicates a binding site to iridium in Formula 1, and
*″ indicates a binding site to a neighboring atom in Formula 1.

The groups represented by Formulae BB-1 to BB-52 may each be unsubstituted or substituted with a substituent, such as R₁ or R₅ described herein, and in this regard, may be easily understood by referring to the structures of Formulae 1-1 and 1-3.

In one or more embodiments, a group represented by

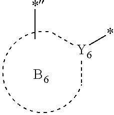

in Formula 1-3 may be one selected from groups represented by Formulae BC-1 to BC-52:

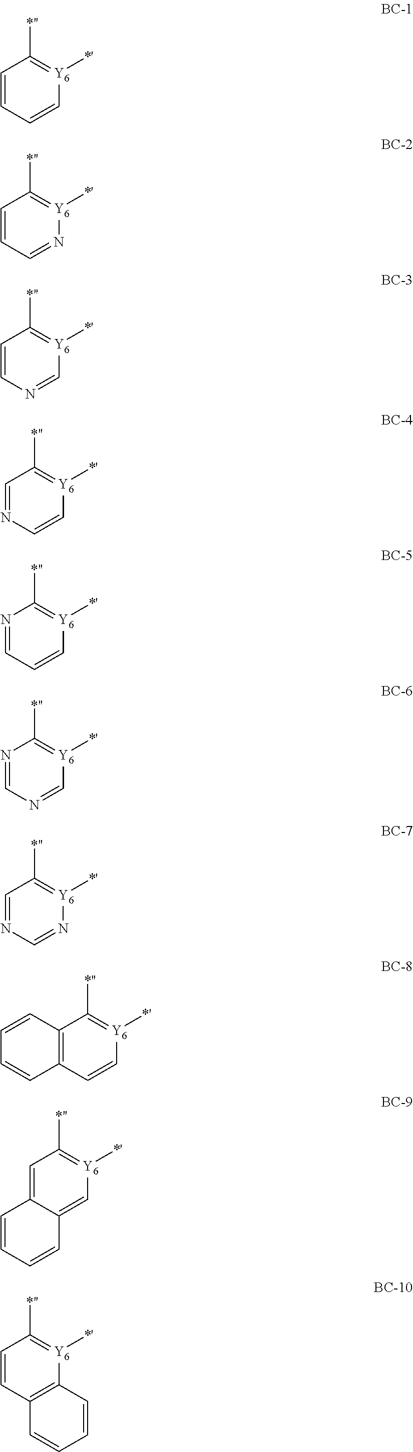

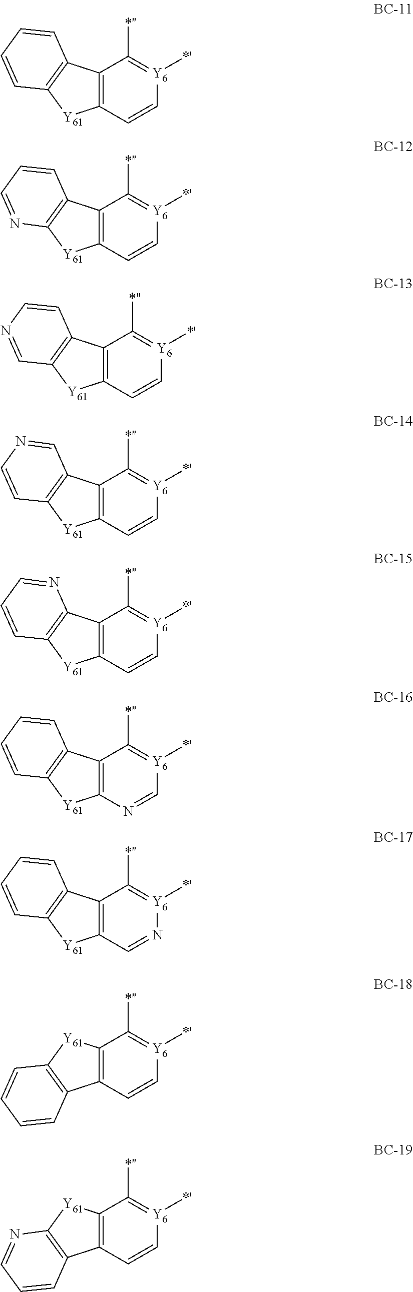

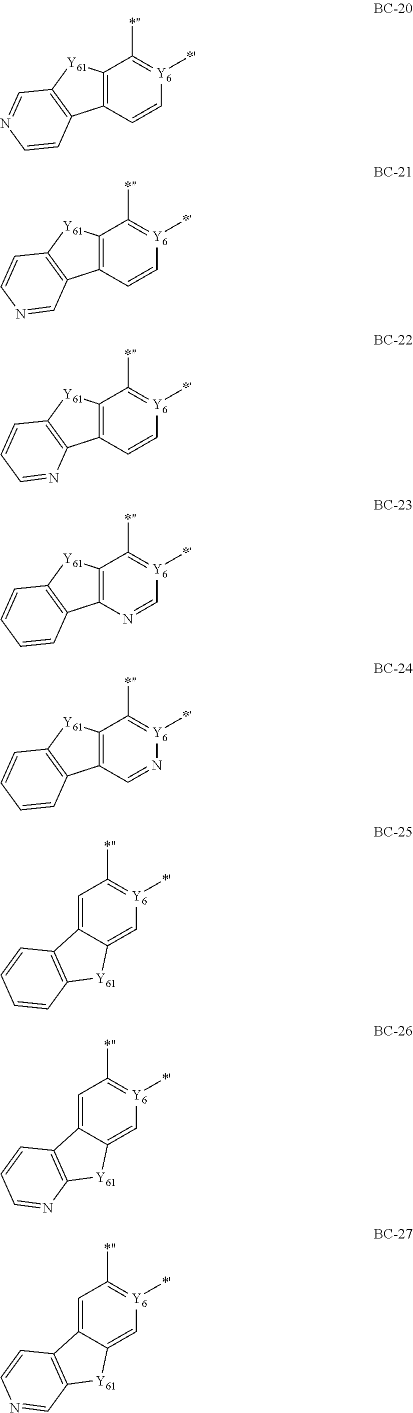

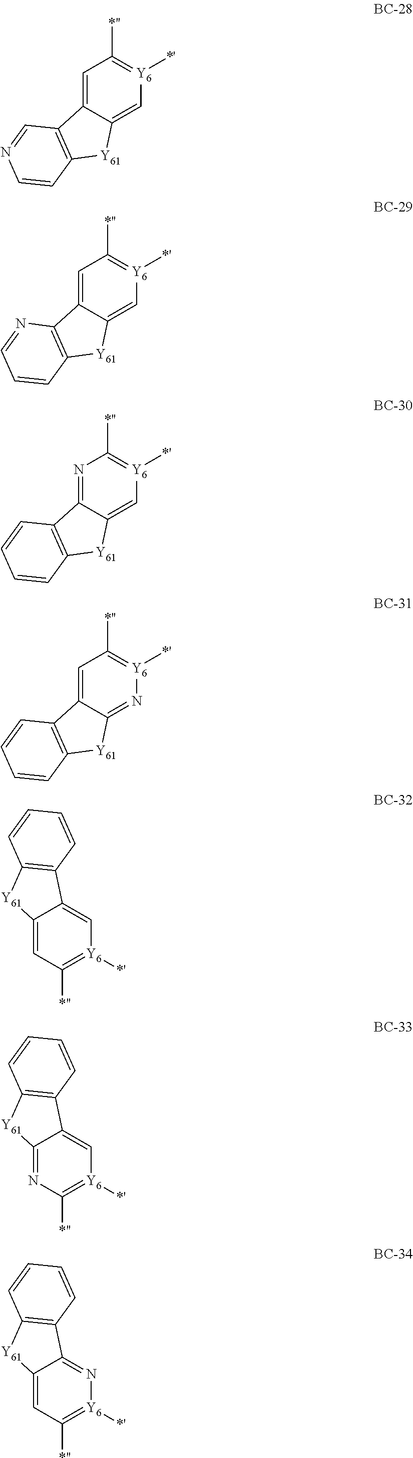

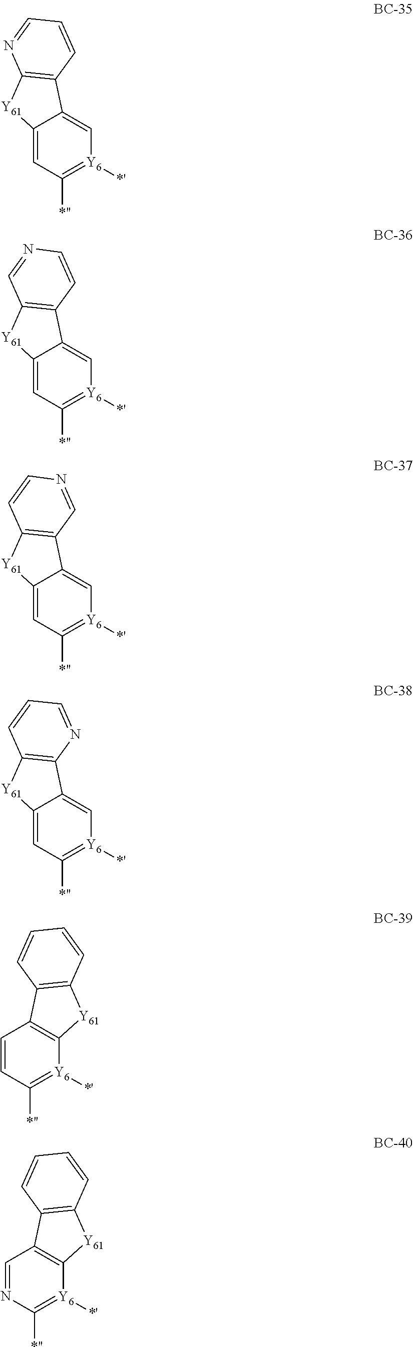

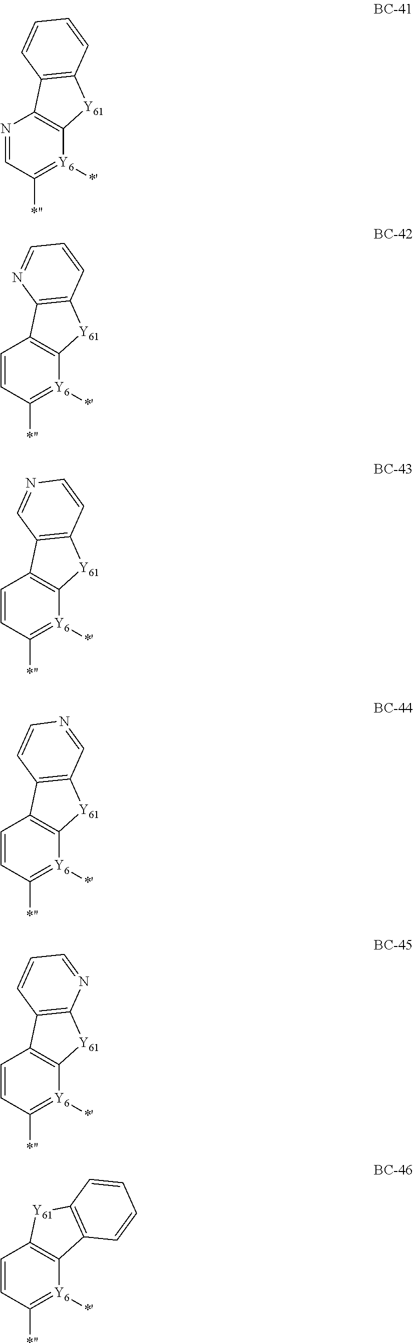

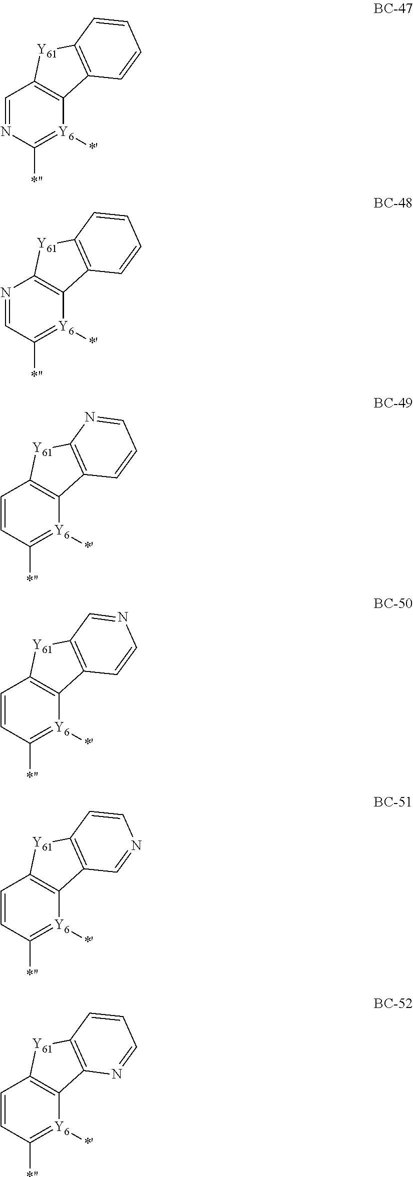

wherein, in Formulae BC1-1 to BC-52,
Y₆₁ may be O, S, Se, N(R₆₁ₐ), C(R₁₁ₐ)(R_{16b}), or Si(R₁₁ₐ)(R_{16b}),
R₆₁ₐ and R_{61b} may each independently be the same as described in connection with R₆,
*′ indicates a binding site to iridium in Formula 1, and
*″ indicates a binding site to a neighboring atom in Formula 1.

The groups represented by Formulae BC-1 to BC-52 may each be unsubstituted or substituted with a substituent such as Rₑ described herein, and in this regard, may be easily understood by referring to the structures of Formulae 1-1 and 1-3.

In one or more embodiments, the first ligand may be represented by Formula 1-1A:

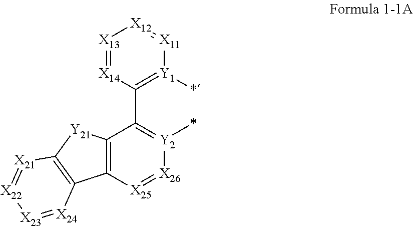

wherein, in Formula 1-1A,
Y₁ and Y₂ may each independently be C or N,
X₁₁ may be C(R₁₁) or N, X₁₂ may be C(R₁₂) or N, X₁₃ may be C(R₁₃) or N, and X₁₄ may be C(R₁₄) or N,
Y₂₁ may be N(R₂₇), O, S, Se, C(R₂₇)(R₂₈), or Si(R₂₇)(R₂₈),
X₂₁ may be C(R₂₁) or N, X₂₂ may be C(R₂₂) or N, X₂₃ may be C(R₂₃) or N, X₂₄ may be C(R₂₄) or N, X₂₅ may be C(R₂₅) or N, and X₂₆ may be C(R₂₆) or N,
at least one selected from X₂₁ to X₂₆ may be N,
R₂₁ to R₂₈ are each the same as described in connection with R₂, and
* and *′ each indicate a binding site to iridium.

In one or more embodiments, the first ligand may be represented by one selected from Formulae 1-1-1 to 1-1-29:

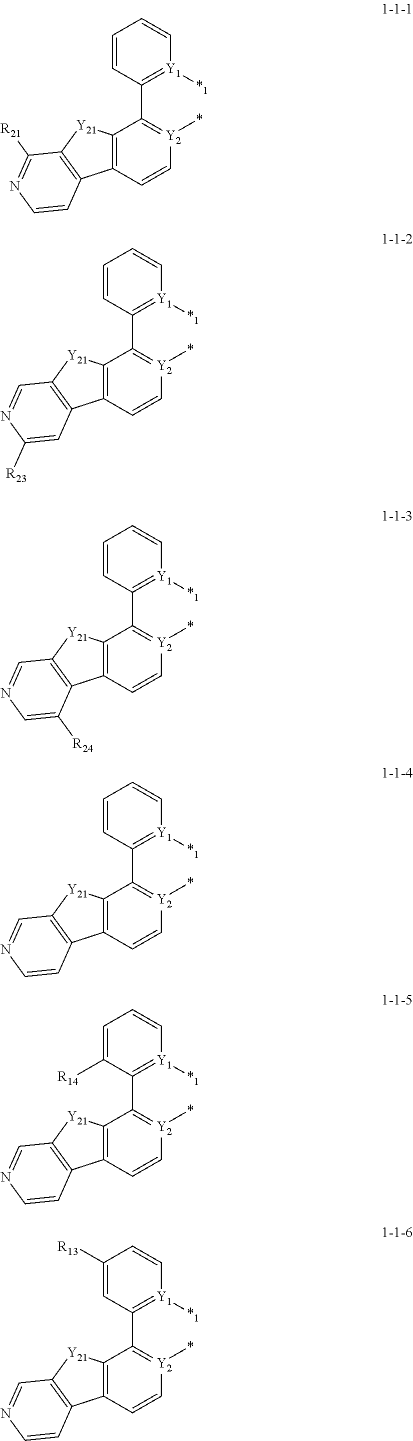

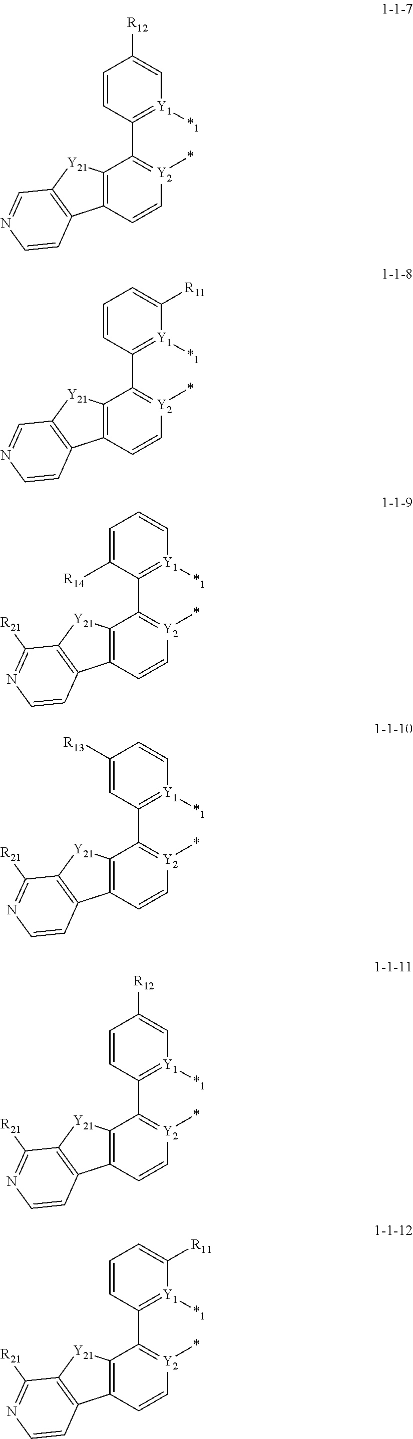

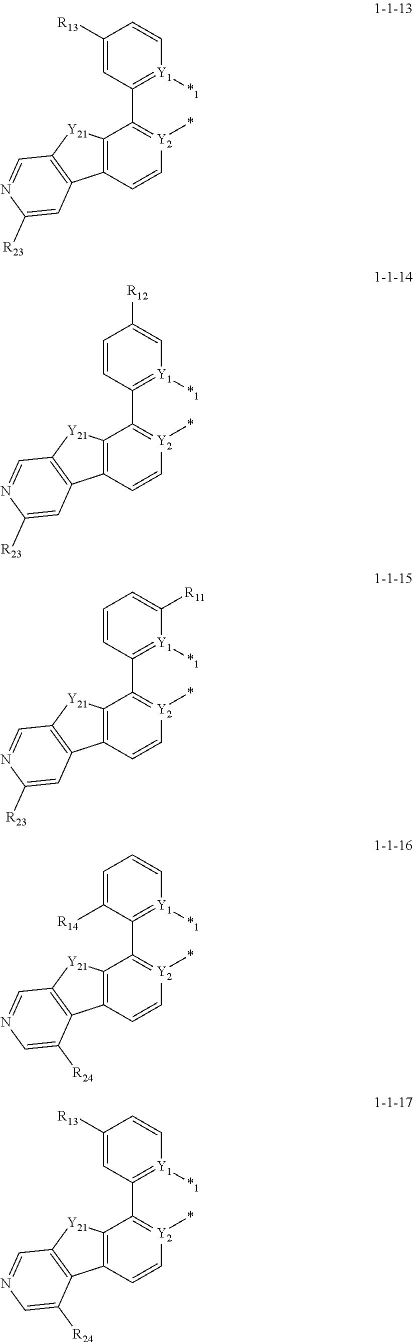

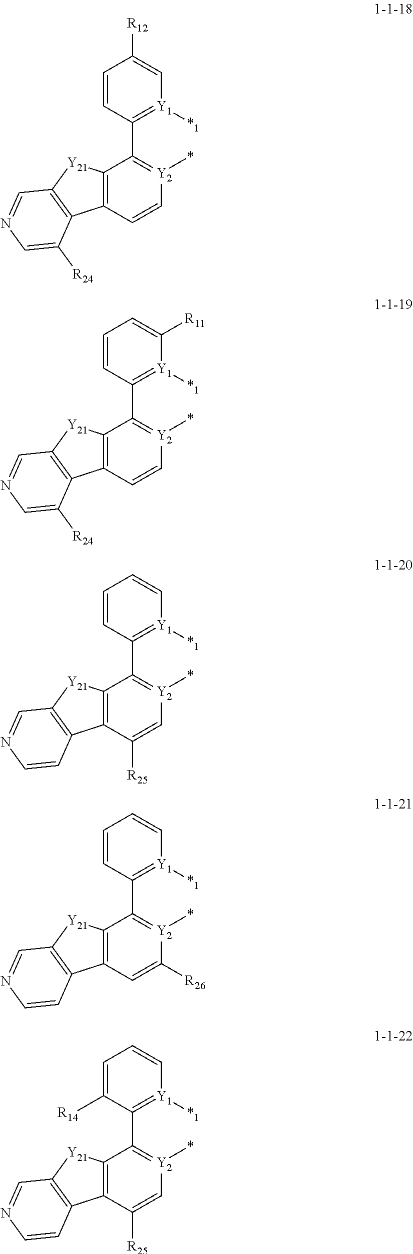

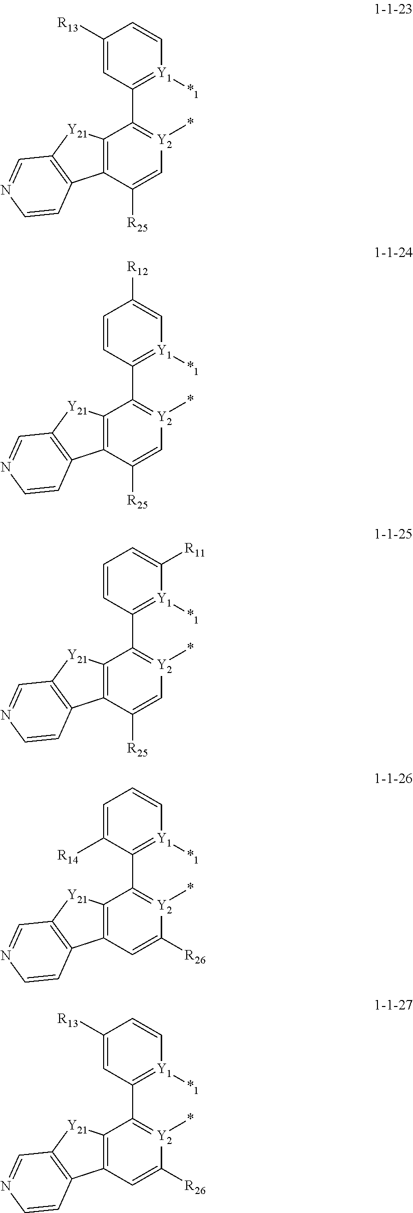

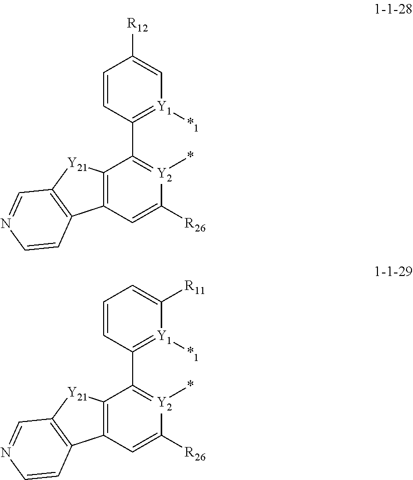

wherein, in Formulae 1-1-1 to 1-1-29,
Y₁ and Y₂ may each independently be C or N,
Y₂₁ may be N(R₂₇), O, S, Se, C(R₂₇)(R₂₈), or Si(R₂₇)(R₂₈),
R₁₁ to R₁₄ are each the same as described in connection with R₁, but may each not be hydrogen,
R₂₁ to R₂₆ are each the same as described in connection with R₂, but may each not be hydrogen,
R₂₇ and R₂₈ are each the same as described in connection with R₂, and
* and *′ each indicate a binding site to iridium.

In one or more embodiments, the second ligand may be represented by Formula 1-2A:

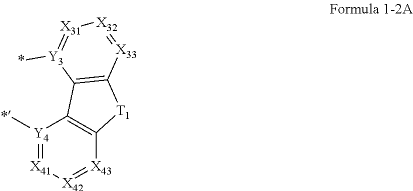

wherein, in Formula 1-2A,
Y₃ and Y₄ may each independently be C or N,
X₃₁ may be C(R₃₁) or N, X₃₂ may be C(R₃₂) or N, and X₃₃ may be C(R₃₃) or N,
X₄₁ may be C(R₄₁) or N, X₄₂ may be C(R₄₂) or N, and X₄₃ may be C(R₄₃) or N,
R₃₁ to R₃₃ are each the same as described in connection with R₃,
R₄₁ to R₄₃ are each the same as described in connection with R₄,
T₁ is the same as described herein, and
* and *′ each indicate a binding site to iridium.

In one or more embodiments, the second ligand may be represented by one selected from Formulae 1-2-1 to 1-2-58:

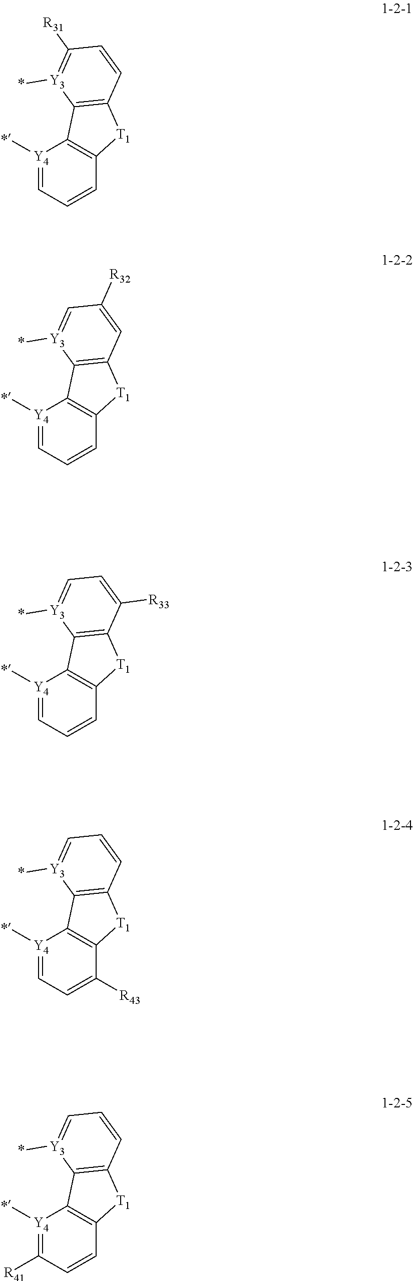

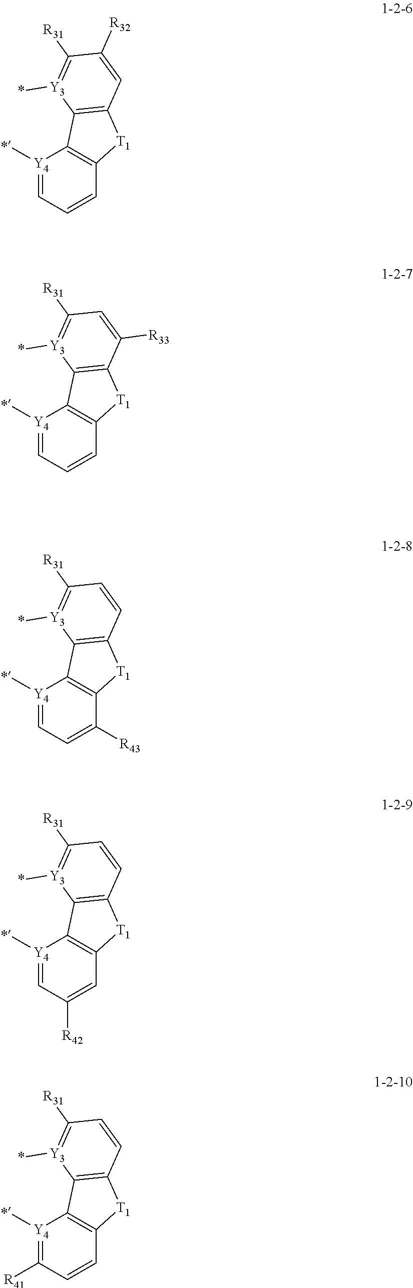

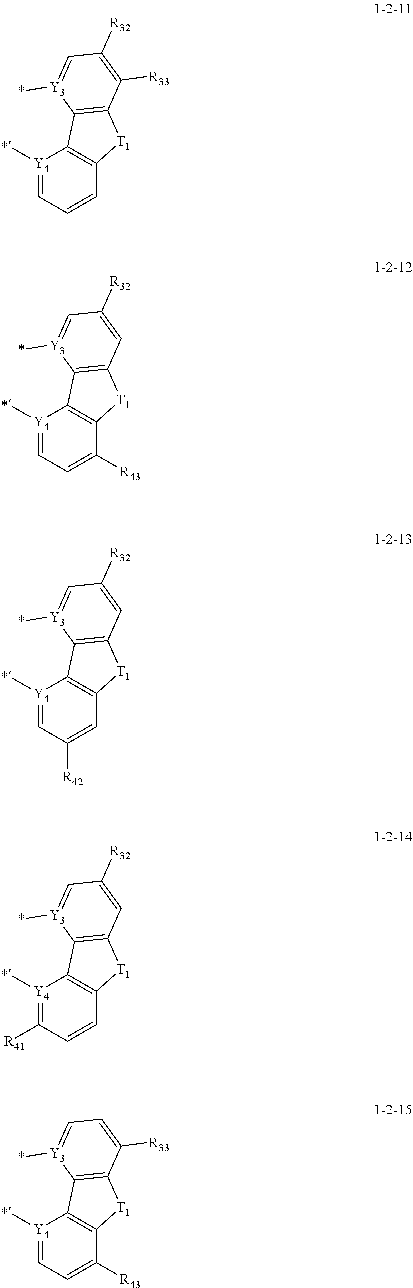

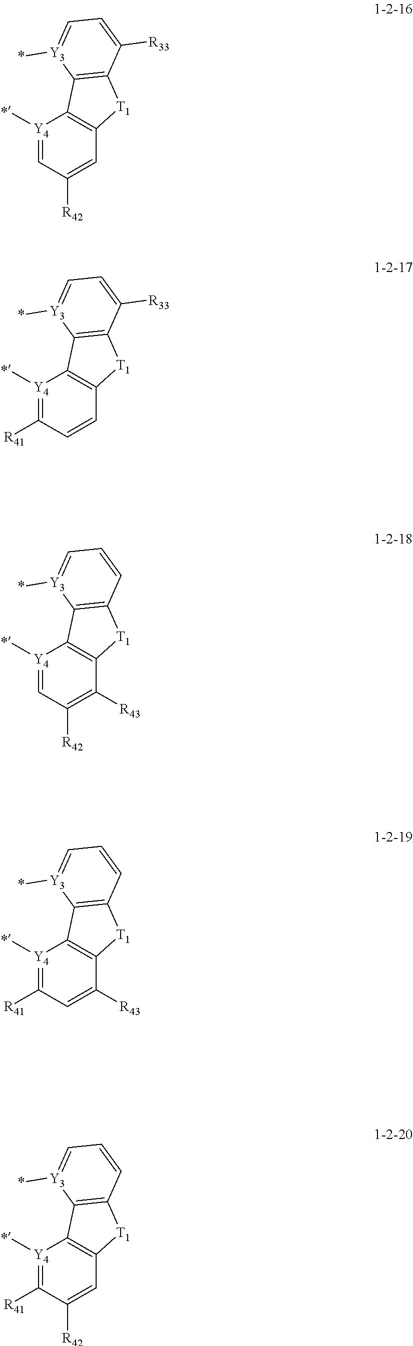

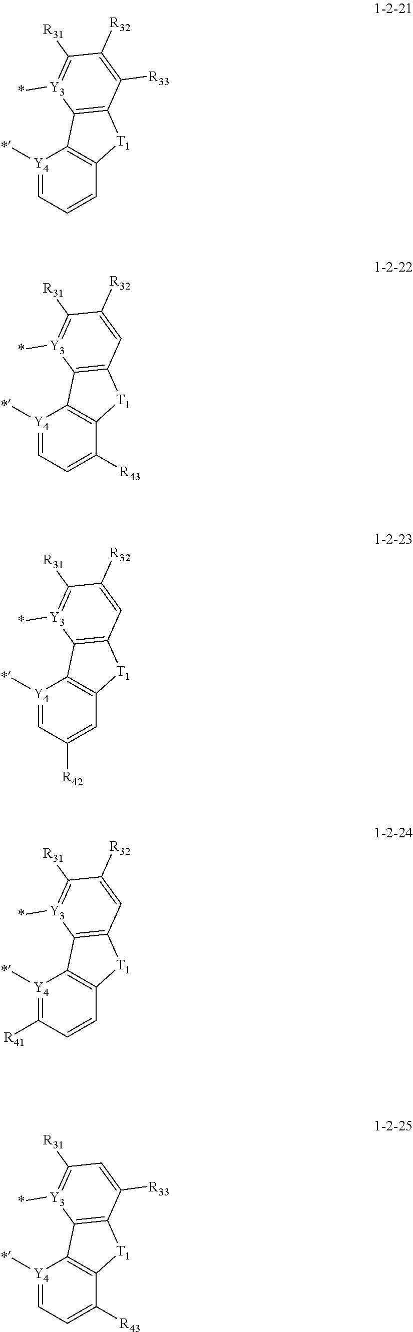

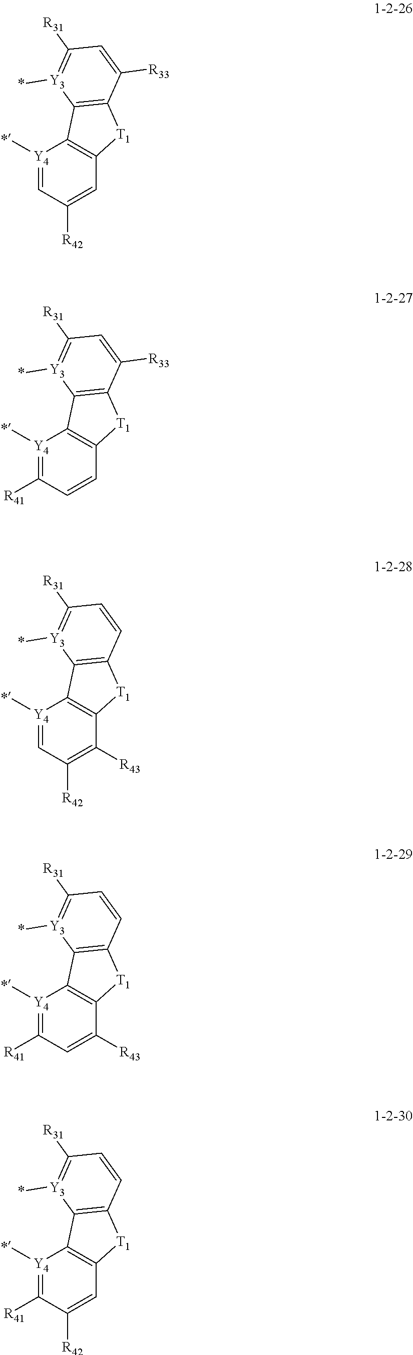

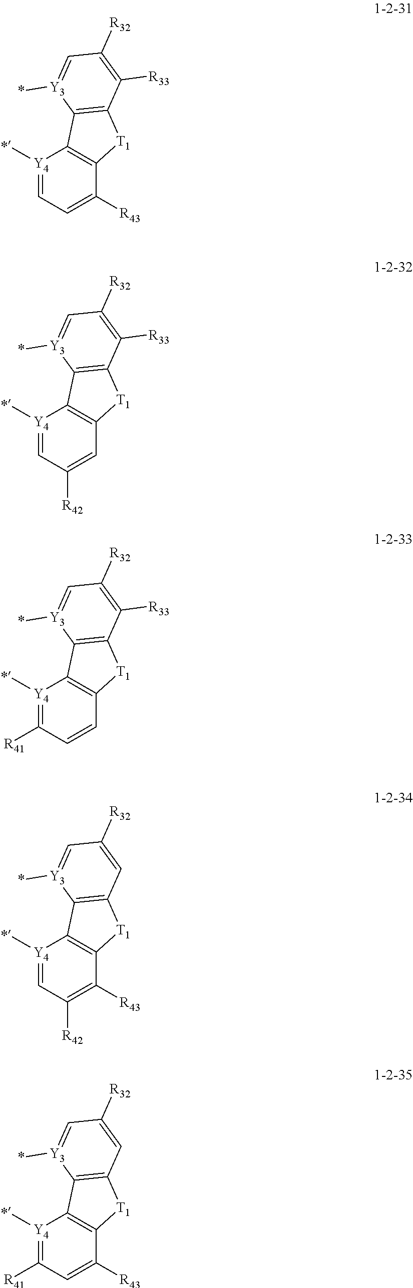

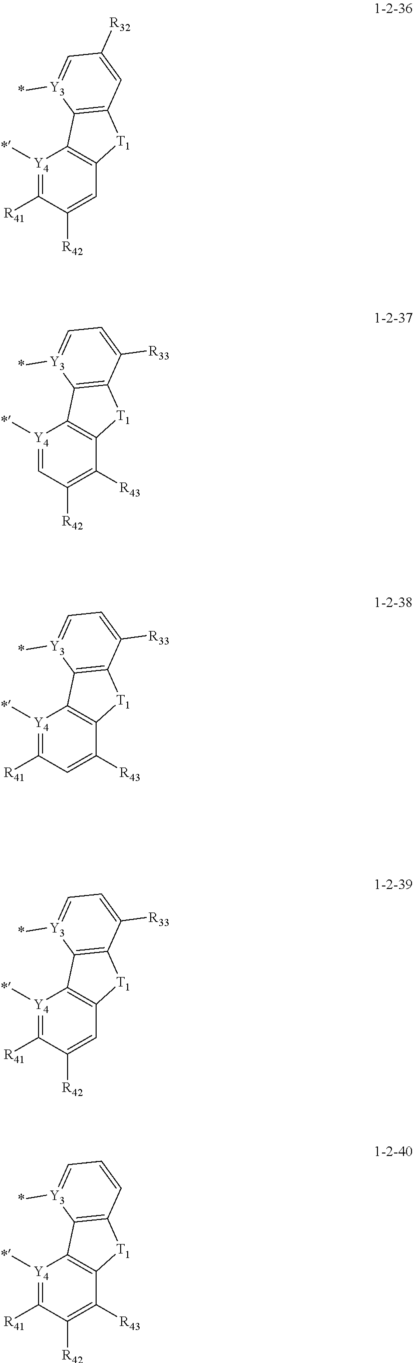

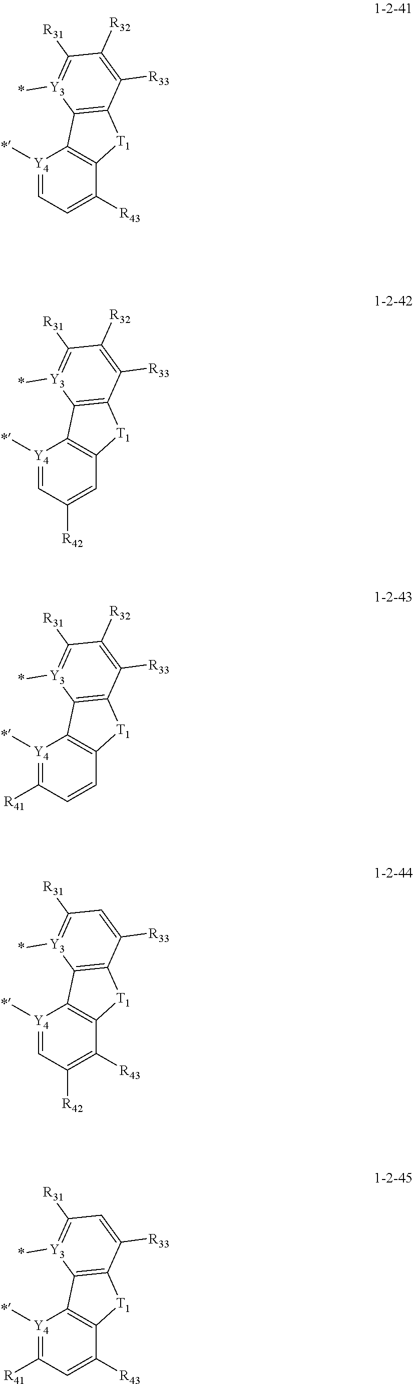

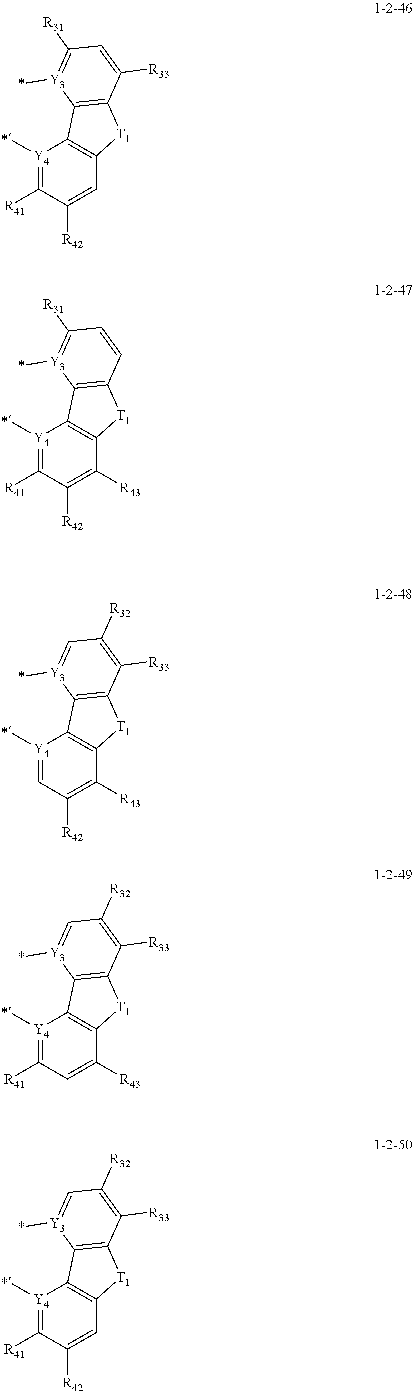

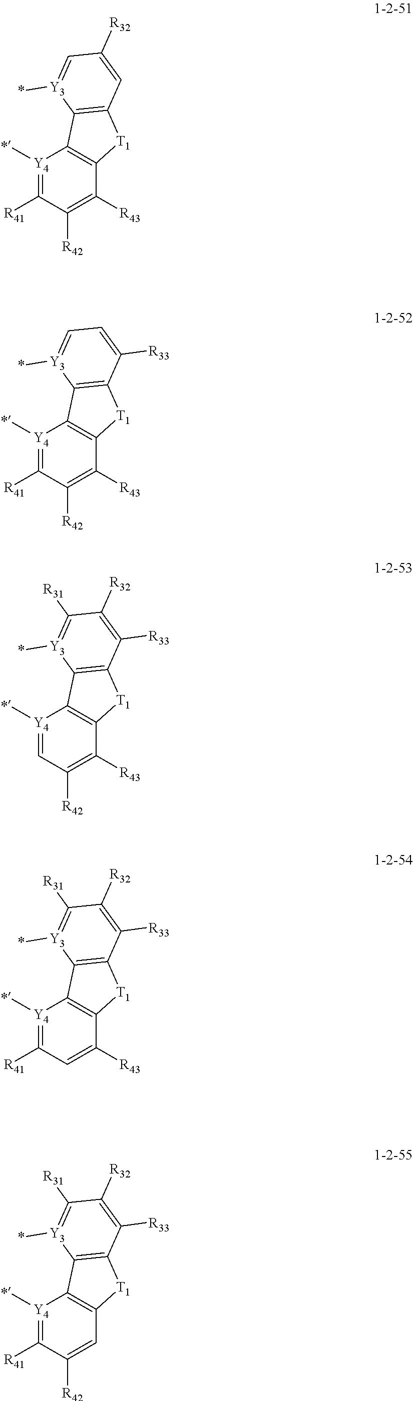

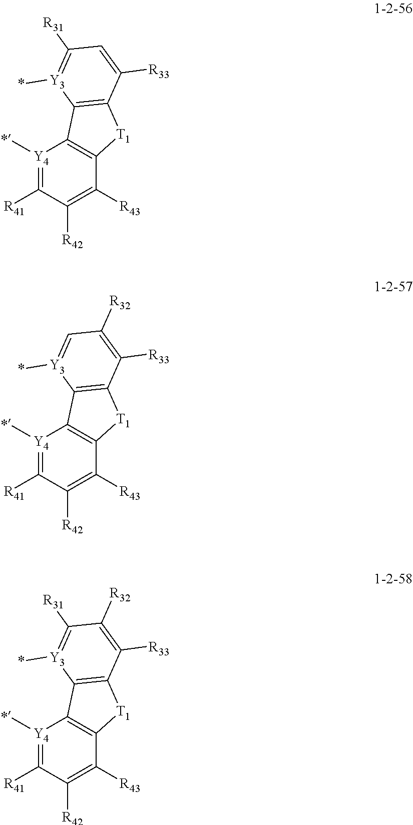

wherein, in Formulae 1-1-1 to 1-2-58,
Y₃ and Y₄ may each independently be C or N,
R₃₁ to R₃₃ are each the same as described in connection with R₃, but may each not be hydrogen,
R₄₁ to R₄₃ are each the same as described in connection with R₄, but may each not be hydrogen,
T₁ is the same as described herein, and
* and *′ each indicate a binding site to iridium.

In Formula 1-2, k1 indicates the number of *′″-[(CZ₁)(CZ₂)]—*″″, and may each independently be an integer from 1 to 3 (e.g., 1, 2, of 3). When k1 is 2 or more, two or more of *′″-[(CZ₁)(CZ₂)]—*″″ may be identical to or different from each other.

In one or more embodiments, k1 may be 1 or 2.

In one or more embodiments, R₁ to R₆, Z₁, and Z₂ may each independently be: hydrogen, deuterium, —F, —Cl, —Br, —I, hydroxyl group, cyano group, a nitro group, a C₁-C₂₀ alkyl group, or a C₁-C₂₀ alkoxy group;
a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₁ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzothiazolyl group, a benzoisoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof; or
—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
Q₁ to Q₃ and Q₃₁ to Q₃₃ may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, a naphthyl group, a pyridinyl group, a pyrimidinyl group, a pyridazinyl group, a pyrazinyl group, or a triazinyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or any combination thereof.

In one or more embodiments, R₁ to R₆, Z₁, and Z₂ may each independently be:
hydrogen, deuterium, —F, —Cl, —Br, —I, —CD₃, —CD₂H, —CDH₂, —CF₃, —CF₂H, —CFH₂, a cyano group, a nitro group, a C₁-C₆₀ alkyl group, a C₂-C₆₀ alkenyl group, a C₂-C₆₀ alkynyl group, or a C₁-C₆₀ alkoxy group; or
a group represented by one selected from Formulae 9-1 to 9-39, 9-44 to 9-61 or a group represented by one selected from Formulae 10-1 to 10-246; or
—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂):

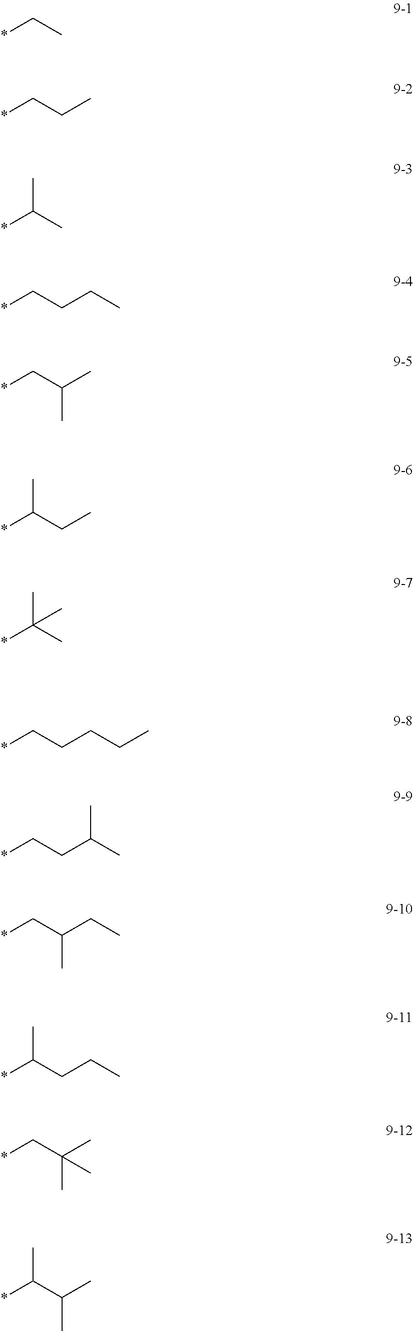

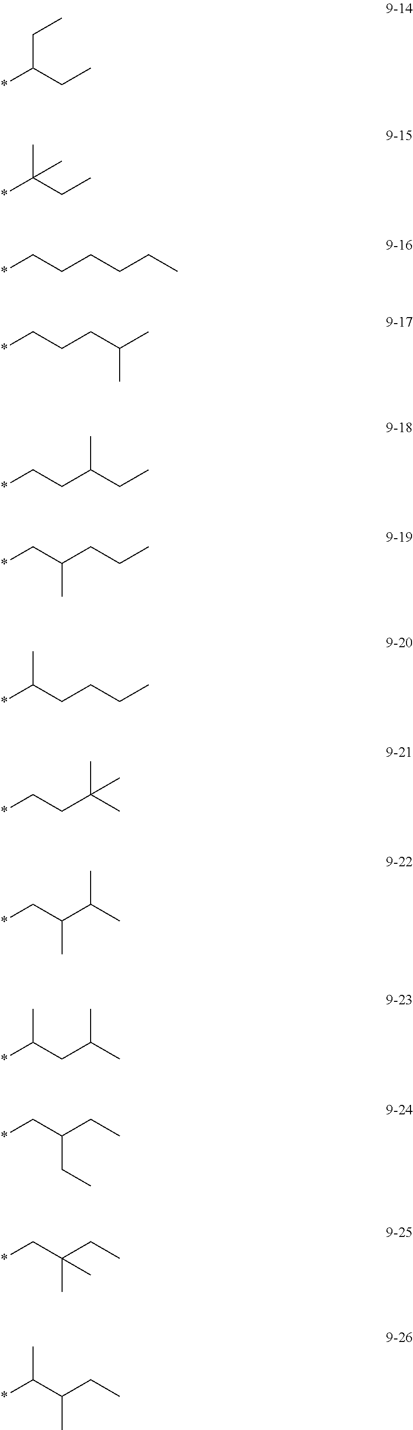

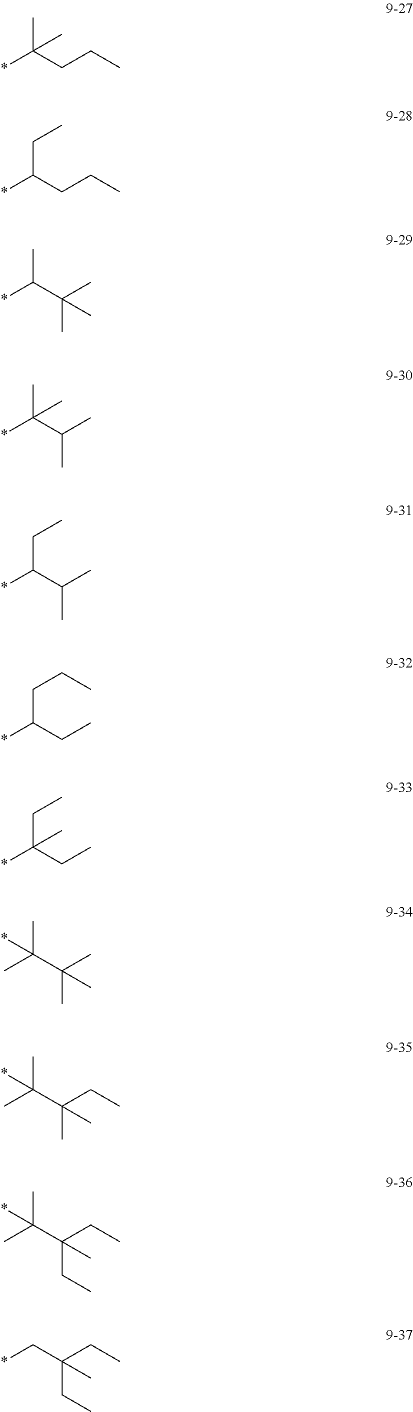

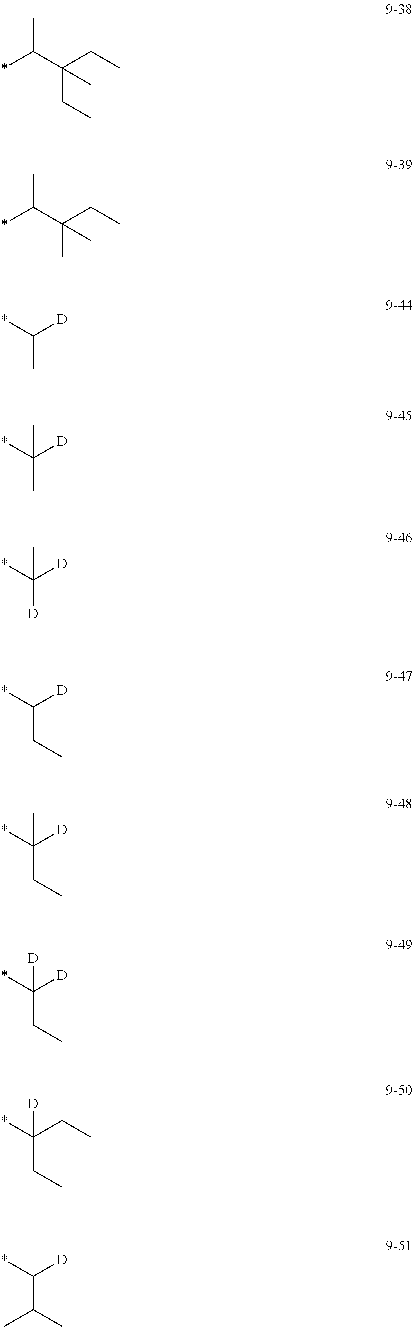

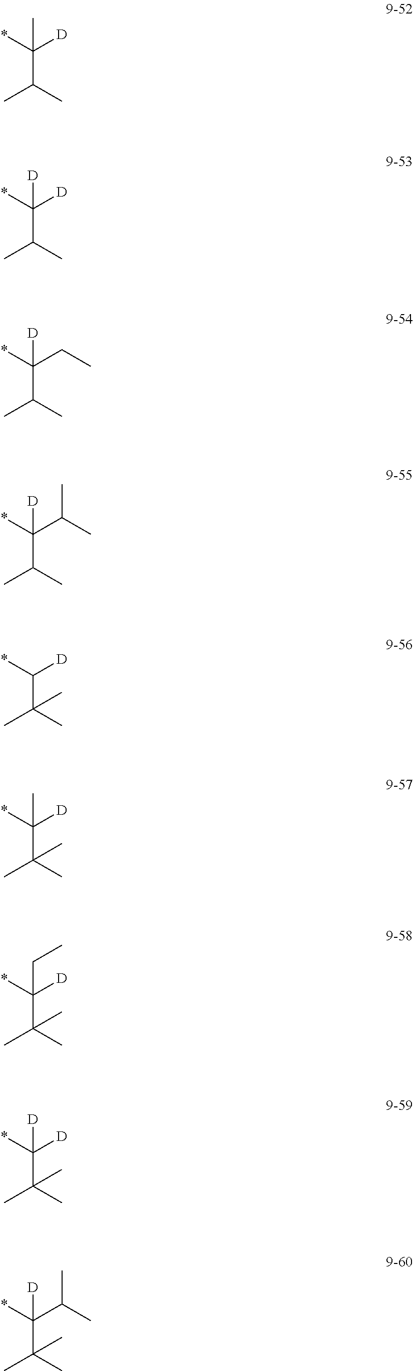

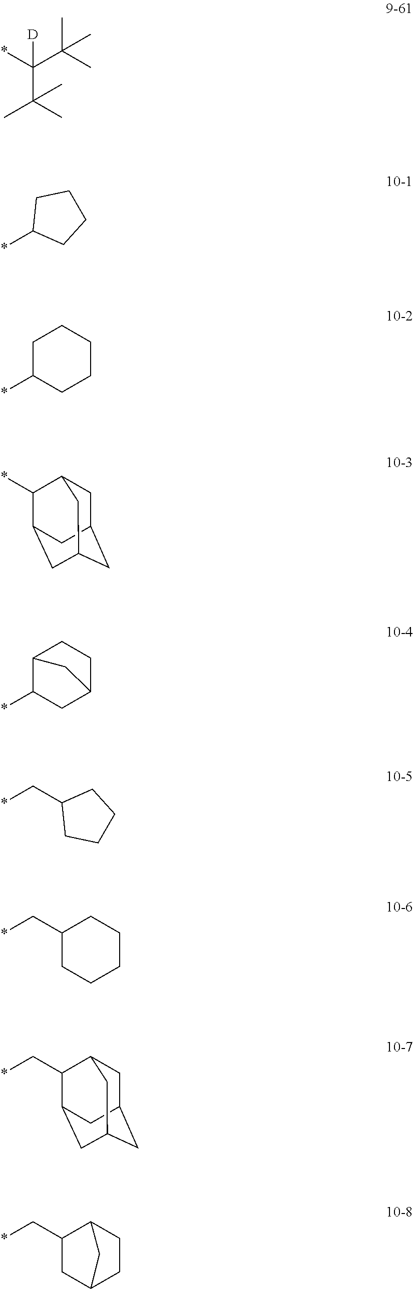

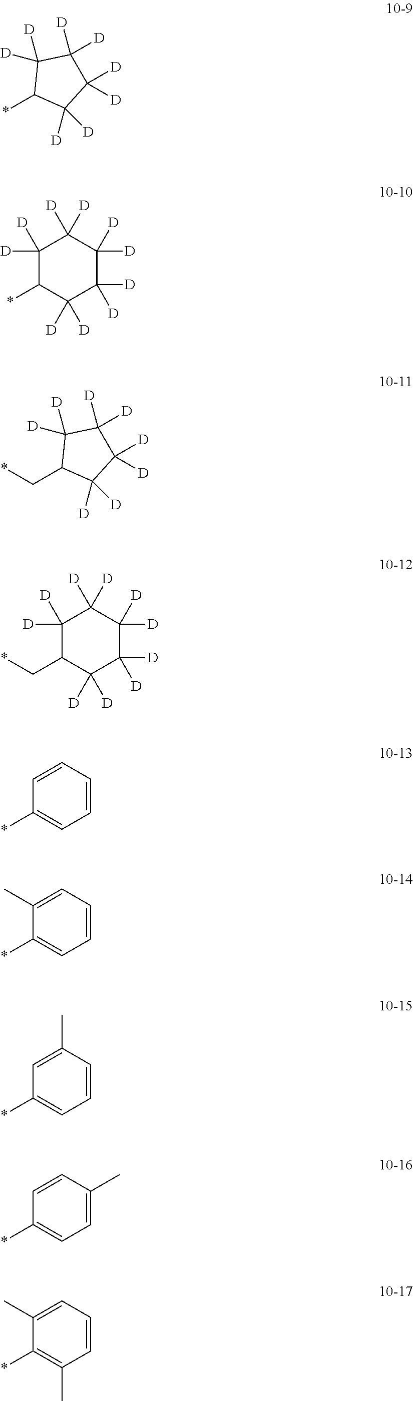

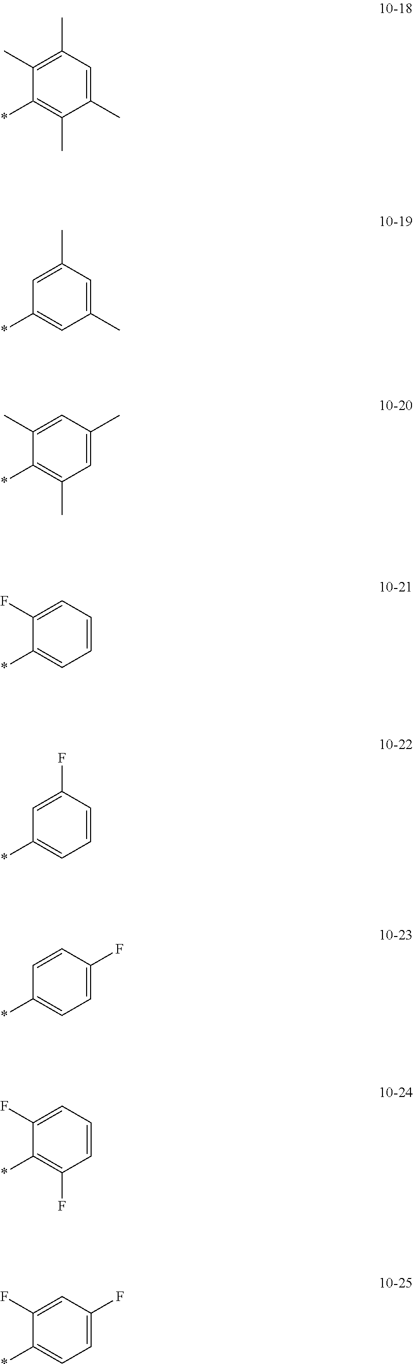

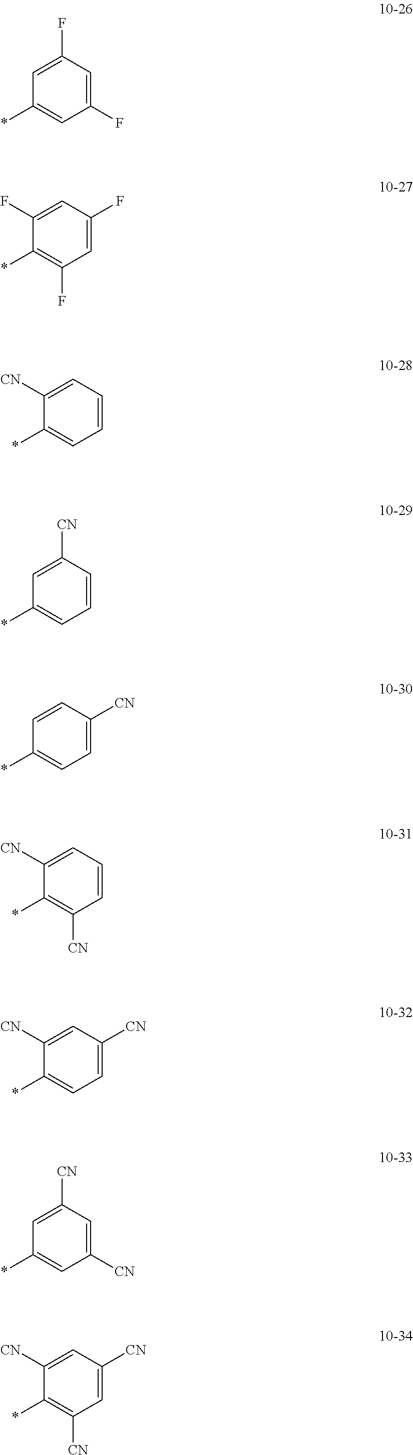

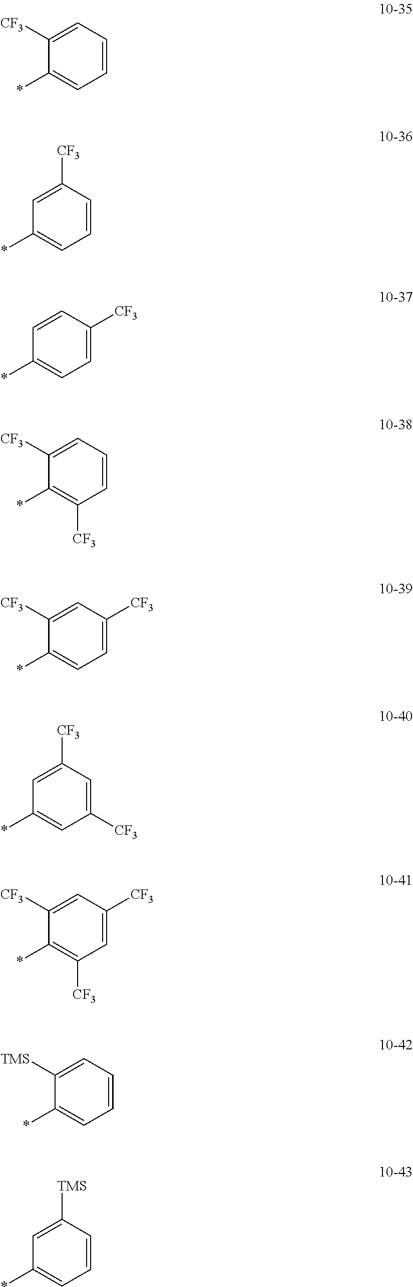

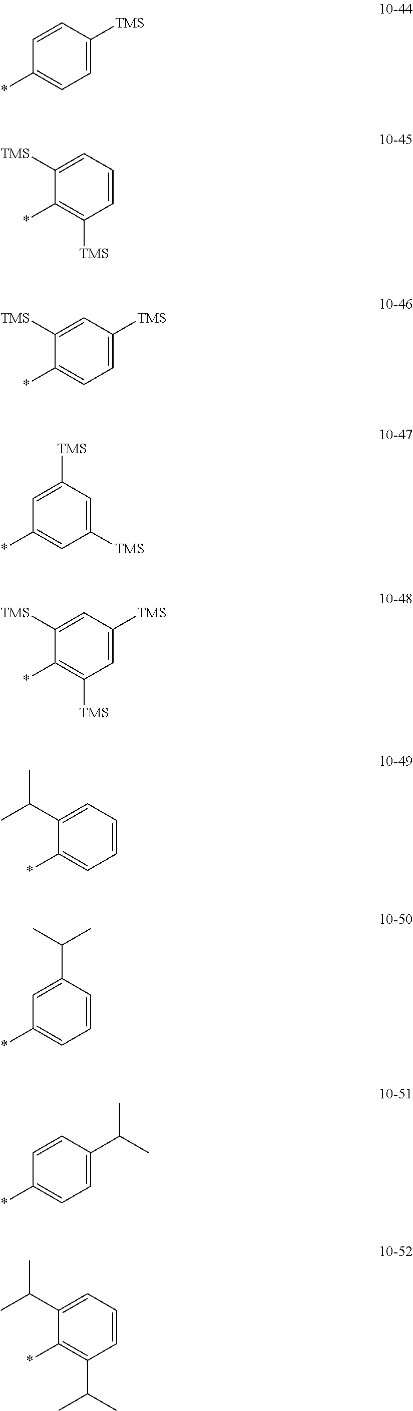

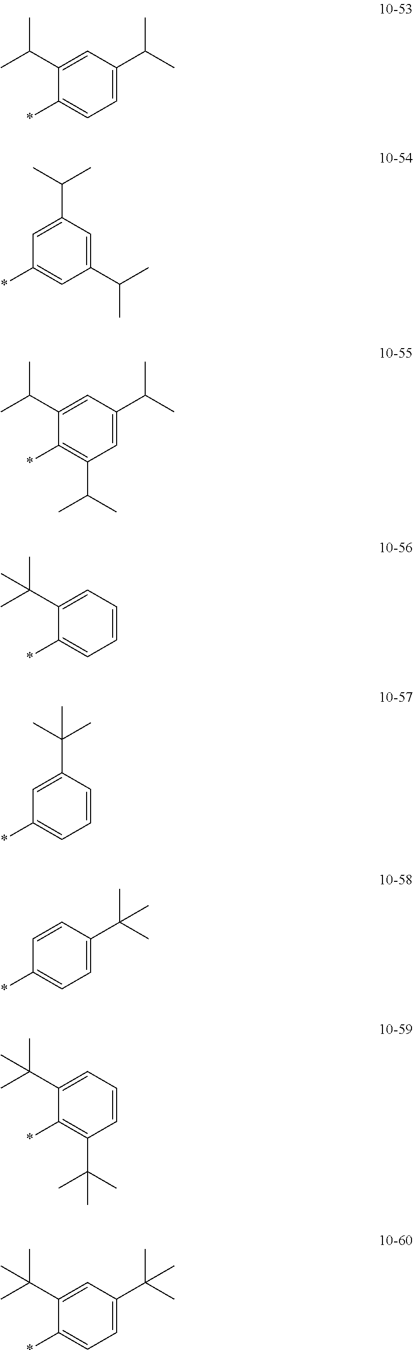

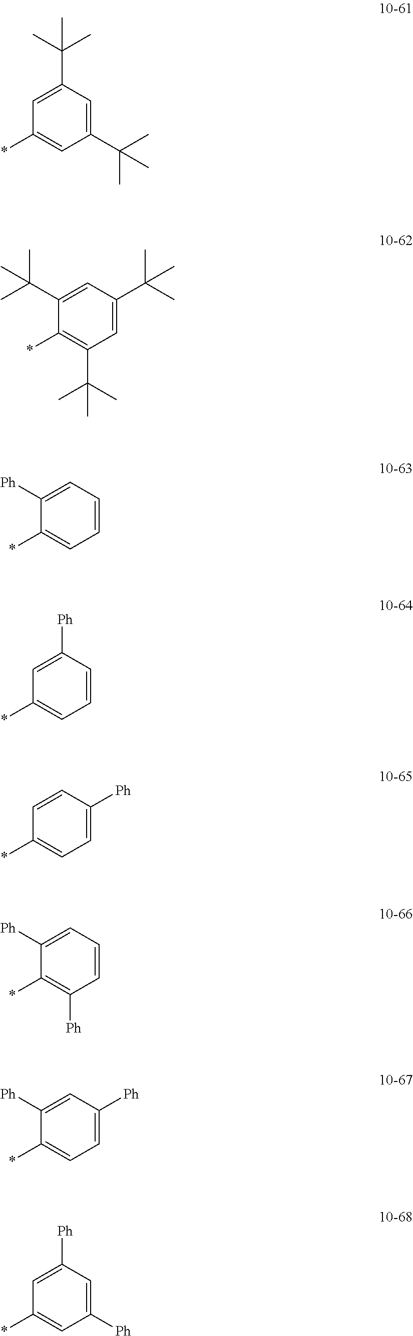

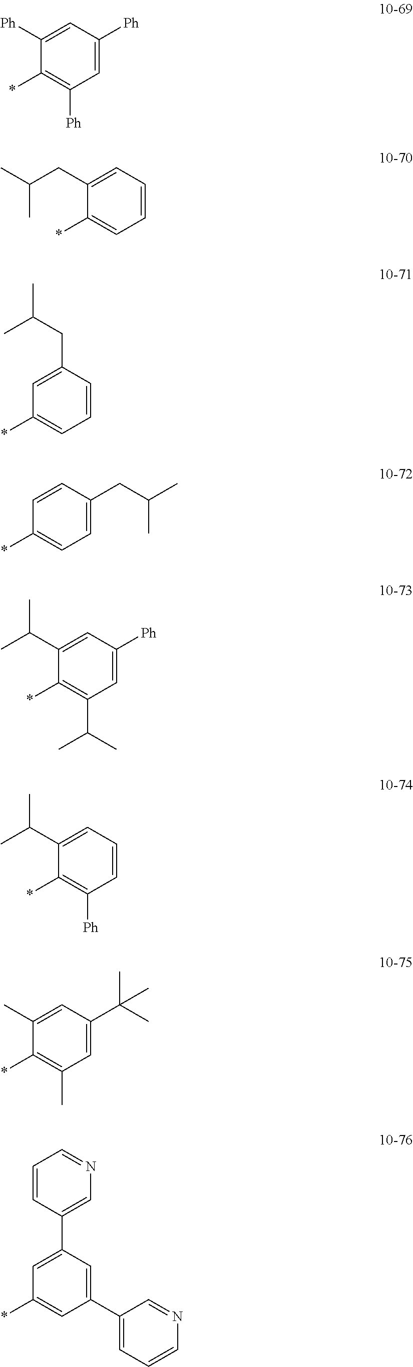

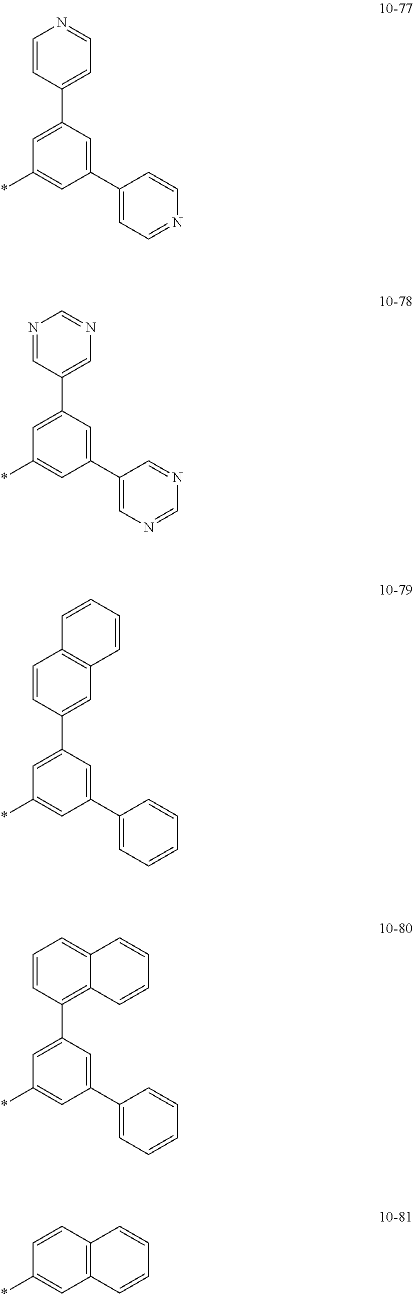

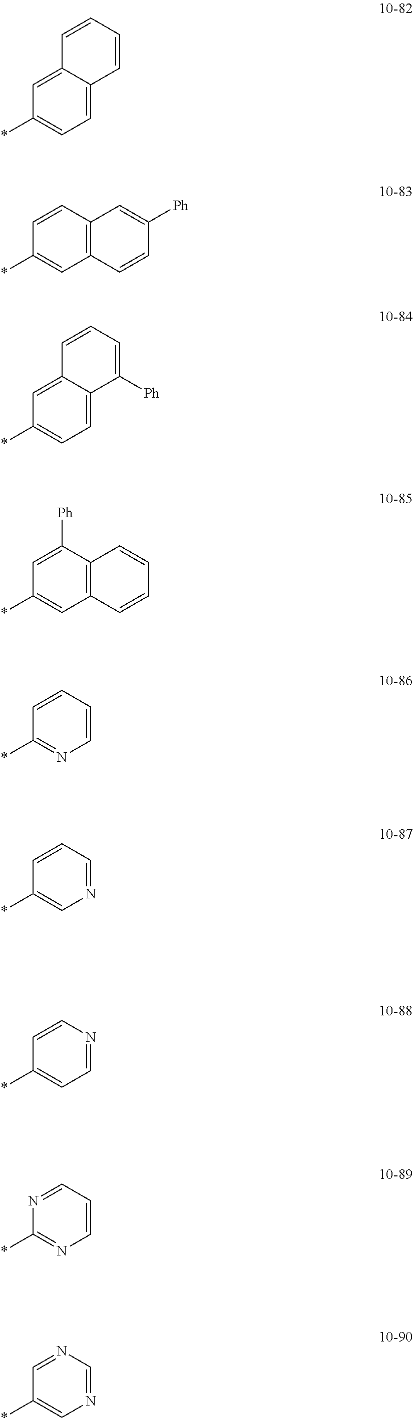

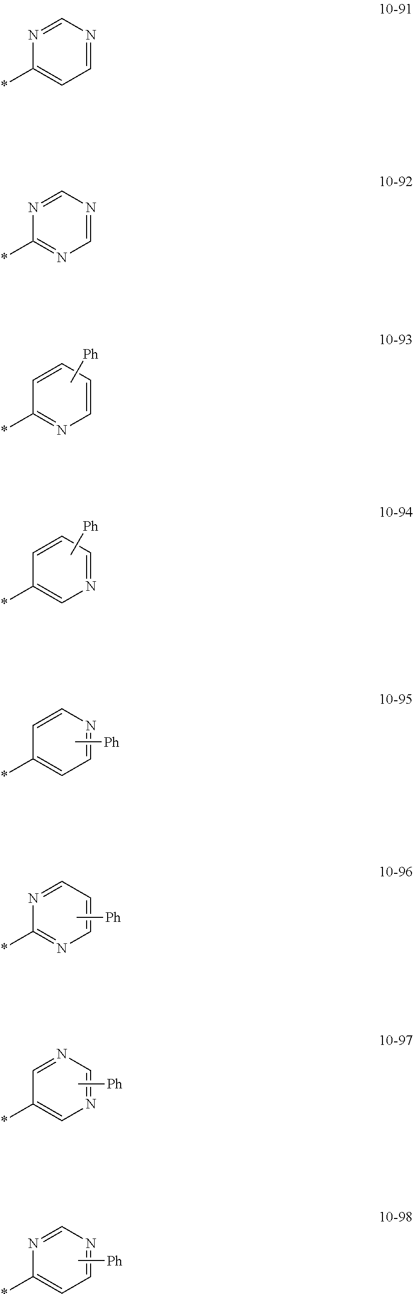

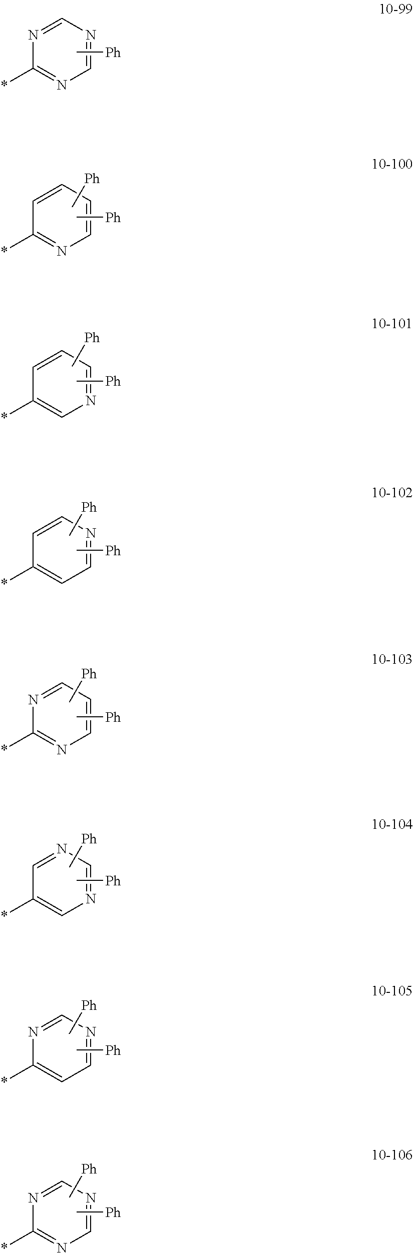

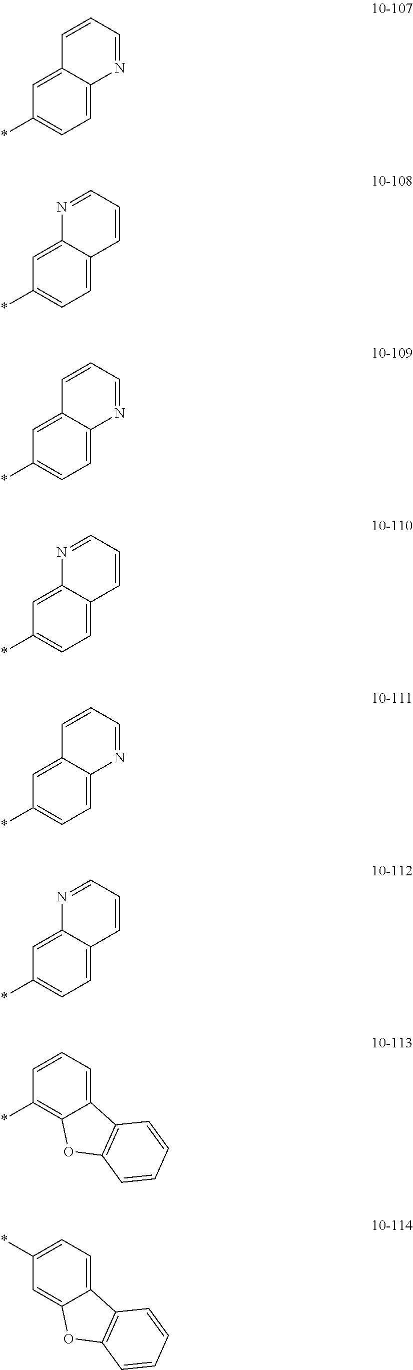

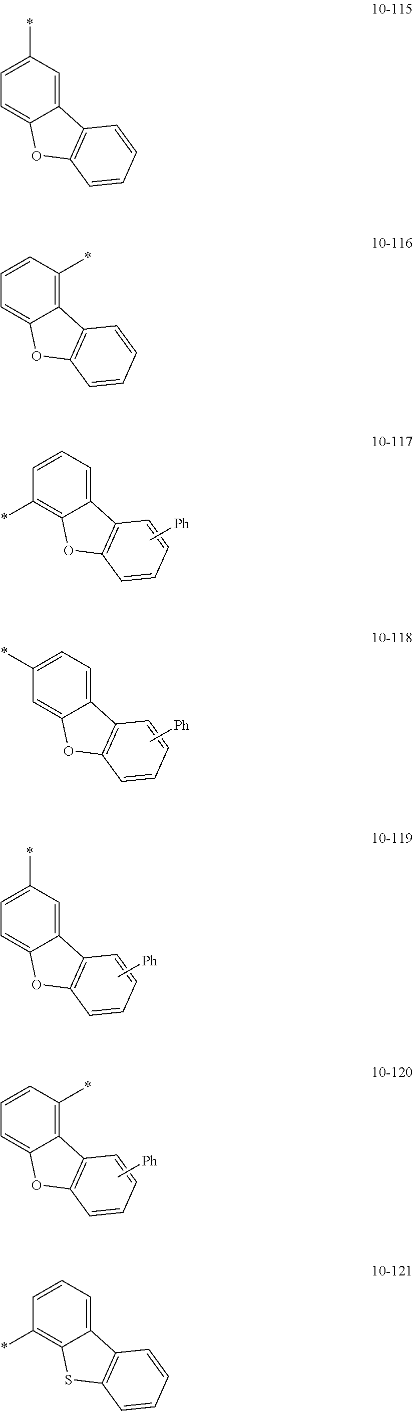

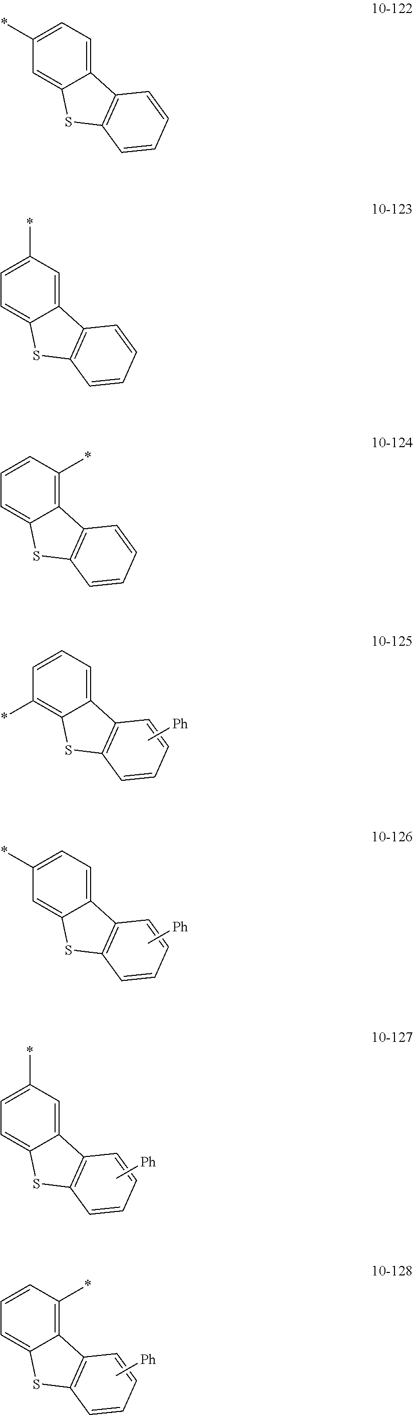

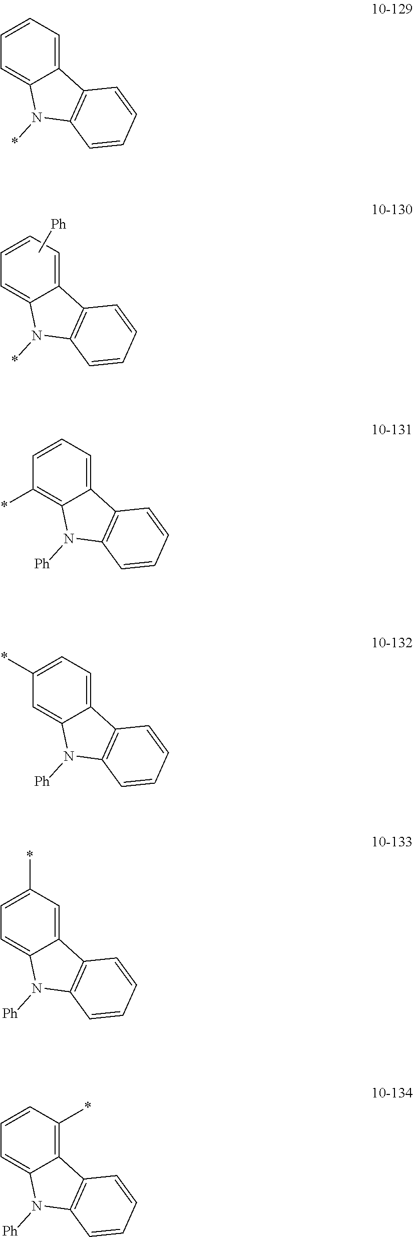

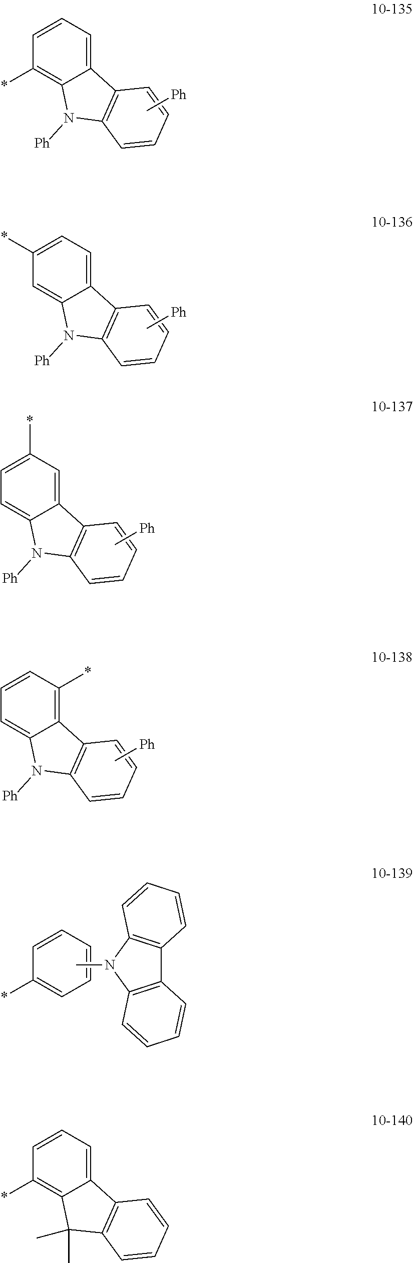

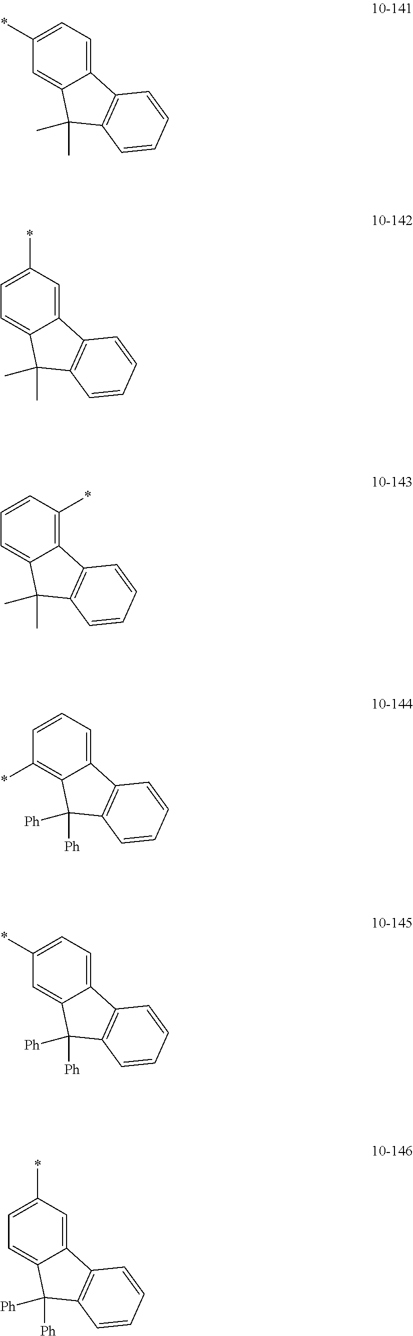

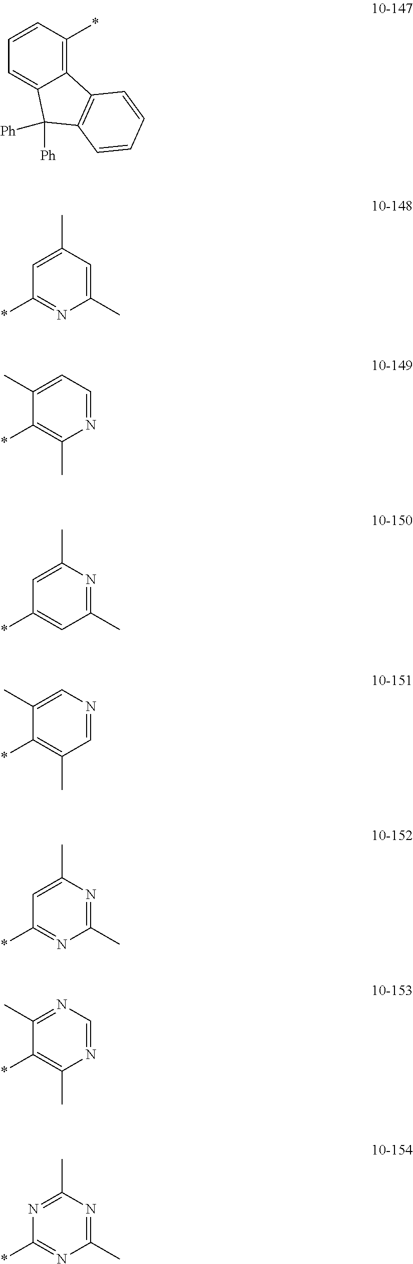

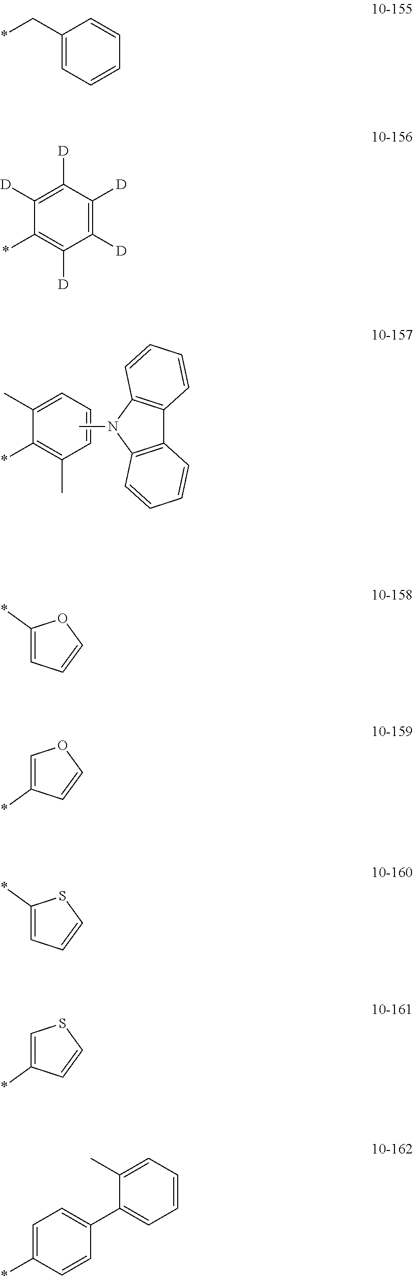

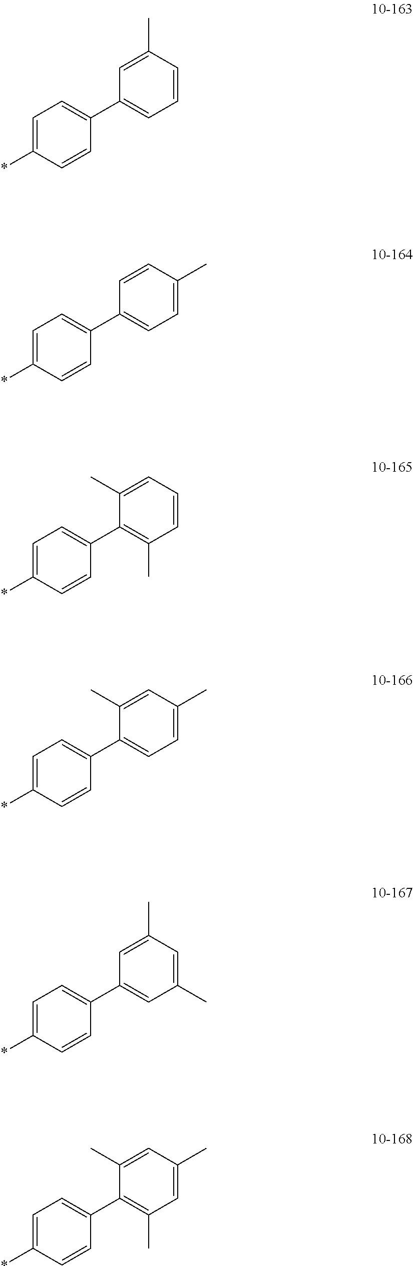

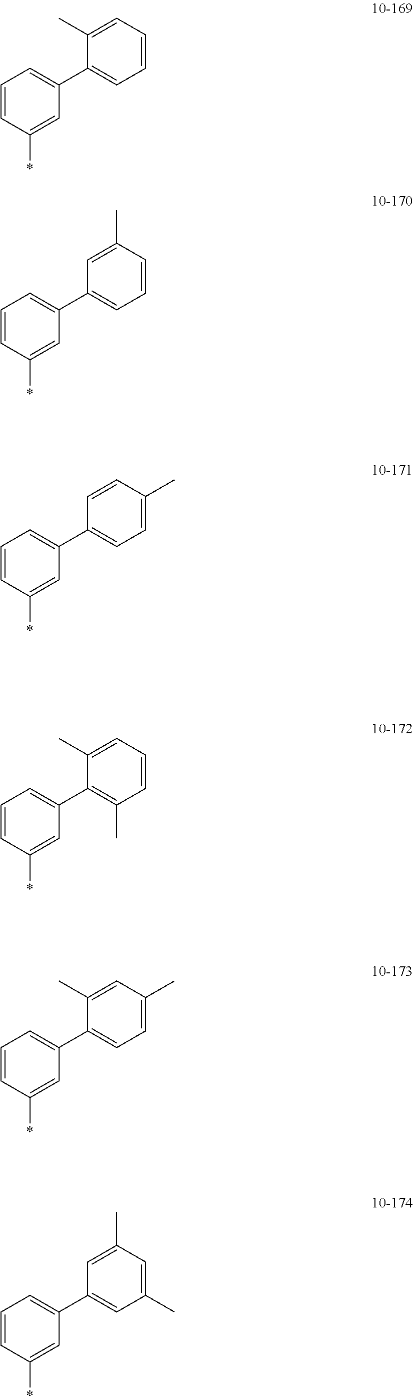

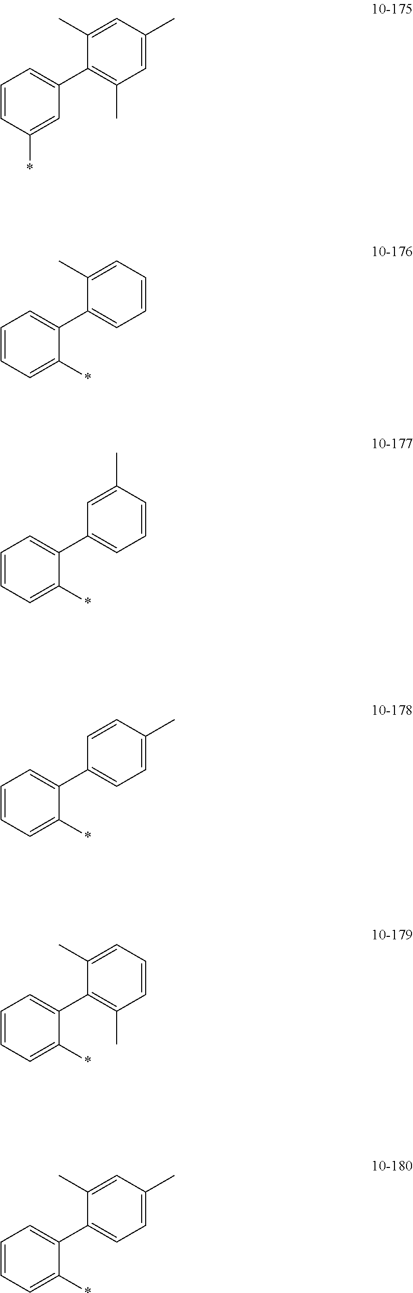

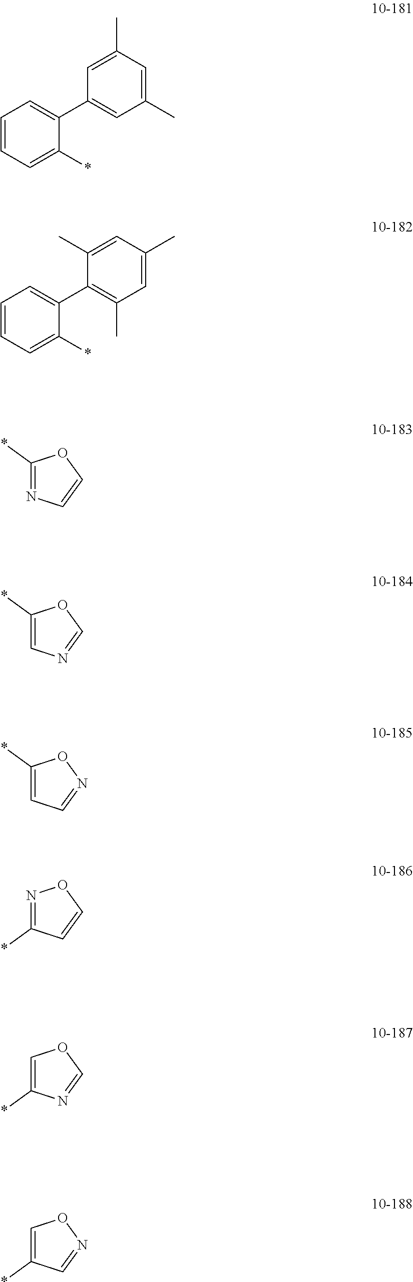

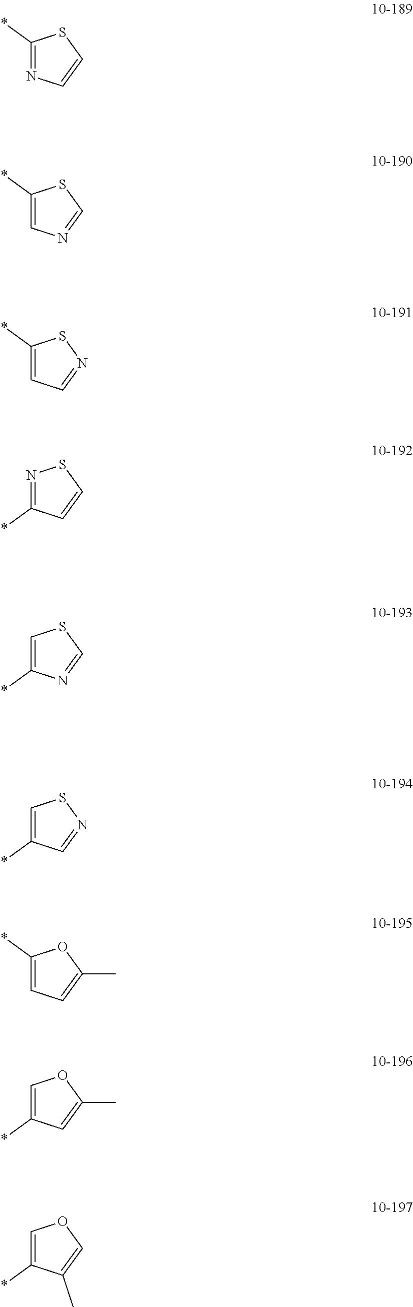

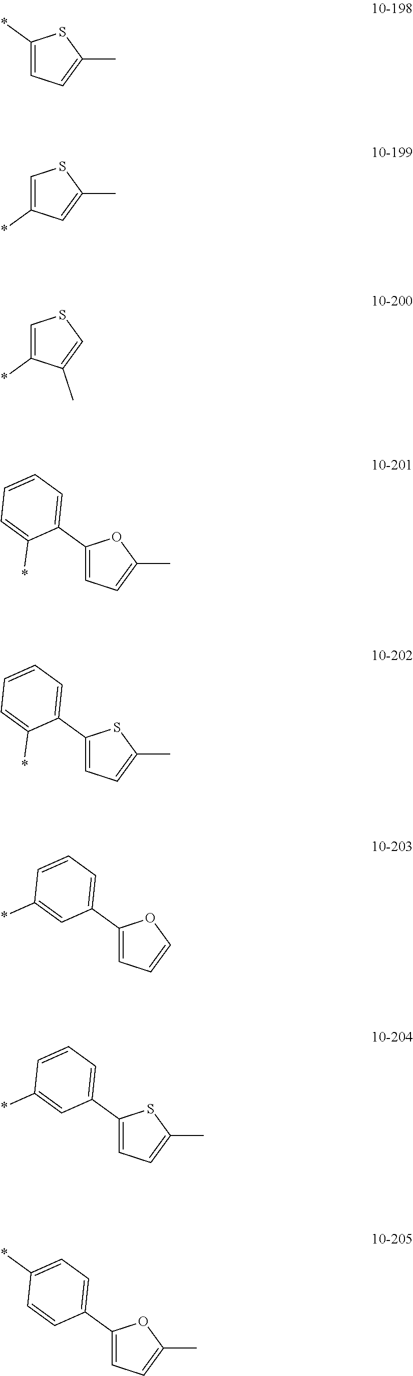

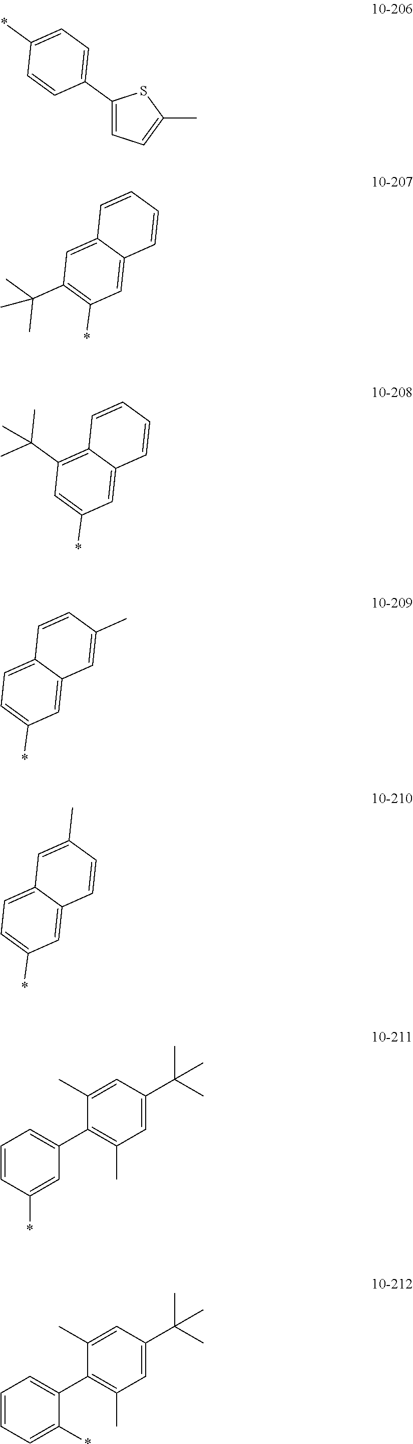

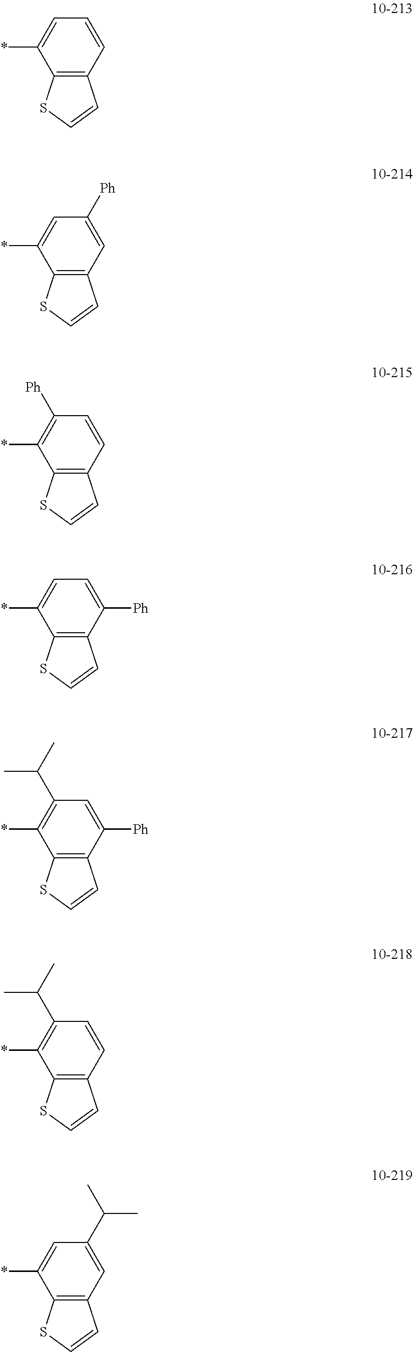

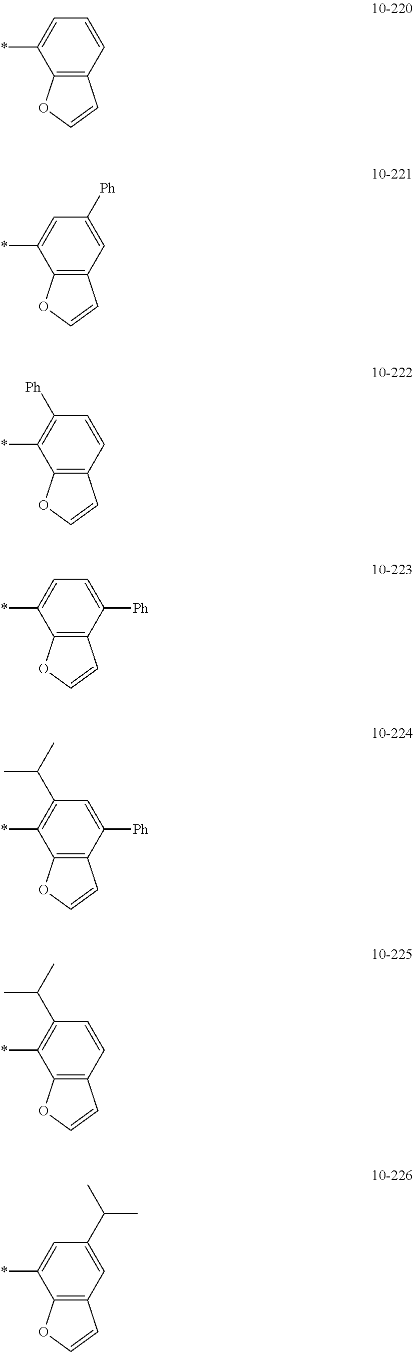

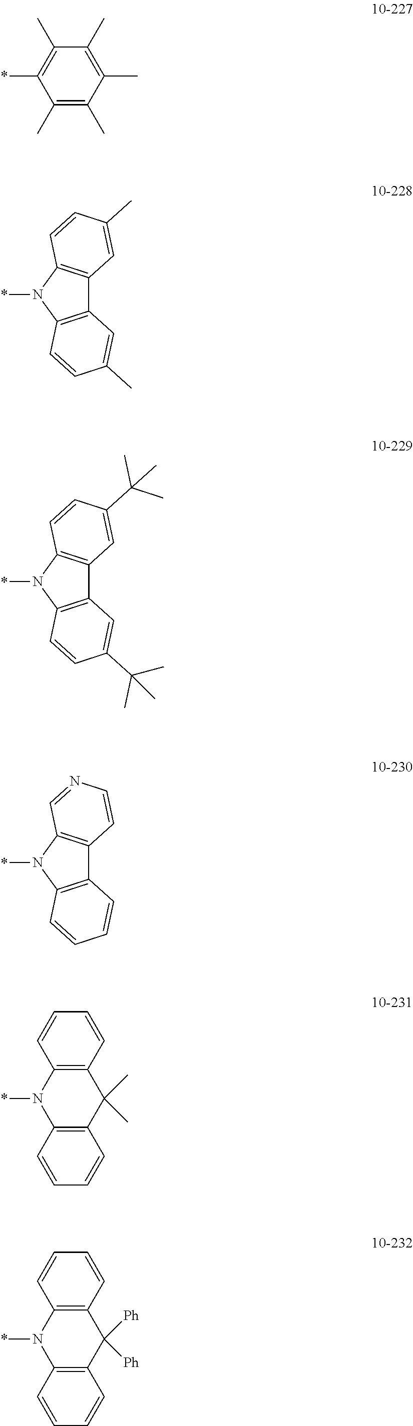

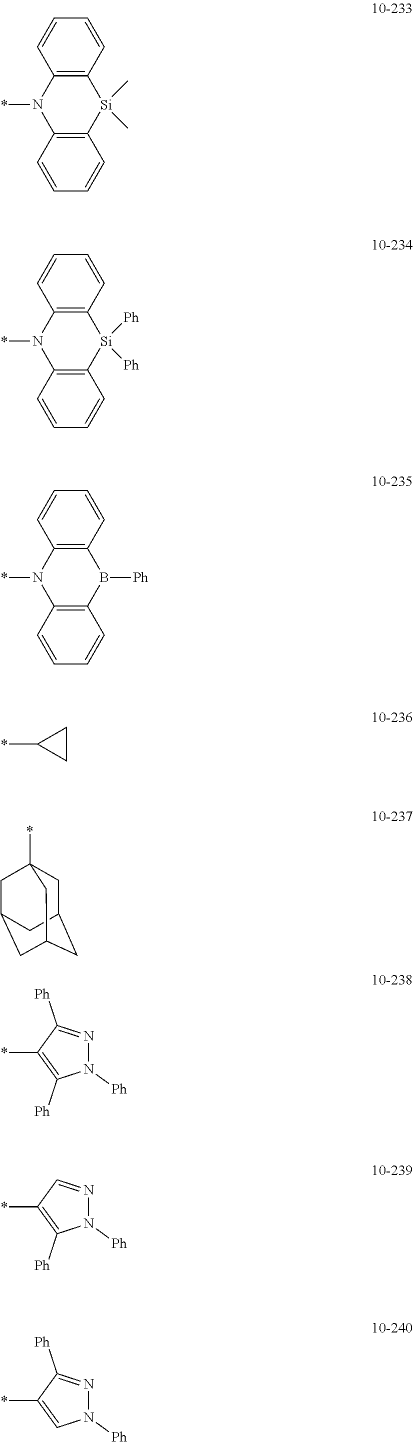

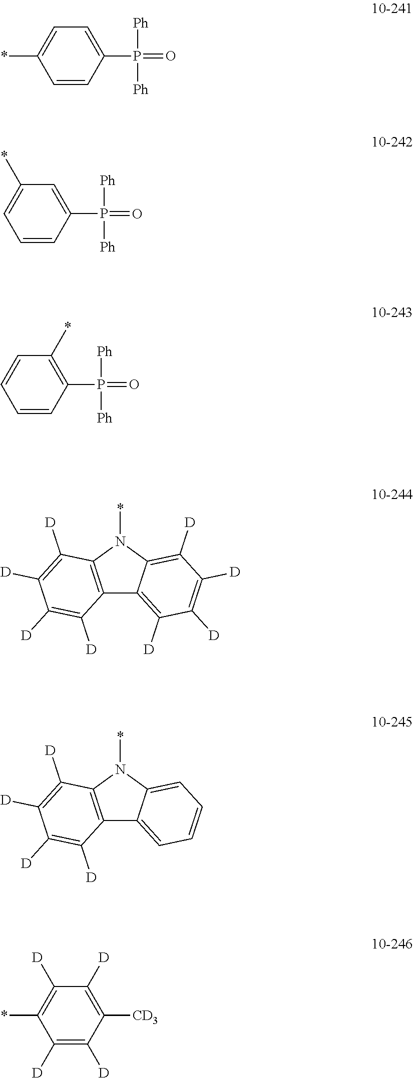

wherein, in Formulae 9-1 to 9-19 and 10-1 to 10-246, * indicates a binding site to a neighboring atom, “Ph” represents a phenyl group, and “TMS” represents a trimethylsilyl group.

In Formulae 1-1 to 1-3, d1 to d6 indicate the number of R₁ to the number of R₆, respectively, and may each independently be an integer from 0 to 10. When d1 is 2 or more, two or more of R₁ may be identical to or different from each other, when d2 is 2 or more, two or more of R₂ may be identical to or different from each other, when d3 is 2 or more, two or more of R₃ may be identical to or different from each other, when d4 is 2 or more, two or more of R₄ may be identical to or different from each other, when d5 is 2 or more, two or more of R₅ may be identical to or different from each other, and d6 is 2 or more, two or more of R₆ may be identical to or different from each other.

In Formulae 1-1 to 1-3, i) two or more of d1 R₁(s) may optionally be bonded together to form a C₃-C₆₀ carbocyclic group unsubstituted or substituted with at least one R₁₀ₐ or a C₁-C₆₀ heterocyclic group unsubstituted or substituted with at least one R₁₀ₐ, ii) two or more of d2 R₂(s) may optionally be bonded together to form a C₃-C₆₀ carbocyclic group unsubstituted or substituted with at least one R₁₀ₐ or a C₁-C₆₀ heterocyclic group unsubstituted or substituted with at least one R₁₀ₐ, iii) two or more of d3 R₃(s) may optionally be bonded together to form a C₃-C₆₀ carbocyclic group unsubstituted or substituted with at least one R₁₀ₐ or a C₁-C₆₀ heterocyclic group unsubstituted or substituted with at least one R₁₀ₐ, iv) two or more of d4 R₄(s) may optionally be bonded together to form a C₃-C₆₀ carbocyclic group unsubstituted or substituted with at least one R₁₀ₐ or a C₁-C₆₀ heterocyclic group unsubstituted or substituted with at least one R₁₀ₐ, v) two or more of d5 R₅(s) may optionally be bonded together to form a C₃-C₆₀ carbocyclic group unsubstituted or substituted with at least one R₁₀ₐ or a C₁-C₆₀ heterocyclic group unsubstituted or substituted with at least one R₁₀ₐ, and vi) two or more of d6 R₆(s) may optionally be bonded together to form a C₃-C₆₀ carbocyclic group unsubstituted or substituted with at least one R₁₀ₐ or a C₁-C₆₀ heterocyclic group unsubstituted or substituted with at least one R₁₀ₐ.

In one or more embodiments, at least one selected from d1 R₁(s), d2 R₂(s), d3 R₃(s), d4 R₄(s), d5 R₅(s), and d6 R₆(s) may not be hydrogen.

In one or more embodiments, at least one selected from d3 R₃(s) and d4 R₄(s) may not be hydrogen.

In one or more embodiments, at least one selected from d1 R₁(s), d2 R₂(s), d3 R₃(s), d4 R₄(s), d5 R₅(s), and d6 R₆(s) may be a substituent R_{X} which is not hydrogen.

In one or more embodiments, at least one selected from d3 R₃(s) and d4 R₄(s) may be a substituent R_{X} which is not hydrogen.

In one or more embodiments, R_{X} may be:
deuterium, —F, a cyano group, or a C₁-C₂₀ alkyl group;
a C₁-C₂₀ alkyl group or a C₃-C₁₀ cycloalkyl group, each substituted with deuterium, —F, a cyano group, or any combination thereof; or
a C₃-C₆₀ carbocyclic group or a C₁-C₆₀ heterocyclic group, each substituted with deuterium, —F, a cyano group, a C₁-C₂₀ alkyl group, a deuterated C₁-C₂₀ alkyl group, a fluorinated C₁-C₂₀ alkyl group, a deuterated phenyl group, a fluorinated phenyl group, a (C₁-C₂₀ alkyl)phenyl group, a deuterated biphenyl group, a fluorinated biphenyl group, or any combination thereof.

The term “biphenyl group” as used herein refers to a monovalent substituent having a structure in which two benzene groups are connected to each other through a single bond.

Examples of the “C₃-C₁₀ cycloalkyl group” are a cyclopentyl group, a cyclohexyl group, a cycloheptyl group, an adamantanyl group, a norbornanyl group, and the like.

The term “deuterated” as used herein includes the meaning of both fully deuterated and partially deuterated.

The term “fluorinated” as used herein includes the meaning of both fully fluorinated and partially fluorinated.

In one or more embodiments, the organometallic compound represented by Formula 1 may be represented by Formula 1A or 1A-1:

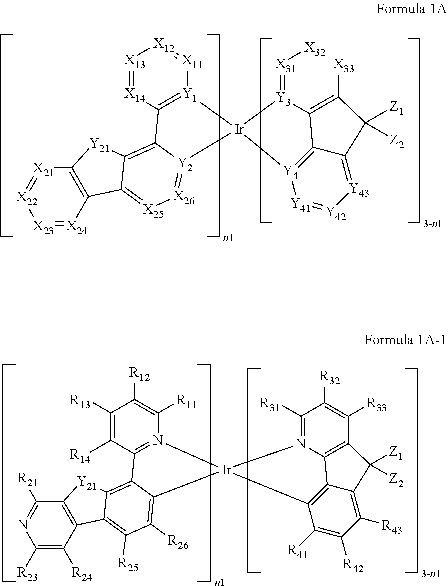

wherein, in Formulae 1A and 1A-1,
Y₁ to Y₄, Y₂₁, X₂₁ to X₂₆, Y₃₁ to Y₃₃, Y₄₁ to Y₄₄, Z₁, and Z₂ are each be the same as described herein,
X₁₁ may be C(R₁₁) or N, X₁₂ may be C(R₁₂) or N, X₁₃ may be C(R₁₃) or N, and X₁₄ may be C(R₁₄) or N,
R₁₁ to R₁₄ are each the same as described in connection with R₁,
R₂₁ to R₂₆ are each the same as described in connection with R₂,
R₃₁ to R₃₃ are each the same as described in connection with R₃,
R₄₁ to R₄₃ are each the same as described in connection with R₄, and
n1 may be 1 or 2.

In one or more embodiments, the organometallic compound represented by Formula 1 may be one selected from Compounds 1 to 45, but embodiments are not limited thereto:

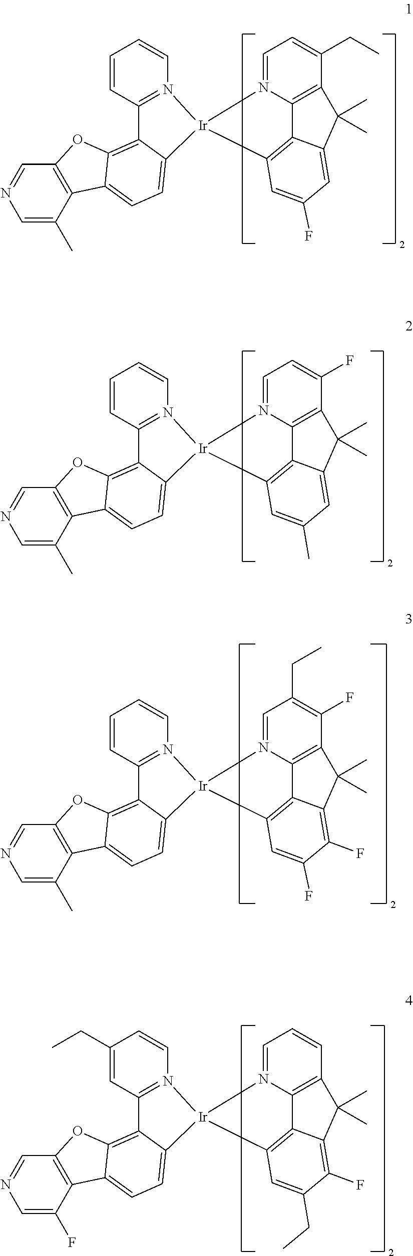

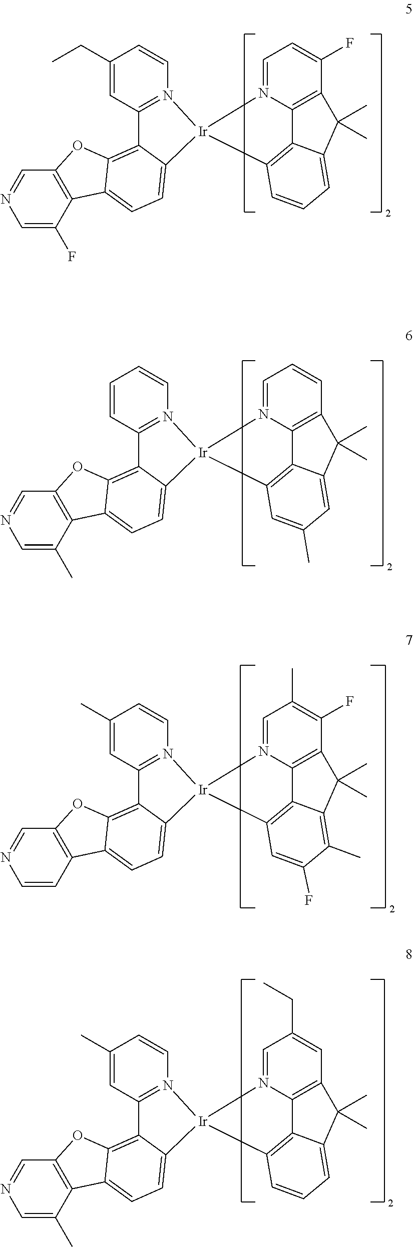

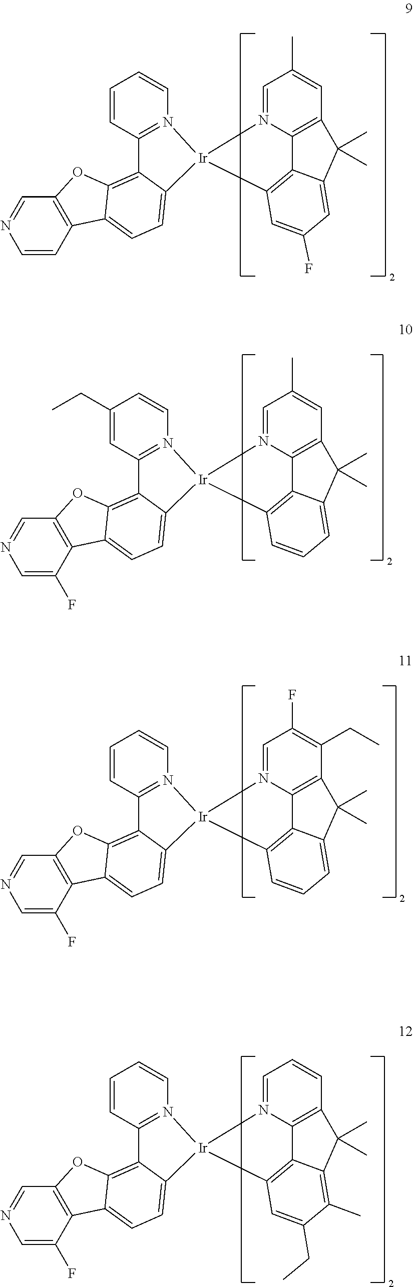

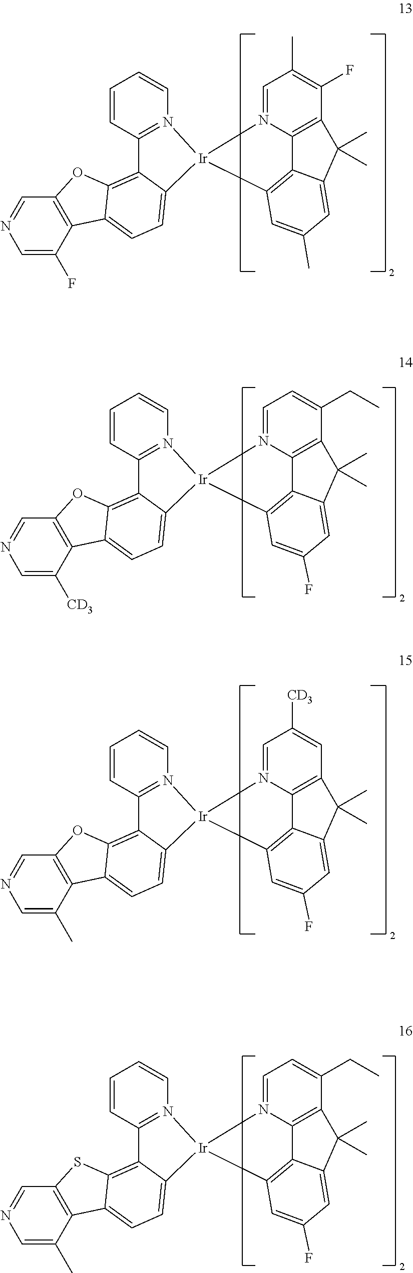

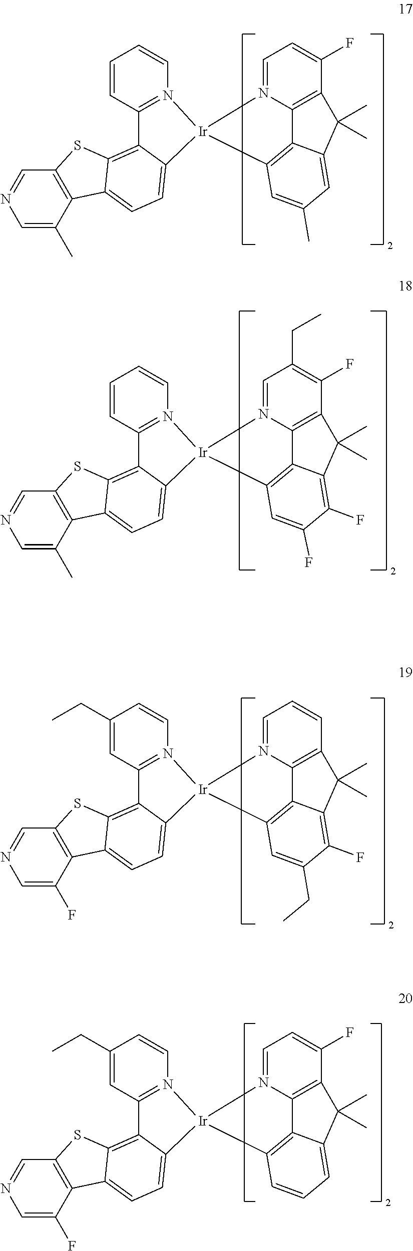

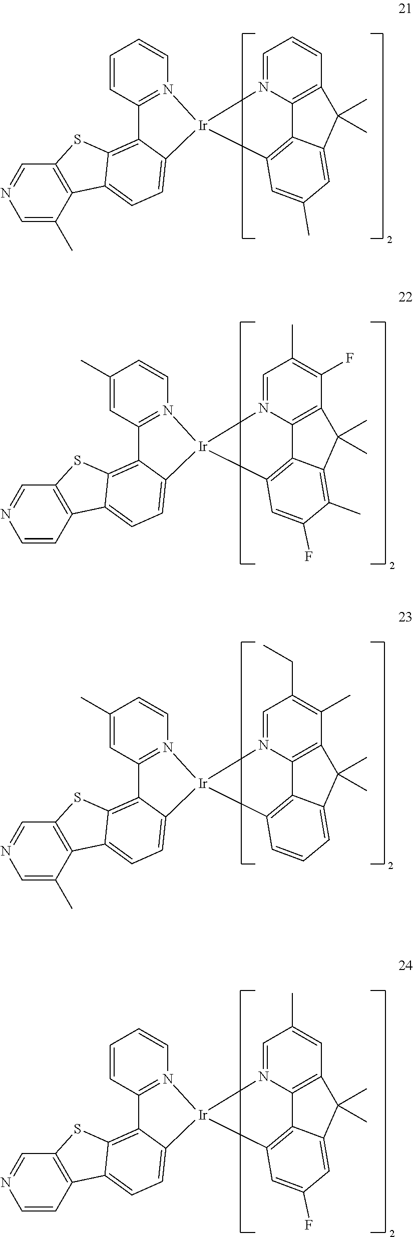

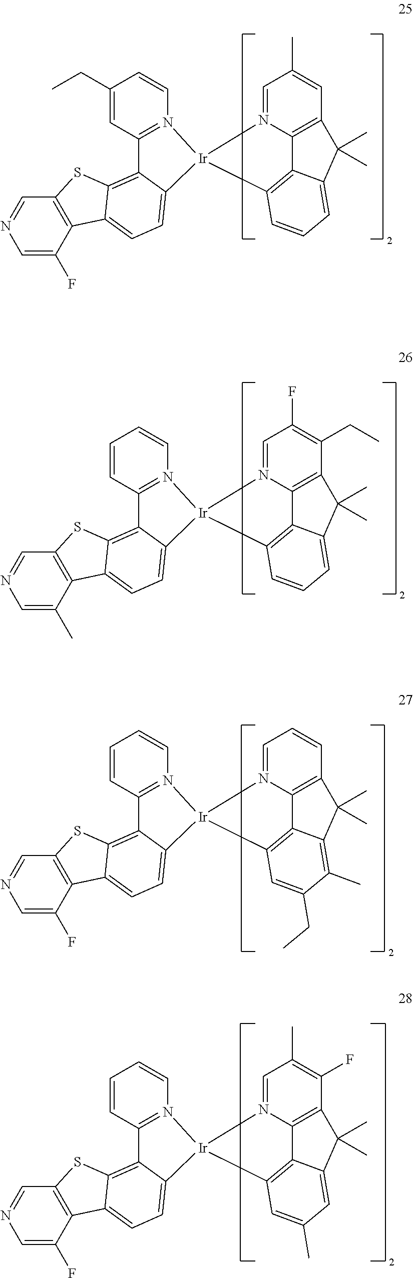

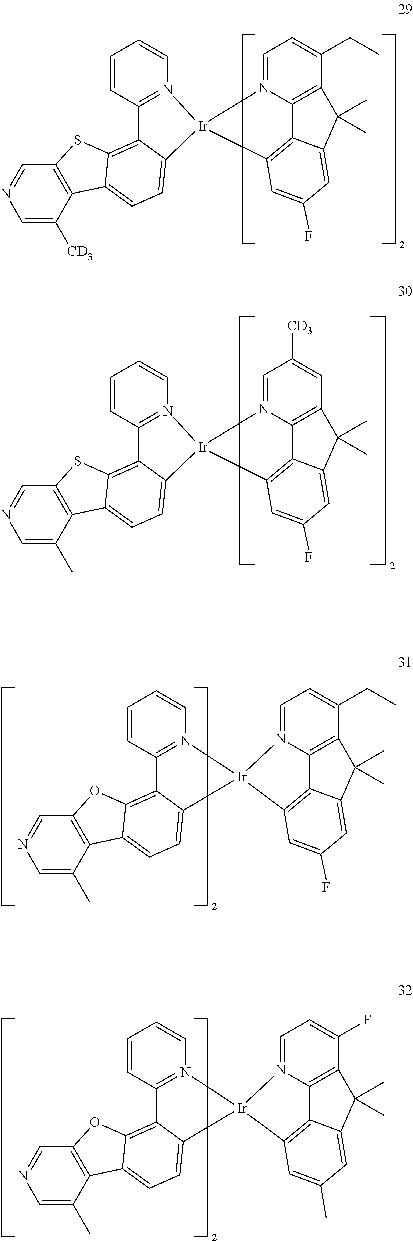

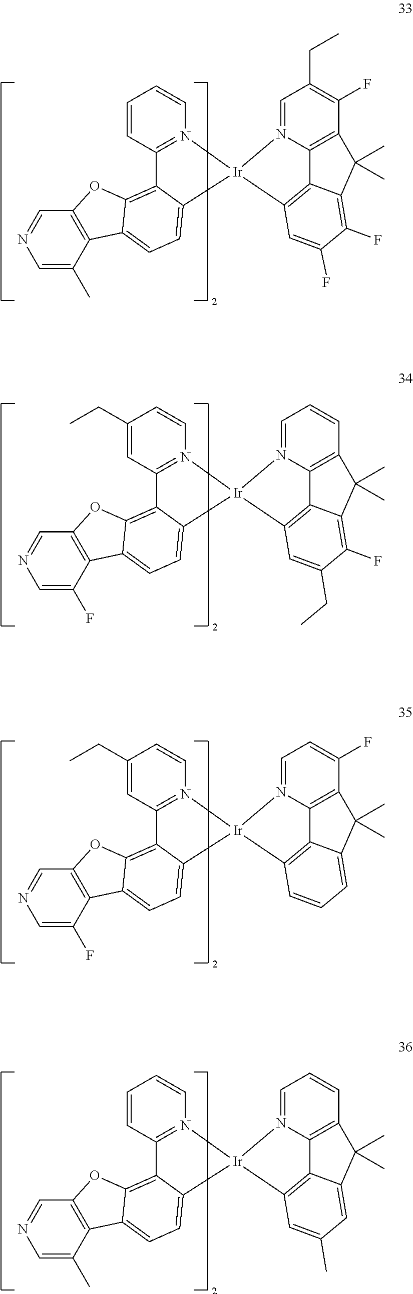

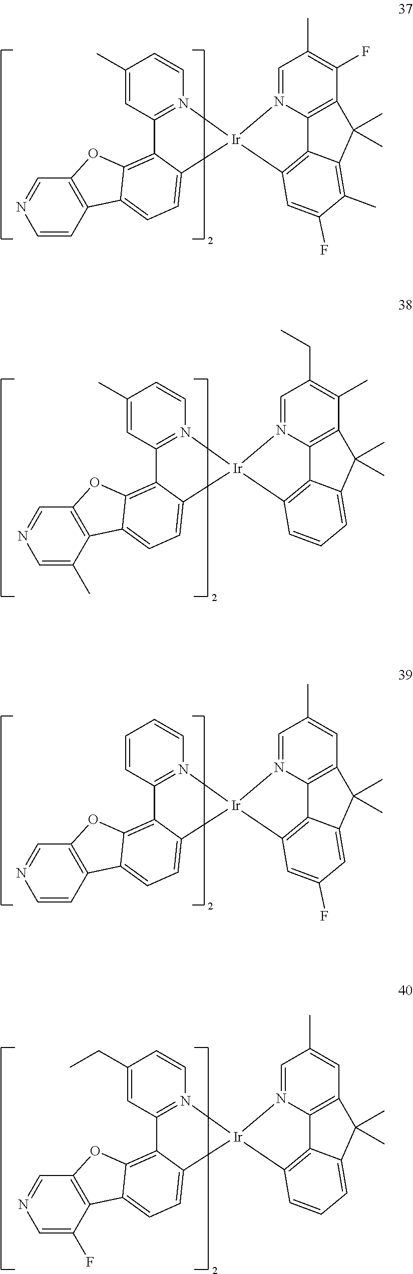

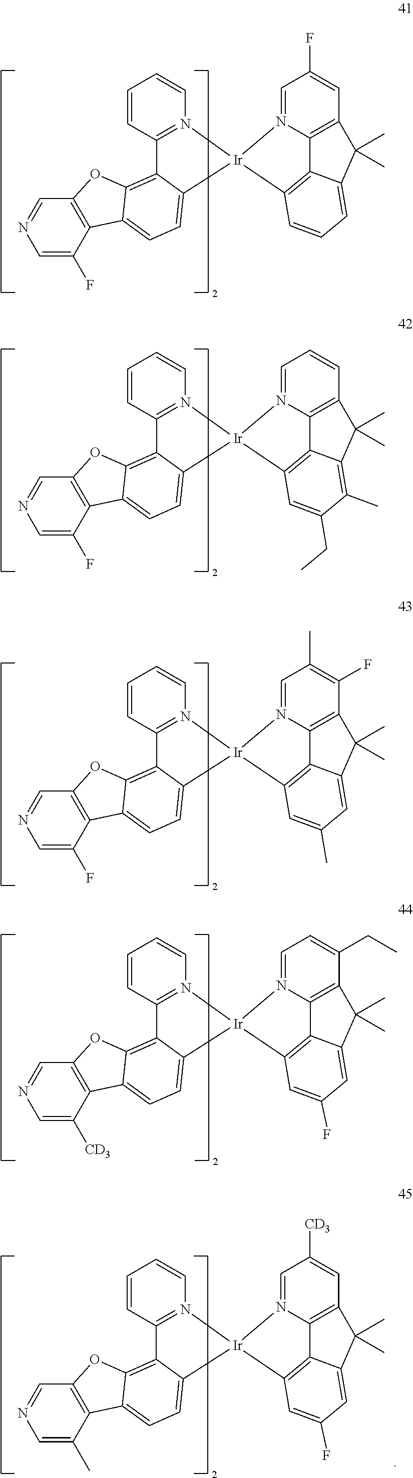

Another aspect of embodiments of the disclosure provides a light-emitting device including: a first electrode; a second electrode facing the first electrode; an interlayer between the first electrode and the second electrode; and the organometallic compound. The organometallic compound may be an organometallic compound represented by Formula 1 or an organometallic compound including a first metal and the first ligand, wherein Formula 1, the first metal, and the first ligand are each the same as described herein.

Synthesis methods of the organometallic compound should be readily recognizable by one of ordinary skill in the art by referring to Synthesis Examples and/or Examples provided herein below.

In one or more embodiments, the interlayer may include an emission layer, and the emission layer may include the organometallic compound.

In one or more embodiments,
the first electrode of the light-emitting device may be an anode,
the second electrode of the light-emitting device may be a cathode,
the interlayer may further include a hole transport region between the first electrode and the emission layer and an electron transport region between the emission layer and the second electrode,
the hole transport region may include a hole injection layer, a hole transport layer, an emission auxiliary layer, an electron blocking layer, or any combination thereof, and
the electron transport region may include a hole blocking layer, an electron transport layer, an electron injection layer, or any combination thereof.

In one or more embodiments, the emission layer may emit light having a maximum emission wavelength in a range of 515 nm to 530 nm.

In one or more embodiments, the emission layer may emit green light.

In one or more embodiments, the emission layer of the light-emitting device may include the organometallic compound, and may additionally include a host, wherein a weight of the organometallic compound may be greater than or equal to 5 parts by weight based on 100 parts by weight of the emission layer or less than or equal to 15 parts by weight based on 100 parts by weight of the emission layer.

In one or more embodiments, the emission layer of the light-emitting device may include a dopant and a host, and the dopant may include the organometallic compound. For example, the organometallic compound may act as a dopant. In one or more embodiments, the emission layer may emit green light.

In one or more embodiments, the light-emitting device may further include at least one selected from a first capping layer outside the first electrode and a second capping layer outside the second electrode.

In one or more embodiments, at least one selected from the first capping layer and the second capping layer may include a material having a refractive index of greater than or equal to about 1.6 at a wavelength of 530 nm.

For example, at least one selected from the first capping layer and the second capping layer may include a material having a refractive index of greater than or equal to 1.5, greater than or equal to 1.55, greater than or equal to 1.6, greater than or equal to 1.65, or greater than or equal to 1.7, at a wavelength of 530 nm.

In one or more embodiments, the refractive index of at least one selected from the first capping layer and the second capping layer may be greater than or equal to about 1.6 at a wavelength of 530 nm.

For example, the refractive index of at least one selected from the first capping layer and the second capping layer may be greater than or equal to 1.5, greater than or equal to 1.55, greater than or equal to 1.6, greater than or equal to 1.65, or greater than or equal to 1.7, at a wavelength of 530 nm.

In one or more embodiments, the light-emitting device may further include at least one selected from a first capping layer outside the first electrode and a second capping layer outside the second electrode, and the organometallic compound may be included in at least one selected from the first capping layer and the second capping layer. The first capping layer and/or the second capping layer may each be the same as described herein.

In one or more embodiments, the light-emitting device may include: a first capping layer outside the first electrode and including the organometallic compound; a second capping layer outside the second electrode and including the organometallic compound; or the first capping layer and the second capping layer.

The wording “(interlayer and/or capping layer) includes an organometallic compound” as used herein may be understood as “(interlayer and/or capping layer) may include one kind of organometallic compound represented by Formula 1 or two different kinds of organometallic compounds, each represented by Formula 1.”

In one or more embodiments, the interlayer and/or the capping layer may include Compound 1 only as the organometallic compound. Here, Compound 1 may be present in the emission layer of the light-emitting device. In one or more embodiments, the interlayer may include, as the organometallic compound, Compound 1 and Compound 2. Here, Compound 1 and Compound 2 may be present in the same layer (for example, both Compound 1 and Compound 2 may be present in the emission layer), or may be present in different layers (for example, Compound 1 may be present in the emission layer, and Compound 2 may be present in the electron transport region).

The term “interlayer” as used herein refers to a single layer and/or all of a plurality of layers between the first electrode and the second electrode of the light-emitting device.

Another aspect of embodiments of the disclosure provides an electronic apparatus including the light-emitting device. The electronic apparatus may further include a thin-film transistor. For example, the electronic apparatus may further include a thin-film transistor including a source electrode and a drain electrode, wherein the first electrode of the light-emitting device may be electrically connected to the source electrode or the drain electrode. In one or more embodiments, the electronic apparatus may further include a color filter, a color conversion layer, a touch screen layer, a polarizing layer, or any combination thereof. More details of the electronic apparatus may be understood by referring to the descriptions provided elsewhere herein.

Another aspect of embodiments of the disclosure provides an electronic apparatus including the light-emitting device.

The electronic apparatus may be a flat panel display, a curved display, a computer monitor, a medical monitor, a television, an advertisement board, an indoor or outdoor lighting and/or signaling light, a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a 3D display, a virtual or augmented reality display, a vehicle, a video wall including multiple displays tiled together, a theater or stadium screen, a phototherapy device, or a sign.

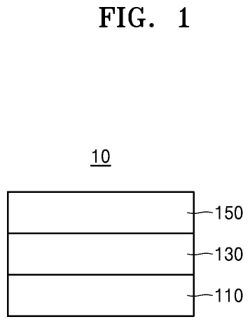

### Description of FIG. 1

FIG. 1 is a schematic cross-sectional view of a light-emitting device 10 according to one or more embodiments. The light-emitting device 10 includes a first electrode 110, an interlayer 130, and a second electrode 150.

Hereinafter, the structure of the light-emitting device 10 according to one or more embodiments and a method of manufacturing the light-emitting device 10 will be described with reference to FIG. 1.

First Electrode 110

In FIG. 1, a substrate may be additionally under the first electrode 110 or on the second electrode 150. In one or more embodiments, as the substrate, a glass substrate and/or a plastic substrate may be used. In one or more embodiments, the substrate may be a flexible substrate, and may include plastics having excellent heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing and/or sputtering a material for forming the first electrode 110 on the substrate. When the first electrode 110 is an anode, a material for forming the first electrode 110 may be a high-work function material that facilitates injection of holes.

The first electrode 110 may be a reflective electrode, a semi-transmissive electrode, or a transmissive electrode. In one or more embodiments, when the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In one or more embodiments, when the first electrode 110 is a semi-transmissive electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a single-layer structure consisting of a single layer or a multi-layer structure including multiple layers. For example, the first electrode 110 may have a three-layer structure of ITO/Ag/ITO.

### Interlayer 130

The interlayer 130 is on the first electrode 110. The interlayer 130 may include the emission layer.

The interlayer 130 may further include a hole transport region between the first electrode 110 and the emission layer, and an electron transport region between the emission layer and the second electrode 150.

In one or more embodiments, the interlayer 130 may further include, in addition to various suitable organic materials, a metal-containing compound such as an organometallic compound, an inorganic material such as a quantum dot, and the like.

In one or more embodiments, the interlayer 130 may include, i) two or more emitting units sequentially stacked between the first electrode 110 and the second electrode 150, and ii) a charge generation layer between the two or more emitting units. When the emission layer 130 includes the two or more emitting units and the charge generation layer, the light-emitting device 10 may be a tandem light-emitting device.

### Hole Transport Region in Interlayer 130

The hole transport region may have: i) a single-layer structure consisting of a single layer consisting of a single material, ii) a single-layer structure consisting of a single layer consisting of multiple materials that are different from each other, or iii) a multi-layer structure including multiple materials including multiple materials that are different from each other.

The hole transport region 120 may include a hole injection layer, a hole transport layer, an emission auxiliary layer, an electron blocking layer, or any combination thereof.

For example, the hole transport region 120 may have a multi-layer structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein constituent layers of each structure are stacked sequentially from the first electrode 110.

The hole transport region 120 may include a compound represented by Formula 201, a compound represented by Formula 202, or any combination thereof:

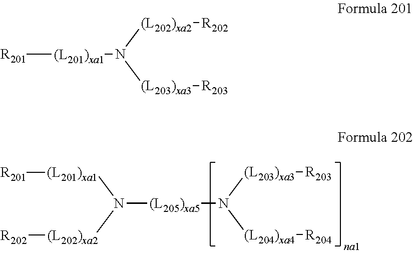

wherein, in Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be bonded to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group (for example, a carbazole group, etc.) unsubstituted or substituted with at least one R₁₀ₐ (for example, Compound HT16, etc.),
R₂₀₃ and R₂₀₄ may optionally be bonded to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer from 1 to 4.

For example, each of Formulae 201 and 202 may include at least one selected from groups represented by Formulae CY201 to CY217:

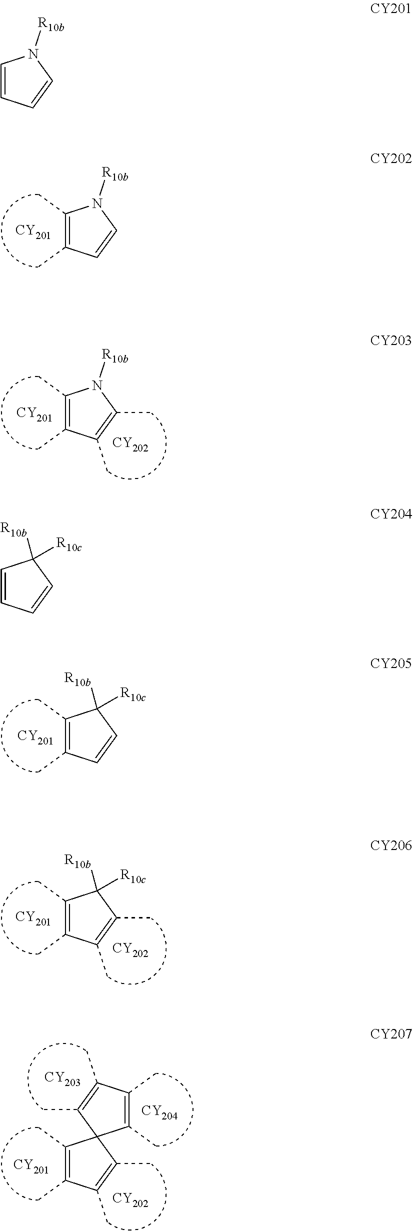

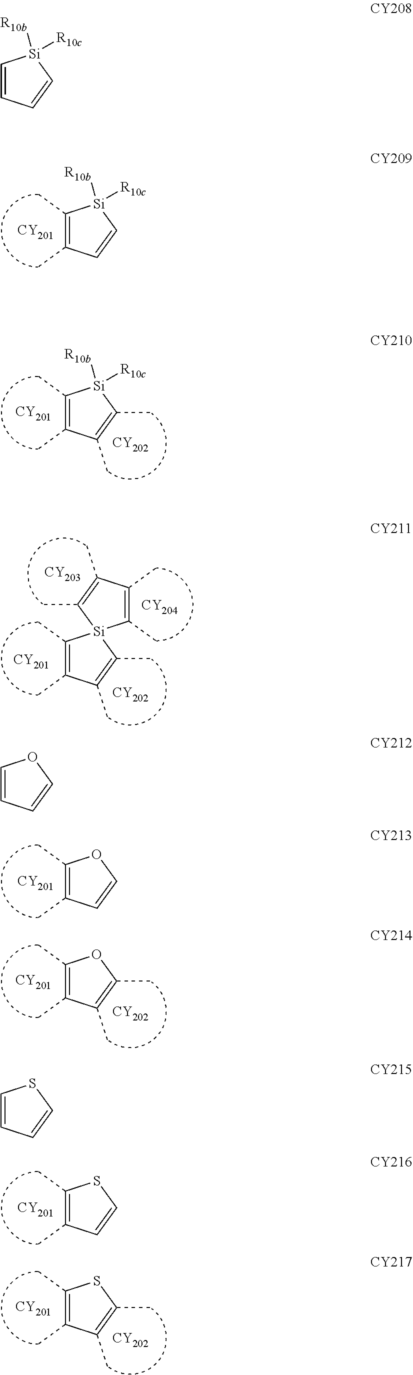

wherein, in Formulae CY201 to CY217, R_{10b} and R_{10c} are each the same as described in connection with R₁₀ₐ, ring CY201 to ring CY204 may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In one or more embodiments, in Formulae CY201 to CY217, ring CY201 to ring CY₂₀₄ may each independently be a benzene group, a naphthalene group, a phenanthrene group, or an anthracene group.

In one or more embodiments, each of Formulae 201 and 202 may include at least one selected from the groups represented by Formulae CY201 to CY203.

In one or more embodiments, Formula 201 may include at least one selected from the groups represented by Formulae CY201 to CY203 and at least one selected from the groups represented by Formulae CY204 to CY217.

In one or more embodiments, in Formula 201, xa1 may be 1, R₂₀₁ may be one selected from the groups represented by Formulae CY201 to CY203, xa2 may be 0, and R₂₀₂ may be one selected from the groups represented by Formulae CY204 to CY207.

In one or more embodiments, each of Formulae 201 and 202 may not include the groups represented by Formulae CY201 to CY203.

In one or more embodiments, each of Formulae 201 and 202 may not include the groups represented by Formulae CY201 to CY203, and may include at least one selected from the groups represented by Formulae CY204 to CY217.

In one or more embodiments, each of Formulae 201 and 202 may not include the groups represented by Formulae CY201 to CY217.

For example, the hole transport region may include one selected from Compounds HT1 to HT46, m-MTDATA, TDATA, 2-TNATA, NPB(NPD), β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

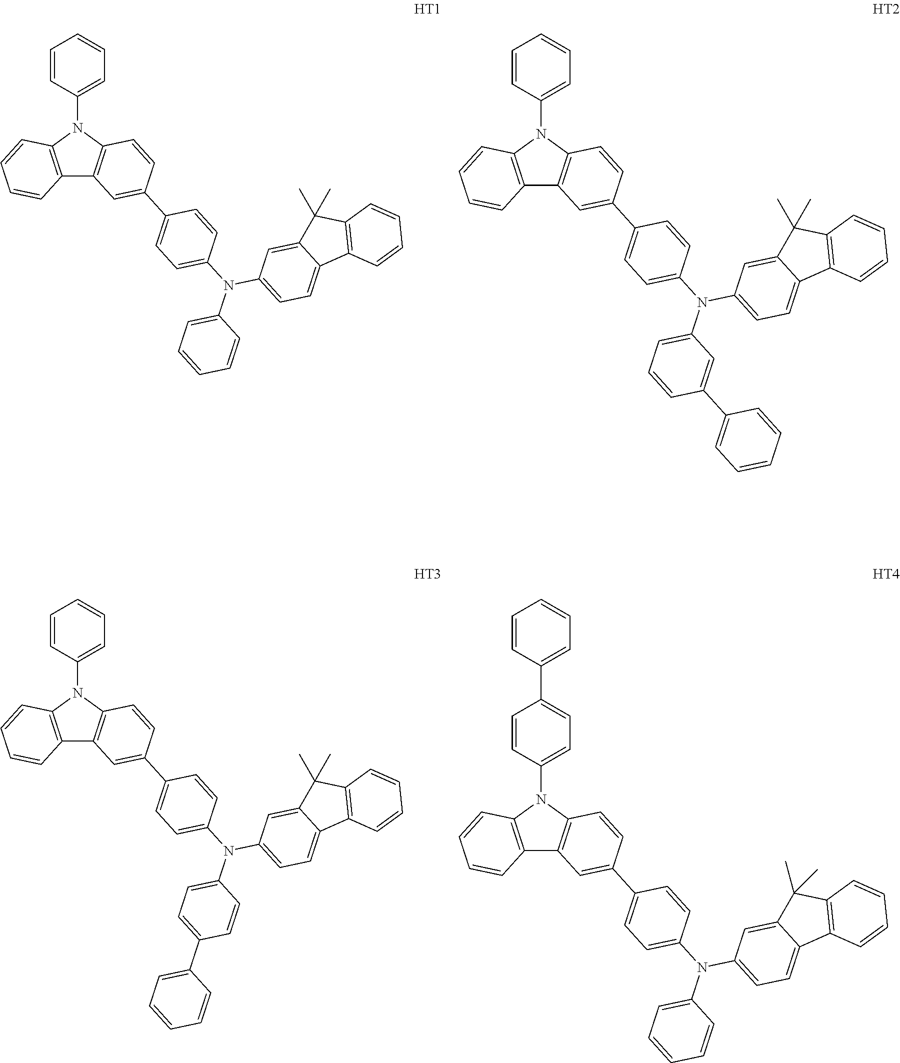 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

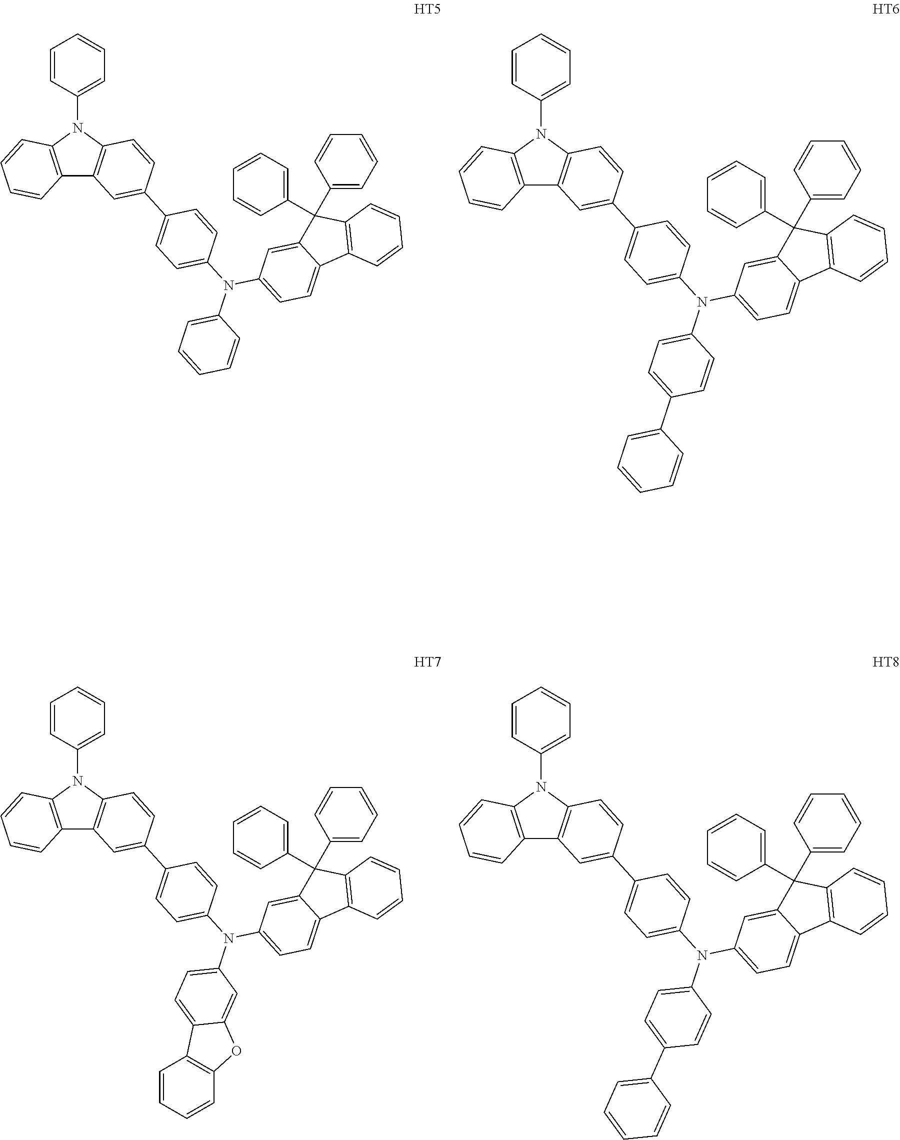 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

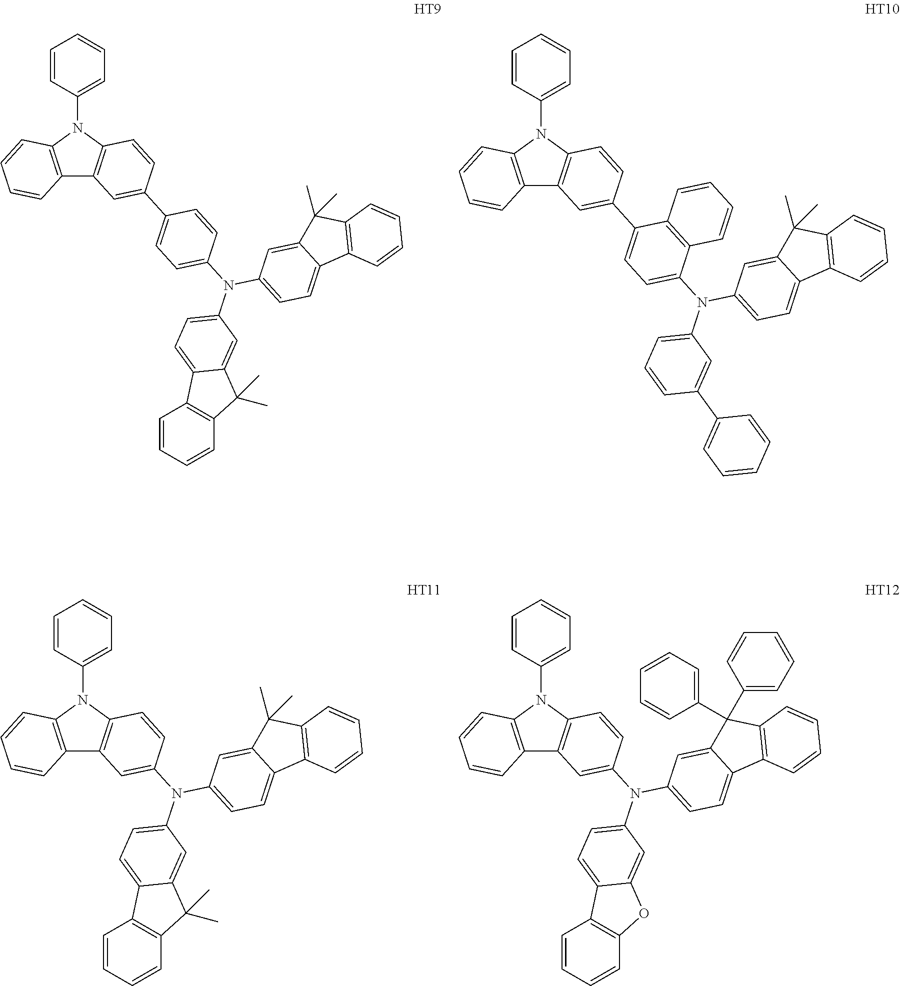 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

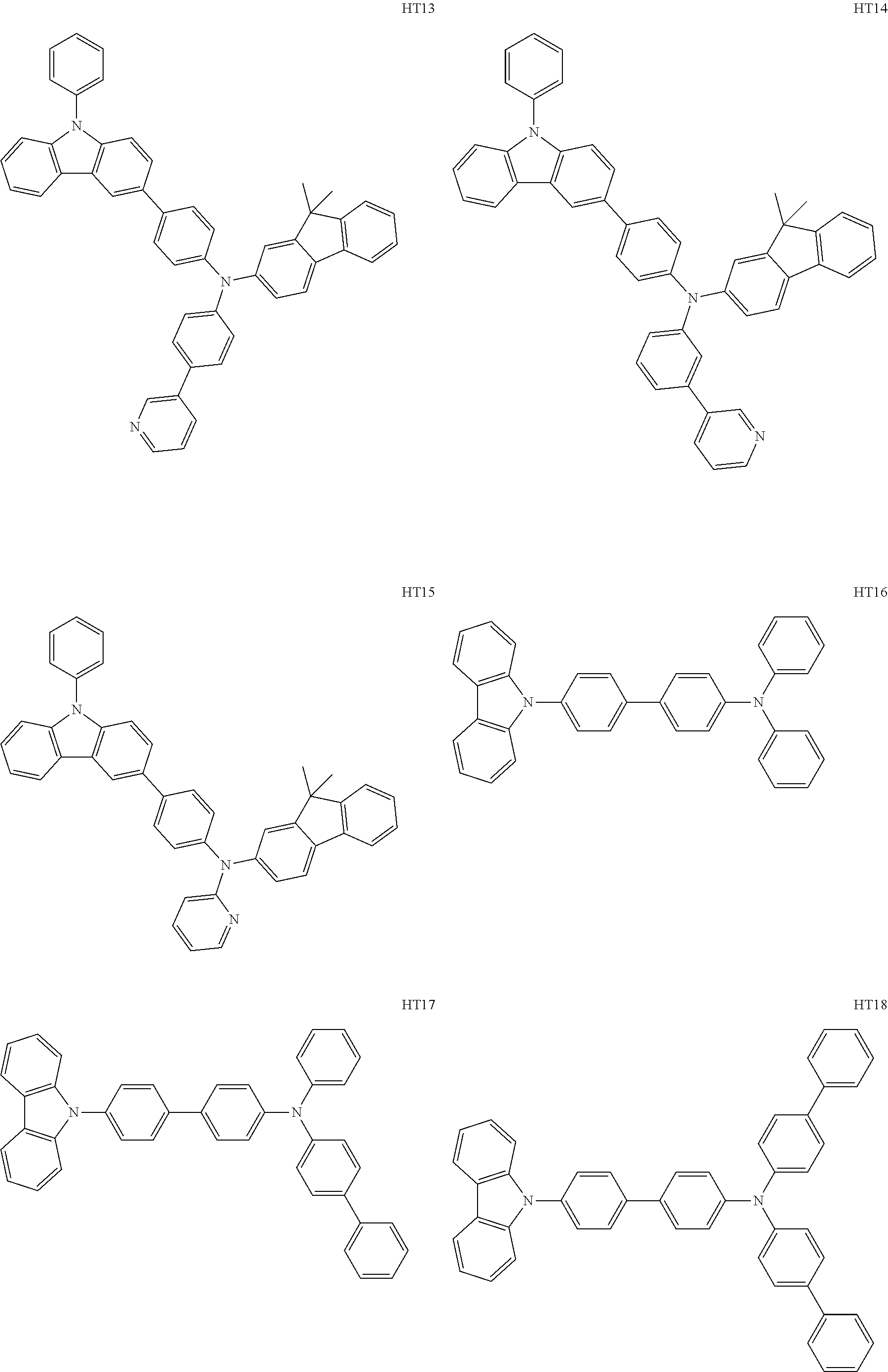 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

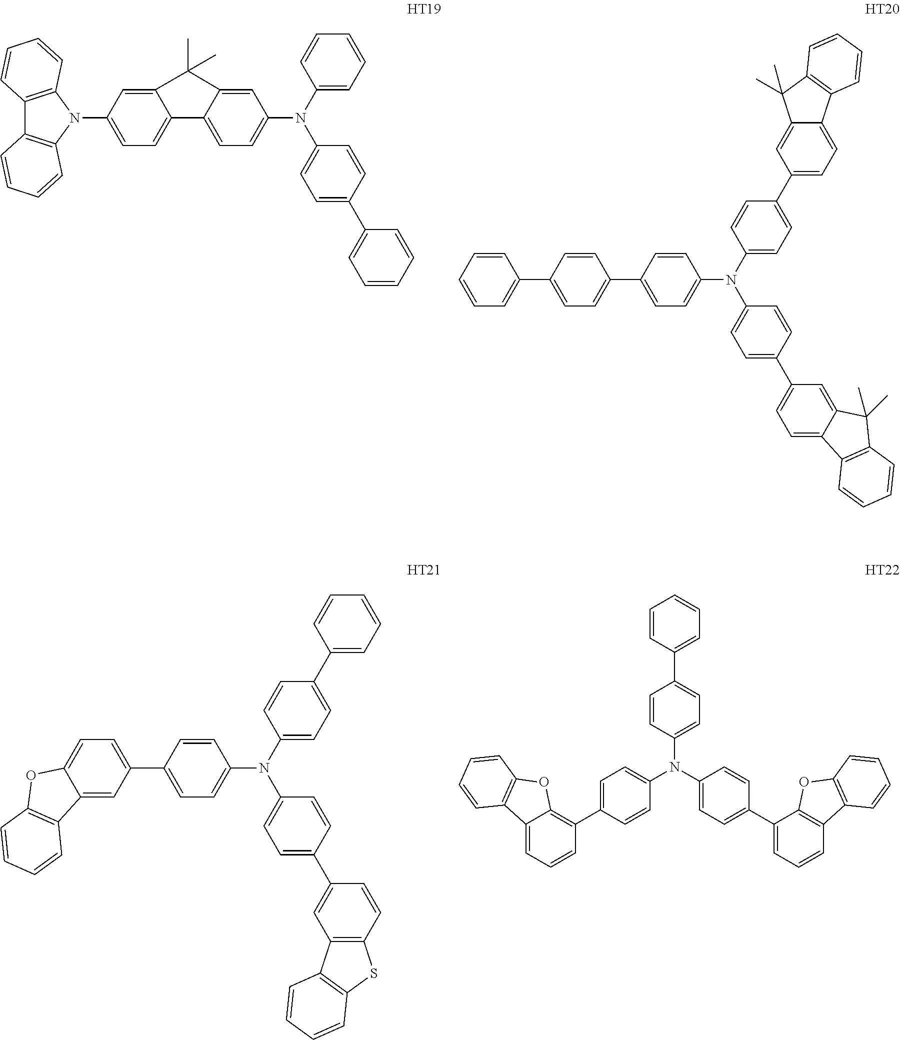 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1]

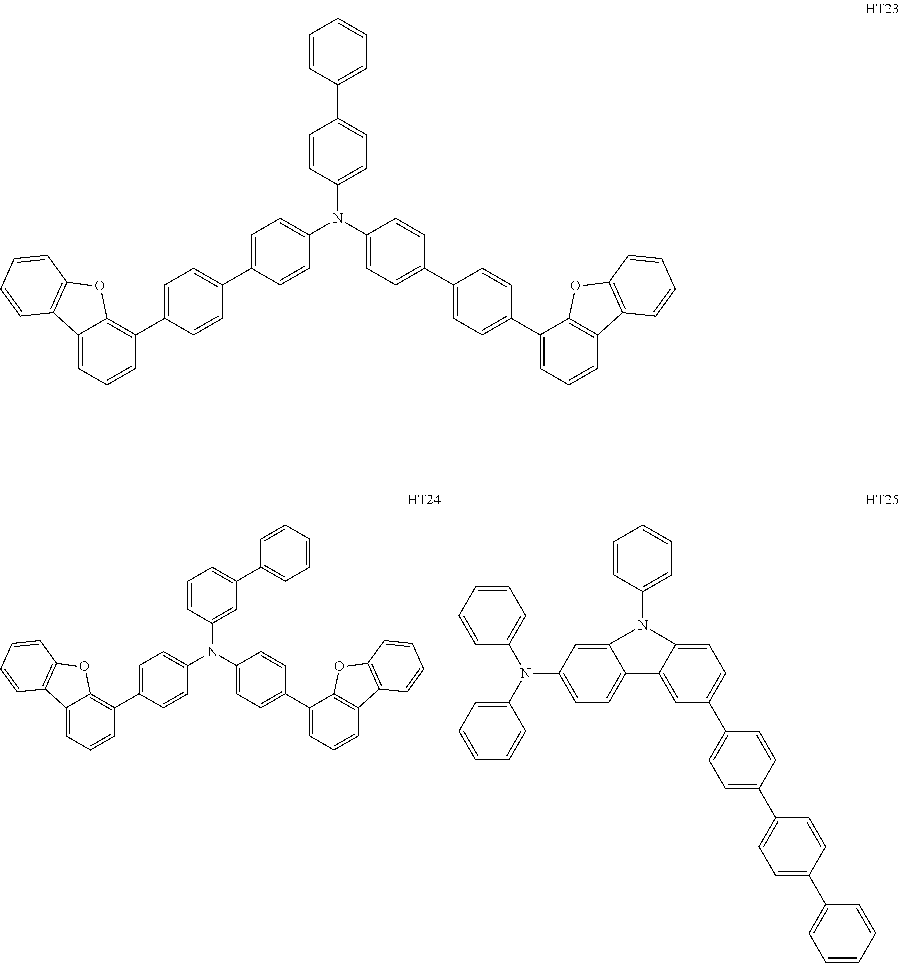 [SMILES: c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1 ; c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(-c3ccc(-c4ccc5c(c4)c4ccc(N(c6ccccc6)c6ccccc6)cc4n5-c4ccccc4)cc3)cc2)cc1]

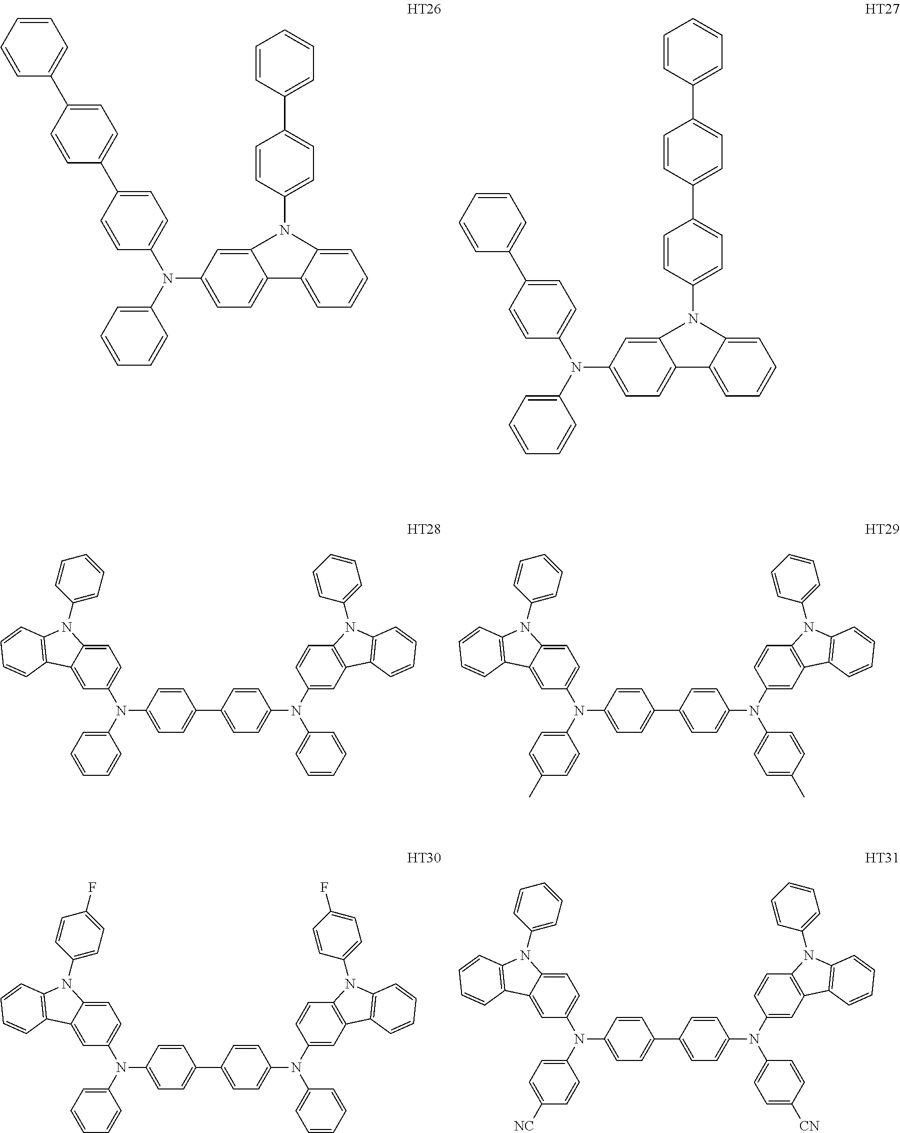

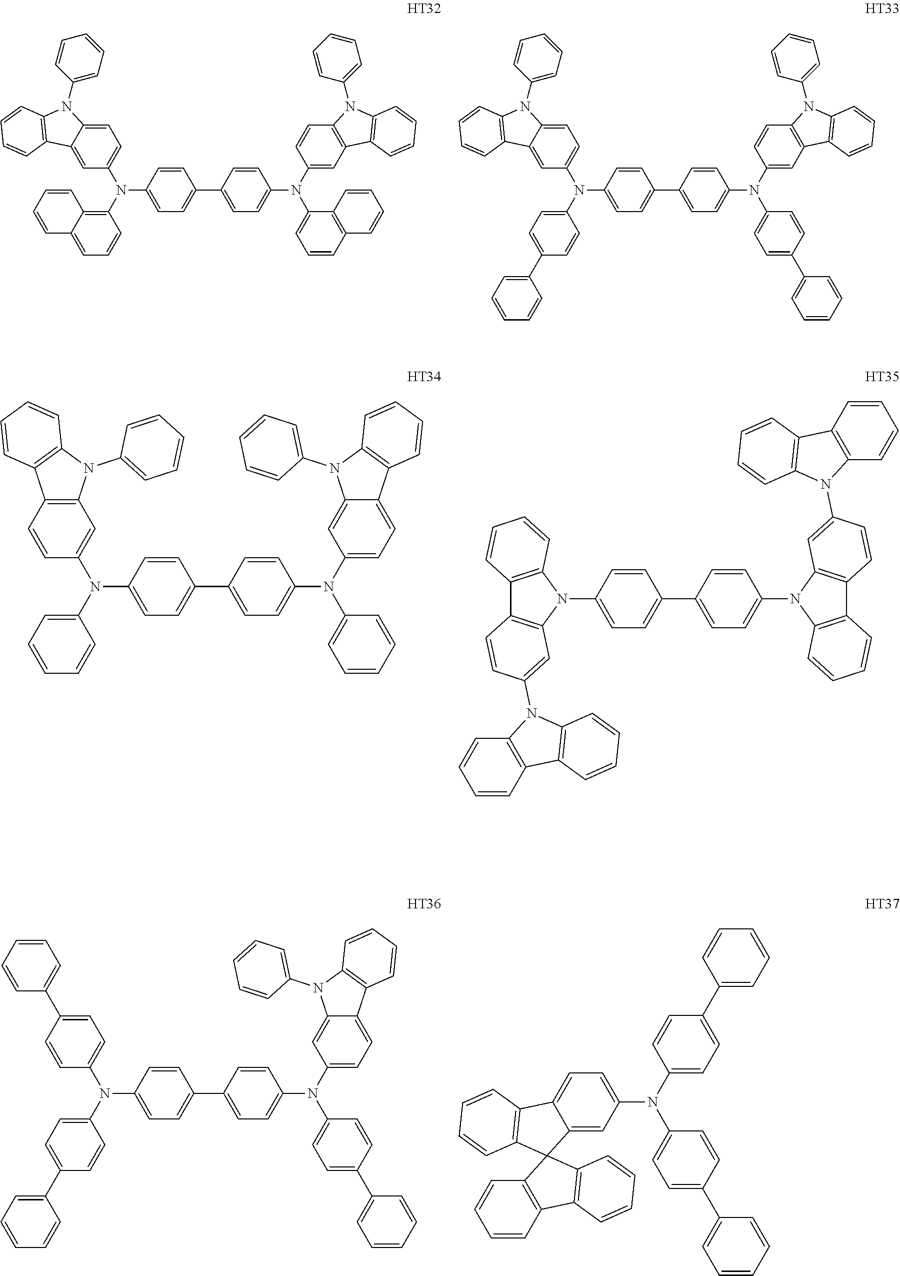

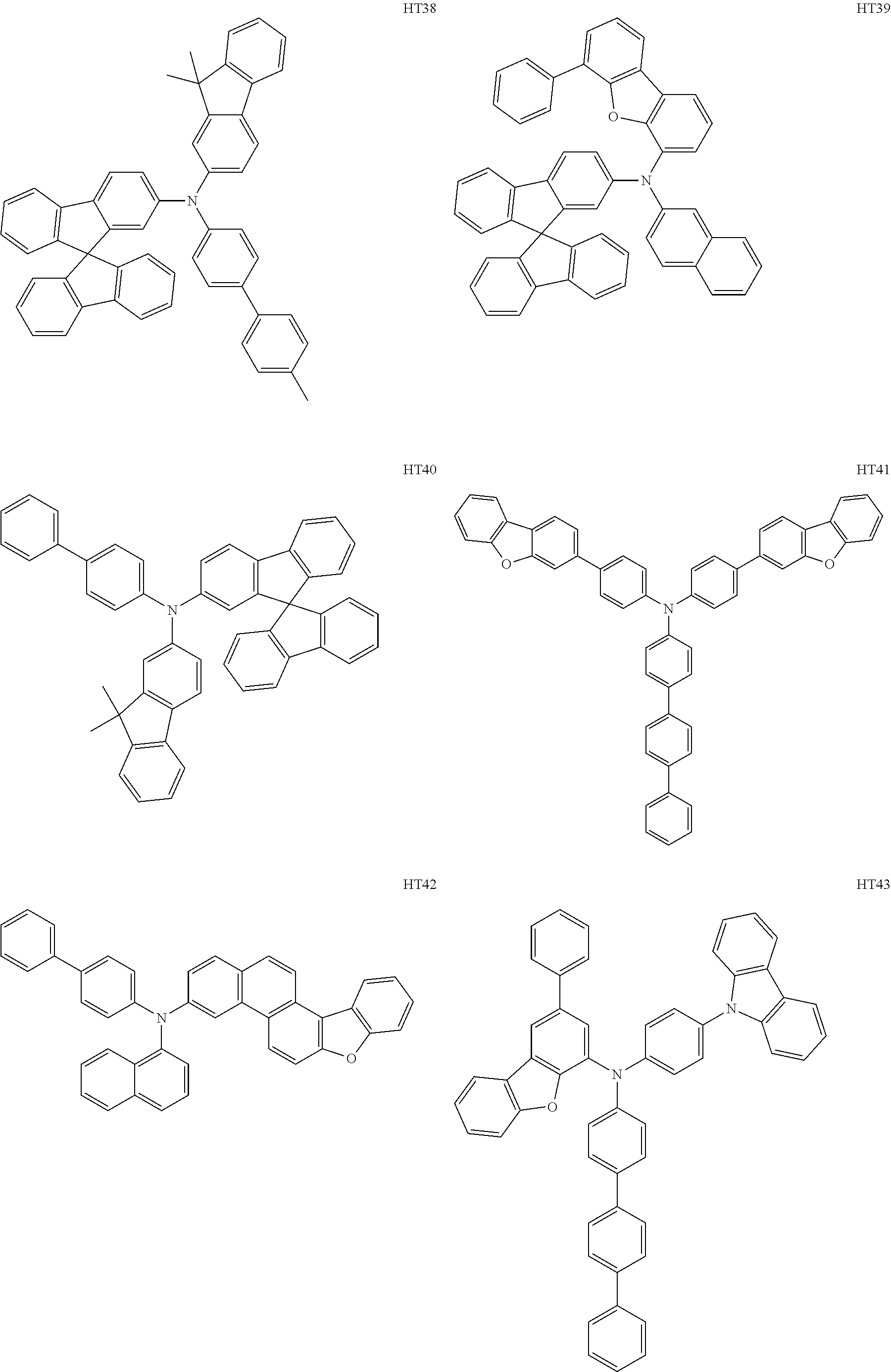

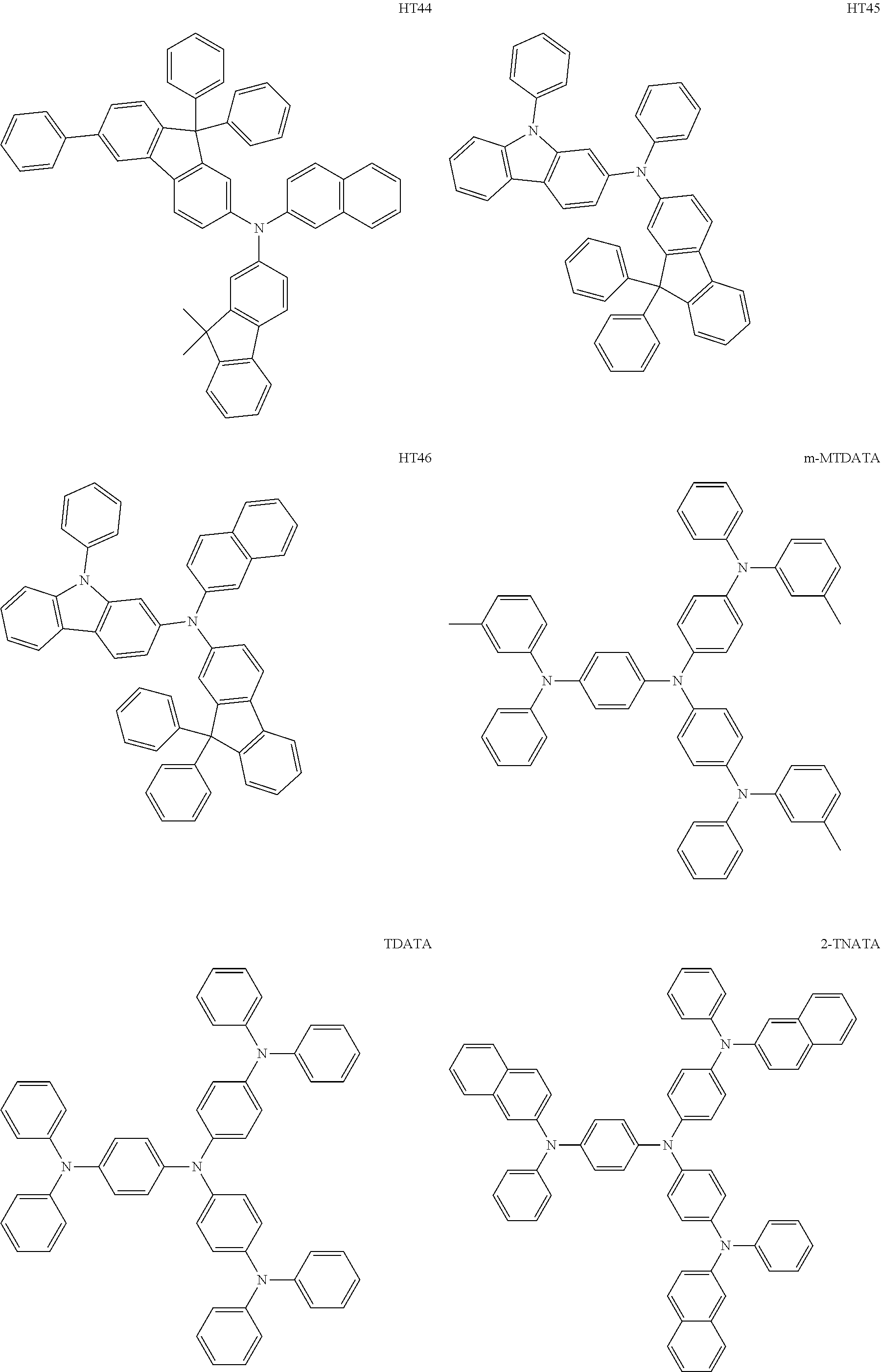

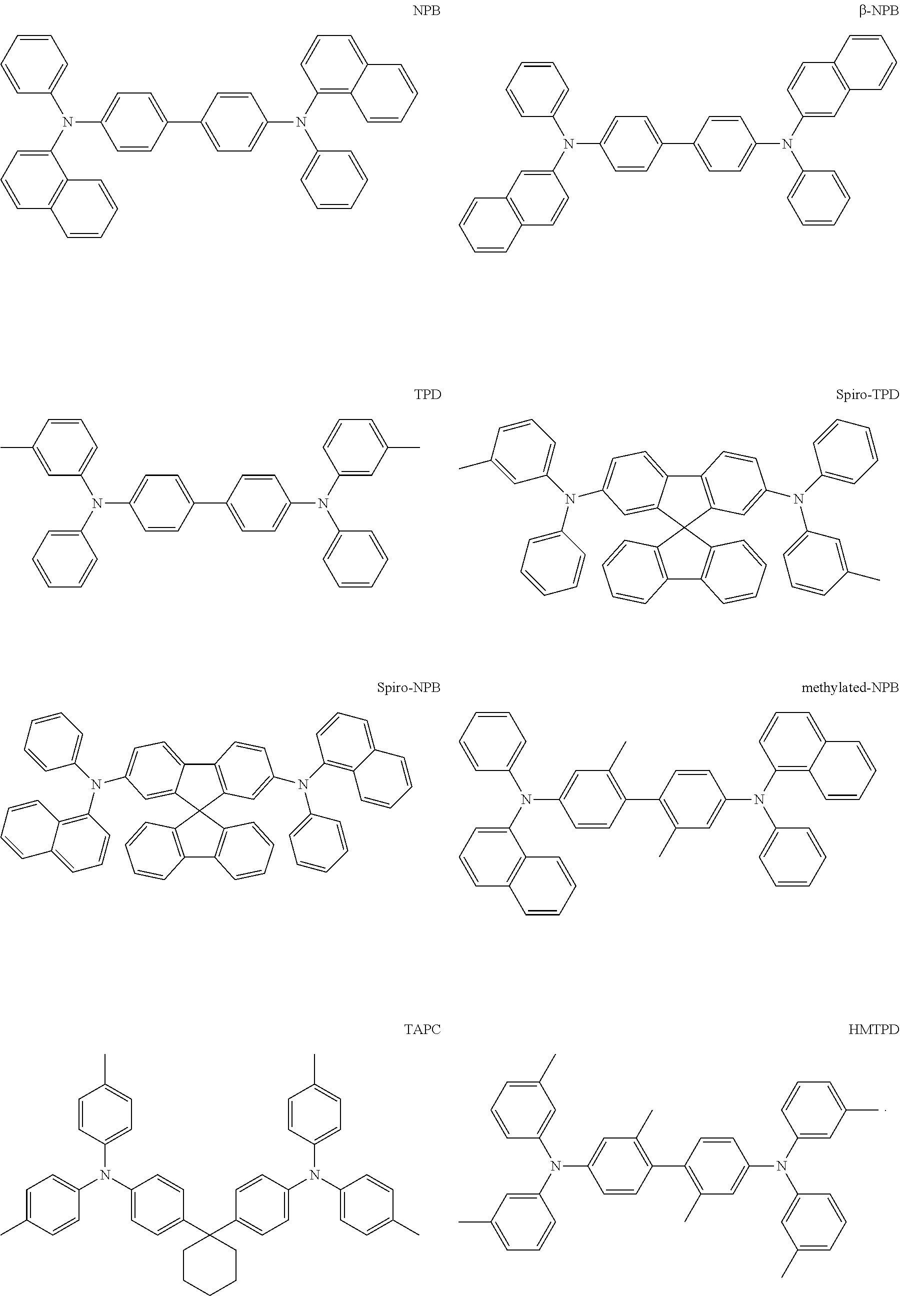

A thickness of the hole transport region may be in a range of about 50 Å to about 10,000 Å, for example, about 100 Å to about 4,000 Å. When the hole transport region includes a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer, and the hole transport layer are within these ranges, suitable or satisfactory hole transporting characteristics may be obtained without a substantial increase in driving voltage.

The emission auxiliary layer may increase light-emission efficiency by compensating for an optical resonance distance according to the wavelength of light emitted by the emission layer, and the electron blocking layer may block or reduce the leakage of electrons from the emission layer to the hole transport region. Materials that may be included in the hole transport region may be included in the emission auxiliary layer and the electron blocking layer.

p-Dopant

The hole transport region may further include, in addition to these materials, a charge-generation material for the improvement of conductive properties (e.g., electrically conductive properties). The charge-generation material may be uniformly or non-uniformly dispersed in the hole transport region (for example, in the form of a single layer consisting of a charge-generation material).

The charge-generation material may be, for example, a p-dopant.

For example, the p-dopant may have a LUMO energy level of less than or equal to about −3.5 eV.

In one or more embodiments, the p-dopant may include a quinone derivative, a cyano group-containing compound, a compound including element EL1 and element EL2, or any combination thereof.

Examples of the quinone derivative are TCNQ, F4-TCNQ, and the like.

Examples of the cyano group-containing compound are HAT-CN, a compound represented by Formula 221, and the like:

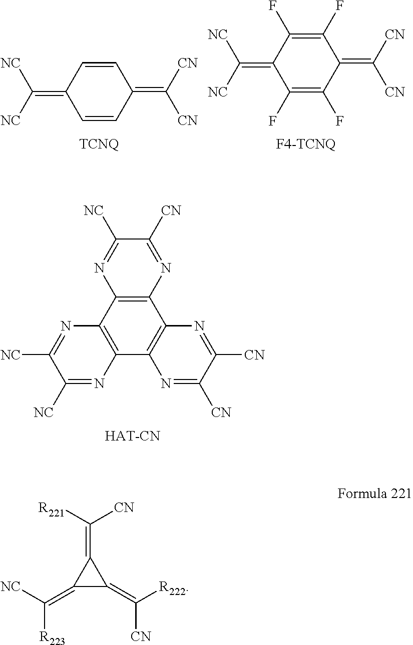

In Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one selected from R₂₂₁ to R₂₂₃ may each independently be a C₃-C₆₀ carbocyclic group or a C₁-C₆₀ heterocyclic group, each substituted with: a cyano group; —F; —C₁; —Br; —I; a C₁-C₂₀ alkyl group substituted with a cyano group, —F, —Cl, —Br, —I, or any combination thereof; or any combination thereof.

In the compound including element EL1 and element EL2, element EL1 may be metal, metalloid, or any combination thereof, and element EL2 may be non-metal, metalloid, or any combination thereof.

Examples of the metal are an alkali metal (for example, lithium (Li), sodium (Na), potassium (K), rubidium (Rb), cesium (Cs), etc.); alkaline earth metal (for example, beryllium (Be), magnesium (Mg), calcium (Ca), strontium (Sr), barium (Ba), etc.); transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); post-transition metal (for example, zinc (Zn), indium (In), tin (Sn), etc.); lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.); and the like.

Examples of the metalloid are silicon (Si), antimony (Sb), tellurium (Te), and the like.

Examples of the non-metal are oxygen (O), halogen (for example, F, Cl, Br, I, etc.), and the like.

Examples of the compound including element EL1 and element EL2 are metal oxide, metal halide (for example, metal fluoride, metal chloride, metal bromide, metal iodide, etc.), metalloid halide (for example, metalloid fluoride, metalloid chloride, metalloid bromide, metalloid iodide, etc.), metal telluride, or any combination thereof.

Examples of the metal oxide are tungsten oxide (for example, WO, W₂O₃, WO₂, WO₃, W₂O₅, etc.), vanadium oxide (for example, VO, V₂O₃, VO₂, V₂O₅, etc.), molybdenum oxide (MoO, Mo₂O₃, MoO₂, MoO₃, Mo₂O₅, etc.), rhenium oxide (for example, ReO₃, etc.), and the like.

Examples of the metal halide are alkali metal halide, alkaline earth metal halide, transition metal halide, post-transition metal halide, lanthanide metal halide, and the like.

Examples of the alkali metal halide are LiF, NaF, KF, RbF, CsF, LiCl, NaCl, KCl, RbCl, CsCl, LiBr, NaBr, KBr, RbBr, CsBr, Lil, NaI, KI, Rbl, Csl, and the like.

Examples of the alkaline earth metal halide are BeF₂, MgF₂, CaF₂, SrF₂, BaF₂, BeCl₂, MgCl₂, CaCl₂), SrCl₂, BaCI₂, BeBr₂, MgBr₂, CaBr₂, SrBr₂, BaBr₂, Bel₂, Mg₁₂, Cal₂, Sr₁₂, Bal₂, and the like.

Examples of the transition metal halide are titanium halide (for example, TiF₄, TiCl₄, TiBr₄, Til₄, etc.), zirconium halide (for example, ZrF₄, ZrC₁₄, ZrBr₄, ZrI₄, etc.), hafnium halide (for example, HfF₄, HfC₁₄, HfBr₄, Hfl₄, etc.), vanadium halide (for example, VF₃, VCI₃, VBrs, VI₃, etc.), niobium halide (for example, NbF₃, NbCIs, NbBrs, NbI₃, etc.), tantalum halide (for example, TaF₃, TaCl₃, TaBrs, Tal₃, etc.), chromium halide (for example, CrF₃, CrCl₃, CrBr₃, Crl₃, etc.), molybdenum halide (for example, MoF₃, MoCl₃, MoBrs, MoI₃, etc.), tungsten halide (for example, WF₃, WC₁₃, WBrs, WI₃, etc.), manganese halide (for example, MnF₂, MnCl₂, MnBr₂, Mn₁₂, etc.), technetium halide (for example, TcF₂, TcCl₂, TcBr₂, Tc₁₂, etc.), rhenium halide (for example, ReF₂, ReCl₂, ReBr₂, Rel₂, etc.), iron halide (for example, FeF₂, FeCl₂, FeBr₂, Fel₂, etc.), ruthenium halide (for example, RuF₂, RuCl₂, RuBr₂, RuI₂, etc.), osmium halide (for example, OsF₂, OsC₁₂, OsBr₂, Os₁₂, etc.), cobalt halide (for example, CoF₂, COC₁₂, CoBr₂, C₀₁₂, etc.), rhodium halide (for example, RhF₂, RhCl₂, RhBr₂, RhI₂, etc.), iridium halide (for example, IrF₂, IrCl₂, IrBr₂, Ir₁₂, etc.), nickel halide (for example, NiF₂, NiCl₂, NiBr₂, NiI₂, etc.), palladium halide (for example, PdF₂, PdCI₂, PdBr₂, Pdl₂, etc.), platinum halide (for example, PtF₂, PtCl₂, PtBr₂, Pt₁₂, etc.), copper halide (for example, CuF, CuCl, CuBr, Cul, etc.), silver halide (for example, AgF, AgCl, AgBr, Agl, etc.), gold halide (for example, AuF, AuCl, AuBr, Aul, etc.), and the like.

Examples of the post-transition metal halide are zinc halide (for example, ZnF₂, ZnCl₂, ZnBr₂, Zn₁₂, etc.), indium halide (for example, Ink₃, etc.), tin halide (for example, Sn₁₂, etc.), and the like.

Examples of the lanthanide metal halide are YbF, YbF₂, YbF₃, SmF₃, YbCl, YbCl₂, YbCIs SmCI₃, YbBr, YbBr₂, YbBr₃ SmBrs, YbI, YbI₂, YbI₃, Sm₁₃, and the like.

Examples of the metalloid halide are antimony halide (for example, SbCI₅, etc.) and the like.

Examples of the metal telluride are alkali metal telluride (for example, Li₂Te, a Na₂Te, K₂Te, Rb₂Te, Cs₂Te, etc.), alkaline earth metal telluride (for example, BeTe, MgTe, CaTe, SrTe, BaTe, etc.), transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), post-transition metal telluride (for example, ZnTe, etc.), lanthanide metal telluride (for example, LaTe, CeTe, PrTe, NdTe, PmTe, EuTe, GdTe, TbTe, DyTe, HoTe, ErTe, TmTe, YbTe, LuTe, etc.), and the like.

### Emission Layer in Interlayer 130

When the light-emitting device 10 is a full-color light-emitting device, the emission layer may be patterned into a red emission layer, a green emission layer, and/or a blue emission layer, according to a sub-pixel. In one or more embodiments, the emission layer may have a stacked structure of two or more layers of a red emission layer, a green emission layer, and a blue emission layer, in which the two or more layers contact each other or are separated from each other to emit white light. In one or more embodiments, the emission layer may include two or more materials of a red light-emitting material, a green light-emitting material, and a blue light-emitting material, in which the two or more materials are mixed together with each other in a single layer to emit white light.

In one or more embodiments, the emission layer may include a host and a dopant. The dopant may include a phosphorescent dopant, a fluorescent dopant, or any combination thereof.

An amount of the dopant in the emission layer may be in a range of about 0.01 parts by weight to about 15 parts by weight based on 100 parts by weight of the host.

In one or more embodiments, the emission layer may include a quantum dot.

In one or more embodiments, the emission layer may include a delayed fluorescence material. The delayed fluorescence material may act as a host or a dopant in the emission layer.

A thickness of the emission layer may be in a range of about 100 Å to about 1,000 Å, for example, about 200 Å to about 600 Å. When the thickness of the emission layer is within these ranges, excellent luminescence characteristics may be obtained without a substantial increase in driving voltage.

### Host

In one or more embodiments, the host may include a compound represented by Formula 301:

[Ar₃₀₁]_{xb11}-[(L₃₀₁)_{xb1}-R₃₀₁]_{xb21} Formula 301
wherein, in Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ may each be as defined in Q₁.

For example, when xb11 in Formula 301 is 2 or more, two or more of Ar₃₀₁ may be linked to each other via a single bond.

In one or more embodiments, the host may include a compound represented by Formula 301-1, a compound represented by Formula 301-2, or any combination thereof:

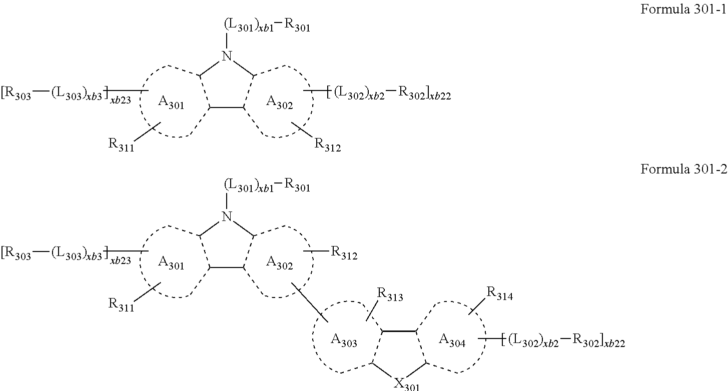

wherein, in Formulae 301-1 and 301-2,
ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N-[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may each be as defined herein,
L₃₀₂ to L₃₀₄ may each independently be as defined in L₃₀₁,
xb2 to xb4 may each independently be as defined in xb1, and
R₃₀₂ to R₃₀₅ and R₃₁₁ to R₃₁₄ may each independently be as defined in R₃₀₁.

In one or more embodiments, the host may include an alkali earth metal complex, a post-transition metal complex, or any combination thereof. In one or more embodiments, the host may include a Be complex (for example, Compound H55), an Mg complex, a Zn complex, or any combination thereof.

In one or more embodiments, the host may include: one selected from Compounds H1 to H124; 9,10-di(2-naphthyl)anthracene (ADN); 2-methyl-9,10-bis(naphthalen-2-yl)anthracene (MADN); 9,10-di-(2-naphthyl)-2-t-butyl-anthracene (TBADN); 4,4′-bis(N-carbazolyl)-1,1′-biphenyl (CBP); 1,3-di-9-carbazolylbenzene (mCP); 1,3,5-tri(carbazol-9-yl)benzene (TCP); or any combination thereof:

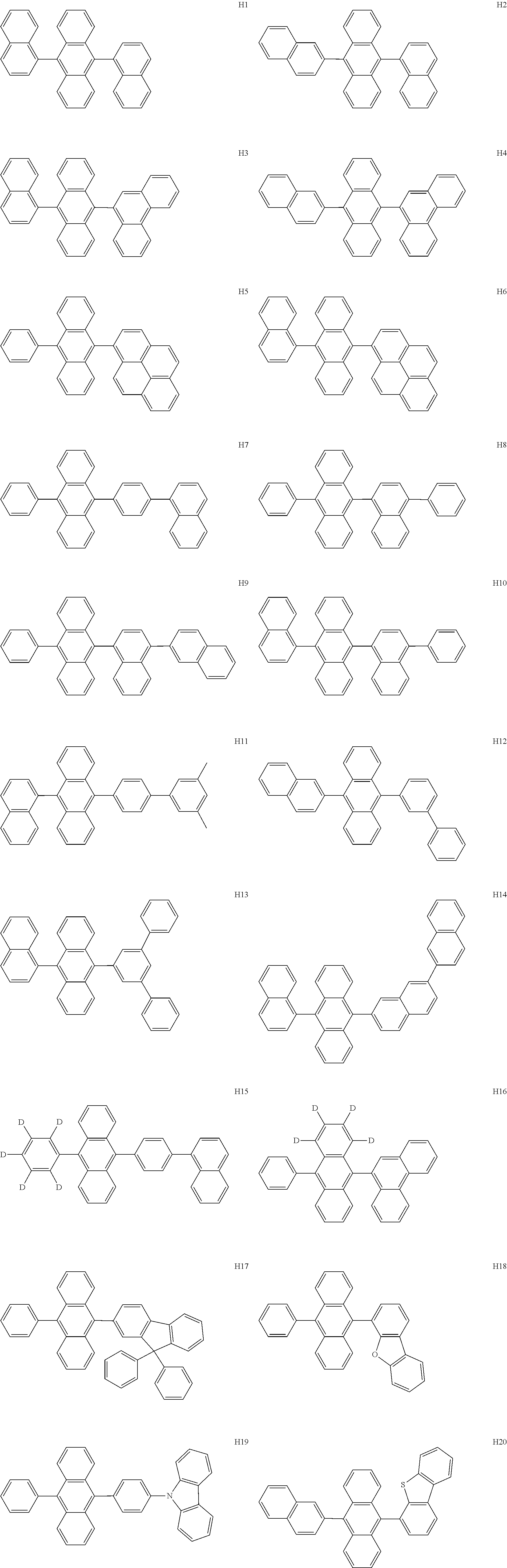

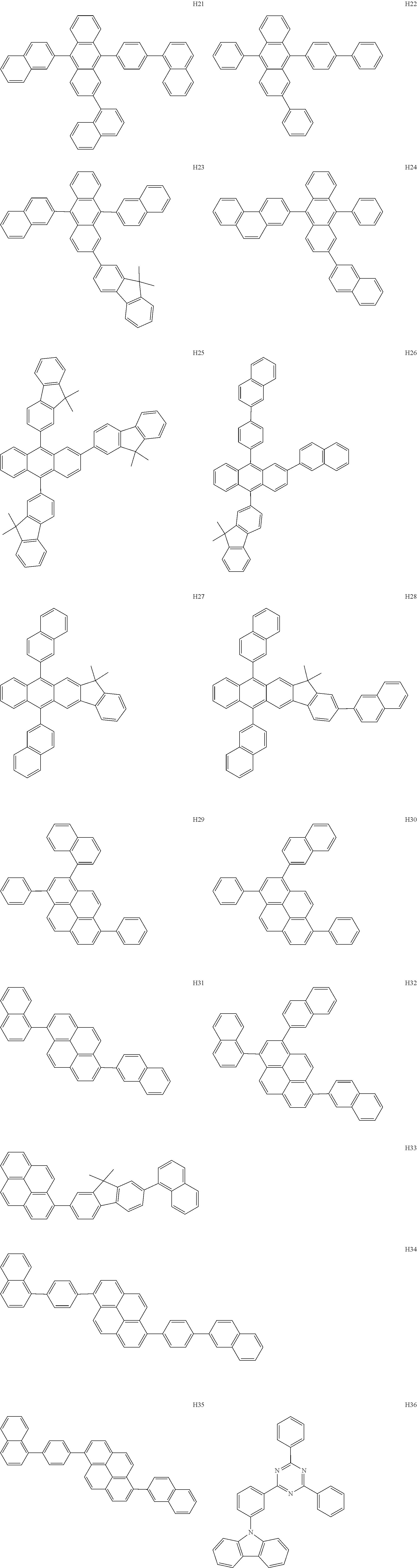

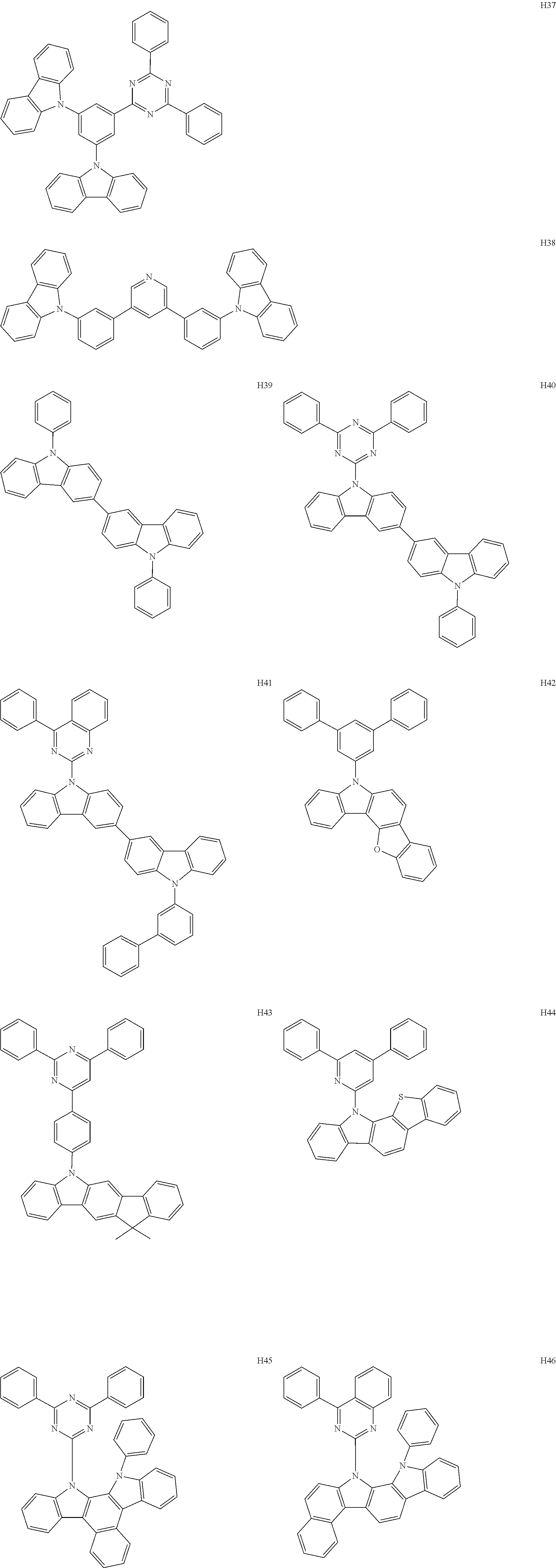

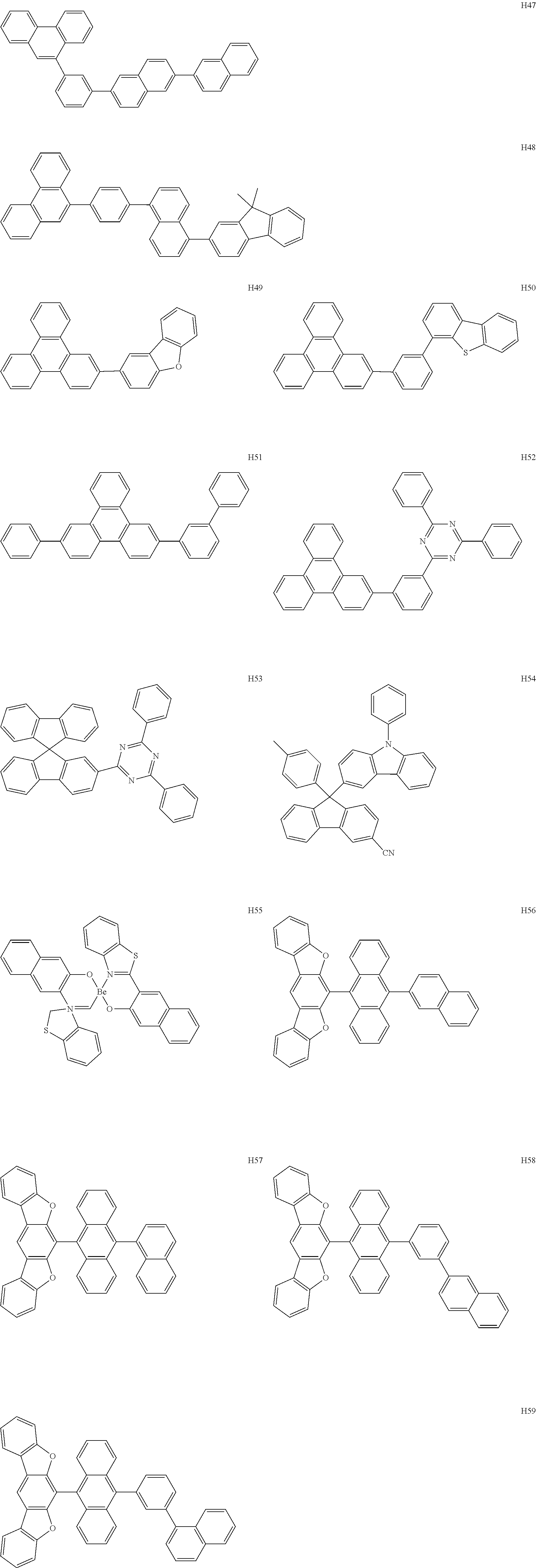

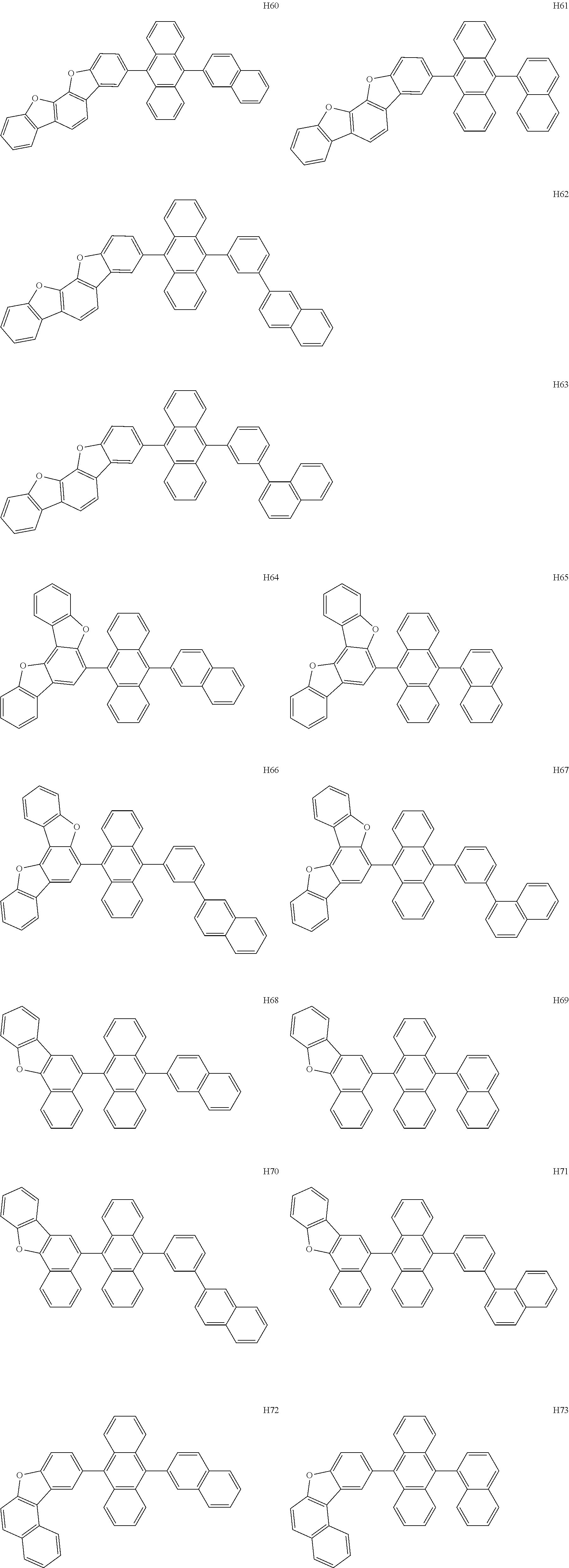

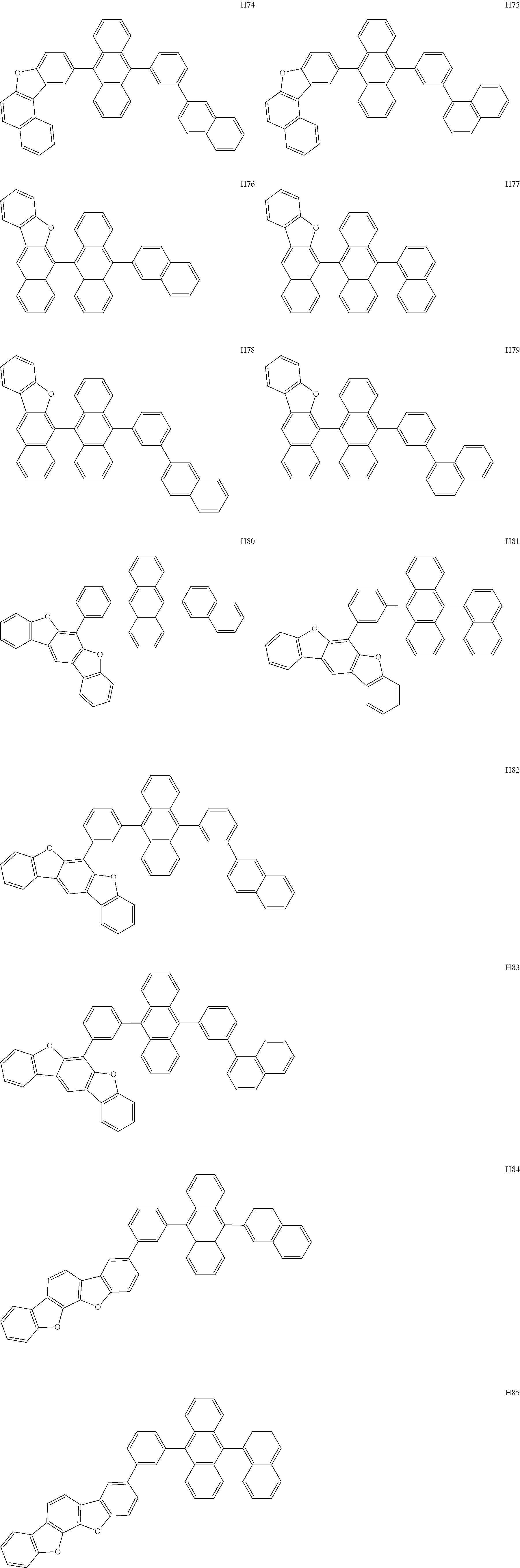

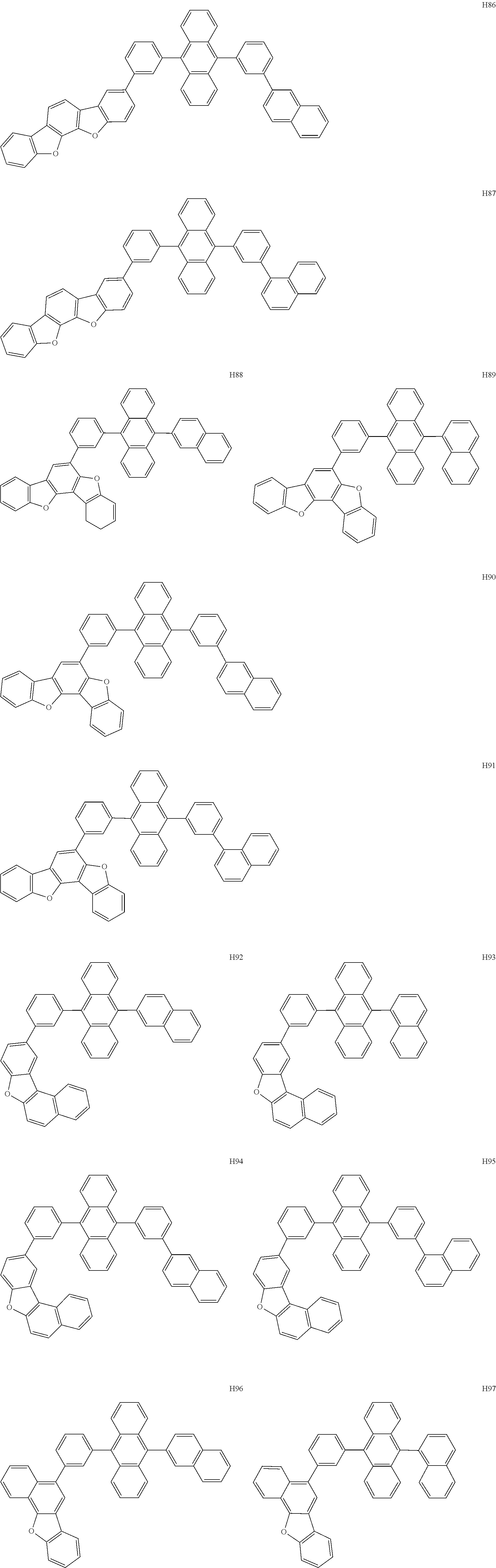

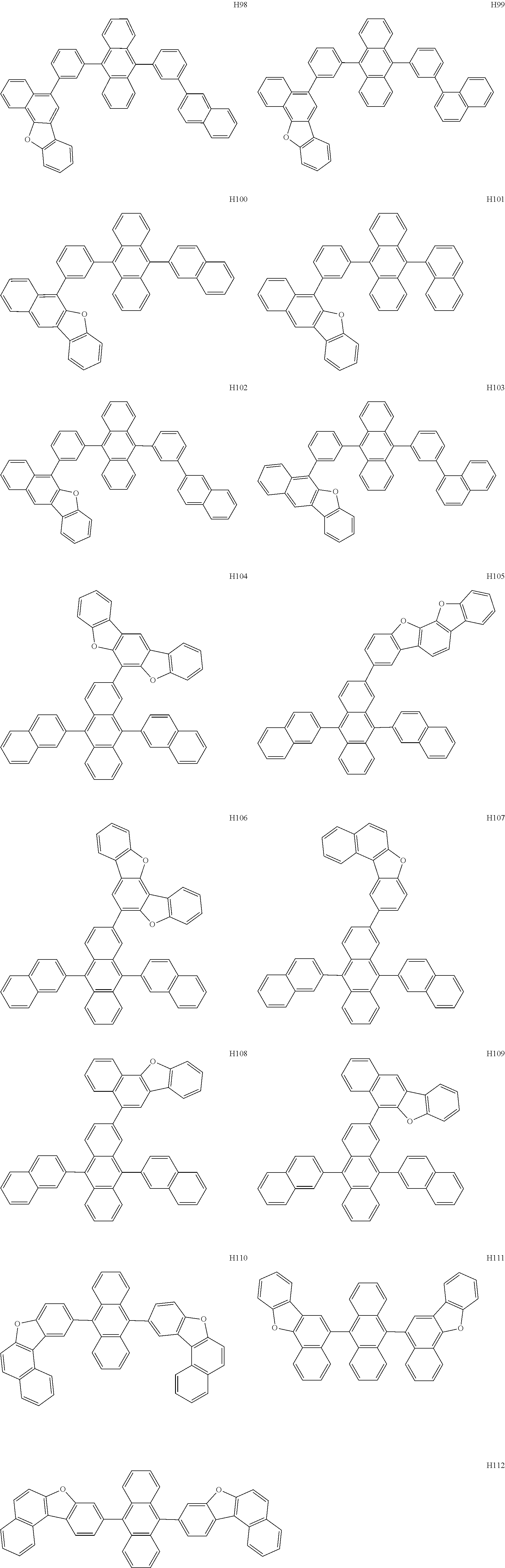

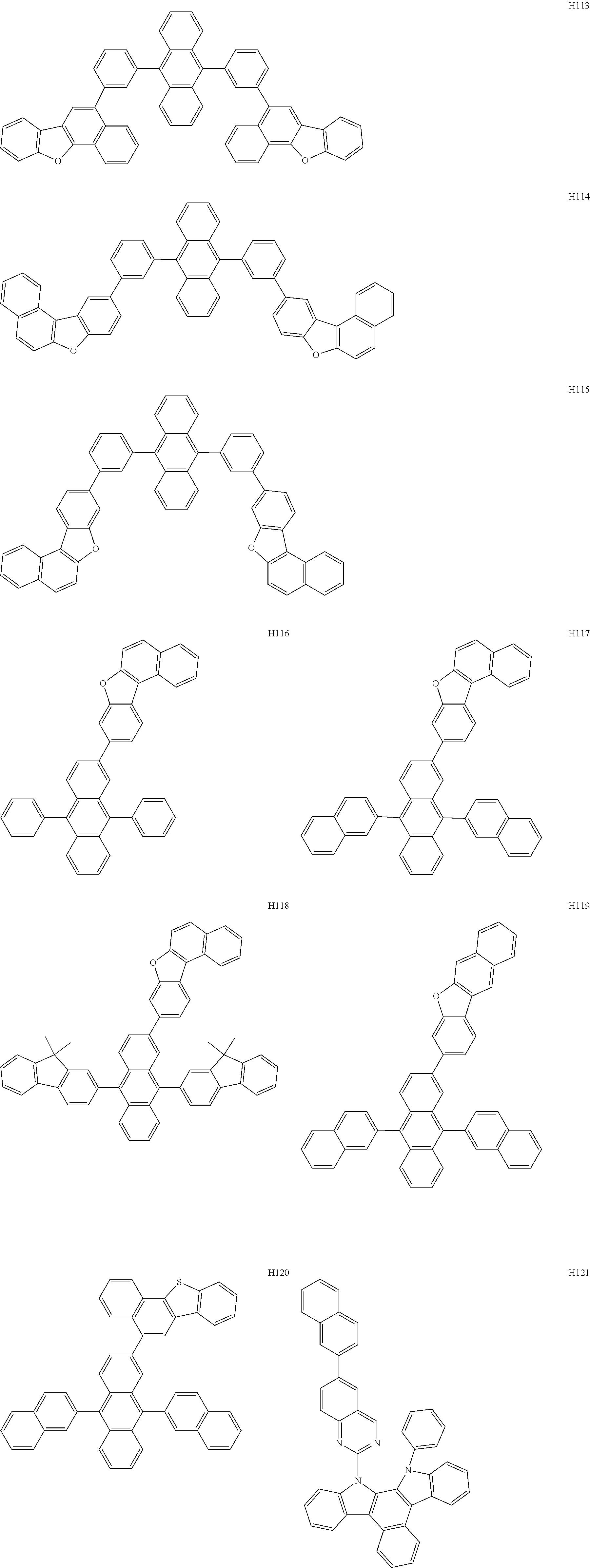

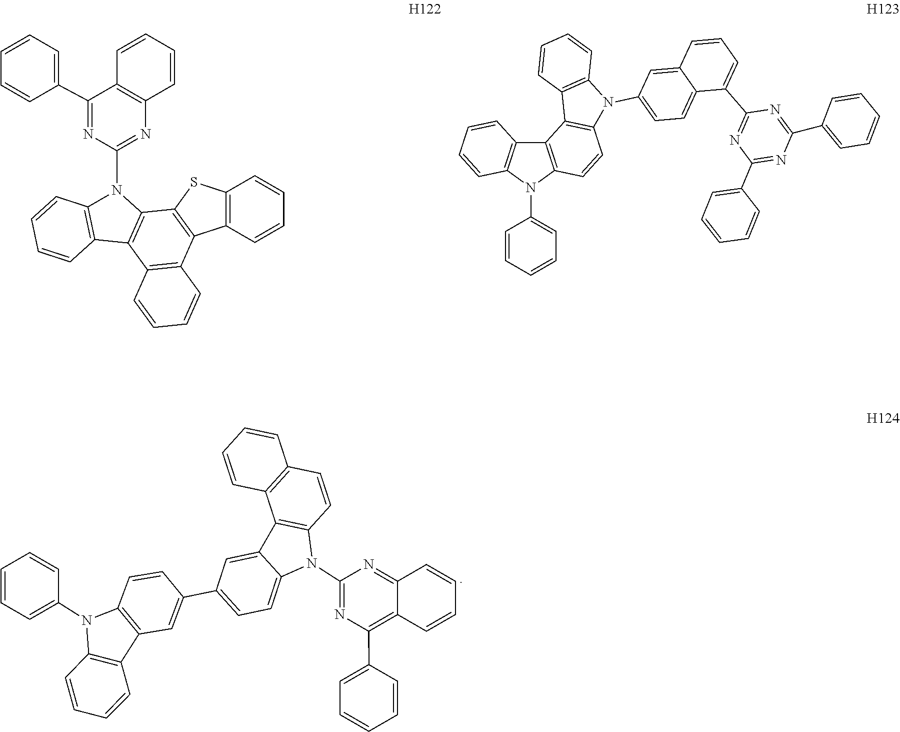 [SMILES: c1ccc(-c2nc(-n3c4ccccc4c4c5ccccc5c5c6ccccc6sc5c43)nc3ccccc23)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

### Phosphorescent Dopant

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

For example, the phosphorescent dopant may include an organometallic compound represented by Formula 401:

M(L₄₀₁)_{xc1}(L₄₀₂)_{xc2} Formula 401

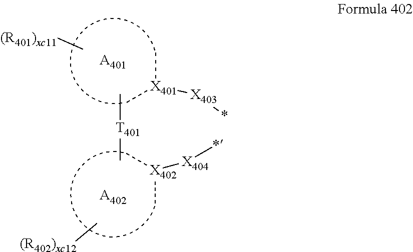

wherein, in Formulae 401 and 402,
M may be a transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 is 1, 2, or 3, wherein, when xc1 is 2 or more, two or more of L₄₀₁ may be identical to or different from each other,
L₄₀₂ may be an organic ligand, and xc2 may be 0, 1, 2, 3, or 4, wherein, when xc2 is 2 or more, two or more of L₄₀₂ may be identical to or different from each other,
X₄₀₁ and X₄₀₂ may each independently be N or C,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)-*′, *—C(Q₄₁₁)(Q₄₁₂)-*′, *—C(Q₄₁₁)═C(Q₄₁₂)-*′, *—C(Q₄₁₁)=*′, or *═C═*′,
X₄₀₃ and X₄₀₄ may each independently be a chemical bond (for example, a covalent bond or a coordination bond (which may also be referred to as a coordinate covalent bond or a dative bond)), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ may each independently be as defined in Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄O₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄O₁), or —P(═O)(Q₄₀₁)(Q₄₀₂),
Q₄₀₁ to Q₄₀₃ may each independently be as defined in Q₁,
xc11 and xc12 may each independently be an integer from 0 to 10, and* and *′ in Formula 402 each indicate a binding site to M in Formula 401.

For example, in Formula 402, i) X₄₀₁ may be nitrogen and X₄₀₂ may be carbon, or ii) each of X₄₀₁ and X₄₀₂ may be nitrogen.

In one or more embodiments, when xc1 in Formula 401 is 2 or more, two ring A₄₀₁(s) among two or more of L₄₀₁ may optionally be linked to each other via T₄₀₂, which is a linking group, and two ring A₄₀₂(s) among two or more of L₄₀₁ may optionally be linked to each other via T₄₀₃, which is a linking group (see Compounds PD1 to PD4 and PD7). T₄₀₂ and T₄₀₃ may each independently be as defined in T₄₀₁.

In Formula 401, L₄₀₂ may be an organic ligand. For example, L₄₀₂ may include a halogen group, a diketone group (for example, an acetylacetonate group), a carboxylic acid group (for example, a picolinate group), —C(═O), an isonitrile group, a —CN group, a phosphorus group (for example, a phosphine group, a phosphite group, etc.), or any combination thereof.

The phosphorescent dopant may include, for example, one selected from Compounds PD1 to PD39, or any combination thereof:

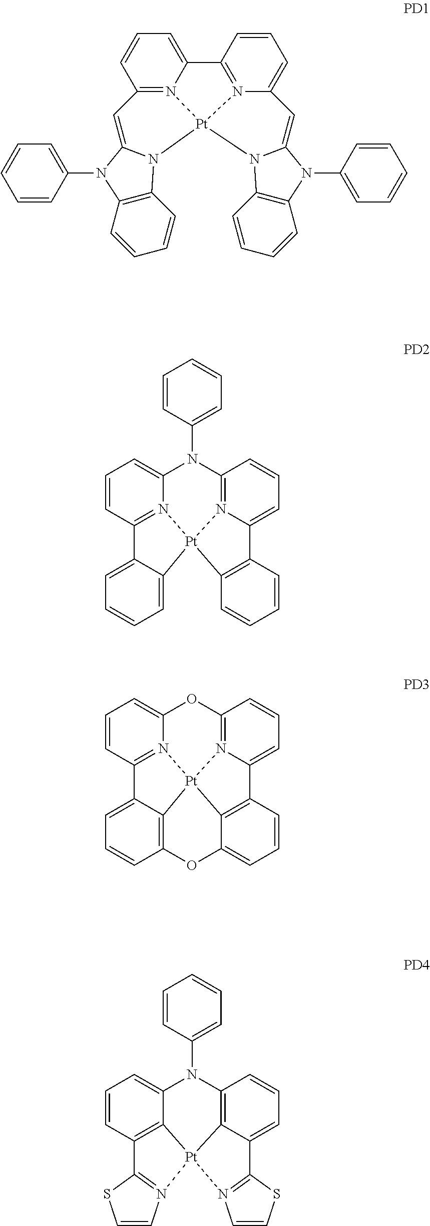

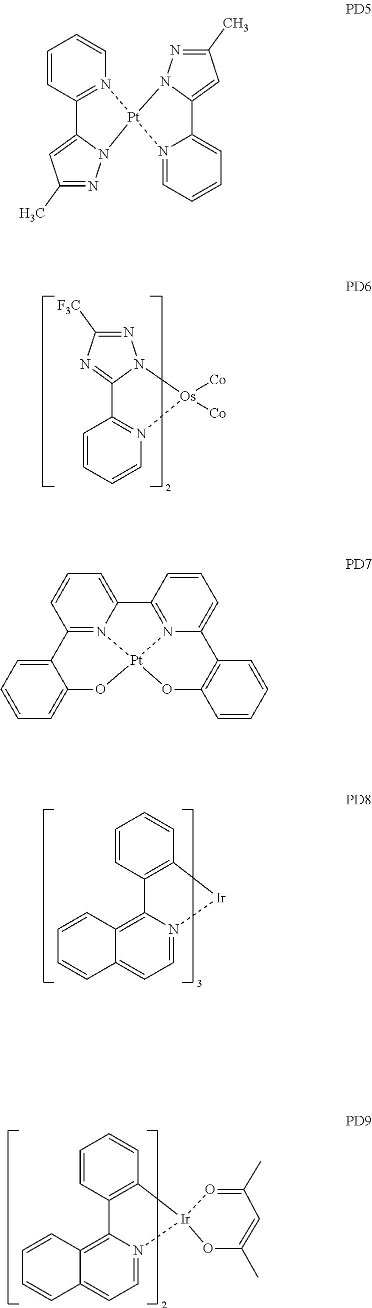

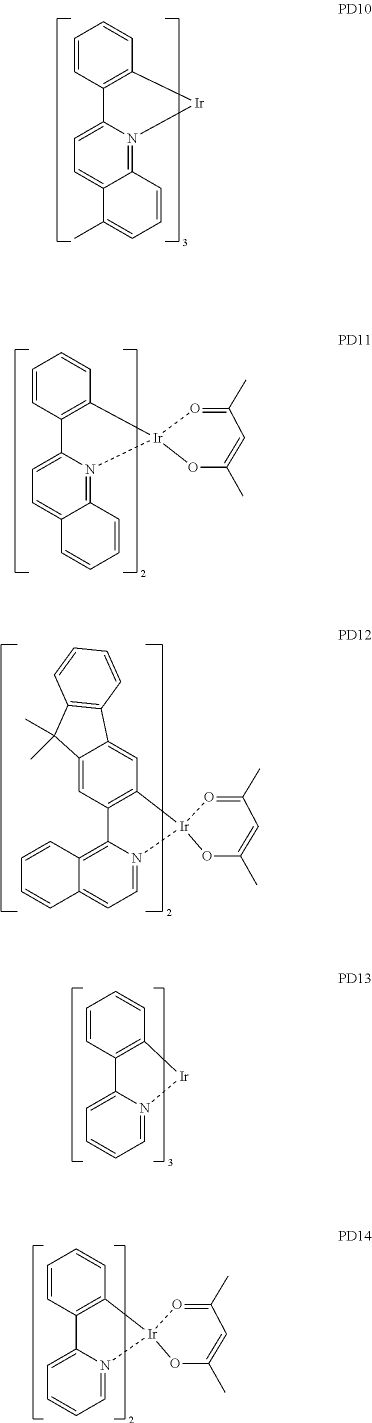

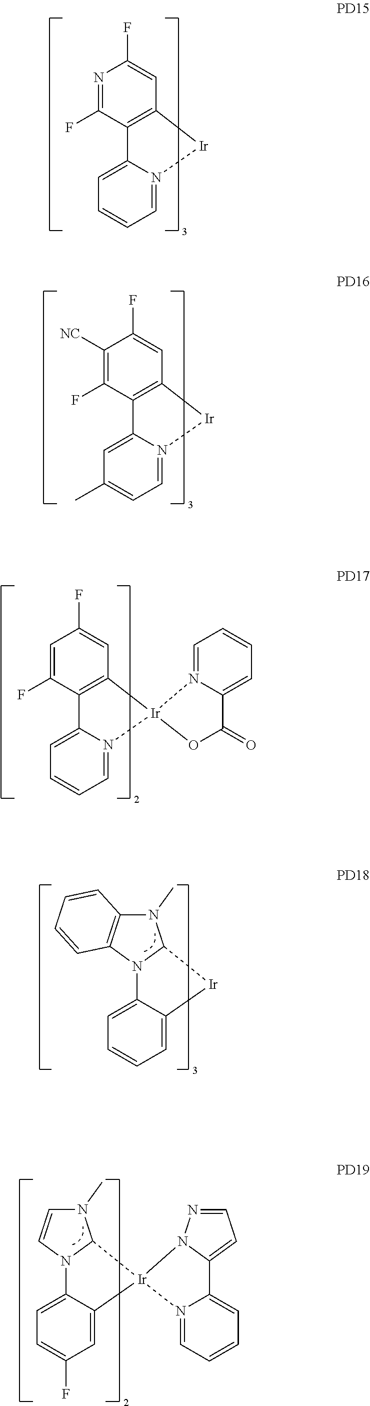

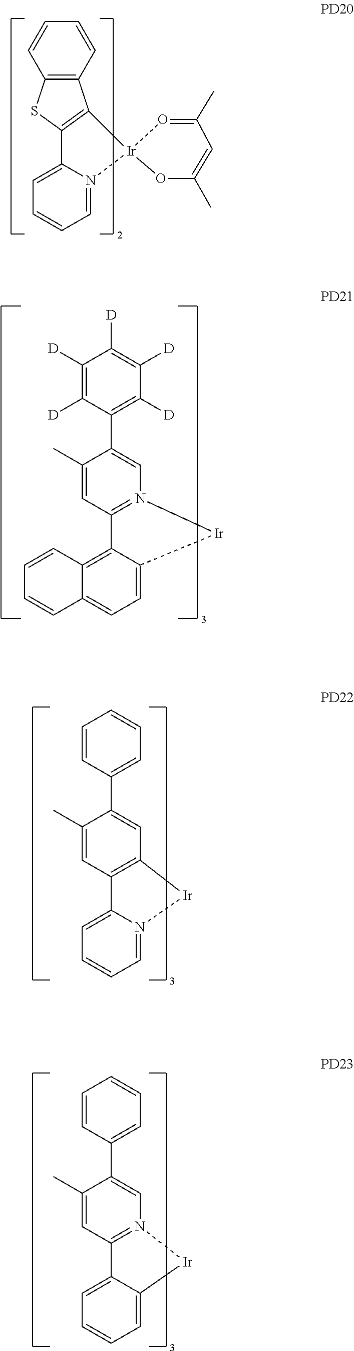

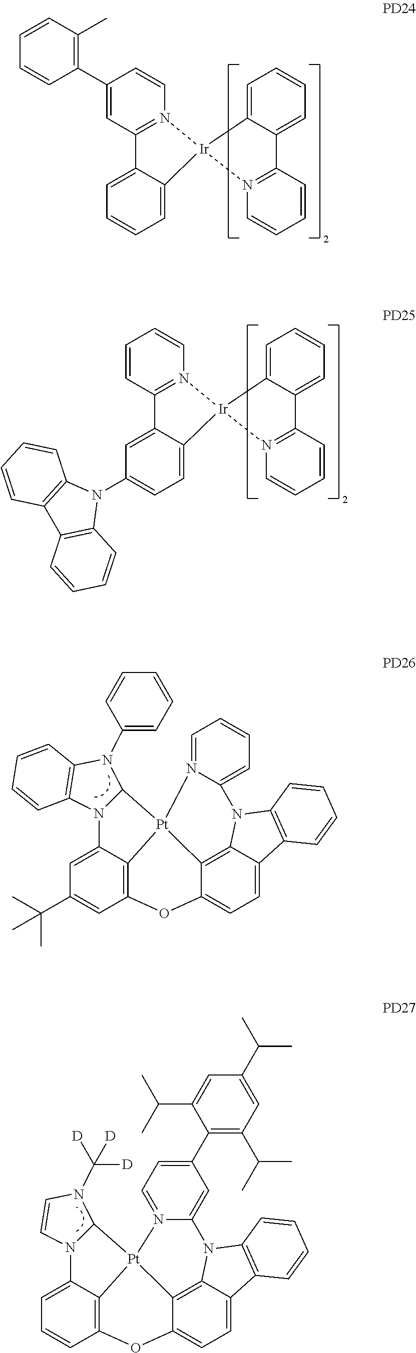

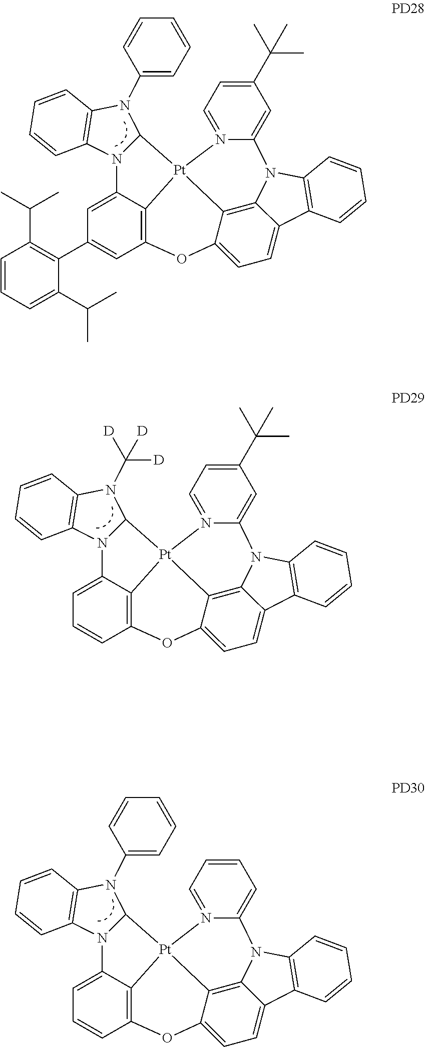

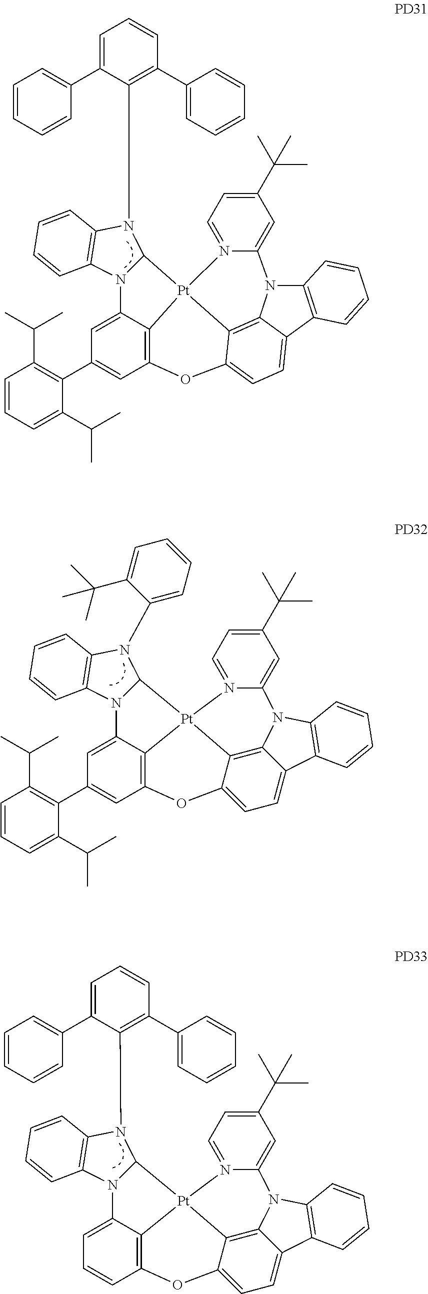

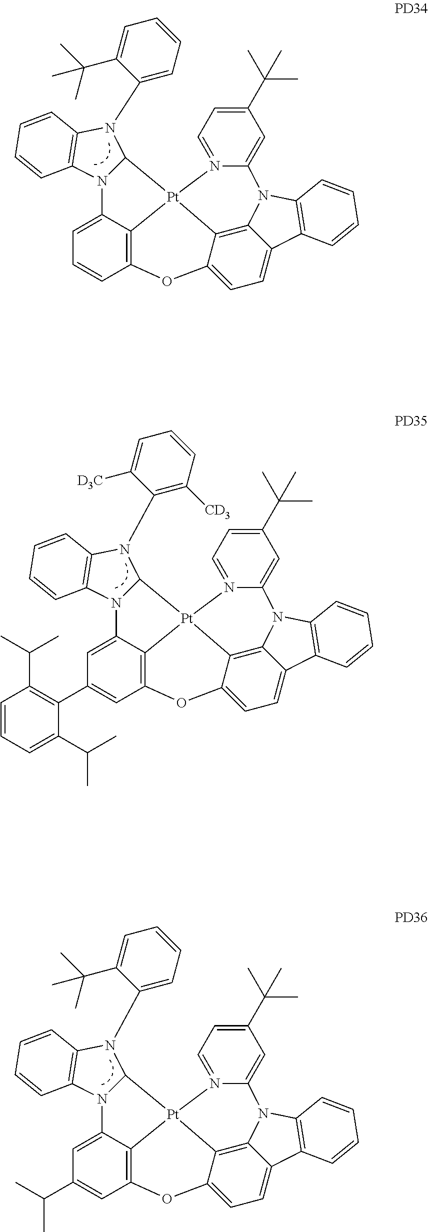

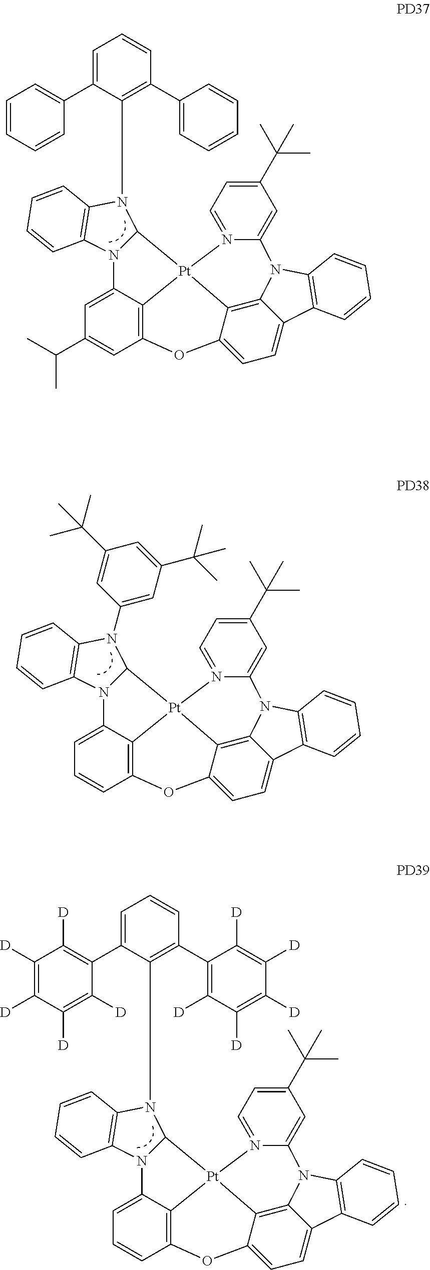

### Fluorescent Dopant

The fluorescent dopant may include an amine group-containing compound, a styryl group-containing compound, or any combination thereof.

For example, the fluorescent dopant may include a compound represented by Formula 501:

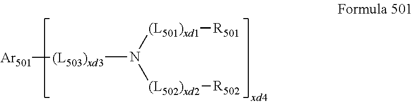

wherein, in Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

In one or more embodiments, Ar₅₀₁ in Formula 501 may be a condensed cyclic group (for example, an anthracene group, a chrysene group, a pyrene group, etc.) in which three or more monocyclic groups are condensed together.

In one or more embodiments, xd4 in Formula 501 may be 2.

For example, the fluorescent dopant may include: one selected from Compounds FD1 to FD36; DPVBi; DPAVBi; or any combination thereof:

[chemical structure]

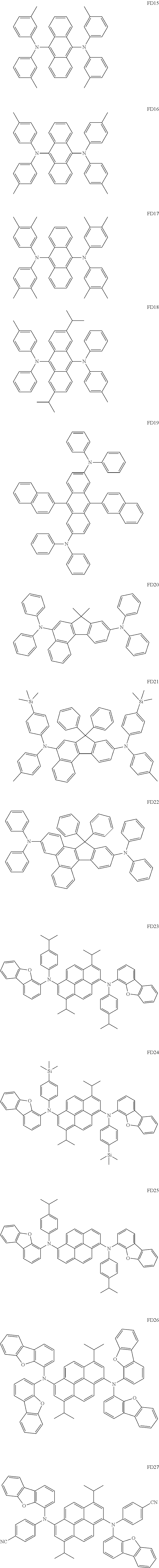

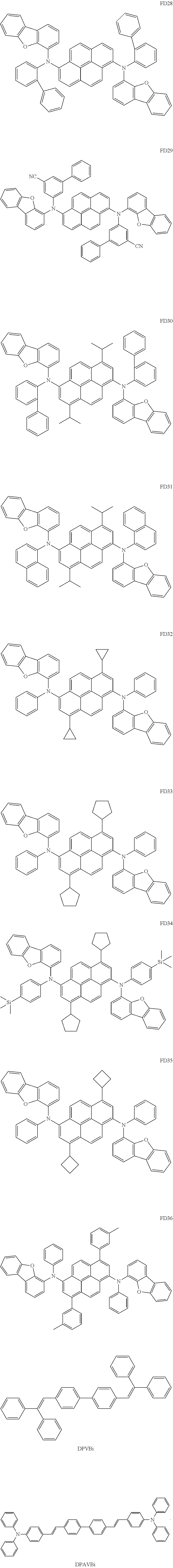

### Delayed Fluorescence Material

The emission layer may include a delayed fluorescence material.

In the specification, the delayed fluorescence material may be selected from compounds capable of emitting delayed fluorescence based on a delayed fluorescence emission mechanism.

The delayed fluorescence material included in the emission layer may act as a host or a dopant depending on the type or kind of other materials included in the emission layer.

In one or more embodiments, a difference between a triplet energy level (eV) of the delayed fluorescence material and the singlet energy level (eV) of the delayed fluorescence material may be at least 0 eV and not more than 0.5 eV. When the difference between the triplet energy level (eV) of the delayed fluorescence material and the singlet energy level (eV) of the delayed fluorescence material is satisfied within the range above, up-conversion from the triplet state to the singlet state of the delayed fluorescence materials may effectively occur, and thus, the light-emitting device 10 may have improved luminescence efficiency.

For example, the delayed fluorescence material may include: i) a material including at least one electron donor (for example, a Π electron-rich C₃-C₆₀ cyclic group and the like, such as a carbazole group) and at least one electron acceptor (for example, a sulfoxide group, a cyano group, a Π electron-deficient nitrogen-containing C₁-C₆₀ cyclic group, and the like), ii) a material including a C₈-C₆₀ polycyclic group including at least two cyclic groups condensed to each other while sharing boron (B), and the like.

Examples of the delayed fluorescence material may include at least one selected from Compounds DF1 to DF9:

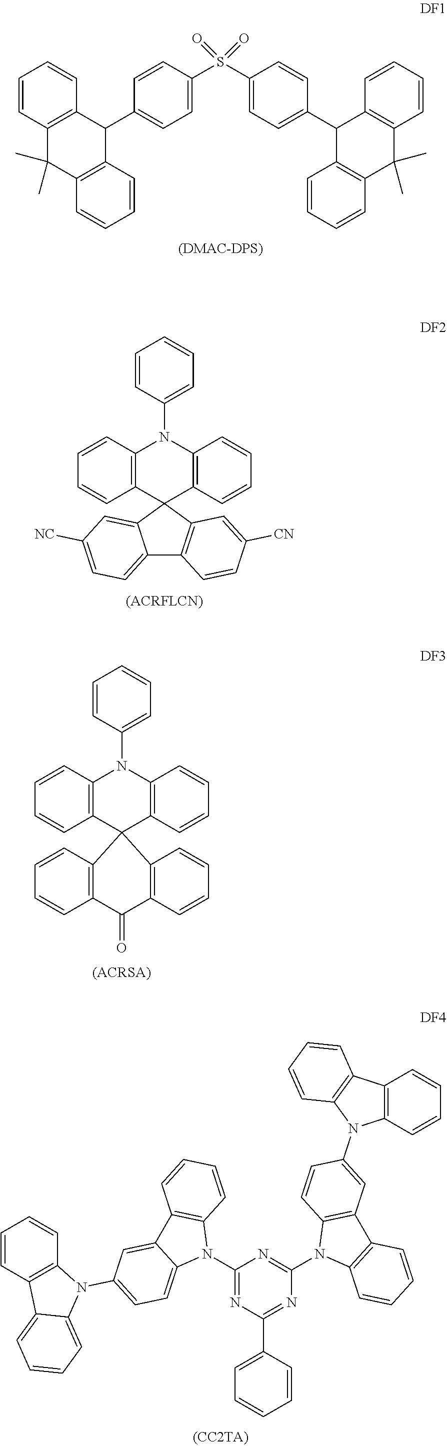

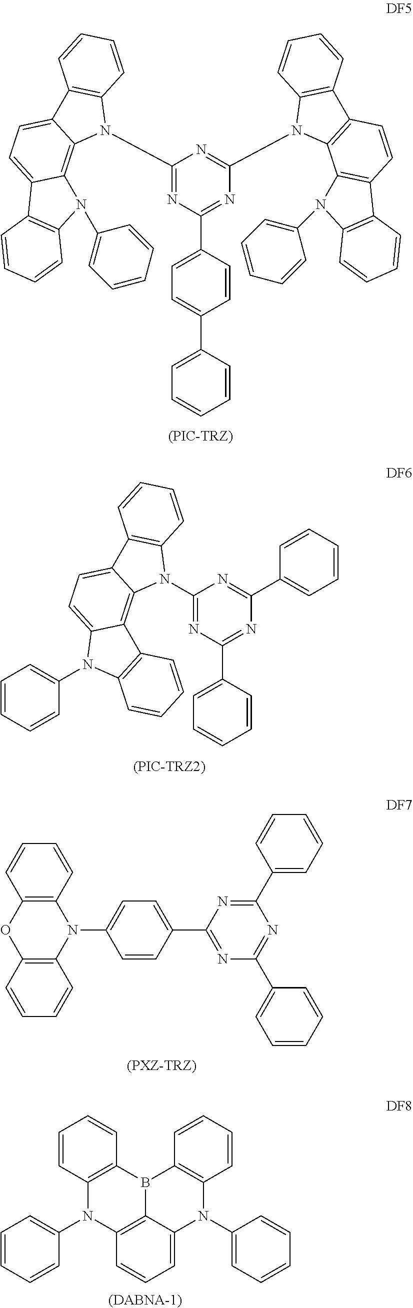

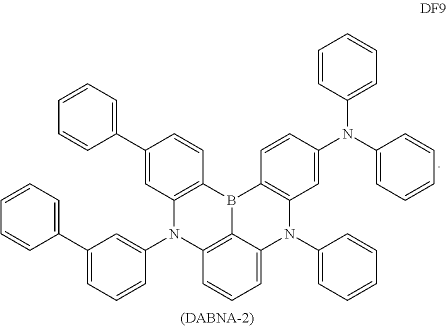

### Quantum Dot

The emission layer may include a quantum dot.

The term “quantum dot” as used herein refers to a crystal of a semiconductor compound, and may include any suitable material capable of emitting light of various suitable emission wavelengths according to the size of the crystal.

A diameter of the quantum dot may be, for example, in a range of about 1 nm to about 10 nm.

The quantum dot may be synthesized by a wet chemical process, a metal organic chemical vapor deposition process, a molecular beam epitaxy process, and/or any suitable process similar thereto.

The wet chemical process is a method including mixing a precursor material together with an organic solvent and then growing quantum dot particle crystals. When the crystal grows, the organic solvent naturally acts as a dispersant coordinated on the surface of the quantum dot crystal and controls the growth of the crystal so that the growth of quantum dot particles can be controlled through a process which costs lower, and is easier than vapor deposition methods, such as metal organic chemical vapor deposition (MOCVD) or molecular beam epitaxy (MBE).

The quantum dot may include: a Group II-VI semiconductor compound; a Group III-V semiconductor compound; a Group III-VI semiconductor compound; a Group I-III-VI semiconductor compound; a Group IV-VI semiconductor compound; a Group IV element or compound; or any combination thereof.

Examples of the Group II-VI semiconductor compound are: a binary compound, such as CdS, CdSe, CdTe, ZnS, ZnSe, ZnTe, ZnO, HgS, HgSe, HgTe, MgSe, MgS, and the like; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and the like; a quaternary compound, such as CdZnSeS, CdZnSeTe, CdZnSTe, CdHgSeS, CdHgSeTe, CdHgSTe, HgZnSeS, HgZnSeTe, HgZnSTe, and the like; or any combination thereof.

Examples of the Group III-V semiconductor compound are: a binary compound, such as GaN, GaP, GaAs, GaSb, AlN, AIP, AIAs, AISb, InN, InP, InAs, InSb, and the like; a ternary compound, such as GaNP, GaNAs, GaNSb, GaPAs, GaPSb, AlNP, AlNAs, AlNSb, AIPAs, AIPSb, InGaP, InNP, InAIP, InNAs, InNSb, InPAs, InPSb, and the like; a quaternary compound, such as GaAlNP, GaAlNAs, GaAlNSb, GaAIPAs, GaAIPSb, GaInNP, GaInNAs, GalnNSb, GaInPAs, GalnPSb, InAlNP, InAlNAs, InAlNSb, InAIPAs, InAIPSb, and the like; or any combination thereof. In one or more embodiments, the Group III-V semiconductor compound may further include a Group II element. Examples of the Group III-V semiconductor compound further including the Group II element are InZnP, InGaZnP, InAlZnP, and the like.

Examples of the Group III-VI semiconductor compound are: a binary compound, such as GaS, GaSe, Ga₂Se₃, GaTe, InS, InSe, In₂S₃, In₂Se₃, InTe, and the like; a ternary compound, such as InGaS₃, InGaSe₃, and the like; or any combination thereof.

Examples of the Group I-III-VI semiconductor compound are: a ternary compound, such as AgInS, AgInS₂, CuInS, CuInS₂, CuGaO₂, AgGaO₂, AgAlO₂, and the like; or any combination thereof.

Examples of the Group IV-VI semiconductor compound are: a binary compound, such as SnS, SnSe, SnTe, PbS, PbSe, PbTe, and the like; a ternary compound, such as SnSeS, SnSeTe, SnSTe, PbSeS, PbSeTe, PbSTe, SnPbS, SnPbSe, SnPbTe, and the like; a quaternary compound, such as SnPbSSe, SnPbSeTe, SnPbSTe, and the like; or any combination thereof.

Examples of the Group IV element or compound are: a single element compound, such as Si, Ge, and the like; a binary compound, such as SiC, SiGe, and the like; or any combination thereof.

Each element included in a multi-element compound, such as the binary compound, the ternary compound, and the quaternary compound, may be present at a uniform concentration or non-uniform concentration in a particle.

In one or more embodiments, the quantum dot may have a single structure in which the concentration of each element in the quantum dot is uniform (e.g., substantially uniform), or may have a core-shell dual structure. For example, a material included in the core and a material included in the shell may be different from each other.

The shell of the quantum dot may act as a protective layer which prevents or reduces chemical denaturation of the core to maintain semiconductor characteristics, and/or as a charging layer which impart electrophoretic characteristics to the quantum dot. The shell may be single-layered or multi-layered. The interface between the core and the shell may have a concentration gradient in which the concentration of an element existing in the shell decreases along a direction toward the center of the core.

Examples of the shell of the quantum dot are an oxide of metal, metalloid, or non-metal, a semiconductor compound, or a combination thereof. Examples of the oxide of metal, metalloid, or non-metal are: a binary compound, such as SiO₂, Al₂₀₃, TiO₂, ZnO, MnO, Mn₂O₃, Mn₃O₄, CuO, FeO, Fe₂O₃, Fe₃₀₄, CoO, Co₃O₄, NiO, and the like; a ternary compound, such as MgAl₂O₄, CoFe₂O₄, NiFe₂O₄, CoMn₂O₄, and the like; or any combination thereof. Examples of the semiconductor compound are: as described herein, a Group II-VI semiconductor compound; a Group III-V semiconductor compound; a Group III-VI semiconductor compound; a Group I-III-VI semiconductor compound; a Group IV-VI semiconductor compound; or any combination thereof. Examples of the semiconductor compound are CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AIAs, AIP, AISb, or any combination thereof.

The quantum dot may have an FWHM of the emission wavelength spectrum of less than or equal to about 45 nm, less than or equal to about 40 nm, or for example, less than or equal to about 30 nm. When the FWHM of the quantum dot is within these ranges, the quantum dot may have improved color purity and/or improved color reproducibility. In addition, because light emitted through the quantum dot is emitted in all (e.g., substantially all) directions, the wide viewing angle may be improved.

In addition, the quantum dot may be in the form of spherical, pyramidal, multi-arm, or cubic nanoparticles, nanotubes, nanowires, nanofibers, and/or nanoplate particles.

Because the energy band gap may be adjusted by controlling the size of the quantum dot, light having various suitable wavelength bands may be obtained from the quantum dot emission layer. Accordingly, by using quantum dots of different sizes, a light-emitting device that emits light of various suitable wavelengths may be implemented. In one or more embodiments, the size of the quantum dots may be selected to emit red light, green light, and/or blue light. In addition, the size of the quantum dots may be configured to emit white light by combination of light of various suitable colors.

### Electron Transport Region in Interlayer 130

The electron transport region may have: i) a single-layer structure consisting of a single layer consisting of a single material, ii) a single-layer structure consisting of a single layer consisting of multiple different materials, or iii) a multi-layer structure including multiple layers including different materials.

The electron transport region may include a buffer layer, a hole blocking layer, an electron control layer, an electron transport layer, an electron injection layer, or any combination thereof.

For example, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein constituent layers of each structure are sequentially stacked from the emission layer.

In one or more embodiments, the electron transport region (for example, the buffer layer, the hole blocking layer, the electron control layer, or the electron transport layer in the electron transport region) may include a metal-free compound including at least one Π electron-deficient nitrogen-containing C₁-C₆₀ cyclic group.

For example, the electron transport region may include a compound represented by Formula 601:

[Ar₆₀₁]ₓₑ₁₁-[(L₆₀₁)ₓₑ₁-R₆₀₁]ₓₑ₂₁ Formula 601
wherein, in Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each be as defined in Q₁,
xe21 may be 1, 2, 3, 4, or 5, and
at least one selected from Ar₆₀₁, L₆₀₁, and R₆₀₁ may each independently be a Π electron-deficient nitrogen-containing C₁-C₆₀ cyclic group unsubstituted or substituted with at least one R₁₀ₐ.

In one or more embodiments, when xe11 in Formula 601 is 2 or more, two or more of Ar₆₀₁ may be linked to each other via a single bond.

In one or more embodiments, Ar₆₀₁ in Formula 601 may be a substituted or unsubstituted anthracene group.

In one or more embodiments, the electron transport region may include a compound represented by Formula 601-1:

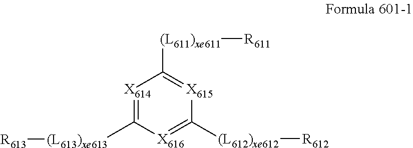

wherein, in Formula 601-1,
X₆₁₄ may be N or C(R₆₁₄), X₆₁₅ may be N or C(R₆₁₅), X₆₁₆ may be N or C(R₆₁₆), and at least one selected from X₆₁₄ to X₆₁₆ may be N,
L₆₁₁ to L₆₁₃ may each be as defined in L₆₀₁,
xe611 to xe613 are each the same as described in connection with xe1,
R₆₁₁ to R₆₁₃ may each be as defined in R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

For example, xe1 and xe611 to xe613 in Formulae 601 and 601-1 may each independently be 0, 1, or 2.

The electron transport region may include one selected from Compounds ET1 to ET45, 2,9-dimethyl-4,7-diphenyl-1,10-phenanthroline (BCP), 4,7-diphenyl-1,10-phenanthroline (Bphen), Alq3, BAIq, TAZ, NTAZ, or any combination thereof:

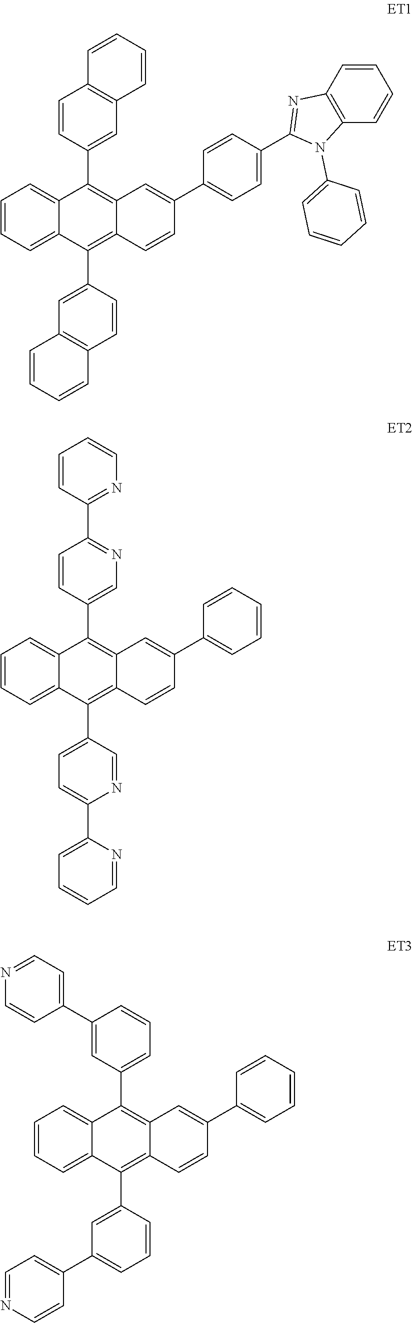 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

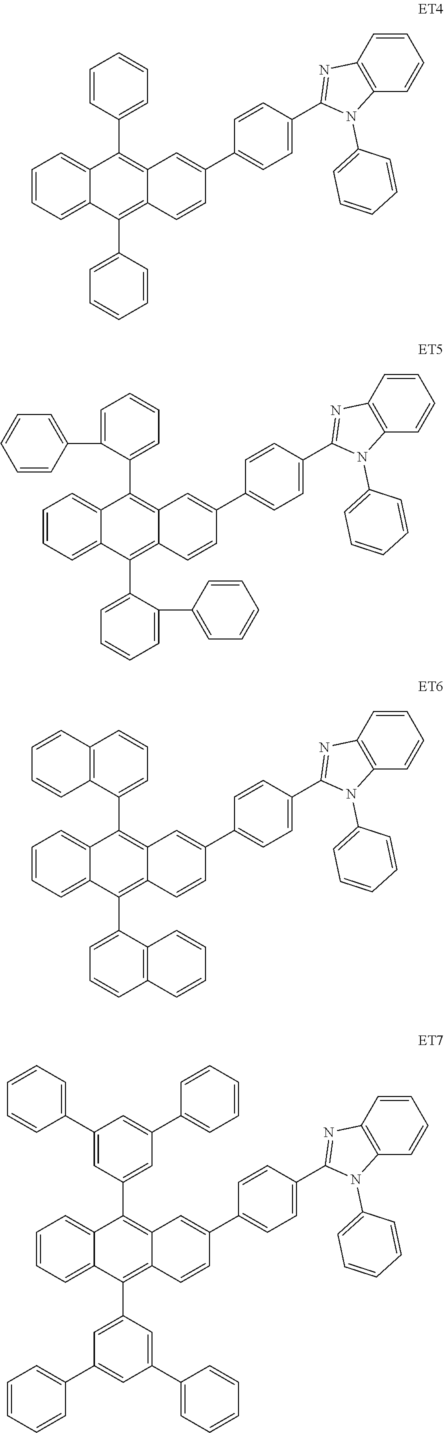 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

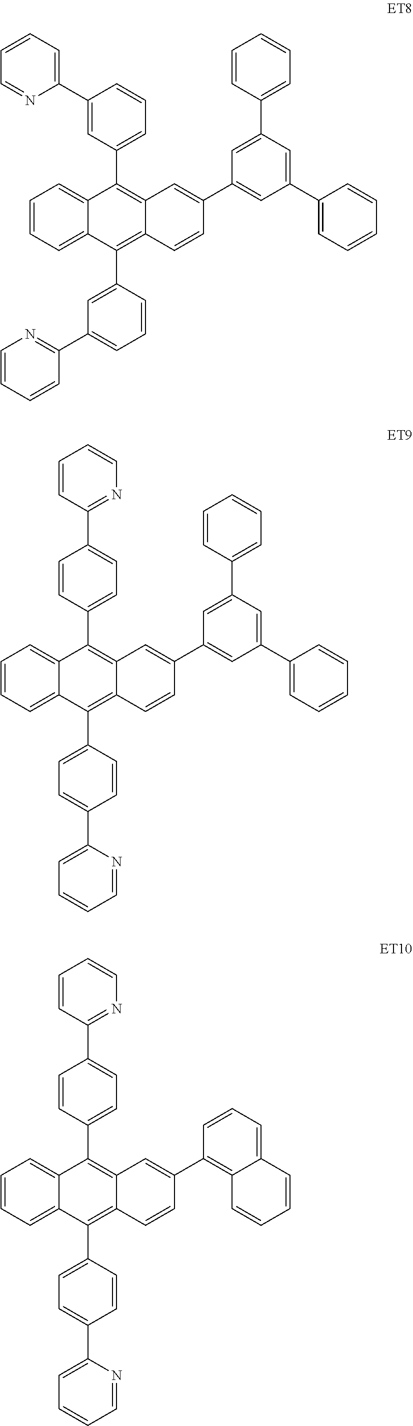 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

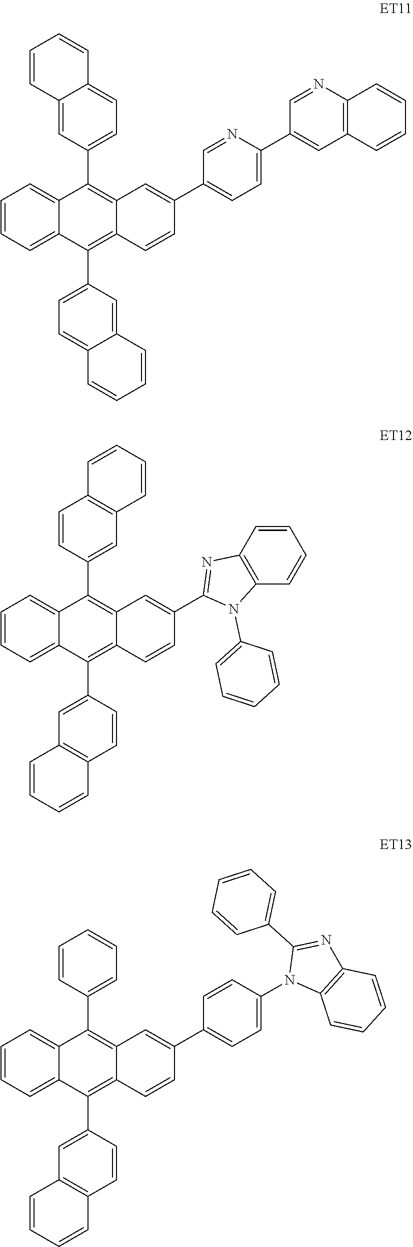

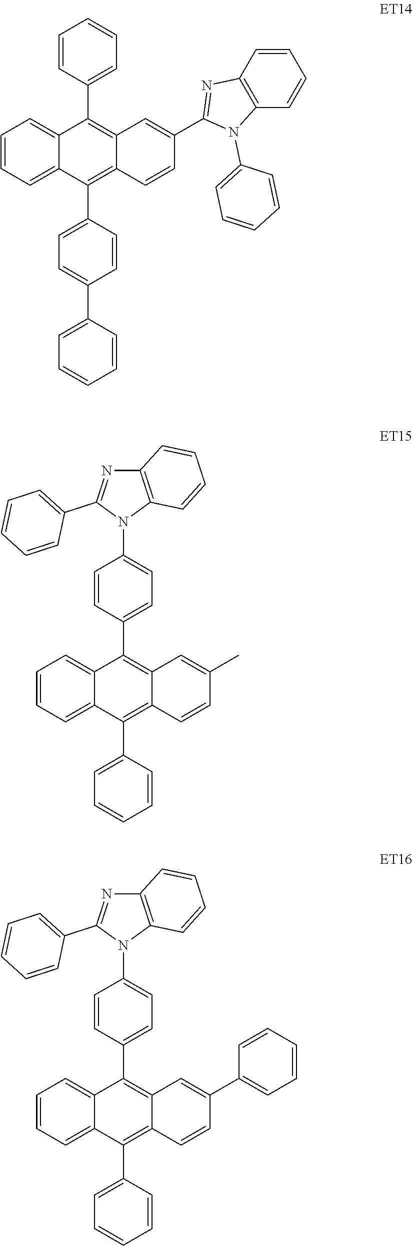 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

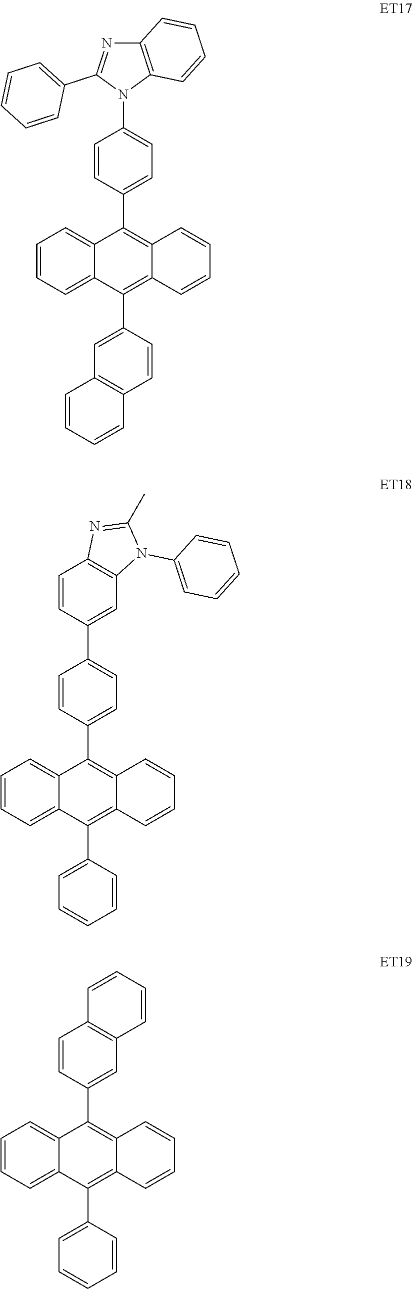

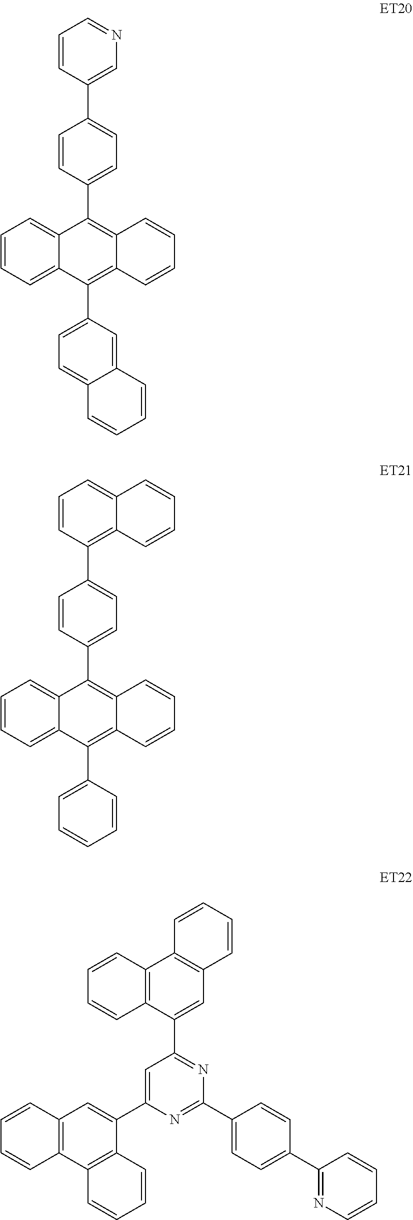

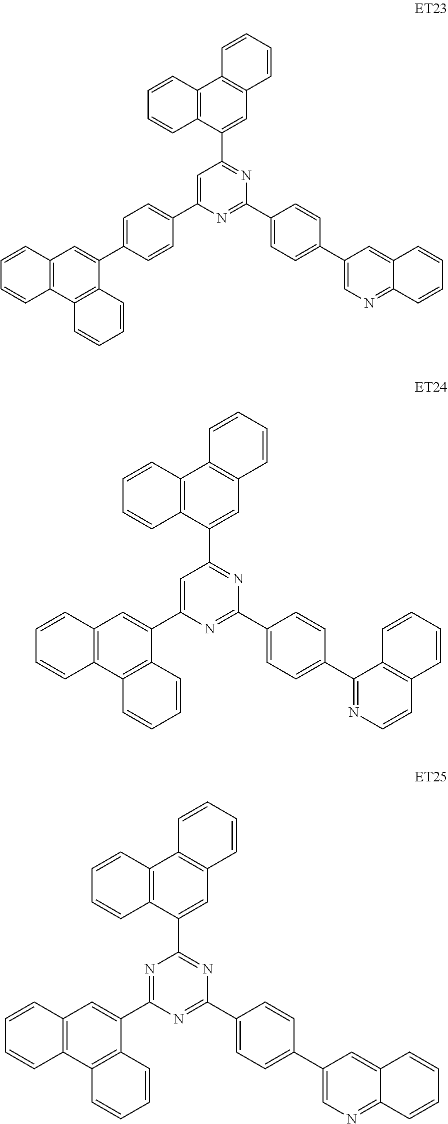 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

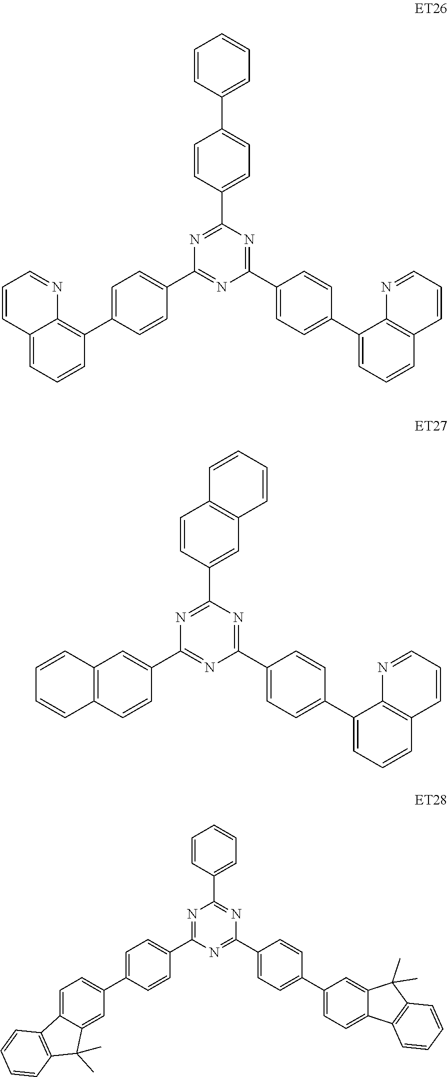 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

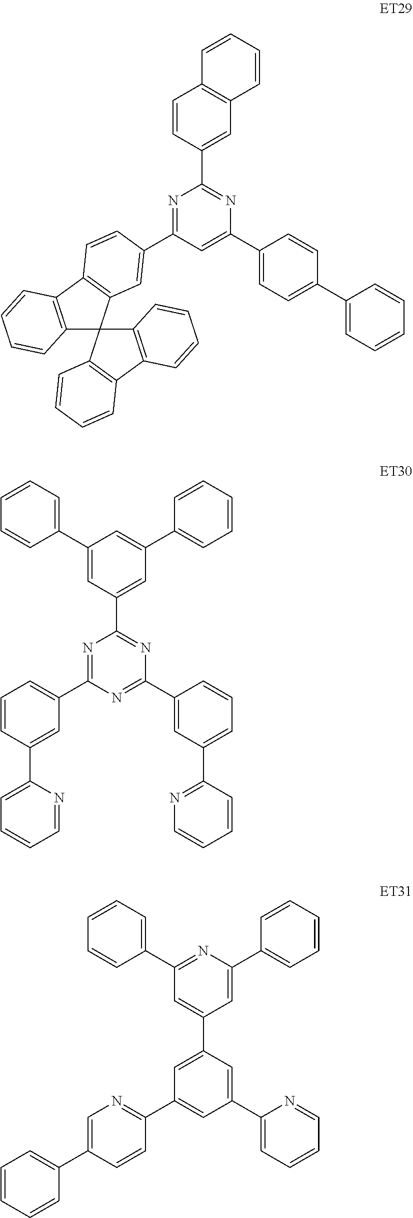 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

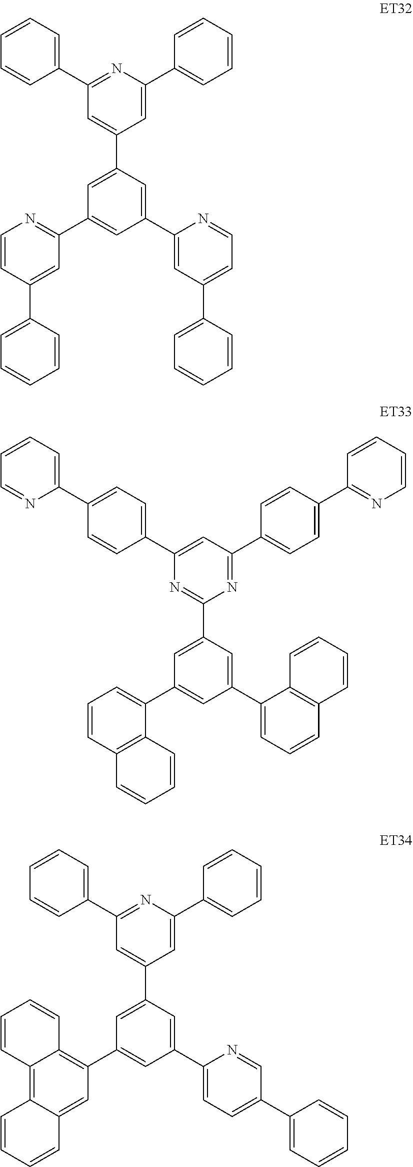 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

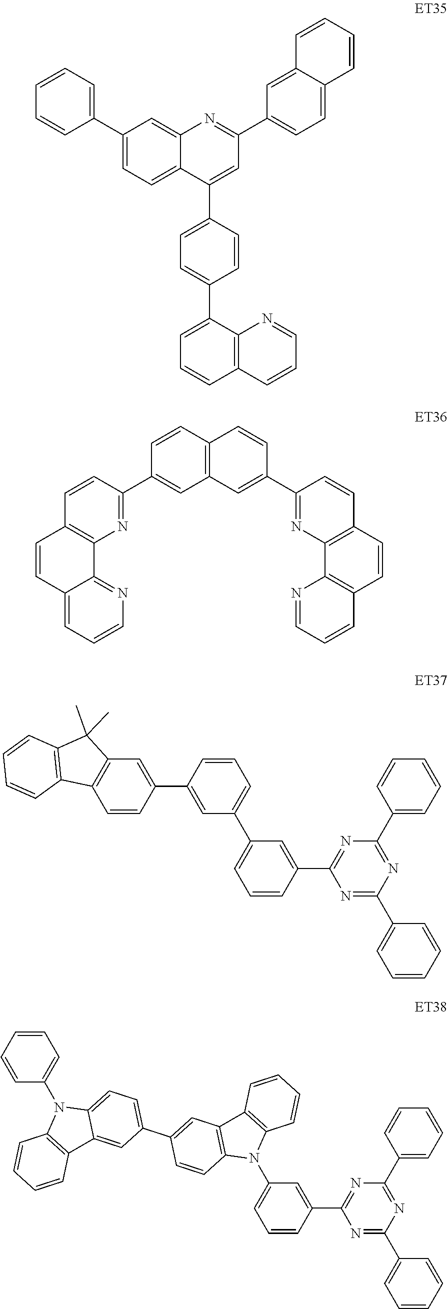 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

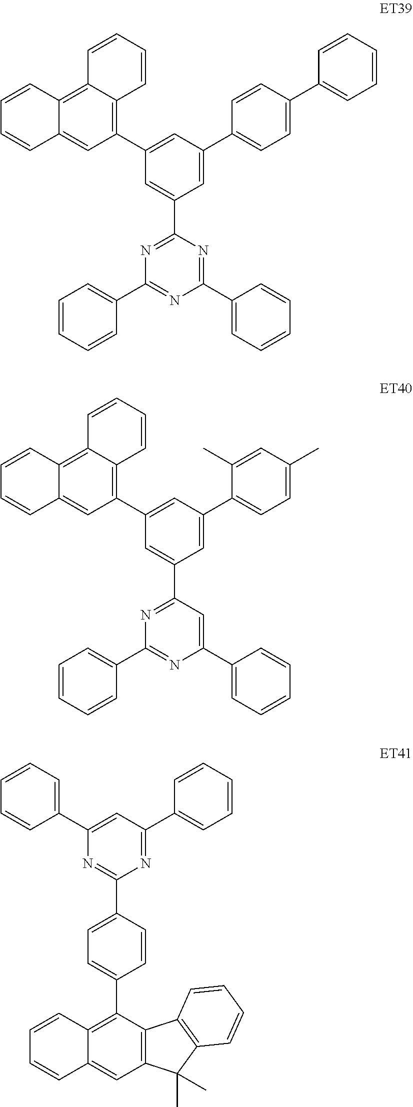 [SMILES: c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1 ; CC1(C)c2ccccc2-c2c1cc1ccccc1c2-c1ccc(-c2nc(-c3ccccc3)cc(-c3ccccc3)n2)cc1]

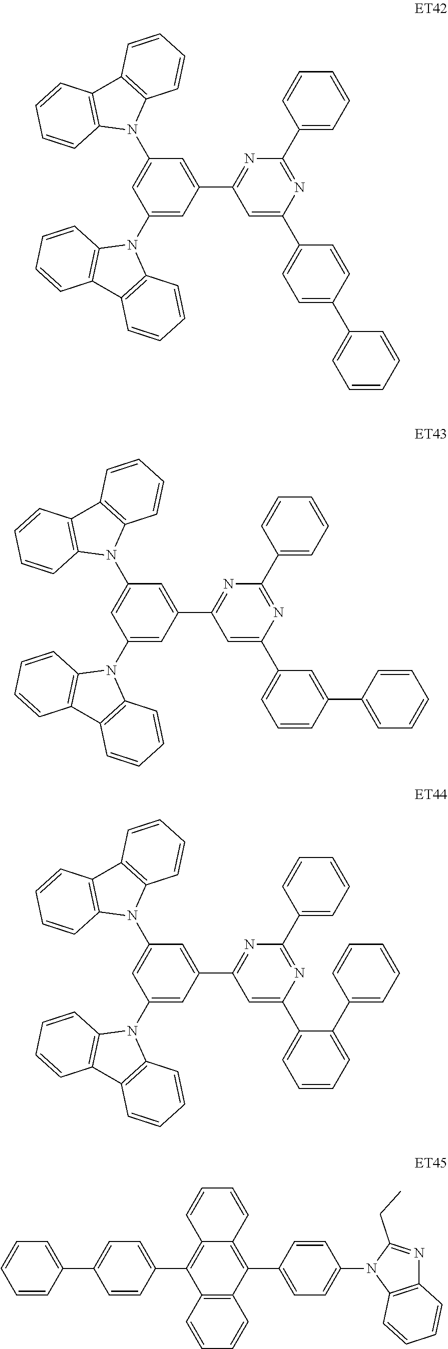 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

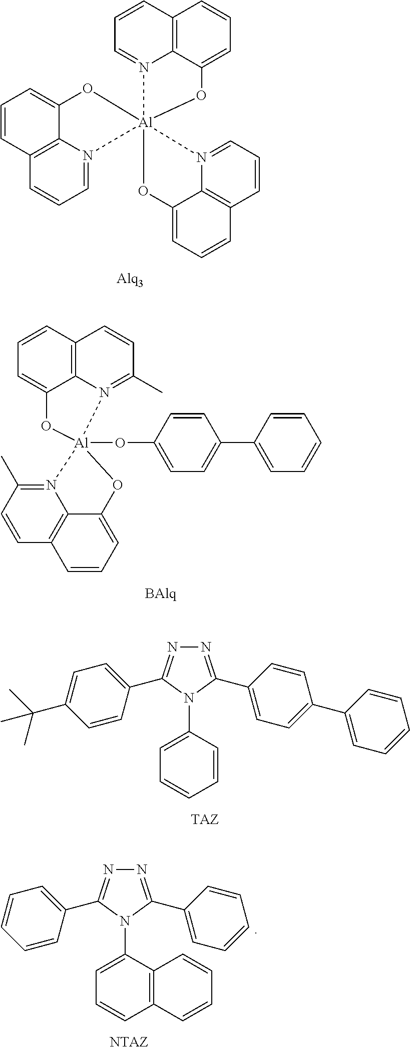

A thickness of the electron transport region may be in a range of about 100 Å to about 5,000 Å, for example, about 160 Å to about 4,000 Å. When the electron transport region includes a buffer layer, a hole blocking layer, an electron control layer, an electron transport layer, or any combination thereof, a thickness of the buffer layer, the hole blocking layer, or the electron control layer may be in a range of about 20 Å to about 1,000 Å, for example, about 30 Å to about 300 Å, and a thickness of the electron transport layer may be in a range of about 100 Å to about 1,000 Å, for example, about 150 Å to about 500 Å. When the thicknesses of the buffer layer, the hole blocking layer, the electron control layer, the electron transport layer, and/or the electron transport region 140 are within these ranges, suitable or satisfactory electron transporting characteristics may be obtained without a substantial increase in driving voltage.

The electron transport region (for example, the electron transport layer in the electron transport region) may further include, in addition to the materials described above, a metal-containing material.

The metal-containing material may include an alkali metal complex, an alkaline earth metal complex, or any combination thereof. The metal ion of an alkali metal complex may be a Li ion, a Na ion, a K ion, a Rb ion, or a Cs ion, and the metal ion of an alkaline earth metal complex may be a Be ion, a Mg ion, a Ca ion, a Sr ion, or a Ba ion. A ligand coordinated with the metal ion of the alkali metal complex and/or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

For example, the metal-containing material may include a Li complex. The Li complex may include, for example, Compound ET-D1 (LiQ) and/or ET-D2:

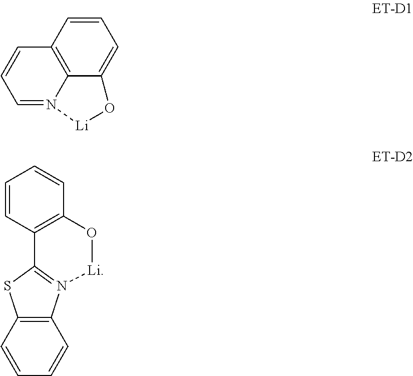

The electron transport region may include an electron injection layer that facilitates the injection of electrons from the second electrode 150. The electron injection layer may directly contact the second electrode 150.

The electron injection layer may have: i) a single-layer structure consisting of a single layer consisting of a single material, ii) a single-layer structure consisting of a single layer consisting of multiple different materials, or iii) a multi-layer structure including multiple layers including different materials.

The electron injection layer may include an alkali metal, alkaline earth metal, a rare earth metal, an alkali metal-containing compound, alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may be oxides, halides (for example, fluorides, chlorides, bromides, iodides, etc.), or tellurides of the alkali metal, the alkaline earth metal, and the rare earth metal, or any combination thereof.

The alkali metal-containing compound may include: an alkali metal oxide, such as Li₂O, Cs₂O, K₂O, and/or the like; alkali metal halides, such as LiF, NaF, CsF, KF, Lil, NaI, Csl, KI, and/or the like; or any combination thereof. The alkaline earth metal-containing compound may include an alkaline earth metal compound, such as BaO, SrO, CaO, BaₓSr₁₋ₓO (wherein x is a real number satisfying 0<x<1), BaₓCa₁₋ₓO (wherein x is a real number satisfying 0<x<1), and/or the like. The rare earth metal-containing compound may include YbF₃, ScF₃, Sc₂O₃, Y₂₀₃, Ce₂O₃, GdF₃, TbF₃, YbI₃, ScI₃, TbI₃, or any combination thereof. In one or more embodiments, the rare earth metal-containing compound may include lanthanide metal telluride. Examples of the lanthanide metal telluride are LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and the like.

The alkali metal complex, the alkaline earth-metal complex, and the rare earth metal complex may include i) one selected from ions of the alkali metal, the alkaline earth metal, and the rare earth metal and ii), as a ligand bonded to the metal ion, for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof.

In one or more embodiments, the electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In one or more embodiments, the electron injection layer may further include an organic material (for example, a compound represented by Formula 601).

In one or more embodiments, the electron injection layer may consist of i) an alkali metal-containing compound (for example, alkali metal halide), ii) a) an alkali metal-containing compound (for example, alkali metal halide); and b) an alkali metal, an alkaline earth metal, a rare earth metal, or any combination thereof. For example, the electron injection layer may be a KI:Yb co-deposited layer, an Rbl:Yb co-deposited layer, a LiF:Yb co-deposited layer, and/or the like.

When the electron injection layer further includes an organic material, an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof may be uniformly or non-uniformly dispersed in a matrix including the organic material.

A thickness of the electron injection layer may be in a range of about 1 Å to about 100 Å, and, for example, about 3 Å to about 90 Å. When the thickness of the electron injection layer is within the ranges above, suitable or satisfactory electron injection characteristics may be obtained without a substantial increase in driving voltage.

### Second Electrode 150

The second electrode 150 may be on the interlayer 130 having a structure as described above. The second electrode 150 may be a cathode, which is an electron injection electrode, and as a material for forming the second electrode 150, a metal, an alloy, an electrically conductive compound, or any combination thereof, each having a low-work function, may be used.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a semi-transmissive electrode, or a reflective electrode.

The second electrode 150 may have a single-layer structure or a multi-layer structure including multiple layers.

### Capping Layer

The first capping layer may be outside the first electrode 110, and/or the second capping layer may be outside the second electrode 150. For example, the light-emitting device 10 may have a structure in which the first capping layer, the first electrode 110, the interlayer 130, and the second electrode 150 are sequentially stacked in the stated order, a structure in which the first electrode 110, the interlayer 130, the second electrode 150, and the second capping layer are sequentially stacked in the stated order, or a structure in which the first capping layer, the first electrode 110, the interlayer 130, the second electrode 150, and the second capping layer are sequentially stacked in the stated order.

Light generated in the emission layer of the interlayer 130 of the light-emitting device 10 may be extracted toward the outside through the first electrode 110 which is a semi-transmissive electrode or a transmissive electrode, and the first capping layer. Light generated in the emission layer of the interlayer 130 of the light-emitting device 10 may be extracted toward the outside through the second electrode 150 which is a semi-transmissive electrode or a transmissive electrode, and the second capping layer.

The first capping layer and the second capping layer may increase external emission efficiency according to the principle of constructive interference. Accordingly, the light extraction efficiency of the light-emitting device 10 may be increased, so that the luminescence efficiency of the light-emitting device 10 may be improved.

Each of the first capping layer and the second capping layer may include a material having a refractive index of greater than or equal to 1.6 (at a wavelength of 530 nm).

The first capping layer and the second capping layer may each independently be an organic capping layer including an organic material, an inorganic capping layer including an inorganic material, or an organic-inorganic composite capping layer including an organic material and an inorganic material.

At least one selected from the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with a substituent including O, N, S, Se, Si, F, Cl, Br, I, or any combination thereof. In one or more embodiments, at least one selected from the first capping layer and the second capping layer may each independently include an amine group-containing compound.

In one or more embodiments, at least one selected from the first capping layer and the second capping layer may each independently include a compound represented by Formula 201, a compound represented by Formula 202, or any combination thereof.

In one or more embodiments, at least one selected from the first capping layer and the second capping layer may each independently include: one selected from Compounds HT28 to HT33; one selected from Compounds CP1 to CP7; β-NPB; or any combination thereof:

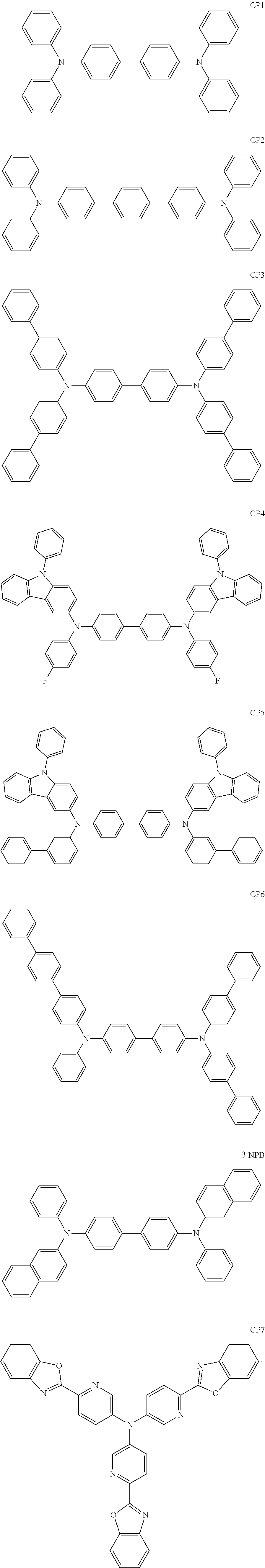

### Film

The organometallic compound represented by Formula 1 may be included in various suitable films. Accordingly, another aspect of embodiments of the disclosure provides a film including the organometallic compound represented by Formula 1. The film may be, for example, an optical member (or a light control means) (for example, a color filter, a color conversion member, a capping layer, a light extraction efficiency enhancement layer, a selective light absorbing layer, a polarizing layer, a quantum dot-containing layer, and/or the like), a light-blocking member (for example, a light reflective layer, a light absorbing layer, and/or the like), and/or a protective member (for example, an insulating layer, a dielectric layer, and/or the like).

### Electronic Apparatus

The light-emitting device may be included in various suitable electronic apparatuses. For example, the electronic apparatus including the light-emitting device may be a light-emitting apparatus, an authentication apparatus, and/or the like.

The electronic apparatus (for example, a light-emitting apparatus) may further include, in addition to the light-emitting device, i) a color filter, ii) a color conversion layer, or iii) a color filter and a color conversion layer. The color filter and/or the color conversion layer may be in at least one traveling direction of light emitted from the light-emitting device. For example, the light emitted from the light-emitting device may be blue light or white light. Further details of the light-emitting device may be understood by referring to the descriptions provided elsewhere herein. In one or more embodiments, the color conversion layer may include a quantum dot. The quantum dot may be, for example, the quantum dot as described herein.

The electronic apparatus may include a first substrate. The first substrate may include a plurality of subpixel areas, the color filter may include a plurality of color filter areas respectively corresponding to the subpixel areas, and the color conversion layer may include a plurality of color conversion areas respectively corresponding to the subpixel areas.

A pixel-defining film may be arranged among the subpixel areas to define each of the subpixel areas.

The color filter may further include a plurality of color filter areas and light-shielding patterns arranged among the color filter areas, and the color conversion layer may further include a plurality of color conversion areas and light-shielding patterns arranged among the color conversion areas.

The plurality of color filter areas (or the plurality of color conversion areas) may include a first area that emits a first color light, a second area that emits a second color light, and/or a third area that emits a third color light, wherein the first color light, the second color light, and/or the third color light may have different maximum emission wavelengths from one another. For example, the first color light may be red light, the second color light may be green light, and the third color light may be blue light. For example, the plurality of color filter areas (or the plurality of color conversion areas) may include quantum dots. In one or more embodiments, the first area may include a red quantum dot, the second area may include a green quantum dot, and the third area may not include a quantum dot. Further details of the quantum dot may be understood by referring to the descriptions provided elsewhere herein. The first area, the second area, and/or the third area may each further include a scatter.

For example, the light-emitting device may emit a first light, the first area may absorb the first light to emit a first-first color light, the second area may absorb the first light to emit a second-first color light, and the third area may absorb the first light to emit a third-first color light. Here, the first-first color light, the second-first color light, and the third-first color light may have different maximum emission wavelengths. For example, the first light may be blue light, the first-first color light may be red light, the second-first color light may be green light, and the third-first color light may be blue light.

The electronic apparatus may further include a thin-film transistor, in addition to the light-emitting device as described above. The thin-film transistor may include a source electrode, a drain electrode, and an activation layer, wherein any one selected from the source electrode and the drain electrode may be electrically connected to any one selected from the first electrode and the second electrode of the light-emitting device 10.

The thin-film transistor may further include a gate electrode, a gate insulating film, and/or the like.

The activation layer may include crystalline silicon, amorphous silicon, an organic semiconductor, an oxide semiconductor, and/or the like.

The electronic apparatus may further include a sealing portion for sealing the light-emitting device. The sealing portion may be between the color filter and/or the color conversion layer and the light-emitting device. The sealing portion allows light from the light-emitting device to be extracted to the outside, and concurrently (e.g., simultaneously) prevents or reduces penetration of ambient air and/or moisture into the light-emitting device. The sealing portion may be a sealing substrate including a transparent glass substrate and/or a plastic substrate. The sealing portion may be a thin-film encapsulation layer including at least one layer of an organic layer and/or an inorganic layer. When the sealing portion is a thin film encapsulation layer, the electronic apparatus may be flexible.

Various suitable functional layers may be additionally on the sealing portion, in addition to the color filter and/or the color conversion layer, according to the use of the electronic apparatus. The functional layers may include a touch screen layer, a polarizing layer, and/or the like. The touch screen layer may be a pressure-sensitive touch screen layer, a capacitive touch screen layer, and/or an infrared touch screen layer.

The authentication apparatus may further include, in addition to the light-emitting device as described above, a biometric information collector. The authentication apparatus may be, for example, a biometric authentication apparatus that authenticates an individual by using biometric information of a living body (for example, fingertips, pupils, etc.).

The electronic apparatus may be applied to various suitable displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, and/or endoscope displays), fish finders, various suitable measuring instruments, meters (for example, meters for a vehicle, an aircraft, and/or a vessel), projectors, and/or the like.

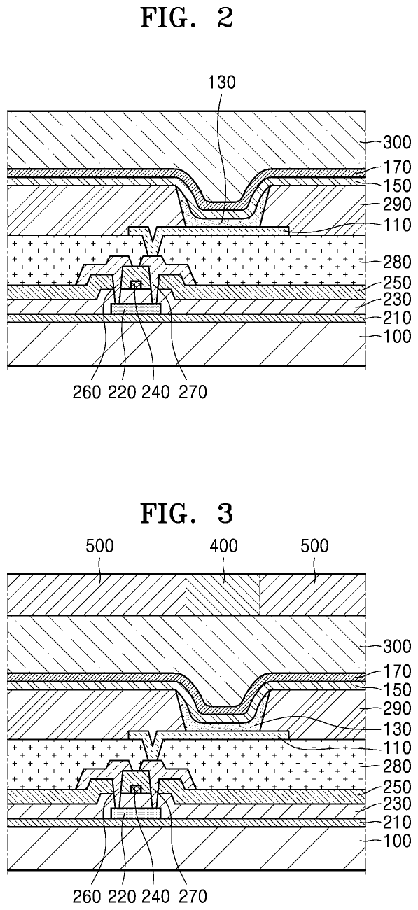

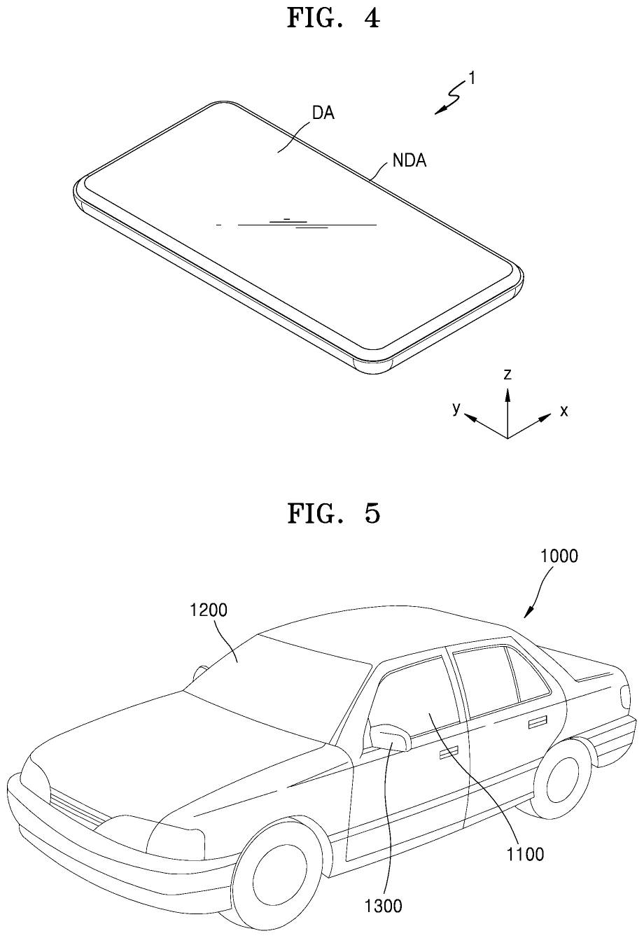

### Description of FIGS. 2 and 3

FIG. 2 is a cross-sectional view showing a light-emitting apparatus according to one or more embodiments.

The light-emitting apparatus of FIG. 2 includes a substrate 100, a thin-film transistor (TFT), a light-emitting device, and an encapsulation portion 300 that seals the light-emitting device.

The substrate 100 may be a flexible substrate, a glass substrate, and/or a metal substrate. A buffer layer 210 may be on the substrate 100. The buffer layer 210 may prevent or reduce penetration of impurities through the substrate 100 and may provide a flat surface on the substrate 100.

A TFT may be on the buffer layer 210. The TFT may include an activation layer 220, a gate electrode 240, a source electrode 260, and a drain electrode 270.

The activation layer 220 may include an inorganic semiconductor such as silicon or polysilicon, an organic semiconductor, or an oxide semiconductor, and may include a source region, a drain region, and a channel region.

A gate insulating film 230 for insulating the activation layer 220 from the gate electrode 240 may be on the activation layer 220, and the gate electrode 240 may be on the gate insulating film 230.

An interlayer insulating film 250 may be on the gate electrode 240. The interlayer insulating film 250 may be between the gate electrode 240 and the source electrode 260 and between the gate electrode 240 and the drain electrode 270, to insulate from one another.

The source electrode 260 and the drain electrode 270 may be on the interlayer insulating film 250. The interlayer insulating film 250 and the gate insulating film 230 may expose the source region and the drain region of the activation layer 220, and the source electrode 260 and the drain electrode 270 may be in contact with the exposed portions of the source region and the drain region of the activation layer 220.

The TFT may be electrically connected to a light-emitting device 10 to drive the light-emitting device, and may be covered and protected by a passivation layer 280. The passivation layer 280 may include an inorganic insulating film, an organic insulating film, or any combination thereof. The light-emitting device may be provided on the passivation layer 280. The light-emitting device may include the first electrode 110, the interlayer 130, and the second electrode 150.

The first electrode 110 may be on the passivation layer 280. The passivation layer 280 may expose a portion of the drain electrode 270, not fully covering the drain electrode 270, and the first electrode 110 may be connected to the exposed portion of the drain electrode 270.

A pixel defining layer 290 including an insulating material may be on the first electrode 110. The pixel defining layer 290 may expose a certain region of the first electrode 110, and an interlayer 130 may be formed in the exposed region of the first electrode 110. The pixel defining layer 290 may be a polyimide-based organic film and/or a polyacrylic-based organic film. In one or more embodiments, at least some layers of the interlayer 130 may extend beyond the upper portion of the pixel defining layer 290 to be in the form of a common layer.

The second electrode 150 may be on the interlayer 130, and a capping layer 170 may be additionally on the second electrode 150. The capping layer 170 may cover the second electrode 150.

The encapsulation portion 300 may be on the capping layer 170. The encapsulation portion 300 may be on a light-emitting device to protect the light-emitting device from moisture and/or oxygen. The encapsulation portion 300 may include: an inorganic film including silicon nitride (SiNx), silicon oxide (SiOx), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate, polyacrylic acid, and/or the like), an epoxy-based resin (for example, aliphatic glycidyl ether (AGE), and/or the like), or any combination thereof; or any combination of the inorganic films and the organic films.

FIG. 3 shows a cross-sectional view showing a light-emitting apparatus according to another embodiment.

The light-emitting apparatus of FIG. 3 is the same as the light-emitting apparatus of FIG. 2, except that a light-shielding pattern 500 and a functional region 400 are additionally on the encapsulation portion 300. The functional region 400 may be i) a color filter area, ii) a color conversion area, or iii) a combination of the color filter area and the color conversion area. In one or more embodiments, the light-emitting device included in the light-emitting apparatus of FIG. 3 may be a tandem light-emitting device.

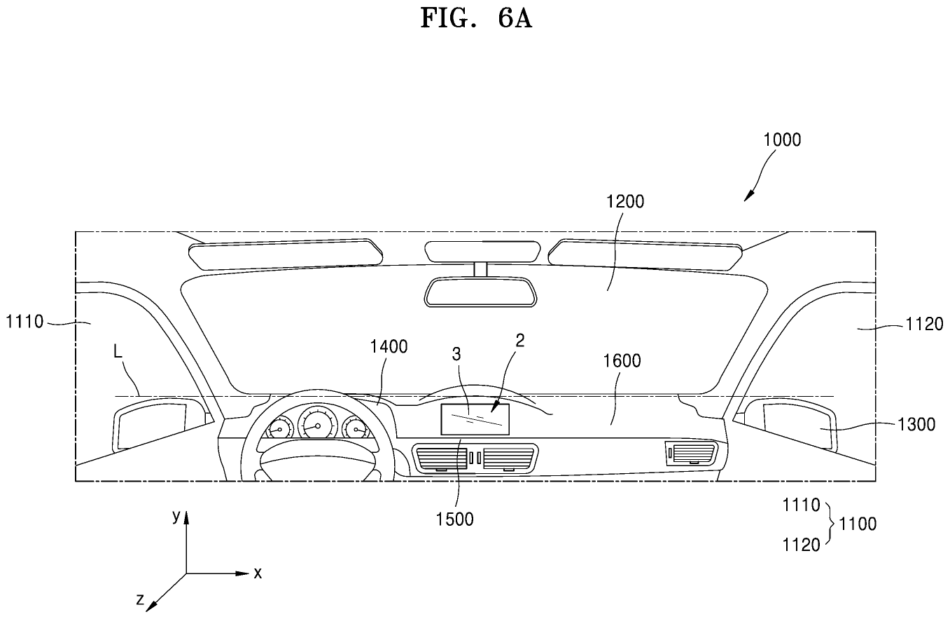

### Description of FIG. 4

FIG. 4 is a schematic perspective view of electronic equipment 1 including a light-emitting device according to one or more embodiments. The electronic equipment 1 may be, as a device apparatus that displays a moving image or still image, a portable electronic equipment, such as a mobile phone, a smart phone, a tablet personal computer (PC), a mobile communication terminal, an electronic notebook, an electronic book, a portable multimedia player (PMP), a navigation, and/or a ultra-mobile PC (UMPC), as well as various suitable products, such as a television, a laptop, a monitor, a billboards, and/or an Internet of things (IOT) device. The electronic equipment 1 may be such a product above or a part thereof. In addition, the electronic equipment 1 may be a wearable device, such as a smart watch, a watch phone, a glasses-type display, and/or a head mounted display (HMD), or a part of the wearable device. However, embodiments of the disclosure are not limited thereto. For example, the electron equipment 1 may include a dashboard of a vehicle, a center fascia of a vehicle, a center information display on a dashboard of a vehicle, a room mirror display replacing a side mirror of a vehicle, an entertainment display for the rear seat of a vehicle or a display on the back of the front seat, and/or a head up display (HUD) installed in the front of a vehicle and/or projected on a front window glass, a computer generated hologram augmented reality head up display (CGH AR HUD). FIG. 4 illustrates a case in which the electronic equipment 1 is a smart phone for convenience of explanation.

The electronic equipment 1 may include a display area DA and a non-display area NDA outside the display area DA. A display device may implement an image through an array of a plurality of pixels that are two-dimensionally in the display area DA.

The non-display area NDA is an area that does not display an image, and may entirely surround the display area DA. A driver for providing electrical signals or power to display devices on the display area DA may be on the non-display area NDA. A pad, which is an area to which an electronic element or a printing circuit board, may be electrically connected may be on the non-display area NDA.

In the electronic equipment 1, a length in the x-axis direction and a length in the y-axis direction may be different from each other. In one or more embodiments, as shown in FIG. 4, the length in the x-axis direction may be shorter than the length in the y-axis direction. In one or more embodiments, the length in the x-axis direction may be the same as the length in the y-axis direction. In one or more embodiments, the length in the x-axis direction may be longer than the length in the y-axis direction.

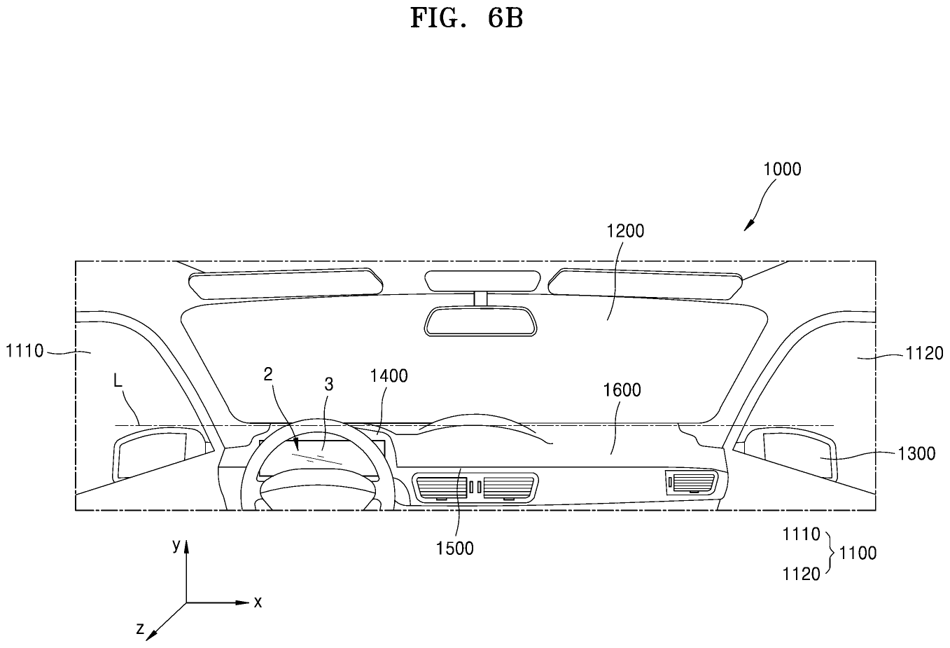

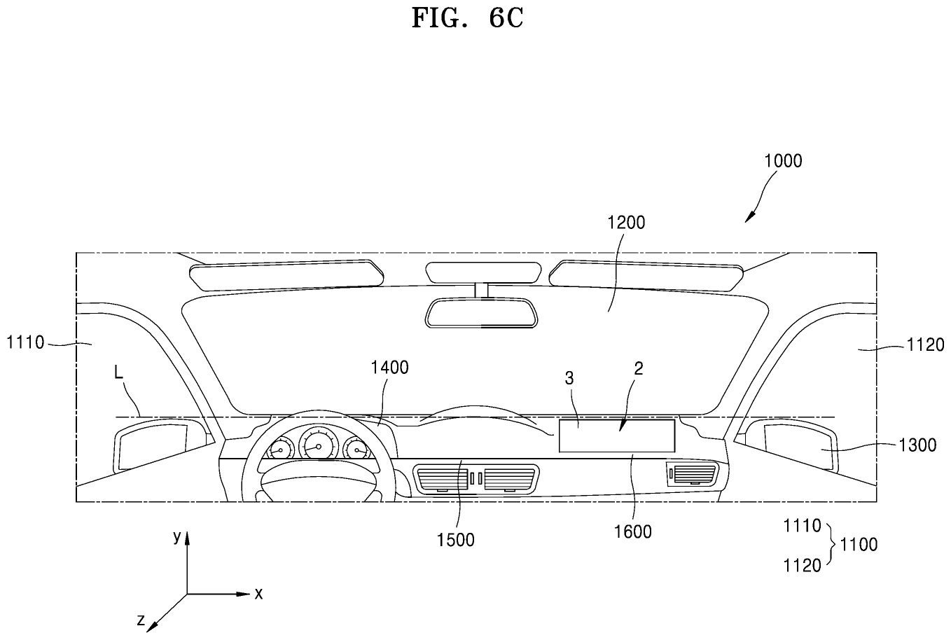

### Descriptions of FIGS. 5 and 6A to 6C

FIG. 5 is a diagram illustrating the exterior of a vehicle 1000 as electronic equipment including the light-emitting device according to one or more embodiments. FIGS. 6A to 6C are each a diagram schematically illustrating the interior of a vehicle 1000 according to various embodiments.

Referring to FIGS. 5 and 6A to 6C, the vehicle 1000 may refer to various suitable apparatuses for moving a subject to be transported, such as a human, an object, or an animal, from a departure point to a destination point. The vehicle 1000 may include a vehicle traveling on a road or track, a vessel moving over the sea or river, an airplane flying in the sky using the action of air, and the like.

The vehicle 1000 may travel on a road or a track. The vehicle 1000 may move in a set or predetermined direction according to rotation of at least one wheel. For example, the vehicle 1000 may include a three-wheeled or four-wheeled vehicle, a construction machine, a two-wheeled vehicle, a prime mover device, a bicycle, and a train running on a track.

The vehicle 1000 may include a body having an interior and an exterior, and a chassis in which mechanical apparatuses necessary for driving are installed as other parts except for the body. The exterior of the body may include a front panel, a bonnet, a roof panel, a rear panel, a trunk, a filler provided at a boundary between doors, and the like. The chassis of the vehicle 1000 may include a power generating device, a power transmitting device, a driving device, a steering device, a braking device, a suspension device, a transmission device, a fuel device, front and rear left and right wheels, and the like.

The vehicle 1000 may include a side window glass 1100, a front window glass 1200, a side mirror 1300, a cluster 1400, a center fascia 1500, a passenger seat dashboard 1600, and a display device 2.

The side window glass 1100 and the front window glass 1200 may be partitioned by a pillar between the side window glass 1100 and the front window glass 1200.

The side window glass 1100 may be installed on the side of the vehicle 1000. In one or more embodiments, the side window glass 1100 may be installed on a door of the vehicle 1000. A plurality of side window glasses 1100 may be provided and may face each other. In one or more embodiments, the side window glass 1100 may include a first side window glass 1110 and a second side window glass 1120. In one or more embodiments, the first side window glass 1110 may be adjacent to the cluster 1400. The second side window glass 1120 may be adjacent to the passenger seat dashboard 1600.

In one or more embodiments, the side window glasses 1100 may be spaced apart from each other in the x-direction or the −x-direction. For example, the first side window glass 1110 and the second side window glass 1120 may be spaced apart from each other in the x direction or the −x direction. In other words, an imaginary straight line L connecting the side window glasses 1100 may extend in the x-direction or the −x-direction. For example, an imaginary straight line L connecting the first side window glass 1110 and the second side window glass 1120 to each other may extend in the x direction or the −x direction.

The front window glass 1200 may be installed in front of the vehicle 1000. The front window glass 1200 may be between the side window glasses 1100 facing each other.

The side mirror 1300 may provide a rear view of the vehicle 1000. The side mirror 1300 may be installed on the exterior of the vehicle body. In one or more embodiments, a plurality of side mirrors 1300 may be provided. Any one of the plurality of side mirrors 1300 may be outside the first side window glass 1110. The other one of the plurality of side mirrors 1300 may be outside the second side window glass 1120.

The cluster 1400 may be in front of the steering wheel. The cluster 1400 may include a tachometer, a speedometer, a coolant thermometer, a fuel gauge turn indicator, a high beam indicator, a warning lamp, a seat belt warning lamp, an odometer, an odometer, an automatic shift selector indicator lamp, a door open warning lamp, an engine oil warning lamp, and/or a low fuel warning light.

The center fascia 1500 may include a control panel including a plurality of buttons for adjusting an audio device, an air conditioning device, and a heater of a seat. The center fascia 1500 may be on one side of the cluster 1400.

A passenger seat dashboard 1600 may be spaced apart from the cluster 1400 with the center fascia 1500 therebetween. In one or more embodiments, the cluster 1400 may correspond to a driver seat, and the passenger seat dashboard 1600 may correspond to a passenger seat. In one or more embodiments, the cluster 1400 may be adjacent to the first side window glass 1110, and the passenger seat dashboard 1600 may be adjacent to the second side window glass 1120.

In one or more embodiments, the display device 2 may include a display panel 3, and the display panel 3 may display an image. The display device 2 may be inside the vehicle 1000. In one or more embodiments, the display device 2 may be between the side window glasses 1100 facing each other. The display device 2 may be on at least one selected from the cluster 1400, the center fascia 1500, and the passenger seat dashboard 1600.

The display device 2 may include an organic light-emitting display device, an inorganic EL display device, a quantum dot display device, and the like. Hereinafter, as the display device 2 according to one or more embodiments of the present disclosure, an organic light-emitting display device display including the light-emitting device according to the present disclosure will be described as an example, but various suitable types or kinds of display devices as described above may be used in embodiments of the present disclosure.

Referring to FIG. 6A, the display device 2 may be on the center fascia 1500. In one or more embodiments, the display device 2 may display navigation information. In one or more embodiments, the display device 2 may display audio, video, or information regarding vehicle settings.

Referring to FIG. 6B, the display device 2 may be on the cluster 1400. When the display device 2 is on the cluster 1400, the cluster 1400 may display driving information and the like through the display device 2. For example, the cluster 1400 may be implemented digitally. The digital cluster 1400 may display vehicle information and driving information as images. For example, a needle and a gauge of a tachometer and various suitable warning light icons may be displayed by a digital signal.

Referring to FIG. 6C, the display device 2 may be on the passenger seat dashboard 1600. The display device 2 may be embedded in the passenger seat dashboard 1600 or on the passenger seat dashboard 1600. In one or more embodiments, the display device 2 on the passenger seat dashboard 1600 may display an image related to information displayed on the cluster 1400 and/or information displayed on the center fascia 1500. In one or more embodiments, the display device 2 on the passenger seat dashboard 1600 may display information different from information displayed on the cluster 1400 and/or information displayed on the center fascia 1500.

### Manufacturing Method

Respective layers included in the hole transport region, the emission layer, and respective layers included in the electron transport region may be formed in a certain region by using one or more suitable methods selected from vacuum deposition, spin coating, casting, Langmuir-Blodgett (LB) deposition, ink-jet printing, laser-printing, laser-induced thermal imaging, and the like.

When respective layers included in the hole transport region, the emission layer, and respective layers included in the electron transport region are formed by vacuum deposition, the deposition may be performed at a deposition temperature of about 100° C. to about 500° C., a vacuum degree of about 10⁻⁸ torr to about 10-3 torr, and a deposition speed of about 0.01 Å/sec to about 100 Å/sec, depending on a material to be included in a layer to be formed and the structure of a layer to be formed.

### Definition of Terms

The term “C₃-C₆₀ carbocyclic group” as used herein refers to a cyclic group consisting of carbon only as a ring-forming atom and having three to sixty carbon atoms, and the term “C₁-C₆₀ heterocyclic group” as used herein refers to a cyclic group that has one to sixty carbon atoms and further has, in addition to carbon, a heteroatom as a ring-forming atom. The C₃-C₆₀ carbocyclic group and the C₁-C₆₀ heterocyclic group may each be a monocyclic group consisting of one ring or a polycyclic group in which two or more rings are condensed together with each other. For example, the number of ring-forming atoms of the C₁-C₆₀ heterocyclic group may be from 3 to 61.

The term “cyclic group” as used herein may include both the C₃-C₆₀ carbocyclic group and the C₁-C₆₀ heterocyclic group.

The term “Π electron-rich C₃-C₆₀ cyclic group” as used herein refers to a cyclic group that has three to sixty carbon atoms and does not include *—N=*′ as a ring-forming moiety, and the term “Π electron-deficient nitrogen-containing C₁-C₆₀ cyclic group” as used herein refers to a heterocyclic group that has one to sixty carbon atoms and includes *—N=*′ as a ring-forming moiety.

For example,
the C₃-C₆₀ carbocyclic group may be i) a T1 group or ii) a condensed cyclic group in which two or more T1 groups are condensed together with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) a T2 group, ii) a condensed cyclic group in which at least two T2 groups are condensed together with each other, or iii) a condensed cyclic group in which at least one T2 group and at least one T1 group are condensed together with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, or the like),
the Π electron-rich C₃-C₆₀ cyclic group may be i) a T1 group, ii) a condensed cyclic group in which at least two T1 groups are condensed together with each other, iii) a T3 group, iv) a condensed cyclic group in which at least two T3 groups are condensed together with each other, or v) a condensed cyclic group in which at least one T3 group and at least one T1 group are condensed together with each other (for example, the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, or the like), and
the Π electron-deficient nitrogen-containing C₁-C₆₀ cyclic group may be i) a T4 group, ii) a condensed cyclic group in which at least two T4 groups are condensed together with each other, iii) a condensed cyclic group in which at least one T4 group and at least one T1 group are condensed together with each other, iv) a condensed cyclic group in which at least one T4 group and at least one T3 group are condensed together with each other, or v) a condensed cyclic group in which at least one T4 group, at least one T1 group, and at least one T3 group are condensed together with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and the like),
the T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
the T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
the T3 group may be a furan group, a thiophene group, a 1H-pyrrole group, a silole group, or a borole group, and

The T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group, the C₃-C₆₀ carbocyclic group, the C₁-C₆₀ heterocyclic group, the Π electron-rich C₃-C₆₀ cyclic group, or the Π electron-deficient nitrogen-containing C₁-C₆₀ cyclic group” as used herein refer to a group condensed to any cyclic group, a monovalent group, or a polyvalent group (for example, a divalent group, a trivalent group, a tetravalent group, etc.) according to the structure of a formula for which the corresponding term is used. For example, the “benzene group” may be a benzo group, a phenyl group, a phenylene group, or the like, which may be easily understood by one of ordinary skill in the art according to the structure of a formula including the “benzene group.”

Examples of the monovalent C₃-C₆₀ carbocyclic group and monovalent C₁-C₆₀ heterocyclic group are a C₃-C₁ cycloalkyl group, a C₁-C₁₀ heterocycloalkyl group, a C₃-C₁ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and examples of the divalent C₃-C₆₀ carbocyclic group and the monovalent C₁-C₆₀ heterocyclic group may include a C₃-C₁ cycloalkylene group, a C₁-C₁₀ heterocycloalkylene group, a C₃-C₁ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed heteropolycyclic group.

The term “C₁-C₆₀ alkyl group” as used herein refers to a linear or branched aliphatic hydrocarbon monovalent group that has 1 to 60 carbon atoms, and examples thereof include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as used herein refers to a divalent group having substantially the same structure as the C₁-C₆₀ alkyl group.

The term “C₂-C₆₀ alkenyl group” as used herein refers to a monovalent hydrocarbon group having at least one carbon-carbon double bond in the middle or at the terminus of the C₂-C₆₀ alkyl group, and examples thereof are an ethenyl group, a propenyl group, a butenyl group, and the like. The term “C₂-C₆₀ alkenylene group” as used herein refers to a divalent group having substantially the same structure as the C₂-C₆₀ alkenyl group.

The term “C₂-C₆₀ alkynyl group” as used herein refers to a monovalent hydrocarbon group having at least one carbon-carbon triple bond in the middle or at the terminus of the C₂-C₆₀ alkyl group, and examples thereof are an ethynyl group, a propynyl group, and the like. The term “C₂-C₆₀ alkynylene group” as used herein refers to a divalent group having substantially the same structure as the C₂-C₆₀ alkynyl group.

The term “C₁-C₆₀ alkoxy group” as used herein refers to a monovalent group represented by —OA₁₀₁ (wherein A₁₀₁ is the C₁-C₆₀ alkyl group), and examples thereof are a methoxy group, an ethoxy group, an isopropyloxy group, and the like.

The term “C₃-C₁₀ cycloalkyl group” as used herein refers to a monovalent saturated hydrocarbon cyclic group having 3 to 10 carbon atoms, and examples thereof are a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and the like. The term “C₃-C₁₀ cycloalkylene group” as used herein refers to a divalent group having substantially the same structure as the C₃-C₁₀ cycloalkyl group.

The term “C₁-C₁₀ heterocycloalkyl group” as used herein refers to a monovalent cyclic group of 1 to 10 carbon atoms, further including, in addition to carbon atoms, at least one heteroatom, as ring-forming atoms, and examples thereof are a 1,2,3,4-oxatriazolidinyl group, a tetrahydrofuranyl group, a tetrahydrothiophenyl group, and the like. The term “C₁-C₁₀ heterocycloalkylene group” as used herein refers to a divalent group having substantially the same structure as the C₁-C₁₀ heterocycloalkyl group.

The term “C₃-C₁₀ cycloalkenyl group” as used herein refers to a monovalent cyclic group that has three to ten carbon atoms and at least one carbon-carbon double bond in the ring thereof and no aromaticity (e.g., is not aromatic), and examples thereof are a cyclopentenyl group, a cyclohexenyl group, a cycloheptenyl group, and the like. The term “C₃-C₁₀ cycloalkenylene group” as used herein refers to a divalent group having substantially the same structure as the C₃-C₁₀ cycloalkenyl group.

The term “C₁-C₁₀ heterocycloalkenyl group” as used herein refers to a monovalent cyclic group of 1 to 10 carbon atoms, further including, in addition to carbon atoms, at least one heteroatom, as ring-forming atoms, and having at least one carbon-carbon double bond in the cyclic structure thereof. Examples of the C₁-C₁ heterocycloalkenyl group are a 4,5-dihydro-1,2,3,4-oxatriazolyl group, a 2,3-dihydrofuranyl group, a 2,3-dihydrothiophenyl group, and the like. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system of 6 to 60 carbon atoms, and the term “C₆-C₆₀ arylene group” as used herein refers to a divalent group having a carbocyclic aromatic system of 6 to 60 carbon atoms. Examples of the C₆-C₆₀ aryl group are a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and the like. When the C₆-C₆₀ aryl group and the C₆-C₆₀ arylene group each include two or more rings, the rings may be condensed together with each other.

The term “C₁-C₆₀ heteroaryl group” as used herein refers to a monovalent group having a heterocyclic aromatic system of 1 to 60 carbon atoms, further including, in addition to carbon atoms, at least one heteroatom, as ring-forming atoms. The term “C₁-C₆₀ heteroarylene group” as used herein refers to a divalent group having a heterocyclic aromatic system of 1 to 60 carbon atoms, further including, in addition to carbon atoms, at least one heteroatom, as ring-forming atoms. Examples of the C₁-C₆₀ heteroaryl group are a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each include two or more rings, the rings may be condensed together with each other.

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure (e.g., is not aromatic). Examples of the monovalent non-aromatic condensed polycyclic group are an indenyl group, a fluorenyl group, a spiro-bifluorenyl group, a benzofluorenyl group, an indenophenanthrenyl group, an indeno anthracenyl group, and the like. The term “divalent non-aromatic condensed polycyclic group” as used herein refers to a divalent group having substantially the same structure as the monovalent non-aromatic condensed polycyclic group described above.

The term “monovalent non-aromatic condensed heteropolycyclic group” as used herein refers to a monovalent group (for example, having 1 to 60 carbon atoms) having two or more rings condensed to each other, further including, in addition to carbon atoms, at least one heteroatom, as ring-forming atoms, and having non-aromaticity in its entire molecular structure (e.g., is not aromatic). Examples of the monovalent non-aromatic condensed heteropolycyclic group are a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as used herein refers to a divalent group having substantially the same structure as the monovalent non-aromatic condensed heteropolycyclic group described above.

The term “C₆-C₆₀ aryloxy group” as used herein indicates —OA₁₀₂ (wherein A₁₀₂ is the C₆-C₆₀ aryl group), and the term “C₆-C₆₀ arylthio group” as used herein indicates —SA₁₀₃ (wherein A₁₀₃ is the C₆-C₆₀ aryl group).

The term “C₇-C₆₀ arylalkyl group” as used herein refers to -A₁₀₄A₁₀₅ (wherein A₁₀₄ is a C₁-C₅₄ alkylene group, and A₁₀₅ is a C₆-C₅₉ aryl group), and the term “C₂-C₆₀ heteroarylalkyl group” as used herein refers to -A₁₀₆A₁₀₇ (wherein A₁₀₆ is a C₁-C₅₉ alkylene group, and A₁₀₇ is a C₁-C₅₉ heteroaryl group).

The term “R₁₀ₐ” as used herein may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the present specification, Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ arylalkyl group; or a C₂-C₆₀ heteroarylalkyl group.

The term “heteroatom” as used herein refers to any atom other than a carbon atom. Examples of the heteroatom are O, S, N, P, Si, B, Ge, Se, and any combination thereof.

In the present specification, the third-row transition metal may include hafnium (Hf), tantalum (Ta), tungsten (W), rhenium (Re), osmium (Os), iridium (Ir), platinum (Pt), gold (Au), and/or the like.

In the present specification, “Ph” refers to a phenyl group, “Me” refers to a methyl group, “Et” refers to an ethyl group, “tert-Bu” or “Bu^{t}” refers to a tert-butyl group, and “OMe” refers to a methoxy group.

The term “biphenyl group” as used herein refers to “a phenyl group substituted with a phenyl group.” In other words, the “biphenyl group” may be a substituted phenyl group having a C₆-C₆₀ aryl group as a substituent.

The term “terphenyl group” as used herein refers to “a phenyl group substituted with a biphenyl group.” In other words, the “terphenyl group” may be a substituted phenyl group having, as a substituent, a C₆-C₆₀ aryl group substituted with a C₆-C₆₀ aryl group.

In the present specification, the x-axis, y-axis, and z-axis are not limited to three axes in an orthogonal coordinate system, and may be interpreted in a broad sense including these axes. For example, the x-axis, y-axis, and z-axis may refer to those orthogonal to each other, or may refer to those in different directions that are not orthogonal to each other.
* and *′ as used herein, unless defined otherwise, each refer to a binding site to a neighboring atom in a corresponding formula or moiety.

Hereinafter, compounds according to embodiments and light-emitting devices according to embodiments will be described in more detail with reference to the following synthesis examples and examples. The wording “B was used instead of A” used in describing Synthesis Examples means that an identical molar equivalent of B was used in place of A.

### EXAMPLES

### Synthesis Example 1: Synthesis of Compound 9

### Synthesis of Intermediate 9-1

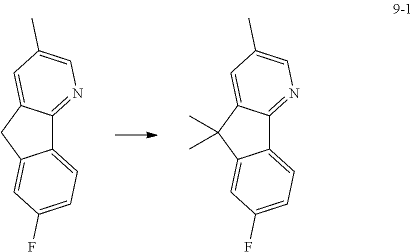 [SMILES: Cc1cnc2c(c1)Cc1cc(F)ccc1-2 ; Cc1cnc2c(c1)C(C)(C)c1cc(F)ccc1-2]

19.9 g (100 mmol) of 7-fluoro-3-methyl-5H-indeno[1,2-b]pyridine and 38.4 g (400 mmol) of sodium tert-butoxide were suspended in 300 ml of DMF. The suspension was stirred at 60° C. for 30 minutes, and subsequently, 12.8 mL (205 mmol) of methyl iodide was added dropwise thereto. The resultant mixture was stirred at 60° C. for 6 hours, and 500 ml of water was added thereto. The precipitated solid was filtered, and the filtrate was washed with 100 ml of water three times and 50 ml of ethanol three times, and then, dried and recrystallized, so as to obtain 16.6 g (73%) of Intermediate 9-1.

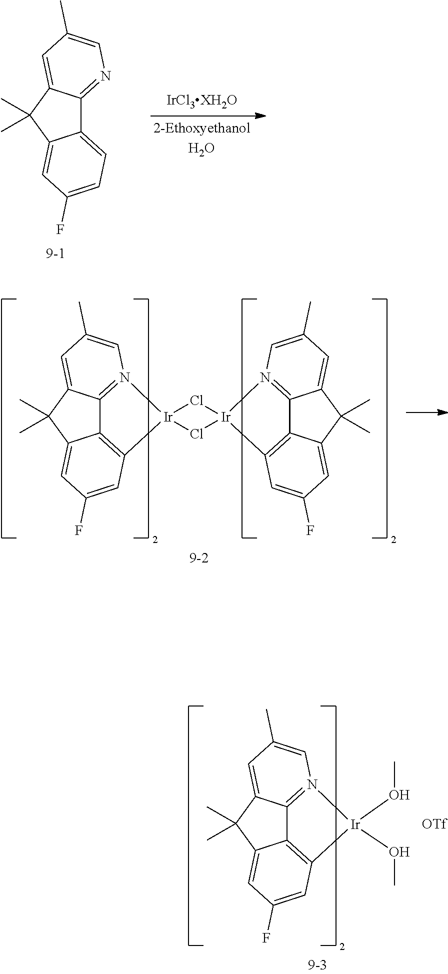

### Synthesis of Intermediate 9-2

Intermediate 9-1 (2.5 g, 11.0 mmol). IrCl₃·H₂O (1.79 g, 4.83 mmol), 2-ethoxyethanol (45 mL), and water (105 mL) were stirred under reflux overnight under nitrogen. The resultant reaction mixture was filtered, and the filtrate was washed with 10 mL of methanol three times, and dried in a vacuum condition, so as to obtain 2.45 g (65%) of Intermediate 9-2.

### Synthesis of Intermediate 9-3

Intermediate 9-2 (2.54 g, 1.87 mmol) and trifluoromethanesulfonate (1.0 g, 3.92 mmol) were added to 200 mL of dichloromethane and 10 mL of methanol to prepare a reaction mixture. The reaction mixture was stirred for 3 hours. The precipitated solid was filtered, and the filtrate was washed with dichloromethane, dried by evaporation, and then dried again under high vacuum, so as to obtain 2.73 g (85%) of Intermediate 9-3.

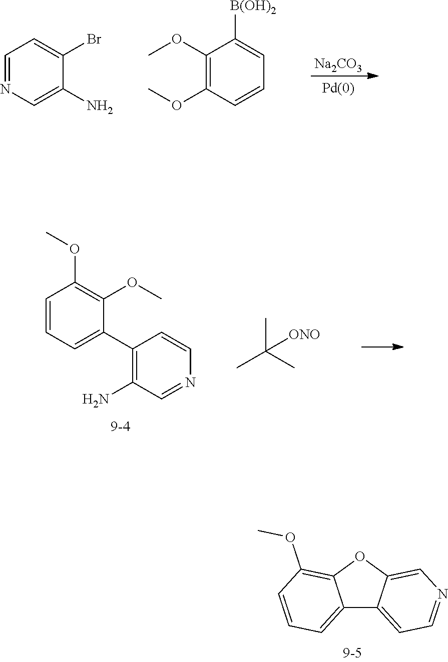

### Synthesis of Intermediate 9-4

4-bromopyridine-3-amine (23.77 g, 137 mmol), (2,3-dimethoxyphenyl)boronic acid (25 g, 137 mmol), and Pd(Ph₃P)₄ (4.76 g, 4.12 mmol) were added to a two-necked flask. The resultant reaction mixture was diluted with THF (600 mL). Next, a solution in which sodium carbonate (14.56 g, 137 mmol) was dissolved in water (300 mL) was added thereto, and the resultant mixture was diluted with ethyl acetate and brine. An organic layer thus obtained was washed with water, and then dried by using sodium sulfate. The resulting product was separated on a silica gel chromatography column in which ethyl acetate (0% to 50%) in DMC was used as an eluent, so as to obtain 28.9 g (91%) of Intermediate 9-4.

### Synthesis of Intermediate 9-5

Intermediate 9-4 (14 g, 60.8 mmol) was added to a 500 mL round-bottom flask, and acetic acid (220 mL) and THF (74 mL) were added thereto. The resultant mixture was stirred in a brine ice bath. Then, t-butyl nitrite (14.5 mL, 109 mmol) was added dropwise thereto. After stirring the resultant reaction mixture in the bath for 3 hours, the ambient temperature was raised while stirring. The resultant mixture was evaporated in vacuum, distributed between ethyl acetate and aqueous sodium bicarbonate, and then subjected to silica gel chromatography in which ethyl acetate (25%) in hexane was used as an eluent, so as to obtain 61 g (54.6%) of Intermediate 9-5.

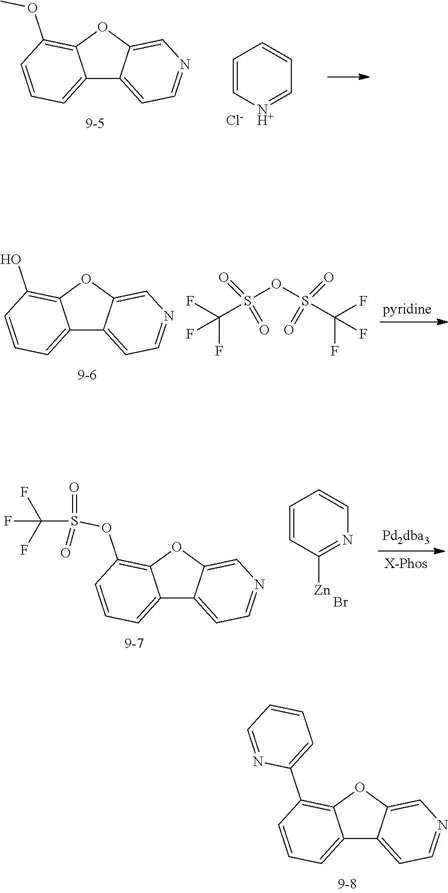

### Synthesis of Intermediate 9-6

Intermediate 9-5 (6.6 g, 33.1 mmol) and pyridine HCl (25 g) were added to a 250 mL round-bottom flask. The resultant mixture was stirred at 200° C. for 10 hours in an oil bath, and aqueous sodium bicarbonate and DCM were added thereto. An organic layer thus obtained was dried and evaporated to a brown solid, so as to obtain 5.07 g (83%) of Intermediate 9-6.

### Synthesis of Intermediate 9-7

Intermediate 9-6 (5.5 g, 29.7 mmol) was added to a 500 mL round-bottom flask, and DCM (250 mL) was added thereto. Pyridine (6.01 mL, 74.3 mmol) was also added thereto, and the flask was placed in an ice bath. Triflic anhydride (7.5 mL, 44.6 mmol) was dissolved in DCM (30 mL) and added dropwise to the flask for 10 minutes.

After the bath was removed, the resultant reaction mixture was heated to the ambient temperature, and then stirred overnight. The resulting solution was washed with saturated sodium bicarbonate solution, followed by water. The resulting product was subjected to silica gel chromatography in which DCM was used as an eluent, so as to obtain 8.1 g (86%) of Intermediate 9-7.

### Synthesis of Intermediate 9-8

Intermediate 9-7 (4 g, 12.61 mmol), X-Phos (0.481 g, 1.009 mmol), and Pd₂dba₃ (0.231 g, 0.252 mmol) were added to a 250 mL three-necked flask. After the flask was evacuated and backfilled with nitrogen, THF (40 mL) and pyridine-2-yl zinc(II) bromide (37.8 mL, 18.91 mmol) were added thereto. The resultant mixture was stirred at 70° C. for 4 hours in an oil bath. The resulting mixture was filtered through Celite®, and the filtrate was washed with ethyl acetate. A crude material thus obtained was absorbed on Celite®, and then subjected to silica gel chromatography in which ethyl acetate (25% to 50%) in hexane was used as an eluent, so as to obtain 2.7 g (87%) of Intermediate 9-8.

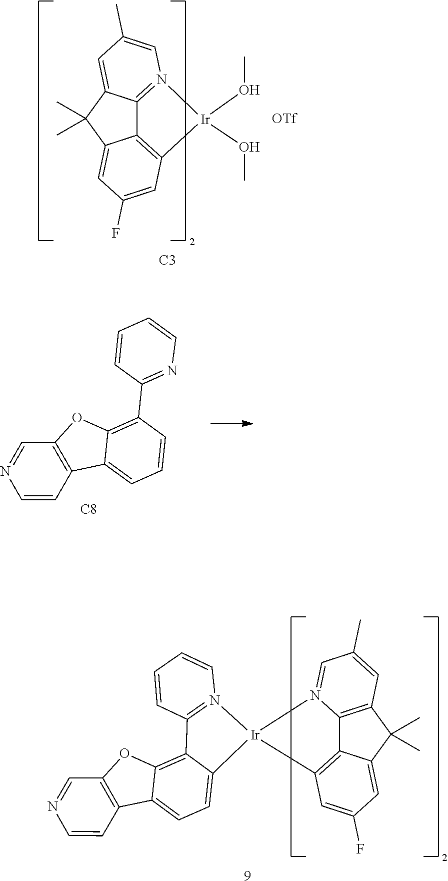

### Synthesis of Compound 9

Intermediate 9-8 (1.8 g, 7.48 mmol) was mixed together with Intermediate 9-3 (1.36 g, 1.58 mmol), and 15 mL of tridecane was added thereto. The resultant mixture was heated at 190° C. overnight. The precipitated solid was filtered, and the filtrate was purified by column chromatography eluting with dichloromethane/hexane (10%, 20%, 40%, and 50%), so as to obtain 0.30 g (21%) of Compound 9.

### Synthesis Example 2: Synthesis of Compound 16

### Synthesis of Intermediate 16-1

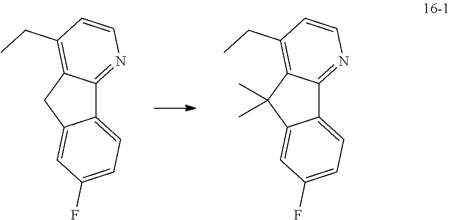 [SMILES: CCc1ccnc2c1Cc1cc(F)ccc1-2 ; CCc1ccnc2c1C(C)(C)c1cc(F)ccc1-2]

21.3 g (100 mmol) of 4-ethyl-7-fluoro-5H-indeno[1,2-b]pyridine and 38.4 g (400 mmol) of sodium tert-butoxide were suspended in 300 ml of DMF. The resultant suspension was stirred at 60° C. for 30 minutes, and subsequently, 12.8 mL (205 mmol) of methyl iodide was added dropwise thereto. The resultant mixture was stirred at 60° C. for 6 hours, and 500 ml of water was added thereto. The precipitated solid was filtered, and the filtrate was washed with 100 ml of water three times and 50 ml of ethanol three times, and then, dried and recrystallized, so as to obtain 15.9 g (66%) of Intermediate 16-1.

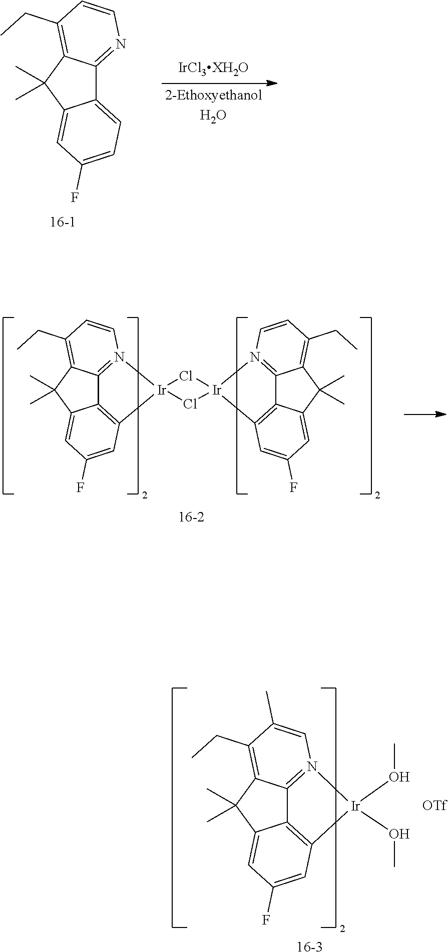

### Synthesis of Intermediate 16-2

Intermediate 16-1 (2.65 g, 11.0 mmol). IrCl₃·4H₂O (1.79 g, 4.83 mmol), 2-ethoxyethanol (45 mL), and water (105 mL) were stirred under reflux overnight under nitrogen. The resultant reaction mixture was filtered, and the filtrate was washed with 10 mL of methanol three times, and dried in a vacuum condition, so as to obtain 2.61 g (67%) of Intermediate 16-2.

### Synthesis of Intermediate 16-3

Intermediate 16-2 (2.61 g, 1.84 mmol) and trifluoromethanesulfonate (1.0 g, 3.92 mmol) were added to 200 mL of dichloromethane and 10 mL of methanol to prepare a reaction mixture. The reaction mixture was stirred for 3 hours. The precipitated solid was filtered, and the filtrate was washed with dichloromethane, dried by evaporation, and then dried again under high vacuum, so as to obtain 2.67 g (82%) of Intermediate 16-3.

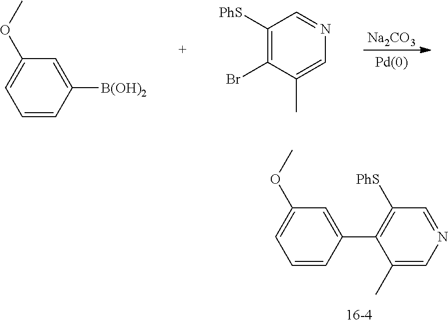

### Synthesis of Intermediate 16-4

4-bromo-3-methyl-5-(phenylthio)pyridine(38.4 g, 137 mmol), (3-methoxyphenyl)boronic acid (20.8 g, 137 mmol), and Pd(Ph₃P)₄ (4.76 g, 4.12 mmol) were added to a 2-necked flask. The resultant reaction mixture was diluted with THF (600 mL). Next, a solution in which sodium carbonate (14.56 g, 137 mmol) was dissolved in water was added thereto, and the resultant mixture was diluted with ethyl acetate and brine. An organic layer thus obtained was washed with water, and then dried by using sodium sulfate. The resulting product was separated on a silica gel chromatography column in which ethyl acetate (0% to 50%) in DMC was used as an eluent, so as to obtain 35.4 g (84%) of Intermediate 16-4.

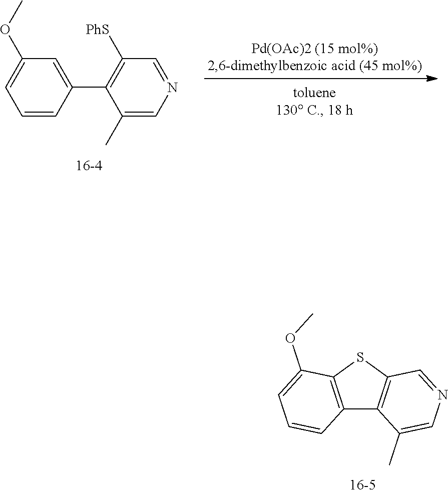

### Synthesis of Intermediate 16-5

Pd(OAc)₂ (1.2 g, 5.4 mmol), Intermediate 16-4 (11.1 g, 36.0 mmol), 2,6-dimethylbenzoate (2.4 g, 16.8 mmol), and toluene (120 mL) were added to a vial in a nitrogen atmosphere. Then, the vial was sealed, and a heating process was performed thereon at 130° C. for 18 hours. The resulting mixture was cooled to room temperature and filtered through silica gel while eluting with EtOAc. The eluate was evaporated, and the residue was purified by flash chromatography (hexane), so as to obtain a while solid, i.e., Intermediate 16-5 (7.8 g, 95%).

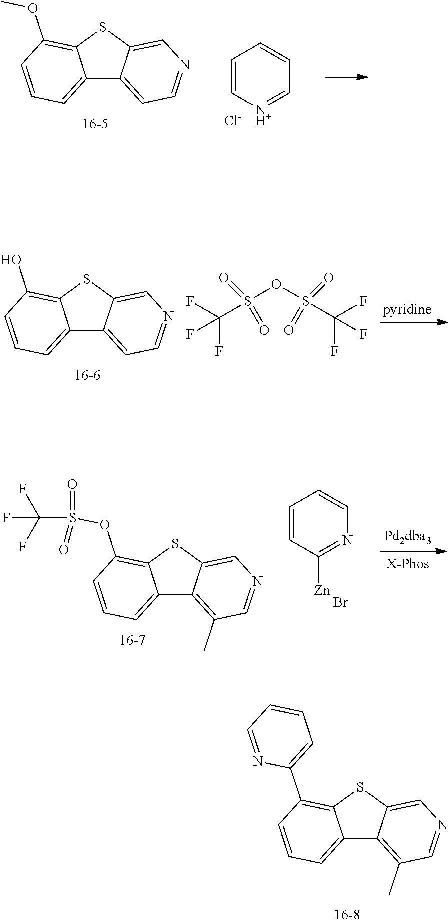

### Synthesis of Intermediate 16-6

Intermediate 16-5 (7.6 g, 33.1 mmol) and pyridine HCl (25 g) were added to a 250 mL round-bottom flask. The resultant mixture was stirred at 200° C. for 10 hours in an oil bath, and aqueous sodium bicarbonate and DCM were added thereto. An organic layer thus obtained was dried and evaporated to a brown solid, so as to obtain 5.9 g (83%) of Intermediate 16-6.

### Synthesis of Intermediate 16-7

Intermediate 16-6 (5.9 g, 27.5 mmol) was added to a 500 mL round-bottom flask, and DCM (250 mL) was added thereto. Pyridine (6.01 mL, 74.3 mmol) was also added thereto, and the flask was placed in an ice bath. Triflic anhydride (7.5 mL, 44.6 mmol) was dissolved in DCM (30 mL) and added dropwise to the flask for 10 minutes. After the bath was removed, the resultant reaction mixture was heated to the ambient temperature, and then stirred overnight. The resulting solution was washed with saturated sodium bicarbonate solution, followed by water. The resulting product was subjected to silica gel chromatography in which DCM was used as an eluent, so as to obtain 8.2 g (86%) of Intermediate 16-7.

### Synthesis of Intermediate 16-8

Intermediate 16-7 (4.4 g, 12.61 mmol), X-Phos (0.481 g, 1.009 mmol), and Pd₂dba₃ (0.231 g, 0.252 mmol) were added to a 250 mL three-necked flask. After the flask was evacuated and backfilled with nitrogen, THF (40 mL) and pyridine-2-yl zinc(II) bromide (37.8 mL, 18.91 mmol) were added thereto. The resultant mixture was stirred at 70° C. for 4 hours in an oil bath. The resulting mixture was filtered through Celite®, and the filtrate was washed with ethyl acetate. A crude material thus obtained was absorbed on Celite®, and then subjected to silica gel chromatography in which ethyl acetate (25% to 50%) in hexane was used as an eluent, so as to obtain 2.9 g (84%) of Intermediate 16-8.

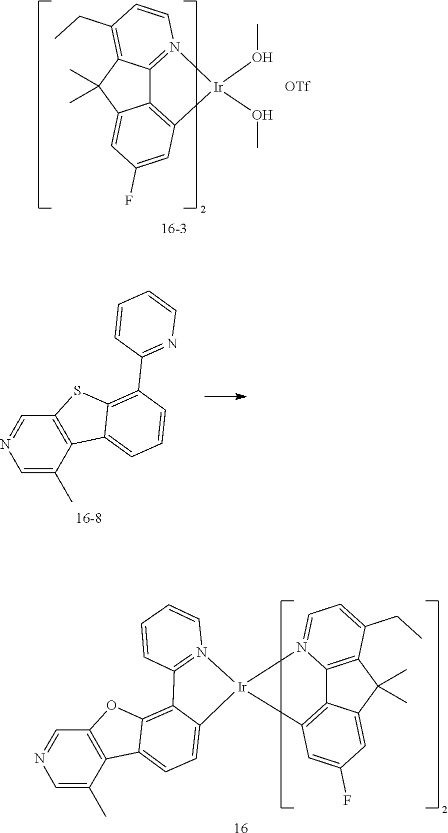

### Synthesis of Compound 16

Intermediate 16-8 (2.07 g, 7.48 mmol) was mixed together with Intermediate 16-3 (1.4 g, 1.58 mmol), and 15 mL of tridecane was added thereto. The resultant mixture was heated at 190° C. overnight. The precipitated solid was filtered, and the filtrate was purified by column chromatography eluting with dichloromethane/hexane (10%, 20%, 40%, and 50%), so as to obtain 345 mg (23%) of Compound 16.

Compounds 1 to 5, 7, 10, and 11 of Table 1 were synthesized in substantially the same manner as in Synthesis Example 1, except that substituents were changed with respect to regarding the reactants in Synthesis Examples 1 and 2

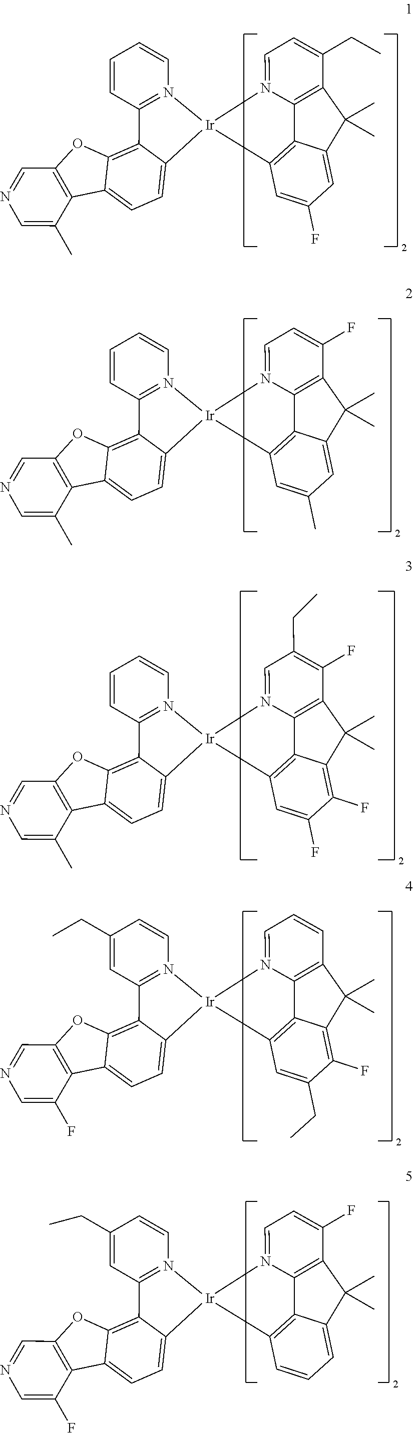

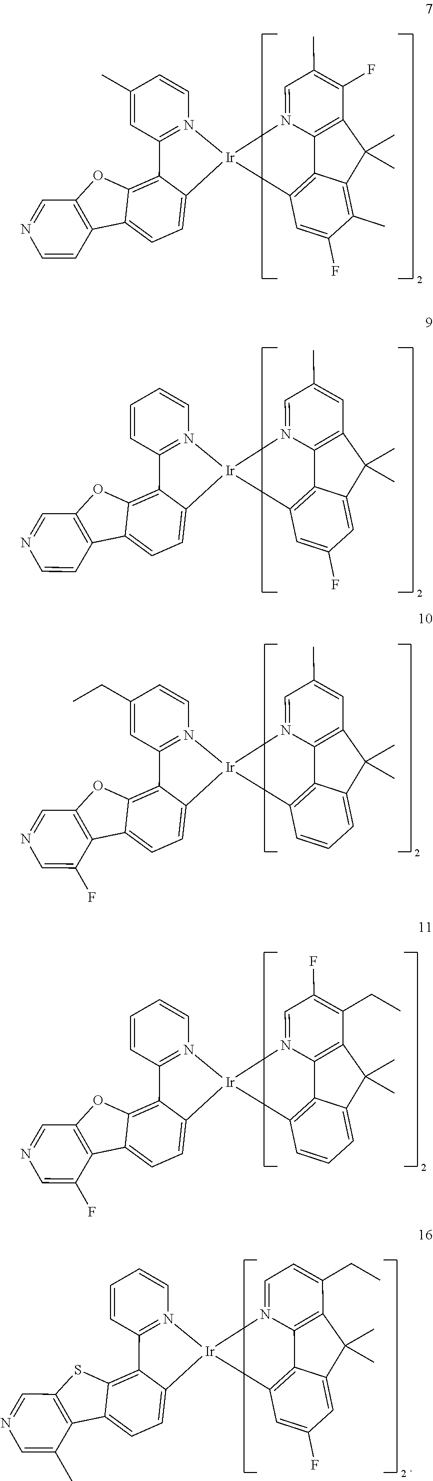

For the compounds synthesized in the Synthesis Examples above, ¹ nuclear magnetic resonance (NMR) and high-resolution mass (HR-MS) spectra were measured, and the results are shown in Table 1. Synthesis methods of compounds other than the compounds synthesized in Synthesis Examples above may be easily recognized by those skilled in the art by referring to the synthesis paths and source materials disclosed herein.

TABLE 1

| | | HR-MS (m/z) | |
|---|---|---|---|
| | | [M⁺] | |
| Compound | ¹H NMR (CDCl₃, 500 MHz) | found | calc. |
| 1 | δ ppm 8.58-8.52 (4H, m), 8.45 (1H, s), 8.05 | 932.4 | 932.29 |
| | (1H, d, J = 7.5 Hz), 7.77 (1H, dd, J = 7.6, 1.6 Hz), | | |
| | 7.70 (1H, d, J = 7.6 Hz), 7.36 (1H, td, J = 7.5, 1.5 | | |
| | Hz), 7.07 (4H, d, J = 7.5 Hz), 6.99-6.93 (3H, m), | | |
| | 3.57 (4H, q, J = 8.0 Hz), 2.44 (3H, s), 1.79 (12H, | | |
| | 1s), 1.15 (6H, t, J = 8.1 Hz) | | |
| 2 | δ ppm 8.56-8.48 (4H, m), 8.44 (1H, s), 7.90 | 904.3 | 904.26 |
| | (1H, d, J = 7.5 Hz), 7.92 (1H, dd, J = 7.6, 1.5 Hz), | | |
| | 7.58 (1H, d, J = 7.5 Hz), 7.44 (1H, td, J = 7.6, 1.6 | | |
| | Hz), 7.30-7.28 (4H, m), 7.00 (1H, td, J = 7.6, 1.6 | | |
| | Hz), 6.65 (2H, t, J = 7.5 Hz), 2.36 (9H, s), 1.70 | | |
| | (12H, 1s) | | |
| 3 | δ ppm 8.59-8.47 (4H, m), 8.34 (1H, s), 7.95 | 1004.3 | 1004.25 |
| | (1H, d, J = 7.5 Hz), 7.81 (1H, dd, J = 7.6, 1.6 Hz), | | |
| | 7.54 (1H, d, J = 7.5 Hz), 7.34 (1H, td, J = 7.5, 1.5 | | |
| | Hz), 7.15-7.07 (2H, m), 6.94 (1H, td, J = 7.6, 1.6 | | |
| | Hz), 2.69 (4H, q, J = 8.0 Hz), 2.43 (3H, s), 1.61 | | |
| | (12H, 1s), 1.17 (6H, t, J = 8.1 Hz) | | |
| 4 | δ ppm 8.57-8.51 (3H, m), 8.38 (1H, d, J = 8.1 | 949.3 | 949.27 |
| | Hz), 8.37 (1H, s), 7.89 (1H, d, J = 7.5 Hz), 7.81 | | |
| | (1H, d, J = 1.6 Hz), 7.47 (1H, d, J = 7.6 Hz), 7.35- | | |
| | 7.29 (4H, m), 7.05 (1H, dd, J = 7.5, 1.5 Hz), 6.76 | | |
| | (2H, t, J = 7.5 Hz), 3.55 (2H, q, J = 8.0 Hz), 2.73 | | |
| | (4H, q, J = 8.0 Hz), 1.70 (12H, s), 1.21 (9H, t, | | |
| | J = 8.1 Hz) | | |
| 5 | δ ppm 8.56-8.48 (4H, m), 8.46 (1H, d, J = 8.1 | 908.2 | 908.23 |
| | Hz), 8.37 (1H, s), 8.02 (1H, d, J = 7.5 Hz), 7.76 | | |
| | (1H, d, J = 1.6 Hz), 7.48-7.34 (6H, m), 7.01 (1H, | | |
| | dd, J = 7.6, 1.6 Hz), 6.60 (2H, t, J = 7.6 Hz), 3.58 | | |
| | (2H, q, J = 8.1 Hz), 1.73 (12H, s), 1.18 (3H, t, | | |
| | J = 8.1 Hz) | | |
| 7 | δ ppm 8.60-8.40 (4H, m), 8.24 (1H, d, J = 8.0 | 968.4 | 968.27 |
| | Hz), 7.88 (1H, d, J = 7.6 Hz), 7.80 (1H, d, J = 1.6 | | |
| | Hz), 7.48 (1H, d, J = 7.5 Hz), 7.33 (1H, d, J = 7.5 | | |
| | Hz), 7.11-7.05 (3H, m), 2.54 (3H, s), 2.35 (6H, | | |
| | s), 2.36 (6H, s), 1.74 (12H, s) | | |
| 9 | δ ppm 8.61-8.50 (4H, m), 8.47 (1H, d, J = 7.6 | 890.2 | 890.24 |
| | Hz), 7.98 (1H, d, J = 7.6 Hz), 7.80 (1H, dd, | | |
| | J = 7.5, 1.6 Hz), 7.53 (1H, d, J = 7.5 Hz), 7.42- | | |
| | 7.34 (2H, m), 7.16-7.10 (6H, m), 6.85 (1H, td, | | |
| | J = 7.6, 1.6 Hz), 2.22 (6H, s), 1.72 (12H, s) | | |
| 10 | δ ppm 8.55 (1H, d, J = 7.6 Hz), 8.50 (2H, d, | 900.4 | 900.28 |
| | J = 1.5 Hz), 8.37 (1H, d, J = 8.0 Hz), 8.29 (1H, s), | | |
| | 7.98 (1H, d, J = 7.5 Hz), 7.81 (1H, d, J = 1.6 Hz), | | |
| | 7.57 (1H, d, J = 7.6 Hz), 7.48-7.34 (6H, m), 7.16 | | |
| | (2H, d, J = 1.6 Hz), 7.07 (1H, dd, J = 7.6, 1.6 Hz), | | |
| | 3.47 (2H, q, J = 8.0 Hz), 2.25 (6H, s), 1.70 (12H, | | |
| | s), 1.20 (3H, t, J = 8.1 Hz) | | |
| 11 | δ ppm 8.65 (1H, dd, J = 7.6, 1.6 Hz), 8.46 (1H, d, | 936.3 | 936.26 |
| | J = 8.0 Hz), 8.36 (1H, s), 8.29 (2H, d, J = 8.0 Hz), | | |
| | 7.90 (1H, d, J = 7.6 Hz), 7.86 (1H, dd, J = 7.5, 1.5 | | |
| | Hz), 7.53 (1H, d, J = 7.5 Hz), 7.48-7.34 (7H, m), | | |
| | 7.00 (1H, td, J = 7.5, 1.5 Hz), 3.58 (4H, q, J = 8.0 | | |
| | Hz), 1.62 (12H, s), 1.19 (6H, t, J = 8.1 Hz) | | |
| 16 | δ ppm 8.59-8.52 (4H, m), 8.41 (1H, s), 8.16 | 948.3 | 948.26 |
| | (1H, d, J = 7.5 Hz), 7.89 (1H, dd, J = 7.6, 1.6 Hz), | | |
| | 7.71 (1H, d, J = 7.6 Hz), 7.40 (1H, td, J = 7.5, 1.5 | | |
| | Hz), 7.14 (4H, d, J = 8.1 Hz), 6.97 (2H, d, J = 7.6 | | |
| | Hz), 7.02 (1H, dd, J = 7.5, 1.6 Hz), 3.52 (4H, q, | | |
| | J = 8.0 Hz), 2.41 (3H, s), 1.70 (12H, s), 1.13 (6H, | | |
| | t, J = 8.1 Hz) | | |

### Evaluation Example 1: Evaluation of Material Properties

According to methods described in Table 2, the reorganization energy and triplet (T₁) energy were evaluated for the synthesized compounds, and the results are shown in Table 3.

TABLE 2

| | |
|---|---|
| Reorganization | Using density functional theory (DFT) calculation, reorganization |
| energy | energy was calculated by subtracting energy value at the S0 state |
| (G) | in T1 structure (E(S0; S0), corresponding to D in FIG. 7) of a |
| | compound from an energy value at the S0 state in S0 structure |
| | (E(S0; T1), corresponding to C in FIG. 7) of the compound. |
| | The DFT-based calculation was carried out utilizing Gaussian09, |
| | which is a commercial program, and using 6-311G(d, p) basis set |
| | and B3LYP exchange-correlation function. |
| Triplet (T₁) | Using unrestricted density functional theory (UDFT) calculation, a |
| energy | structure at the triplet excited state was optimized, and energy |
| | corresponding thereto was calculated. |
| | The UDFT-based calculation was carried out utilizing Gaussian09, |
| | which is a commercial program, and using 6-311G(d, p) basis set |
| | and B3LYP exchange-correlation function. |

TABLE 3

| | Reorganization energy | |
|---|---|---|
| Compound | (eV) | T₁ (eV) |
| 1 | 0.205 | 2.45 |
| 2 | 0.203 | 2.42 |
| 3 | 0.214 | 2.45 |
| 4 | 0.208 | 2.44 |
| 5 | 0.207 | 2.45 |
| 7 | 0.209 | 2.44 |
| 9 | 0.205 | 2.43 |
| 10 | 0.202 | 2.44 |
| 11 | 0.200 | 2.43 |
| 16 | 0.218 | 2.44 |
| C1 | 0.252 | 2.53 |
| C2 | 0.259 | 2.86 |
| C3 | 0.244 | 2.49 |
| C4 | 0.267 | 2.60 |
| C5 | 0.204 | 2.41 |
| C6 | 0.204 | 2.41 |
| C7 | 0.246 | 2.56 |
| C8 | 0.250 | 2.60 |

Referring to Table 3, it can be seen that unlike Compounds C1 to C4, C7, and C8, Compounds 1, 2, 3, 4, 5, 7, 9, 10, 11, and 16 had reorganization energy levels of less than or equal to 0.22 eV, and that as compared with Compounds C1 to C4, C7, and C8, the triplet energy values of Compounds 1, 2, 3, 4, 5, 7, 9, 10, 11, and 16 were suitable for the dopants of green light.

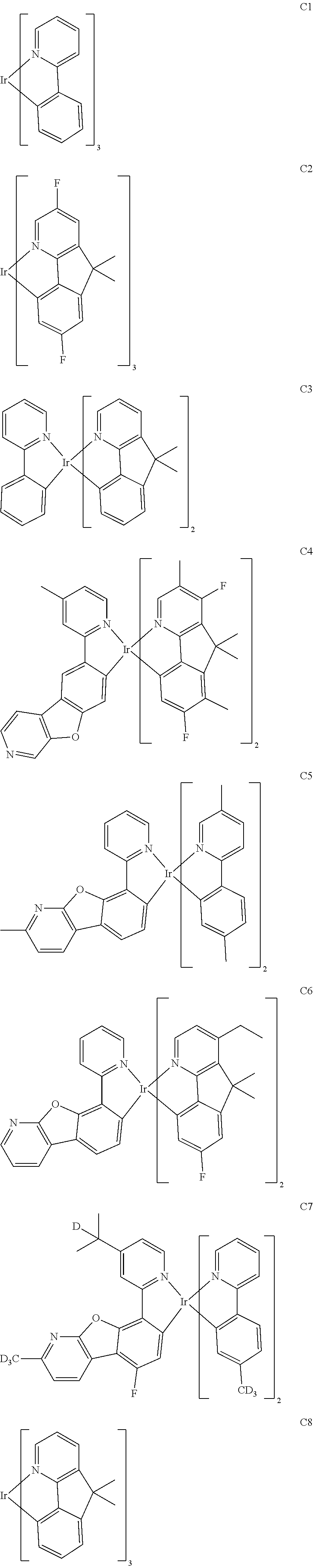

### Evaluation Example 2: Evaluation of PL Spectrum

After mixing together PMMA and Compound 1 (4 wt % relative to PMMA) in CH₂Cl₂ solution, the resulting product was applied to a quartz substrate by using a spin coater. Heat treatment was then performed thereon in an oven at 80° C., followed by cooling at room temperature, so as to prepare Film 1 having a thickness of 40 nm. Subsequently, except that Compounds 2, 3, 4, 5, 7, 9, 10, 11, 16, and C1 to C8 were each used instead of Compound 1, Films 2, 3, 4, 5, 7, 9, 11, 16, and C1 to C8 were prepared by using substantially the same method used for the preparation of Film 1.

For each of Films 1, 2, 3, 4, 5, 7, 9, 10, 11, 16, and C1 to C8, the luminescence spectrum was measured by a Quantaurus-QY Absolute PL quantum yield spectrometer manufactured by Hamamatsu Company (equipped with a xenon light source, a monochromator, a photonic multichannel analyzer, and an integrating sphere, and using a PLQY measurement software (Hamamatsu Photonics, Ltd., Shizuoka, Japan)). At the time of measurement, the excitation wavelength was scanned at 10 nm intervals between 320 nm and 380 nm, and the spectrum measured at the excitation wavelength of 340 nm was taken therefrom. Then, a wavelength (e.g., a maximum emission wavelength) of the first peak, an intensity ratio (I₂/I₁) of the second peak to the first peak, and FWHM of the compounds included in each film were obtained, and summarized in Table 4.

TABLE 4

| | | Wavelength | | |
|---|---|---|---|---|
| | | of first peak | Intensity of second | |
| | | _{λ}₁ | peak to | FWHM |
| | Compound | (nm) | first peak | (nm) |
| Film 1 | 1 | 525 | 0.54 | 52 |
| Film 2 | 2 | 530 | 0.53 | 53 |
| Film 3 | 3 | 520 | 0.57 | 52 |
| Film 4 | 4 | 525 | 0.54 | 53 |
| Film 5 | 5 | 522 | 0.54 | 53 |
| Film 7 | 7 | 525 | 0.55 | 53 |
| Film 9 | 9 | 528 | 0.53 | 52 |
| Film 10 | 10 | 529 | 0.52 | 53 |
| Film 11 | 11 | 529 | 0.52 | 52 |
| Film 16 | 16 | 526 | 0.56 | 55 |
| Film C1 | C1 | 514 | 0.64 | 62 |
| Film C2 | C2 | 494 | 0.72 | 54 |
| Film C3 | C3 | 492 | 0.65 | 53 |
| Film C4 | C4 | 491 | 0.76 | 51 |
| Film C5 | C5 | 539 | 0.52 | 55 |
| Film C6 | C6 | 534 | 0.53 | 54 |
| Film C7 | C7 | 506 | 0.66 | 55 |
| Film C8 | C8 | 493 | 0.70 | 52 |

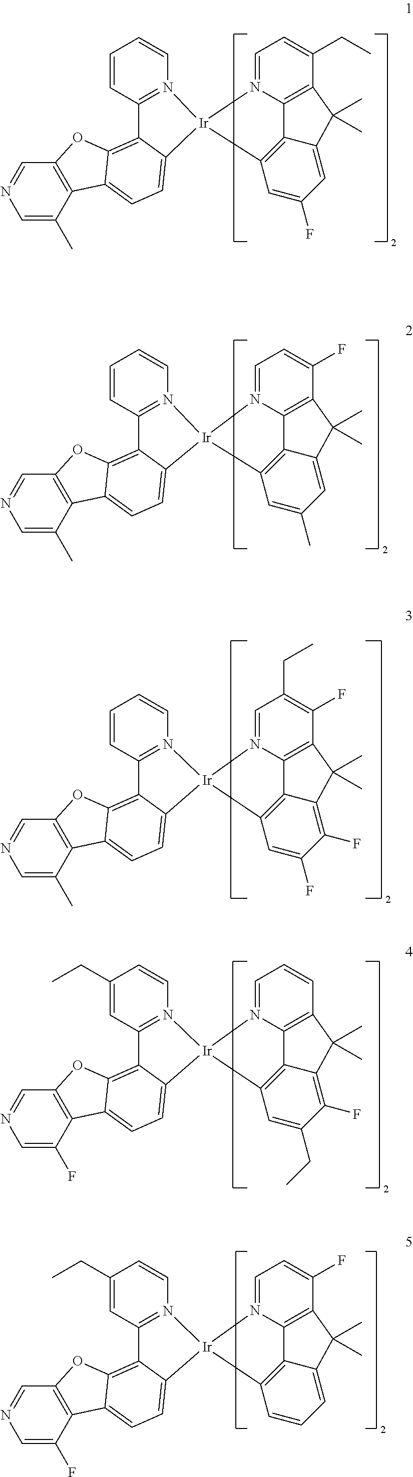

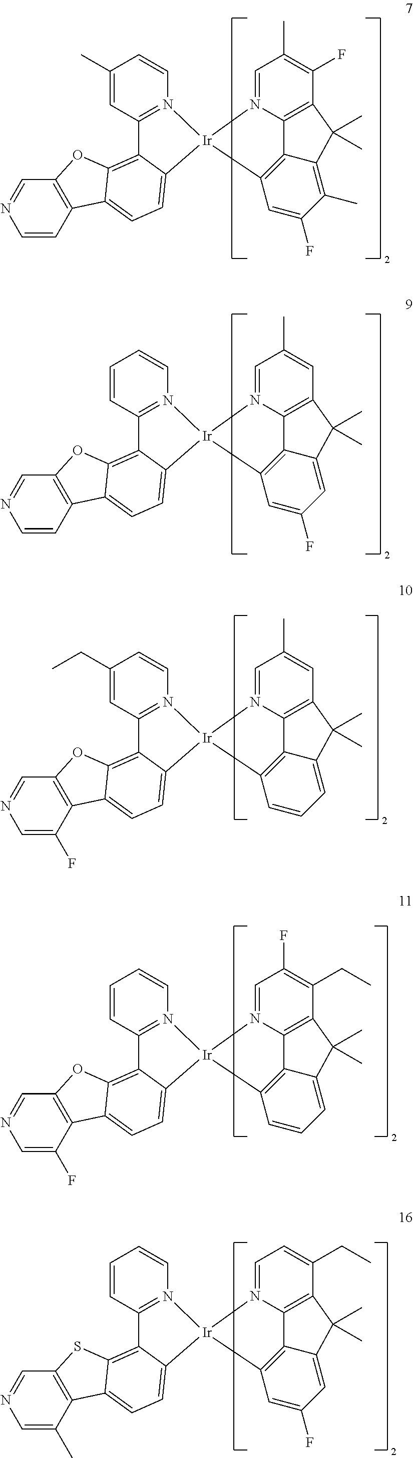

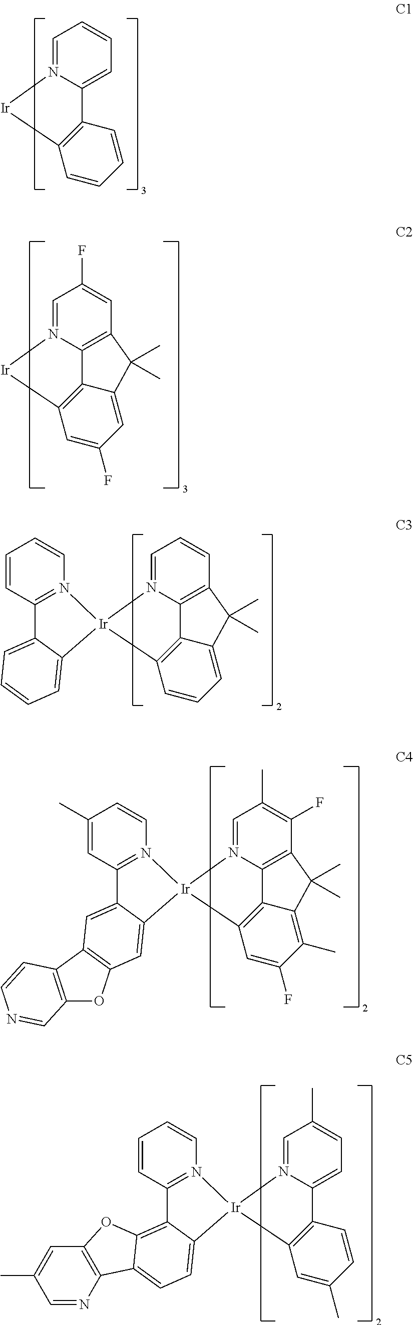

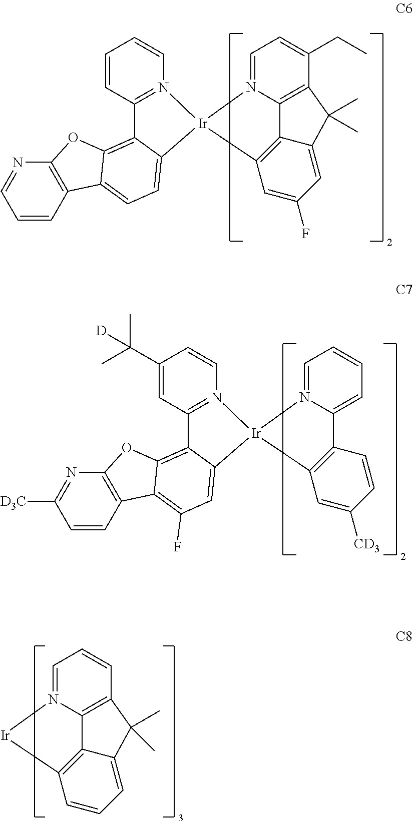

Referring to Table 4, it can be seen that, unlike Compounds C1 to C8, Compounds 1, 2, 3, 4, 5, 7, 9, 10, 11, and 16 each had the first peak having a wavelength satisfied within a range of 515 nm to 530 nm, and the intensity of the second peak was satisfied to be at least about 40% and not more than about 60% compared to the first peak. In addition, it can be seen that, as compared with Compounds C1 to C8, Compounds 1, 2, 3, 4, 5, 7, 9, 10, 11, and 16 emitted green light having relatively smaller or equivalent FWHM.

### Example 1

As an anode, a glass substrate (product of Corning Inc.) with a 15 Ω/cm² (1,200 Å) ITO formed thereon was cut to a size of 50 mm×50 mm×0.7 mm, sonicated by using isopropyl alcohol and pure water each for 5 minutes, cleaned by irradiation of ultraviolet rays and exposure of ozone thereto for 30 minutes, and then mounted on a vacuum deposition apparatus.

Compound HT3 was vacuum-deposited on the anode to form a hole injection layer having a thickness of 600 Å, and Compound HT40 was vacuum-deposited on the hole injection layer to form an emission auxiliary layer having a thickness of 250 Å.

Compound H125, Compound H126, and Compound 1 (dopant) were vacuum-deposited at a weight ratio of 45:45:10 on the emission auxiliary layer to form an emission layer having a thickness of 300 Å.

Compound ET37 was vacuum-deposited on the emission layer to form a buffer layer having a thickness of 50 Å, and Compound ET46 and LiQ were vacuum-deposited at a weight ratio of 5:5 on the buffer layer to form an electron transport layer having a thickness of 310 Å. Subsequently, Yb was vacuum-deposited on the electron transport layer to form an electron injection layer having a thickness of 15 Å, and Ag and Mg were vacuum-deposited thereon to form a cathode having a thickness of 100 Å.

Next, Compound CP7 was vacuum-deposited on the cathode to form a capping layer having a thickness of 700 Å, thereby completing the manufacture of a

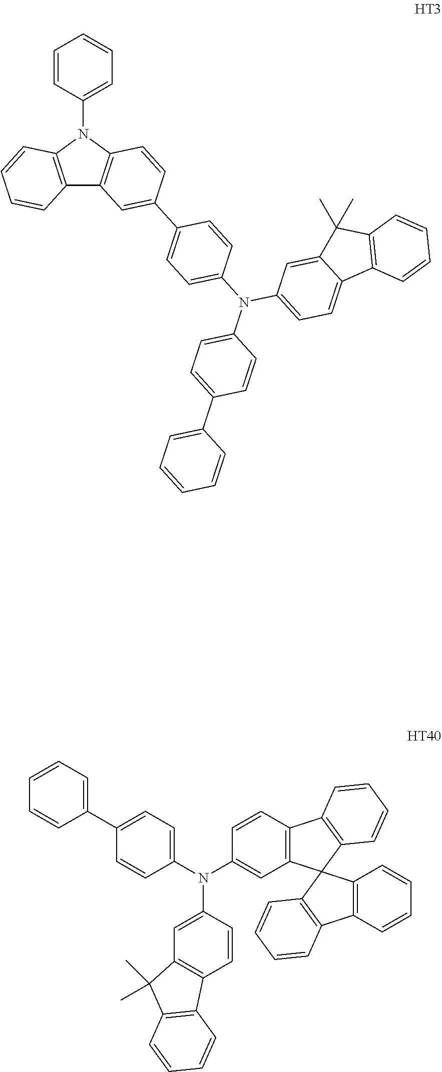 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21]

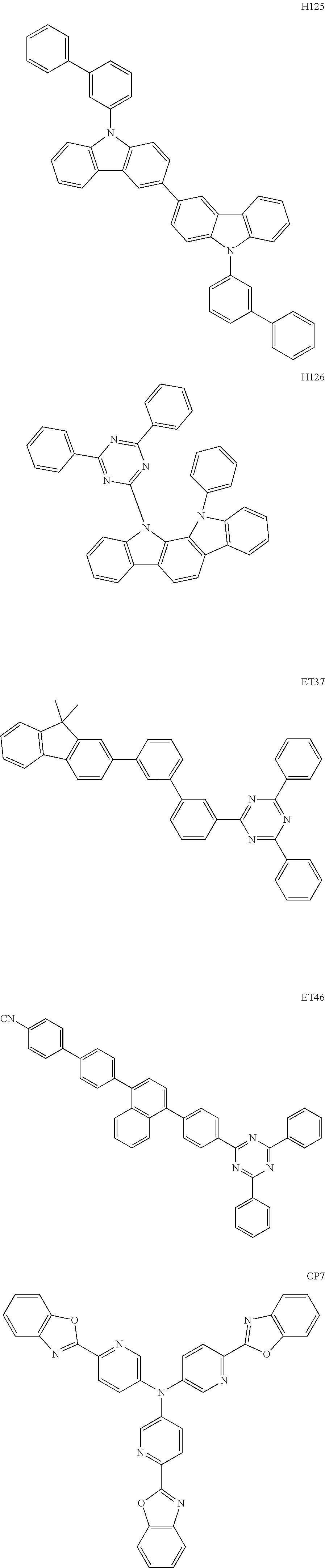

### Examples 2 to 10 and Comparative Examples 1 to 8

Light-emitting devices were manufactured in substantially the same manner as in Example 1, except that compounds shown in Table 5 were each used instead of Compound 1 in forming an emission layer.

### Evaluation Example 3

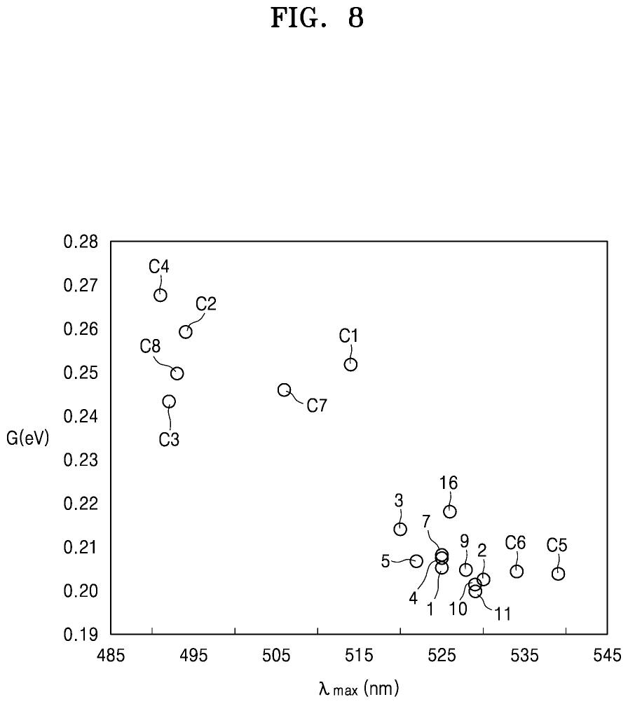

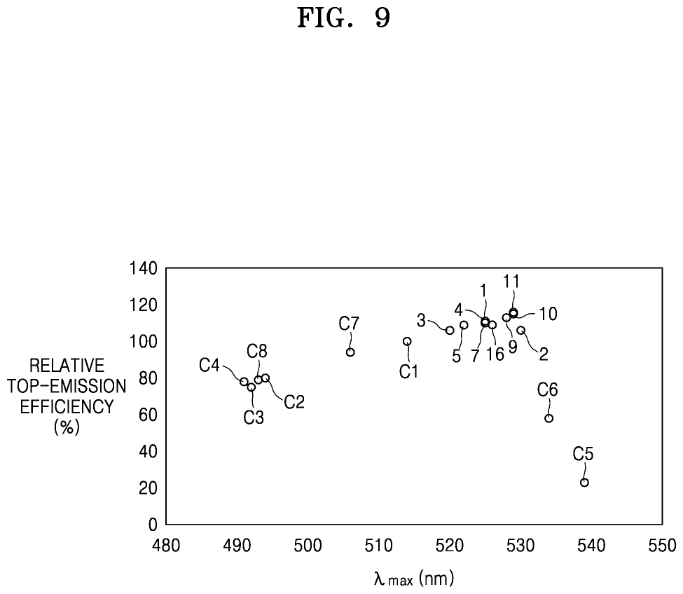

D The maximum emission wavelength, color purity (CIEx and CIEy coordinates) at 400 cd/m², and top-emission efficiency (at 0⁰) of the light-emitting devices of Examples 1 to 10 and Comparative Examples 1 to 8 were evaluated by using a luminance meter (Minolta Cs-1000A), and the results are shown in Table 5 and FIGS. 8 and 9. Here, the top-emission efficiency represents a value obtained by converting the efficiency value of Comparative Example 1 on the basis of 100%.

TABLE 5

| | | Top-emission | | | |
|---|---|---|---|---|---|
| | | efficiency (at | Maximum | | |
| | | 0°)(relative to | emission | | |
| | | Comparative | wavelength | | |
| | Dopant | Example 1) | (nm) | CIEx | CIEy |
| Example1 | 1 | 111% | 525 | 0.255 | 0.716 |
| Example 2 | 2 | 106% | 530 | 0.26 | 0.714 |
| Example 3 | 3 | 106% | 520 | 0.26 | 0.708 |
| Example 4 | 4 | 111% | 525 | 0.256 | 0.715 |
| Example 5 | 5 | 109% | 522 | 0.259 | 0.71 |
| Example 6 | 7 | 110% | 525 | 0.256 | 0.715 |
| Example 7 | 9 | 113% | 528 | 0.258 | 0.716 |
| Example 8 | 10 | 115% | 529 | 0.259 | 0.716 |
| Example 9 | 11 | 116% | 529 | 0.259 | 0.716 |
| Example 10 | 16 | 109% | 526 | 0.26 | 0.713 |
| Comparative | C1 | 100% | 514 | 0.259 | 0.703 |
| Example 1 | | | | | |
| Comparative | C2 | 80% | 494 | 0.185 | 0.715 |
| Example 2 | | | | | |
| Comparative | C3 | 75% | 492 | 0.163 | 0.708 |
| Example 3 | | | | | |
| Comparative | C4 | 78% | 491 | 0.180 | 0.711 |
| Example 4 | | | | | |
| Comparative | C5 | 23% | 539 | 0.259 | 0.716 |
| Example 5 | | | | | |
| Comparative | C6 | 58% | 534 | 0.26 | 0.713 |
| Example 6 | | | | | |
| Comparative | C7 | 94% | 506 | 0.237 | 0.712 |
| Example 7 | | | | | |
| Comparative | C8 | 79% | 493 | 0.181 | 0.714 |
| Example 8 | | | | | |

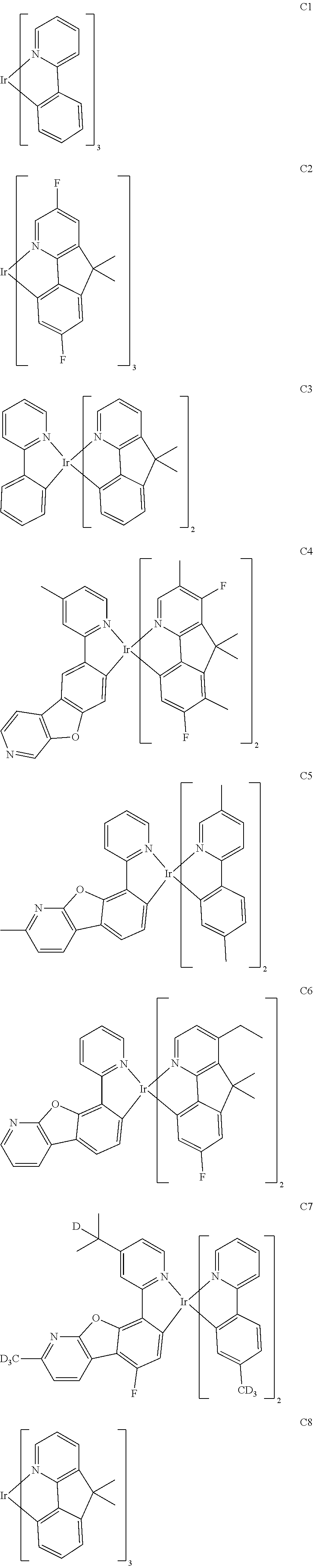

Referring to Tables 3 to 5, it can be seen that the light-emitting devices of Examples 1 to 8 employing Compounds 1, 2, 3, 4, 5, 7, 9, 11, and 16 of which the first peak had a wavelength satisfied within a range of 515 nm to 530 nm, the reorganization energy was less than or equal to 0.22 eV, the intensity of the second peak was at least about 40% and not more than about 60% compared to the intensity of the first peak had improved top-emission efficiency as compared with the light-emitting devices of Comparative Examples 1 to 8.

In addition, FIG. 8 is a diagram showing the reorganization energy relative to the maximum emission wavelength (e.g., the wavelength of the first peak) of the light-emitting devices of Examples 1 to 10 and Comparative Examples 1 to 9, and FIG. 9 is a diagram showing top-emission efficiency relative to the maximum emission wavelength (e.g., the wavelength of the first peak) of the light-emitting devices of Examples 1 to 10 and Comparative Examples 1 to 9. In FIGS. 8 and 9, values of the colored areas refer to areas including the values of Examples 1 to 10.

Referring to FIGS. 8 and 9, it can be seen that, when the wavelength of the first peak, e.g., the maximum emission wavelength, was satisfied a range of 515 nm to 530 nm and the reorganization energy was less than or equal to 0.22 eV, excellent top emission efficiency was obtained.

As described above, according to the one or more embodiments, an organometallic compound satisfies a maximum emission wavelength range, an intensity of a second peak, and/or a reorganization energy at certain ranges, and thus may have low FWHM and excellent electrical characteristics. Therefore, a light-emitting device including the organometallic compound may have excellent top-emission efficiency, and thus by using such a light-emitting device, high-quality electronic apparatus and electronic equipment may be manufactured.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and equivalents thereof.

What is claimed is:

1. An organometallic compound comprising iridium,
wherein the organometallic compound emits a first light,
a photoluminescence (PL) spectrum of the first light has a first peak (Iₘₐₓ) having a maximum intensity and a second peak (I_{2nd}) having a second highest intensity, and
the organometallic compound satisfies Condition 1 and at least one selected from Conditions 2 and 3:
Condition 1
a wavelength of the first peak is in a range of 515 nm to 530 nm;
Condition 2
an intensity of the second peak is at least 40% and not more than 60% compared to an intensity of the first peak; and
Condition 3
a reorganization energy value of the organometallic compound is less than or equal to 0.22 eV.

2. The organometallic compound of claim 1, wherein the first light is green light.

3. The organometallic compound of claim 1, wherein all of Conditions 1 to 3 are satisfied.

4. The organometallic compound of claim 1,
wherein the organometallic compound includes a first ligand, a second ligand, and a third ligand, each bonded to iridium,
the first ligand is a bidentate ligand including ring B₁ and ring B₂,
the second ligand is a bidentate ligand including ring B₃ and ring B₄,
the third ligand is a bidentate ligand including ring B₅ and ring B₆,
ring B₂ is a polycyclic group including at least one nitrogen atom (N),
ring B₃ and ring B₄ are linked to each other via linkers T₁ and T₂, and
T₁ is an alkylene group, and T₂ is a single bond.

5. An organometallic compound comprising iridium,
wherein the organometallic compound includes a first ligand, a second ligand, and a third ligand, each bonded to iridium,
the first ligand is a bidentate ligand including ring B₁ and ring B₂,
the second ligand is a bidentate ligand including ring B₃ and ring B₄,
the third ligand is a bidentate ligand including ring B₅ and ring B₆,
ring B₂ is a polycyclic group including at least one nitrogen atom (N),
ring B₃ and ring B₄ are linked to each other via linkers T₁ and T₂, and
T₁ is an alkylene group, and T₂ is a single bond.

6. The organometallic compound of claim 5, wherein the organometallic compound satisfies at least one selected from Conditions 1 to 3:
Condition 1
the organometallic compound emits a first light,
a photoluminescence (PL) spectrum of the first light has a first peak (Iₘₐₓ) having a maximum intensity and a second peak (I_{2nd}) having a second highest intensity, and
an intensity of the second peak is at least 40% and not more than 60% compared to an intensity of the first peak;
Condition 2
the organometallic compound emits a first light,
a photoluminescence (PL) spectrum of the first light has a first peak (Iₘₐₓ) having a maximum intensity, and a wavelength of the first peak is in a range of 515 nm to 530 nm; and
Condition 3
a reorganization energy value of the organometallic compound is less than or equal to 0.22 eV.

7. The organometallic compound of claim 5, wherein the first ligand and the second ligand are different from each other.

8. The organometallic compound of claim 5, wherein ring B₂ is a polycyclic group in which at least one cyclic group in Group A1 and at least one cyclic group in Group A2 are condensed together with each other:
Group A1
a pyridine group, a pyrimidine group, a pyrazine group, a pyridazine group, and a triazine group; and
Group A2
a benzene group, a naphthalene group, a pyrrole group, a cyclopentadiene group, a borole group, a phosphole group, a silole group, a selenophene group, a furan group, a thiophene group, a pyridine group, a pyrimidine group, a pyrazine group, a pyridazine group, and a triazine group.

9. The organometallic compound of claim 5, wherein at least one selected from the first ligand, the second ligand, and the third ligand includes a substituent R_{X} which is not hydrogen.

10. The organometallic compound of claim 5, wherein T₁ is a substituted or unsubstituted methylene group or a substituted or unsubstituted ethylene group.

11. The organometallic compound of claim 5, wherein the organometallic compound is represented by Formula 1A or 1A-1: 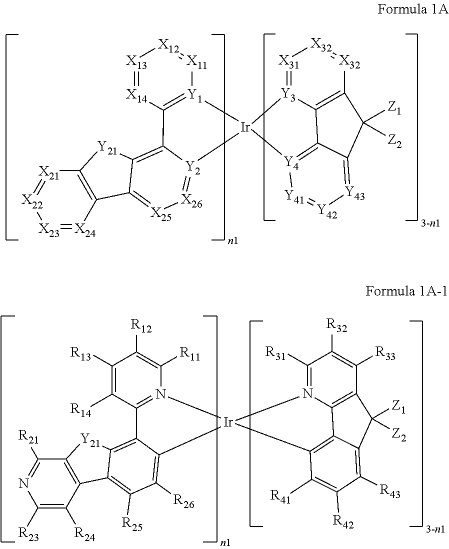
wherein, in Formulae 1A and 1A-1,
Y₁ to Y₄ are each independently C or N,
X₁₁ is C(R₁₁) or N, X₁₂ is C(R₁₂) or N, X₁₃ is C(R₁₃) or N, and X₁₄ is C(R₁₄) or N,
Y₂₁ is N(R₂₇), O, S, Se, C(R₂₇)(R₂₈), or Si(R₂₇)(R₂₈),
X₂₁ is C(R₂₁) or N, X₂₂ is C(R₂₂) or N, X₂₃ is C(R₂₃) or N, X₂₄ is C(R₂₄) or N, X₂₅ is C(R₂₅) or N, and X₂₆ is C(R₂₆) or N, wherein at least one selected from X₂₁ to X₂₆ is N,
X₃₁ is C(R₃₁) or N, X₃₂ is C(R₃₂) or N, and X₃₃ is C(R₃₃) or N,
X₄₁ is C(R₄₁) or N, X₄₂ is C(R₄₂) or N, and X₄₃ is C(R₄₃) or N,
R₁₁ to R₁₄, R₂₁ to R₂₈, R₃₁ to R₃₃, R₄₁ to R₄₃, Z₁, and Z₂ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₁-C₆₀ alkylthio group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
n1 is 1 or 2,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ arylalkyl group; or a C₂-C₆₀ heteroarylalkyl group.

12. A light-emitting device comprising:
a first electrode;
a second electrode facing the first electrode;
an interlayer between the first electrode and the second electrode; and
the organometallic compound of claim 1.

13. The light-emitting device of claim 12,
wherein the interlayer comprises an emission layer,
the emission layer comprises the organometallic compound,
the emission layer further comprises a host, and
a weight of the organometallic compound is greater than or equal to 5 parts by weight based on 100 parts by weight of the emission layer.

14. The light-emitting device of claim 12, wherein the light-emitting device emits green light.

15. The light-emitting device of claim 12, further comprising at least one selected from a first capping layer outside the first electrode and a second capping layer outside the second electrode, wherein
at least one selected from the first capping layer and the second capping layer comprises a material having a refractive index of greater than or equal to 1.6 at a wavelength of 530 nm.

16. An electronic apparatus comprising the light-emitting device of claim 12.

17. The electronic apparatus of claim 16, further comprising a thin-film transistor,
wherein the thin-film transistor comprises a source electrode and a drain electrode, and
the first electrode of the light-emitting device is electrically connected to at least one selected from the source electrode and the drain electrode of the thin-film transistor.

18. The electronic apparatus of claim 16, further comprising a color filter, a color conversion layer, a touch screen layer, a polarizing layer, or any combination thereof.

19. The electronic apparatus of claim 16, further comprising:
a thin-film transistor; and
a color filter, a color conversion layer, a touch screen layer, a polarizing layer, or any combination thereof,
wherein the thin-film transistor comprises a source electrode and a drain electrode, and
the first electrode of the light-emitting device is electrically connected to the source electrode or the drain electrode of the thin-film transistor.

20. Electronic equipment comprising the light-emitting device of claim 12,
wherein the electronic equipment is a flat panel display, a curved display, a computer monitor, a medical monitor, a television, an advertisement board, an indoor or outdoor lighting and/or signaling light, a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a 3D display, a virtual or augmented reality display, a vehicle, a video wall including multiple displays tiled together, a theater or stadium screen, a phototherapy device, or a sign.
